(19) United States
(12) Patent Application Publication
(10) Pub. No.: US 2022/0140247 A1
(43) Pub. Date: May 5, 2022

(54) PLURALITY OF HOST MATERIALS, COMPOSITION COMPRISING THE SAME, AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Yoo-Jin DOH, Gyeonggi-do (KR); Chi-Sik KIM, Gyeonggi-do (KR); Dong-Hyung LEE, Gyeonggi-do (KR); Kyung-Hoon CHOI, Gyeonggi-do (KR); Mi-Ran SEO, Gyeonggi-do (KR); Soo-Yong LEE, Gyeonggi-do (KR); Seung-Hoon YOO, Gyeonggi-do (KR); Soo-Jin HWANG, Gyeonggi-do (KR)

(21) Appl. No.: 17/516,965

(22) Filed: Nov. 2, 2021

(30) Foreign Application Priority Data
Nov. 5, 2020 (KR) 10-2020-0146634
Oct. 21, 2021 (KR) 10-2021-0140712

(51) Int. Cl. H01L 51/00; C09K 11/02; C09K 11/06

(52) U.S. Cl. CPC H01L 51/0058; C09K 11/02; C09K 11/06; H01L 51/5012; C09K 2211/1018; C09K 2211/1014; C09K 2211/1007; H01L 51/0073

(57) ABSTRACT

The present disclosure relates to a plurality of host materials, a composition comprising the same, and an organic electroluminescent device comprising the same. By comprising the plurality of host materials and the composition comprising the same according to the present disclosure as a light-emitting material, an organic electroluminescent device having low driving voltage and/or high luminous efficiency and/or long lifespan property can be provided.

### TECHNICAL FIELD

The present disclosure relates to a plurality of host materials, a composition comprising the same, and an organic electroluminescent device comprising the same.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987, by using small aromatic diamine molecules and aluminum complexes as materials for forming a light-emitting layer [Appl. Phys. Lett. 51, 913, 1987].

An organic electroluminescent device (OLED) changes electric energy into light by applying electricity to an organic electroluminescent material, and the most important factor determining luminous efficiency in an OLED is the light-emitting material used. The light-emitting material must have high quantum efficiency and high mobility of electrons and holes, and the formed light-emitting material layer must be uniform and stable. Desirable properties of the host material serving as a solid-state solvent and energy transporter must have high purity and a suitable molecular weight to enable vacuum deposition. In addition, it is preferable that the glass transition temperature and thermal decomposition temperature of the host material are high, and thus thermal stability must be ensured; high electrochemical stability is required for long lifespan property; the host material must easily form an amorphous thin film; and the host material must have good adhesion to the materials of other adjacent layers without interlayer movement.

To realize an organic electroluminescent device exhibiting high efficiency and long lifespan property, two or more host materials (co-hosts) are used in the light-emitting layer. The light-emitting layer including a plurality of host materials may be formed by co-deposition or mixed deposition. The co-deposition is a mixed deposition method in which two or more isomer materials are put into respective individual crucible sources and a current is applied to both cells simultaneously to evaporate the materials and to perform mixed deposition: and the mixed deposition is a mixed deposition method in which two or more isomer materials are mixed in one crucible source before deposition, and then a current is applied to one cell to evaporate the materials.

However, when the light-emitting layer is formed using several sublimation crucibles as a source as in the co-deposition, there has been a problem that the process is very complicated and expensive, compared to the light-emitting layer having a single host. In addition, when two or more host materials are mixed in advance and sublimated in one crucible source as in the mixed deposition, there has been a problem that the manufacturing process can be simplified, but uniformity and consistency cannot be ensured when evaporating a plurality of materials.

The method of using a plurality of host materials has been applied to fluorescent organic electroluminescent devices in the past, and in particular, has been mainly used in the solution OLED field to improve device properties. However, in the case of a fluorescent organic electroluminescent device, the pre-mix technique as in the present disclosure was rarely applied.

To use a pre-mix host, the host must have a solubility and should not change over time in a continuous process. The anthracene-based host, which has been mostly used as a fluorescent host, is not suitable for use as a pre-mix host because it does not dissolve well.

### DISCLOSURE OF INVENTION

### Technical Problem

The object of the present disclosure is firstly, to provide a plurality of host materials comprising at least two compounds, which is able to produce an organic electroluminescent device having low driving voltage and high luminous efficiency and/or long lifespan property, and secondly, to provide a composition comprising the plurality of host materials, and an organic electroluminescent device comprising the composition.

### Solution to Problem

As a result of intensive studies to solve the technical problems above, the present inventors found that the aforementioned objective can be achieved by a plurality of host materials comprising at least two compounds wherein at least one compound(s) included in the plurality of host materials satisfies the following equation (1), and is represented by the following formula (1), and then completed the present invention.

Tm≤Td equation (1)

wherein, Tm is a melting temperature, and Td is a deposition temperature;

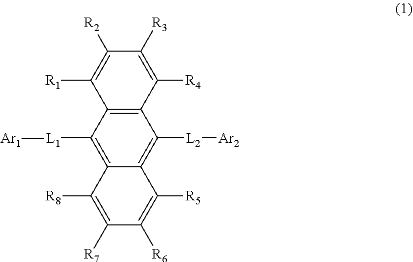

In formula 1,

L₁ and L₂ each independently represent a single bond, a substituted or unsubstituted (C6-C30)arylene, or a substituted or unsubstituted (3- to 30-membered)heteroarylene;

Ar₁ and Ar₂ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C6-C30)aryl, or a substituted or unsubstituted (3- to 30-membered)heteroaryl; and R₁ to Rₐ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

### Advantageous Effects of Invention

By comprising the plurality of host materials and the composition comprising the same according to the present disclosure, an organic electroluminescent device having low driving voltage and high luminous efficiency and/or long lifespan property can be prepared.

### MODE FOR THE INVENTION

Hereinafter, the present disclosure will be described in detail. However, the following description is intended to explain the invention, and is not meant in any way to restrict the scope of the invention.

The present disclosure relates to a plurality of host materials, a composition comprising the same, and an organic electroluminescent device comprising the same.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (containing host and dopant materials), an electron buffer material, a hole blocking material, an electron transport material, or an electron injection material, etc.

Herein, “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g. after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two host materials are comprised in one light-emitting layer, the at least two host materials may be mixture-evaporated to form a layer or may be individually and simultaneously co-evaporated to form a layer.

Herein, the term “a melting material” refers to a material in which the melting temperature (Tm) is lower than the deposition temperature (Td) when Tm cannot be measured during DSC (Differential Scanning Calorimetry) measurement, wherein the glass transition temperature (Tg) is defined as Tm. On the other hand, when it can be obtained Tm, “a melting material” means a material whose measured Tm is lower than Td. Specifically, when the melting material is heated to a process temperature in a solid powder state and then cooled, it undergoes melting to form an amorphous solid without recrystallization.

The term “(C1-C30)alkyl” in the present disclosure is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. The term “(C3-C30)cycloalkyl” in the present disclosure is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The term “(C6-C30)aryl(ene)” in the present disclosure is a monocyclic or fused ring radical derived from an aromatic hydrocarbon having 6 to 30 ring backbone carbon atoms, in which the number of the ring backbone carbon atoms is preferably 6 to 20, more preferably 6 to 15, may be partially saturated, and may include a spiro structure. Examples of the aryl specifically may be phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl spiro[fluoren-fluoren]yl, spiro[fluoren-benzofluoren]yl, azulenyl, tetramethyl-dihydrophenanthrenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11 diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. Herein, “(3- to 30-membered)heteroaryl(ene)” is an aryl having 3 to 30 ring backbone atoms including at least one, preferably 1 to 4 heteroatoms selected from the group consisting of B, N, O, S, Si, P, Se, and Ge, in which the number of the ring backbone carbon atoms is preferably 5 to 25. The above heteroaryl(ene) may be a monocyclic ring, or a fused ring condensed with at least one benzene ring; and may be partially saturated. Also, the above heteroaryl or heteroarylene herein may be one formed by linking at least one heteroaryl or aryl group to a heteroaryl group via a single bond(s). Examples of the heteroaryl specifically may be a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthiridinyl, benzofuropyrimidinyl, naphthofuropyrimidinyl, benzothienoquinolinyl, benzothienoquinazolinyl, benzothienonaphthiridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyi, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyi, 2-carbazolyi, 3-carbazolyi, 4-carbazolyi, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyi, 4-oxazolyl, 5-oxazolyl, 2-oxadiazolyl, 5-oxadiazolyi, 3-furazanyl, 2-thienyl, 3-thienyl, 2-methylpyrrol-1-yl, 2-methylpyrrol-3-yl, 2-rnethylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl. 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. The term “a fused ring of (C3-C30) aliphatic ring and (C6-C30) aromatic ring” in the present disclosure means a ring formed by fusing at least one aliphatic ring having 3 to 30 ring backbone carbon atoms in which the number of the carbon atoms is preferably 3 to 25, more preferably 3 to 18, and at least one aromatic ring having 6 to 30 ring backbone carbon atoms in which the number of the carbon atoms is preferably 6 to 25, more preferably 6 to 18. For example, the fused ring may be a fused ring of at least one benzene and at least one cyclohexane, or a fused ring of at least one naphthalene and at least one cyclopentane, etc. The carbon atoms in the fused ring of (C3-C30) aliphatic ring and (C6-C30) aromatic ring of the present disclosure may be replaced with at least one heteroatoms selected from B, N, O, S, Si and P, preferably at least one heteroatoms selected from N, O and S. The term “halogen” in the present disclosure includes F, C, Br, and I.

In addition, “ortho (o),” “meta (m),” and “para (p)” are meant to signify the substitution position of all substituents. Ortho position is a compound with substituents, which are adjacent to each other, e.g., at the 1 and 2 positions on benzene. Meta position is the next substitution position of the immediately adjacent substitution position, e.g., a compound with substituents at the 1 and 3 positions on benzene. Para position is the next substitution position of the meta position, e.g., a compound with substituents at the 1 and 4 positions on benzene.

Herein, “a ring formed in linking to an adjacent substituent” means a substituted or unsubstituted (3- to 30-membered) mono- or polycyclic, alicyclic, aromatic ring, or a combination thereof, formed by linking or fusing two or more adjacent substituents, preferably may be a substituted or unsubstituted (3- to 26-membered) mono- or polycyclic, alicyclic, aromatic ring, or a combination thereof. Further, the formed ring may include at least one heteroatom selected from the group consisting of B, N, O, S, Si and P, preferably, N, O and S. According to one embodiment of the present disclosure, the number of atoms in the ring skeleton is 5 to 20; according to another embodiment of the present disclosure, the number of atoms in the ring skeleton is 5 to 15. In one embodiment, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, a substituted or unsubstituted carbazole ring, etc.

In addition, “substituted” in the expression “substituted or unsubstituted” means that a hydrogen atom in a certain functional group is replaced with another atom or functional group, i.e., a substituent, and substituted with a group to which two or more substituents are connected among the substituents. For example, “a substituent to which two or more substituents are connected” may be pyridine-triazine. That is, pyridine-triazine may be heteroaryl or may be interpreted as one substituent in which two heteroaryls are connected. The substituents of the substituted alkyl, the substituted aryl(ene), the substituted heteroaryl(ene), the substituted cycloalkyl, the substituted alkoxy, the substituted triarylsilyl, the substituted tialkylsilyl, the substituted dialkylarylsilyl, the substituted alkyldiarylsilyl, the substituted fused ring of aliphatic ring and aromatic ring, the substituted mono- or di-alkylamino, the substituted mono- or di-alkenylamino, the substituted mono- or di-arylamino, the substituted mono- or di-heteroarylamino, the substituted alkylalkenylamino, the substituted alkylarylamino, the substituted alkylheteroarylamino, the substituted alkenylarylamino, the substituted alkenylheteroarylamino, and the substituted arylheteroarylamino in the formulas of the present disclosure, each independently represent, at least one selected from the group consisting of deuterium, halogen, cyano, carboxyl, nitro, hydroxy, phosphine oxide, (C1-C30)alkyl, halo(C1-C30)alkyl, (C2-C30)alkenyl, (C2-C30)alkynyl, (C1-C30)alkoxy, (C1-C30)alkylthio, (C3-C30)cycloalkyl, (C3-C30)cycloalkenyl, (3- to 7-membered)heterocycloalkyl, (C6-C30)aryloxy, (C6-C30)arylthio, (5- to 30-membered)heteroaryl unsubstituted or substituted with (C6-C30)aryl, (C6-C30)aryl unsubstituted or substituted with (5- to 30-membered)heteroaryl, tri(C1-C30)alkylsilyl, tri(C6-C30)arylsilyl, di(C1-C30)alkyl(C6-C30)arylsilyl, (C1-C30)alkyldi(C6-C30)arylsilyl, amino, mono- or di-(C1-C30)alkylamino, mono- or di-(C6-C30)arylamino unsubstituted or substituted with (C1-C30)alkyl, (C1-C30)alkyl(C6-C30)arylamino, (C1-C30)alkylcarbonyl, (C1-C30)alkoxycarbonyl, (C6-C30)arylcarbonyl, (C6-C30)arylphosphinyl, di(C6-C30)arylboronyl, di(C1-C30)alkylboronyl, (C1-C30)alkyl(C6-C30)arylboronyl, (C6-C30)ar(C1-C30)alkyl, and (C1-C30)alkyl(C6-C30)aryl. For example, the substituents may be at least one of deuterium; methyl; tert-butyl; phenyl unsubstituted or substituted with at least one of methyl, pyridinyl, carbazolyl, dibenzofuranyl, diphenylamino, phenoxazinyl, phenothiazinyl, and acridinyl substituted with methyl; naphthyl; biphenyl; terphenyl; triphenylenyl; dimethylfluorenyl; phenylfluorenyl; diphenylfluorenyl; phenanthrenyl; pyridinyl; triazinyl substituted with at least one of phenyl and naphthyl; indolyl substituted with diphenyl; benzoimidazolyl substituted with phenyl; quinolyl; isoquinolyl; quinazolinyl substituted with phenyl; carbazolyl unsubstituted or substituted with phenyl; dibenzofuranyl; dibenzothiophenyl; benzocarbazolyl unsubstituted or substituted with phenyl; dibenzocarbazolyl; benzophenanthrothiophenyl; phenoxazinyl; phenothiazinyl; acridinyl substituted with one or more methyl; xanthenyl substituted with one or more methyl; diphenylamino unsubstituted or substituted with at least one of methyl and diphenylamino; dimethylfluorenylphenylamino; phenyinaphthylamino; phenylamino substituted with phenylcarbazolyl or dibenzofuranyl; and a substituted or unsubstituted (16- to 33-membered)heteroaryl containing at least one of N, O, and S.

Hereinafter, a plurality of host materials according to one embodiment will be described.

A plurality of host materials according to one embodiment comprises at least two compounds, wherein at least one compound(s) included in the plurality of host materials satisfies the following equation (1), and is represented by the following formula (1).

Tm≤Td equation (1)

In equation (1),

Tm is a melting temperature, and Td is a deposition temperature;

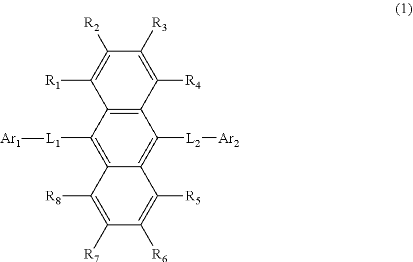

In formula 1,

L₁ and L₂ each independently represent a single bond, a substituted or unsubstituted (C6-C30)arylene, or a substituted or unsubstituted (3- to 30-membered)heteroarylene;

Ar₁ and Ar₂ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C6-C30)aryl, or a substituted or unsubstituted (3- to 30-membered)heteroaryl; and

R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

In general, it is difficult for a host material having a low voltage property to have high efficiency and/or long lifespan property at the same time. In addition, it is generally difficult for a host material having high efficiency and/or long lifespan property to have a low voltage property at the same time. However, a plurality of host materials according to one embodiment includes at least two compounds represented by the formula 1 satisfying the equation (1), thereby providing an organic electroluminescent device capable of low voltage drive and having high efficiency and long lifespan property. Specifically, according to one embodiment, as a plurality of host materials comprising at least two compounds, at least one compound included in the plurality of host materials is a melting material which satisfies the equation (1), and can be evaporated in one sublimation crucible to form a light-emitting layer, thereby simplifying the manufacturing process. In addition, it is possible to secure the uniformity and consistency of the composition deposited on the light-emitting layer through the co-evaporation process.

The melting temperature (Tm) of the compound of the formula 1 according to one embodiment is expressed as a glass transition temperature (Tg) when Tm is not measured, and may be, for example, from 50° C. to 250° C., preferably from 90° C. to 210° C. When Tm is measured, Tm may be, for example, from 200° C. to 400° C., preferably from 250° C. to 350° C. The deposition temperature (Td) of the compound of the formula 1 may be from 100° C. to 450° C., preferably from 180° C. to 380° C. Wherein, the difference between the melting temperature and the deposition temperature may be from 0° C. to 450° C., preferably from 0° C. to 200° C.

In one embodiment, L₁ and L₂ each independently may be a single bond, a substituted or unsubstituted (C6-C30)arylene, or a substituted or unsubstituted (5- to 30-membered)heteroarylene, preferably, a single bond, a substituted or unsubstituted (C6-C25)arylene, or a substituted or unsubstituted (5- to 25-membered)heteroarylene, more preferably, a single bond, a substituted or unsubstituted (C6-C18)arylene, or a substituted or unsubstituted (5-to 25-membered)heteroarylene. For example, L₁ and L₂ each independently may be a single bond, a substituted or unsubstituted phenylene, a substituted or unsubstituted m-biphenylene a substituted or unsubstituted p-biphenylene, a substituted or unsubstituted naphthalenylene, a substituted or unsubstituted phenanthrenylene, a substituted or unsubstituted carbazolylene, a substituted or unsubstituted benzoxazolylene, a substituted or unsubstituted benzocarbazolylene, or a substituted or unsubstituted dibenzocarbazolylene.

In one embodiment, Ar₁ and Ar₂ each independently may be a substituted or unsubstituted (C6-C30)aryl or a substituted or unsubstituted (5- to 30-membered)heteroaryl, preferably, a substituted or unsubstituted (C6-C25)aryl, or a substituted or unsubstituted (5- to 25-membered)heteroaryl, more preferably, a substituted or unsubstituted (C6-C25)aryl, or a substituted or unsubstituted (5- to 20-membered)heteroaryl. For example, Ar₁ and Ar₂ each independently may be a substituted or unsubstituted phenyl, a substituted or unsubstituted naphthyl, a substituted or unsubstituted m-biphenyl, a substituted or unsubstituted p-biphenyl, a substituted or unsubstituted m-terphenyl, a substituted or unsubstituted p-terphenyl, a substituted or unsubstituted triphenylenyl, a substituted or unsubstituted phenanthrenyl, a substituted or unsubstituted fluorenyl, a substituted or unsubstituted benzofluorenyl, a substituted or unsubstituted spirobifluorenyl, a substituted or unsubstituted indenofluorenyl, a substituted or unsubstituted furanyl, a substituted or unsubstituted benzofuranyl, a substituted or unsubstituted dibenzofuranyl, a substituted or unsubstituted benzonaphthofuranyl, a substituted or unsubstituted dinaphthofuranyl, a substituted or unsubstituted triphenylenofuranyl, a substituted or unsubstituted dibenzothiophenyl, a substituted or unsubstituted benzonaphthothiophenyl, a substituted or unsubstituted benzocarbazolyl, a substituted or unsubstituted benzofurocarbazolyl, a substituted or unsubstituted benzothienocarbazolyl, a substituted or unsubstituted benzobisbenzofuranyl, a substituted or unsubstituted oxathiaindenofluorenyl, a substituted or unsubstituted dibenzocarbazolyl, a substituted or unsubstituted benzobisbenzothiophenyl, a substituted or unsubstituted carbazolyl, a substituted or unsubstituted indolocarbazolyl, a substituted or unsubstituted benzoxazolyl, a substituted or unsubstituted naphthooxazolyl, a substituted or unsubstituted phenanthrooxazolyl, a substituted or unsubstituted phenanthrothiazolyl, a substituted or unsubstituted phenanthrofuranyl, a substituted or unsubstituted cyclopentaphenanthrenyl, a substituted or unsubstituted benzothiazolyl, or a substituted or unsubstituted naphthothiazolyl.

The compound represented by formula 1 according to one embodiment may be represented any one of the following formulas 1-1 to 1-3.

The plurality of host materials according to one embodiment may comprise a compound represented by the following formula 1-1, a compound represented by the following formula 1-2, a compound represented by the following formula 1-3, or the combination thereof. For example, the plurality of host materials may comprise at least two compounds represented by the following formula 1-1, at least two compounds represented by the following formula 1-2, or at least two compounds represented by the following formula 1-3. For example, the plurality of host materials may comprise a compound represented by the following formula 1-1 and a compound represented by the following formula 1-2, a compound represented by the following formula 1-1 and a compound represented by the following formula 1-3, or a compound represented by the following formula 1-2 and a compound represented by the following formula 1-3.

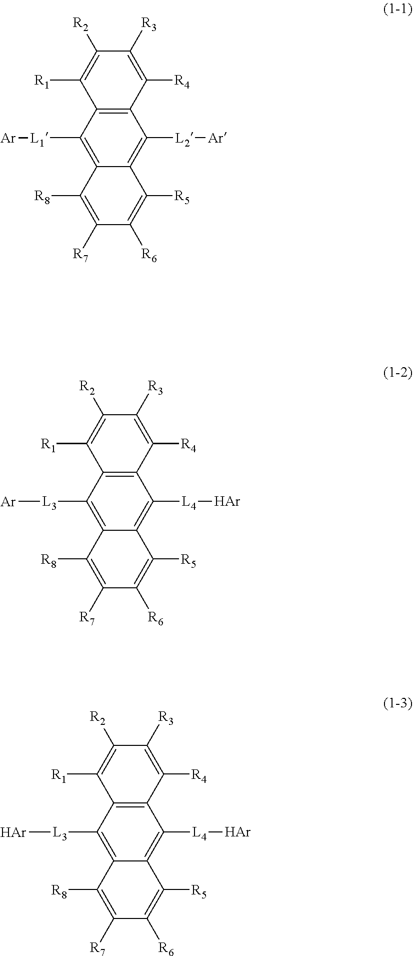

In formulas 1-1 to 1-3,

L₁′, L₂′, L₃, and L₄ each independently represent a single bond or a substituted or unsubstituted (C6-C30)arylene;

Ar and Ar′ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted (C6-C30)aryl;

HAr represents a substituted or unsubstituted (3- to 30-membered)heteroaryl; and

R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

In one embodiment, L₁′, L₂′, L₃, and L₄ each independently may be a single bond or a substituted or unsubstituted (C6-C30)arylene, preferably, a single bond or a substituted or unsubstituted (C6-C25)arylene, more preferably, a single bond or a substituted or unsubstituted (C6-C18)arylene. For example, L₁′, L₂′, L₃, and L₄ each independently may be a single bond, a substituted or unsubstituted phenylene, a substituted or unsubstituted m-biphenylene, a substituted or unsubstituted p-biphenylene, a substituted or unsubstituted naphthalenylene, or a substituted or unsubstituted phenanthrenylene.

In one embodiment, Ar and Ar′ each independently may be a substituted or unsubstituted (C6-C30)aryl, preferably, a substituted or unsubstituted (C6-C25)aryl, more preferably, a substituted or unsubstituted (C6-C20)aryl. For example, Ar and Ar′ each independently may be a substituted or unsubstituted phenyl, a substituted or unsubstituted naphthyl, a substituted or unsubstituted m-biphenyl, a substituted or unsubstituted p-biphenyl, a substituted or unsubstituted m-terphenyl, a substituted or unsubstituted p-terphenyl, a substituted or unsubstituted triphenylenyl, a substituted or unsubstituted phenanthrenyl, a substituted or unsubstituted fluorenyl, a substituted or unsubstituted benzofluorenyl, a substituted or unsubstituted spirobifluorenyl, a substituted or unsubstituted cyclopentaphenanthrenyl, or a substituted or unsubstituted indenofluorenyl.

In one embodiment, HAr may be a substituted or unsubstituted (5- to 30-membered)heteroaryl, preferably, a substituted or unsubstituted (5- to 25-membered)heteroaryl, more preferably, a substituted or unsubstituted (5- to 20-membered)heteroaryl. For example, HAr may be a substituted or unsubstituted furanyl, a substituted or unsubstituted benzofuranyl, a substituted or unsubstituted dibenzofuranyl, a substituted or unsubstituted benzonaphthofuranyl, a substituted or unsubstituted dinaphthofuranyl, a substituted or unsubstituted triphenylenofuranyl, a substituted or unsubstituted dibenzothiophenyl, a substituted or unsubstituted benzonaphthothiophenyl, a substituted or unsubstituted benzocarbazolyl, a substituted or unsubstituted benzofurocarbazolyl, a substituted or unsubstituted benzothienocarbazolyl, a substituted or unsubstituted benzobisbenzofuranyl, a substituted or unsubstituted oxathiaindenofluorenyl, a substituted or unsubstituted dibenzocarbazolyl, a substituted or unsubstituted benzobisbenzothiophenyl, a substituted or unsubstituted carbazolyl, a substituted or unsubstituted indolocarbazolyl, a substituted or unsubstituted benzoxazolyl, a substituted or unsubstituted naphthooxazolyl, a substituted or unsubstituted phenanthrooxazolyl, a substituted or unsubstituted phenanthrothiazolyl, a substituted or unsubstituted phenanthrofuranyl, a substituted or unsubstituted benzothiazolyl, or a substituted or unsubstituted naphthothiazolyl.

HAr according to one embodiment may be represented by any one of the following formulas 1-1-1 to 1-1-10,

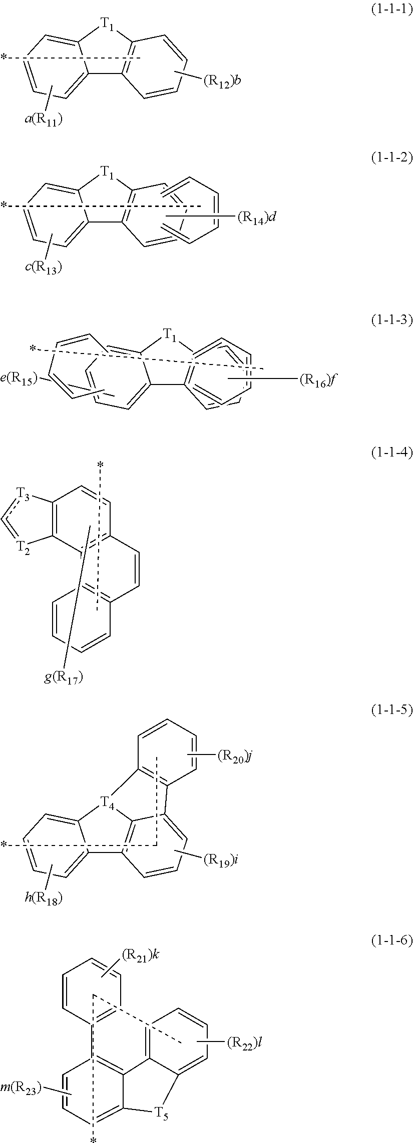

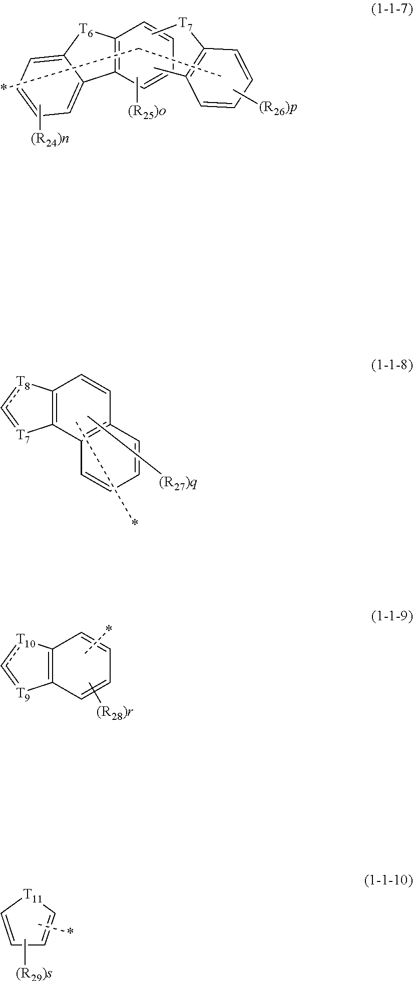

In formulas 1-1-1 to 1-1-10,

T₁, T₅, T₆, T₉, and T₁₀ each independently represent —N-L₅-Ar₅, O, or S;

T₂, T₃, T₇, and T₈ each independently represent —N═, —NR—, —O—, or —S—; provided that T₂ and T₇ are —N═, T₃ and T₈ each independently represent —NR—, —O—, or —S—;

T₄ represents N;

T₁₁ represents O or S;

L₅ represents a single bond, a substituted or unsubstituted (C6-C30)arylene, or a substituted or unsubstituted (3- to 30-membered)heteroarylene; Ar₅ represents a substituted or unsubstituted (C6-C30)aryl or a substituted or unsubstituted (3- to 30-membered)heteroaryl;

R₁, to R₂₉ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino;

o represents an integer of 1 or 2; i, l, and m each independently represent an integer of 1 to 3; a to c, h, j, k, n, p, r, and s each independently represent an integer of 1 to 4; d, e, f, and q each independently represent an integer of 1 to 6; and g represents an integer of 1 to 8; and when a to s are an integer of 2 or more, each of R₁₁ to R₂₉ may be the same or different; and

[symbol]

In one embodiment, HAr may be any one of the substituents listed in the following Group 1.

[Group 1]

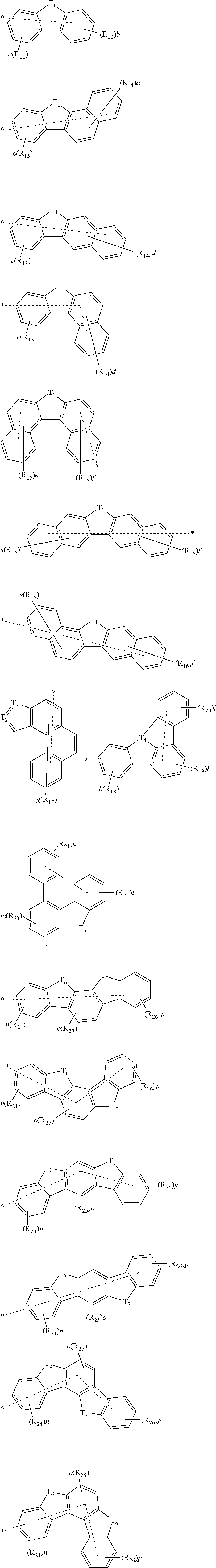

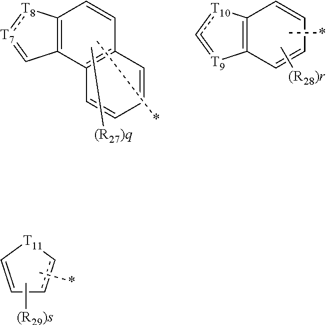

The definitions of the respective substituents in the compounds of Group 1 above are as defined in formulas 1-1-1 to 1-1-10 above,

According to one embodiment, the compound represented by formula 1 above may be more specifically illustrated by the following compounds, but is not limited thereto.

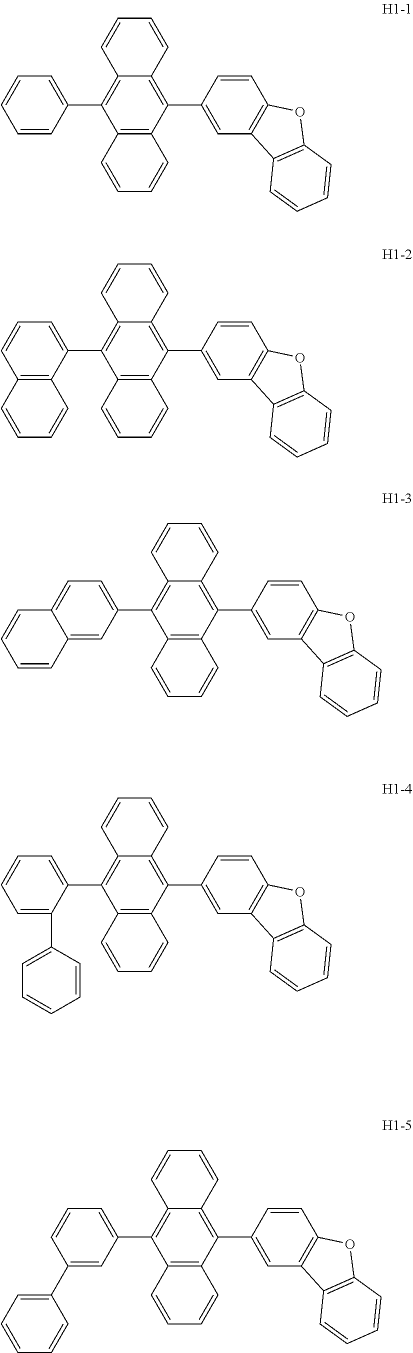 [SMILES: c1ccc(-c2c3ccccc3c(-c3ccc4oc5ccccc5c4c3)c3ccccc23)cc1 ; c1ccc2c(-c3c4ccccc4c(-c4ccc5oc6ccccc6c5c4)c4ccccc34)cccc2c1 ; c1ccc2cc(-c3c4ccccc4c(-c4ccc5oc6ccccc6c5c4)c4ccccc34)ccc2c1 ; c1ccc(-c2ccccc2-c2c3ccccc3c(-c3ccc4oc5ccccc5c4c3)c3ccccc23)cc1 ; c1ccc(-c2cccc(-c3c4ccccc4c(-c4ccc5oc6ccccc6c5c4)c4ccccc34)c2)cc1]

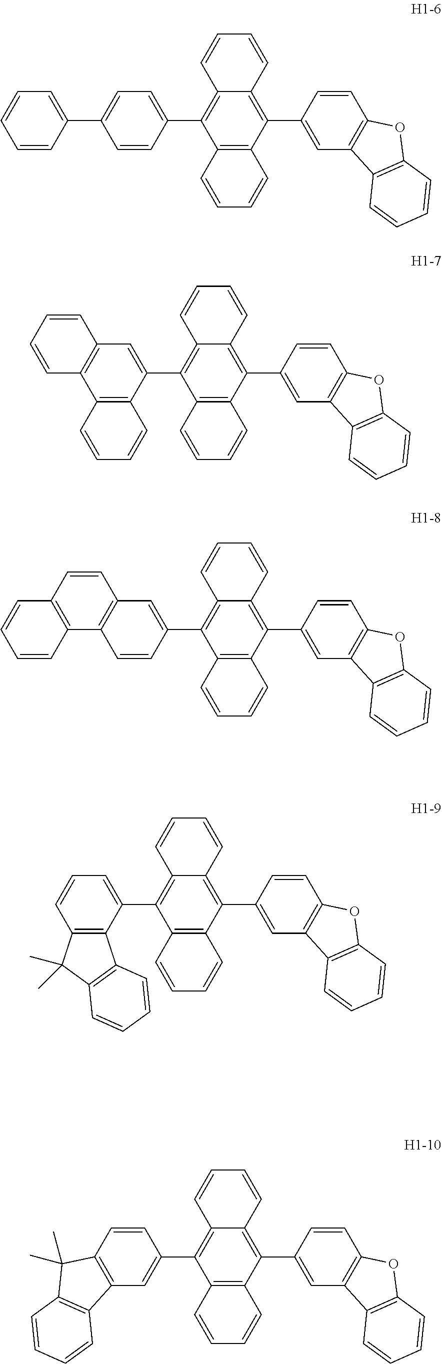 [SMILES: c1ccc(-c2ccc(-c3c4ccccc4c(-c4ccc5oc6ccccc6c5c4)c4ccccc34)cc2)cc1 ; c1ccc2c(c1)cc(-c1c3ccccc3c(-c3ccc4oc5ccccc5c4c3)c3ccccc13)c1ccccc12 ; c1ccc2c(c1)ccc1cc(-c3c4ccccc4c(-c4ccc5oc6ccccc6c5c4)c4ccccc34)ccc12 ; CC1(C)c2ccccc2-c2c(-c3c4ccccc4c(-c4ccc5oc6ccccc6c5c4)c4ccccc34)cccc21 ; CC1(C)c2ccccc2-c2cc(-c3c4ccccc4c(-c4ccc5oc6ccccc6c5c4)c4ccccc34)ccc21]

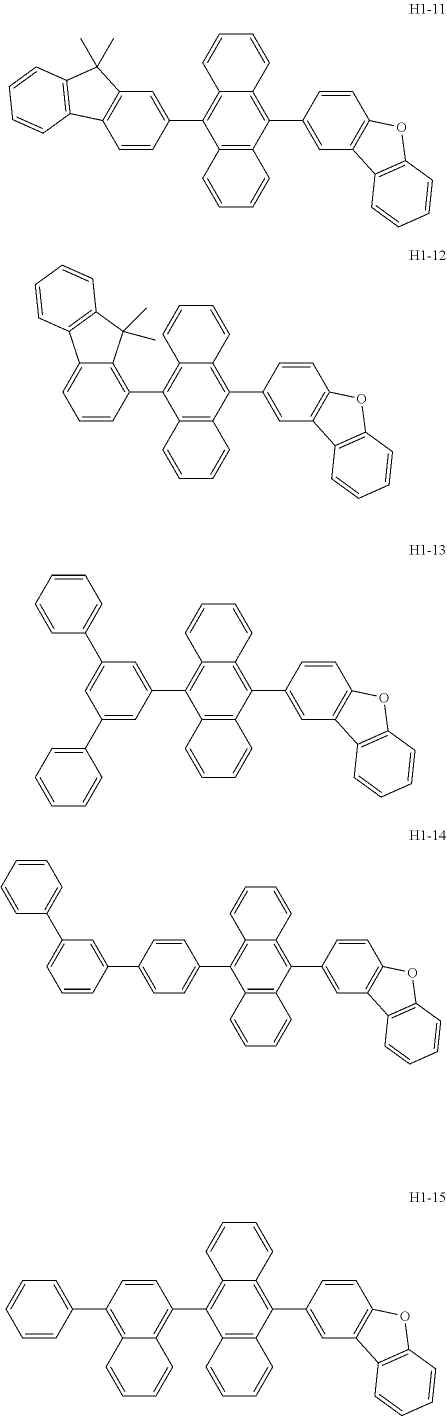 [SMILES: CC1(C)c2ccccc2-c2ccc(-c3c4ccccc4c(-c4ccc5oc6ccccc6c5c4)c4ccccc34)cc21 ; CC1(C)c2ccccc2-c2cccc(-c3c4ccccc4c(-c4ccc5oc6ccccc6c5c4)c4ccccc34)c21 ; c1ccc(-c2cc(-c3ccccc3)cc(-c3c4ccccc4c(-c4ccc5oc6ccccc6c5c4)c4ccccc34)c2)cc1 ; c1ccc(-c2cccc(-c3ccc(-c4c5ccccc5c(-c5ccc6oc7ccccc7c6c5)c5ccccc45)cc3)c2)cc1 ; c1ccc(-c2ccc(-c3c4ccccc4c(-c4ccc5oc6ccccc6c5c4)c4ccccc34)c3ccccc23)cc1]

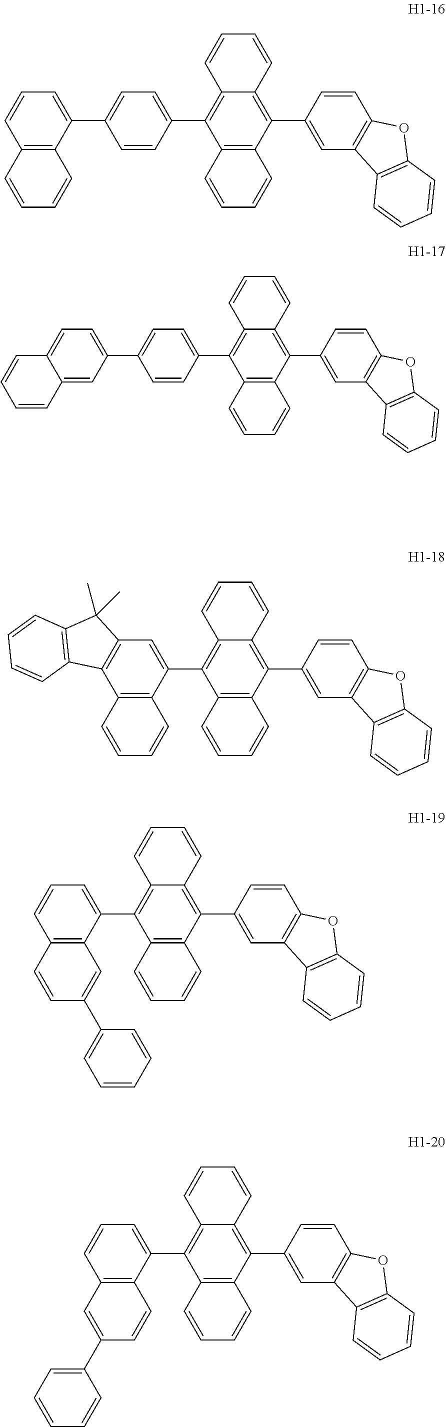 [SMILES: c1ccc2c(-c3ccc(-c4c5ccccc5c(-c5ccc6oc7ccccc7c6c5)c5ccccc45)cc3)cccc2c1 ; c1ccc2cc(-c3ccc(-c4c5ccccc5c(-c5ccc6oc7ccccc7c6c5)c5ccccc45)cc3)ccc2c1 ; CC1(C)c2ccccc2-c2c1cc(-c1c3ccccc3c(-c3ccc4oc5ccccc5c4c3)c3ccccc13)c1ccccc21 ; c1ccc(-c2ccc3cccc(-c4c5ccccc5c(-c5ccc6oc7ccccc7c6c5)c5ccccc45)c3c2)cc1 ; c1ccc(-c2ccc3c(-c4c5ccccc5c(-c5ccc6oc7ccccc7c6c5)c5ccccc45)cccc3c2)cc1]

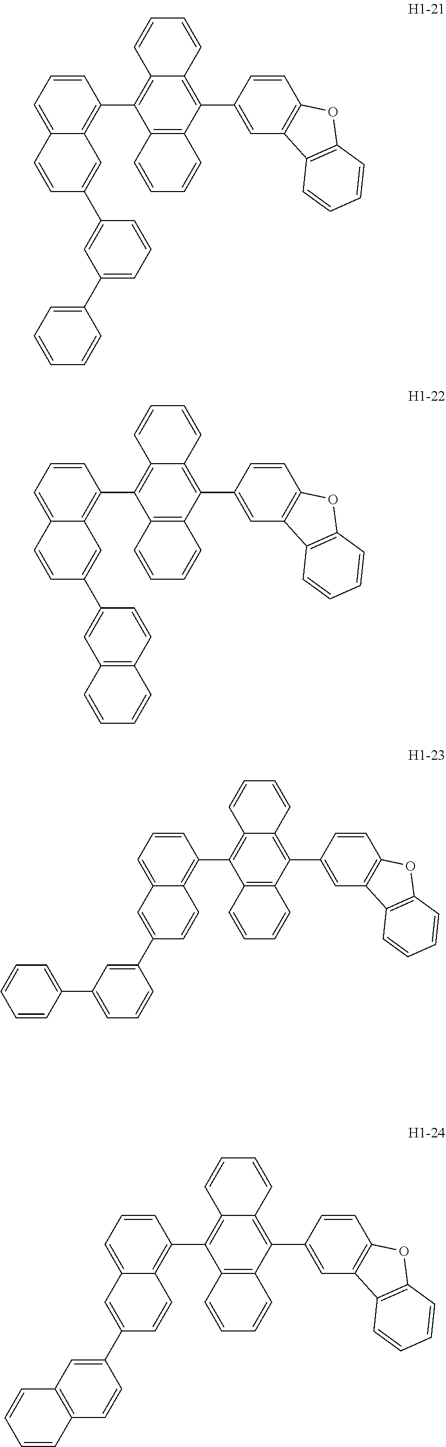 [SMILES: c1ccc(-c2cccc(-c3ccc4cccc(-c5c6ccccc6c(-c6ccc7oc8ccccc8c7c6)c6ccccc56)c4c3)c2)cc1 ; c1ccc2cc(-c3ccc4cccc(-c5c6ccccc6c(-c6ccc7oc8ccccc8c7c6)c6ccccc56)c4c3)ccc2c1 ; c1ccc(-c2cccc(-c3ccc4c(-c5c6ccccc6c(-c6ccc7oc8ccccc8c7c6)c6ccccc56)cccc4c3)c2)cc1 ; c1ccc2cc(-c3ccc4c(-c5c6ccccc6c(-c6ccc7oc8ccccc8c7c6)c6ccccc56)cccc4c3)ccc2c1]

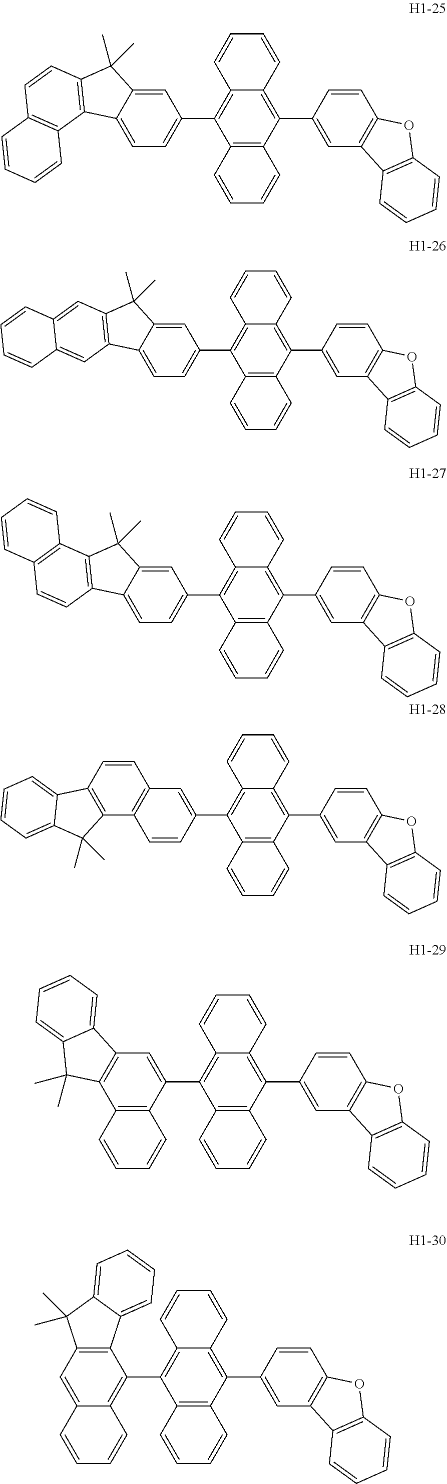 [SMILES: CC1(C)c2cc(-c3c4ccccc4c(-c4ccc5oc6ccccc6c5c4)c4ccccc34)ccc2-c2c1ccc1ccccc21 ; CC1(C)c2cc(-c3c4ccccc4c(-c4ccc5oc6ccccc6c5c4)c4ccccc34)ccc2-c2cc3ccccc3cc21 ; CC1(C)c2cc(-c3c4ccccc4c(-c4ccc5oc6ccccc6c5c4)c4ccccc34)ccc2-c2ccc3ccccc3c21 ; CC1(C)c2ccccc2-c2ccc3cc(-c4c5ccccc5c(-c5ccc6oc7ccccc7c6c5)c5ccccc45)ccc3c21 ; CC1(C)c2ccccc2-c2cc(-c3c4ccccc4c(-c4ccc5oc6ccccc6c5c4)c4ccccc34)c3ccccc3c21 ; CC1(C)c2ccccc2-c2c1cc1ccccc1c2-c1c2ccccc2c(-c2ccc3oc4ccccc4c3c2)c2ccccc12]

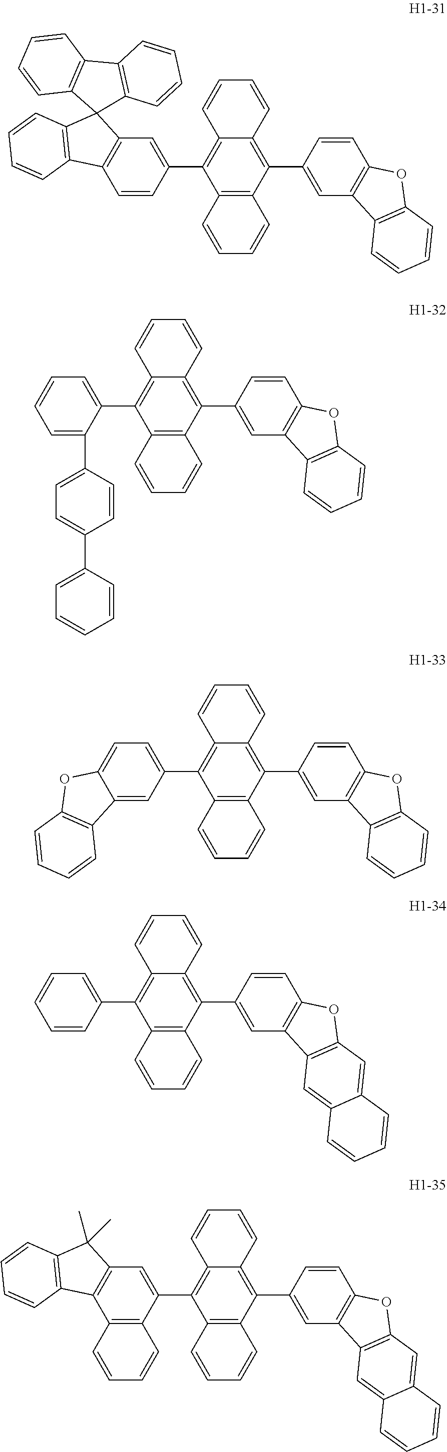 [SMILES: c1ccc2c(c1)-c1ccccc1C21c2ccccc2-c2ccc(-c3c4ccccc4c(-c4ccc5oc6ccccc6c5c4)c4ccccc34)cc21 ; c1ccc(-c2ccc(-c3ccccc3-c3c4ccccc4c(-c4ccc5oc6ccccc6c5c4)c4ccccc34)cc2)cc1 ; c1ccc2c(c1)oc1ccc(-c3c4ccccc4c(-c4ccc5oc6ccccc6c5c4)c4ccccc34)cc12 ; c1ccc(-c2c3ccccc3c(-c3ccc4oc5cc6ccccc6cc5c4c3)c3ccccc23)cc1 ; CC1(C)c2ccccc2-c2c1cc(-c1c3ccccc3c(-c3ccc4oc5cc6ccccc6cc5c4c3)c3ccccc13)c1ccccc21]

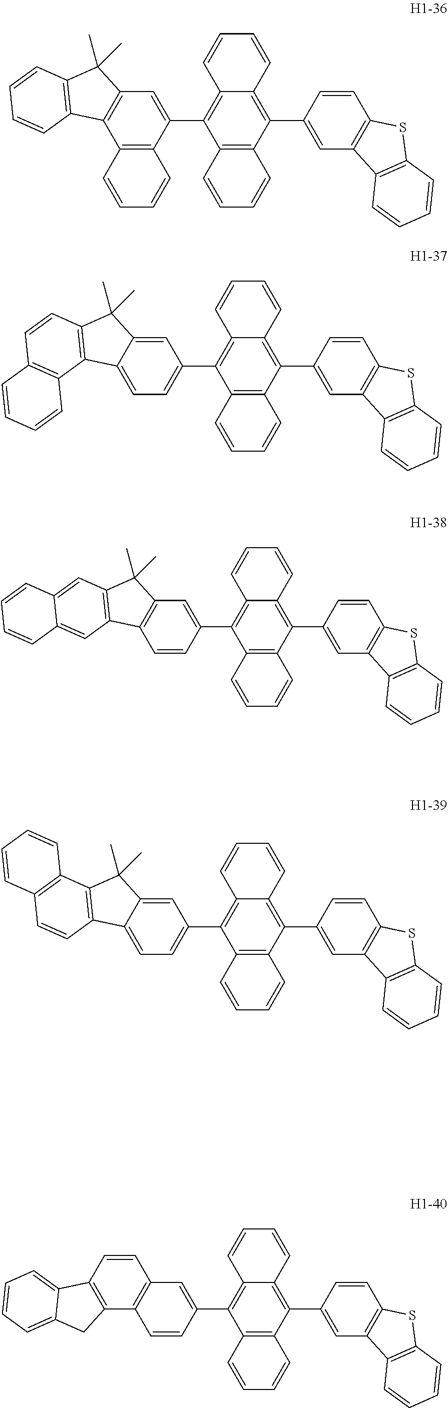 [SMILES: CC1(C)c2ccccc2-c2c1cc(-c1c3ccccc3c(-c3ccc4sc5ccccc5c4c3)c3ccccc13)c1ccccc21 ; CC1(C)c2cc(-c3c4ccccc4c(-c4ccc5sc6ccccc6c5c4)c4ccccc34)ccc2-c2c1ccc1ccccc21 ; CC1(C)c2cc(-c3c4ccccc4c(-c4ccc5sc6ccccc6c5c4)c4ccccc34)ccc2-c2cc3ccccc3cc21 ; CC1(C)c2cc(-c3c4ccccc4c(-c4ccc5sc6ccccc6c5c4)c4ccccc34)ccc2-c2ccc3ccccc3c21 ; c1ccc2c(c1)Cc1c-2ccc2cc(-c3c4ccccc4c(-c4ccc5sc6ccccc6c5c4)c4ccccc34)ccc12]

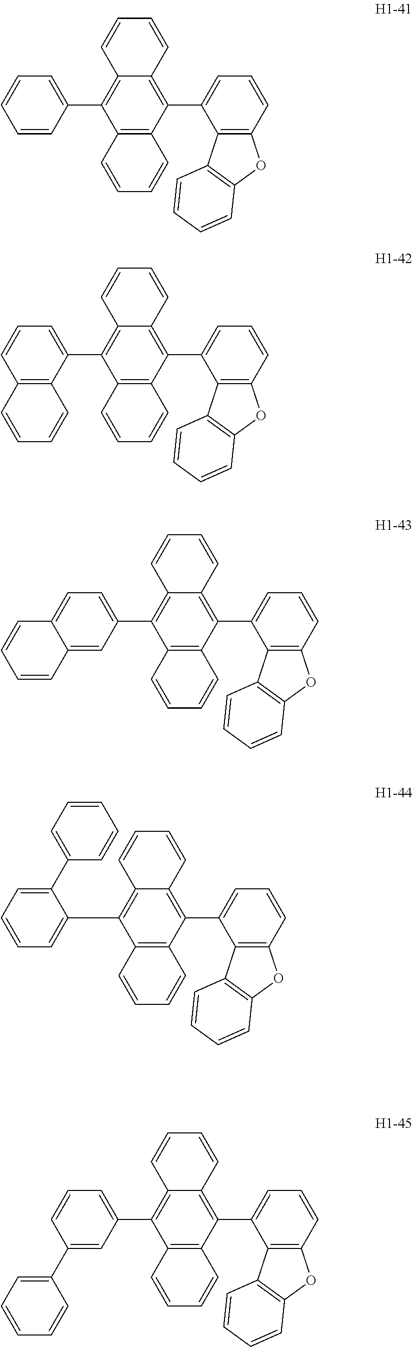 [SMILES: c1ccc(-c2c3ccccc3c(-c3cccc4oc5ccccc5c34)c3ccccc23)cc1 ; c1ccc2c(-c3c4ccccc4c(-c4cccc5oc6ccccc6c45)c4ccccc34)cccc2c1 ; c1ccc2cc(-c3c4ccccc4c(-c4cccc5oc6ccccc6c45)c4ccccc34)ccc2c1 ; c1ccc(-c2ccccc2-c2c3ccccc3c(-c3cccc4oc5ccccc5c34)c3ccccc23)cc1 ; c1ccc(-c2cccc(-c3c4ccccc4c(-c4cccc5oc6ccccc6c45)c4ccccc34)c2)cc1]

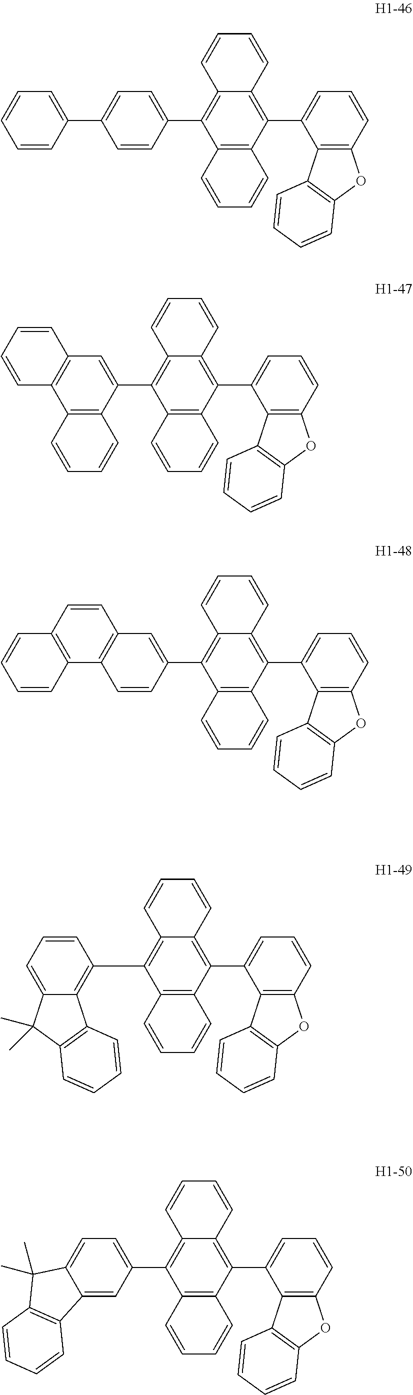 [SMILES: c1ccc(-c2ccc(-c3c4ccccc4c(-c4cccc5oc6ccccc6c45)c4ccccc34)cc2)cc1 ; c1ccc2c(c1)cc(-c1c3ccccc3c(-c3cccc4oc5ccccc5c34)c3ccccc13)c1ccccc12 ; c1ccc2c(c1)ccc1cc(-c3c4ccccc4c(-c4cccc5oc6ccccc6c45)c4ccccc34)ccc12 ; CC1(C)c2ccccc2-c2c(-c3c4ccccc4c(-c4cccc5oc6ccccc6c45)c4ccccc34)cccc21 ; CC1(C)c2ccccc2-c2cc(-c3c4ccccc4c(-c4cccc5oc6ccccc6c45)c4ccccc34)ccc21]

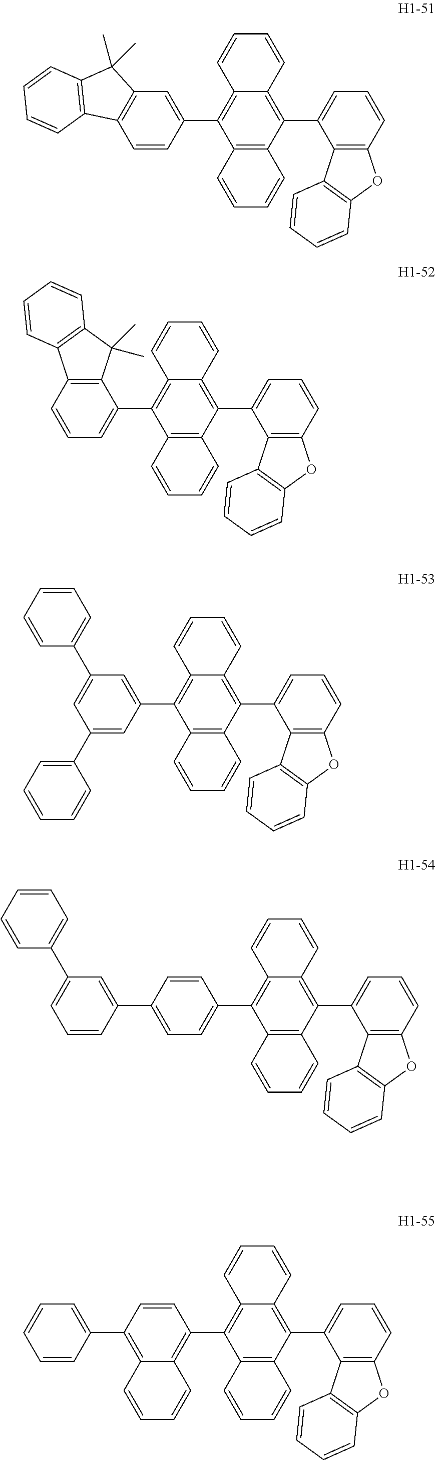 [SMILES: CC1(C)c2ccccc2-c2ccc(-c3c4ccccc4c(-c4cccc5oc6ccccc6c45)c4ccccc34)cc21 ; CC1(C)c2ccccc2-c2cccc(-c3c4ccccc4c(-c4cccc5oc6ccccc6c45)c4ccccc34)c21 ; c1ccc(-c2cc(-c3ccccc3)cc(-c3c4ccccc4c(-c4cccc5oc6ccccc6c45)c4ccccc34)c2)cc1 ; c1ccc(-c2cccc(-c3ccc(-c4c5ccccc5c(-c5cccc6oc7ccccc7c56)c5ccccc45)cc3)c2)cc1 ; c1ccc(-c2ccc(-c3c4ccccc4c(-c4cccc5oc6ccccc6c45)c4ccccc34)c3ccccc23)cc1]

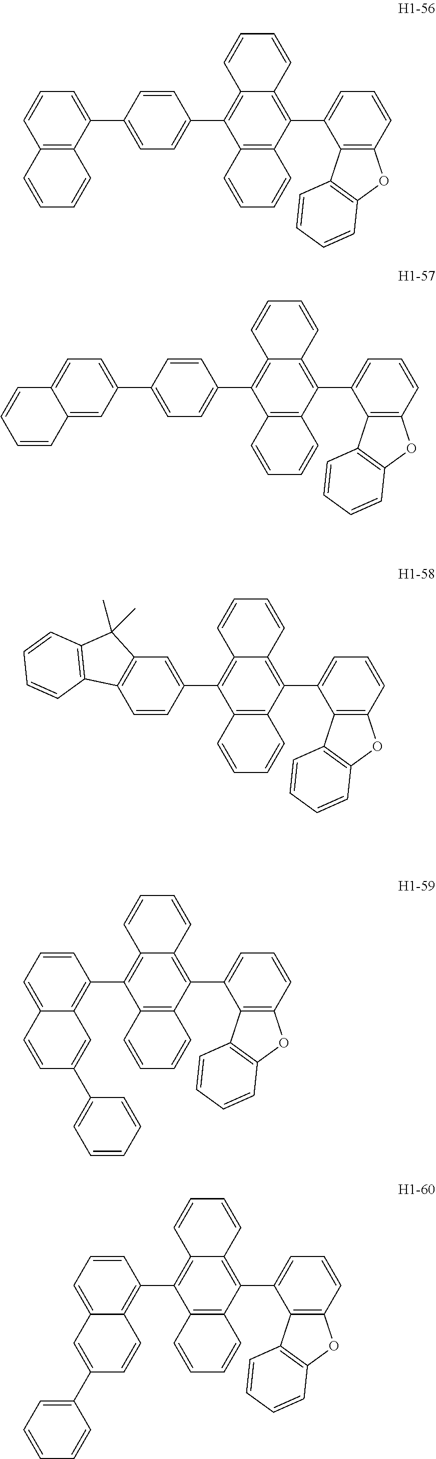 [SMILES: c1ccc2c(-c3ccc(-c4c5ccccc5c(-c5cccc6oc7ccccc7c56)c5ccccc45)cc3)cccc2c1 ; c1ccc2cc(-c3ccc(-c4c5ccccc5c(-c5cccc6oc7ccccc7c56)c5ccccc45)cc3)ccc2c1 ; CC1(C)c2ccccc2-c2ccc(-c3c4ccccc4c(-c4cccc5oc6ccccc6c45)c4ccccc34)cc21 ; c1ccc(-c2ccc3cccc(-c4c5ccccc5c(-c5cccc6oc7ccccc7c56)c5ccccc45)c3c2)cc1 ; c1ccc(-c2ccc3c(-c4c5ccccc5c(-c5cccc6oc7ccccc7c56)c5ccccc45)cccc3c2)cc1]

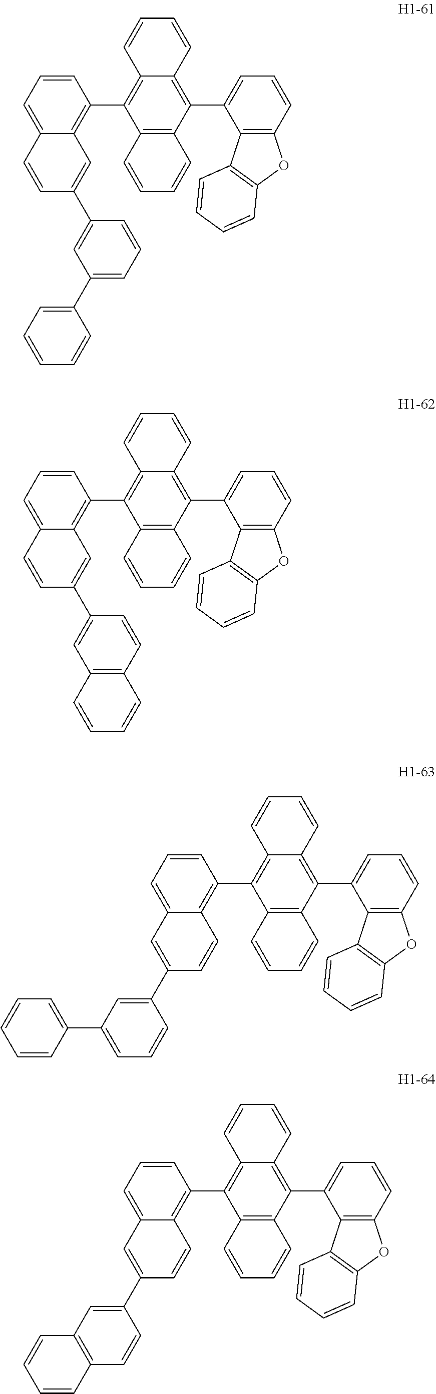 [SMILES: c1ccc(-c2cccc(-c3ccc4cccc(-c5c6ccccc6c(-c6cccc7oc8ccccc8c67)c6ccccc56)c4c3)c2)cc1 ; c1ccc2cc(-c3ccc4cccc(-c5c6ccccc6c(-c6cccc7oc8ccccc8c67)c6ccccc56)c4c3)ccc2c1 ; c1ccc(-c2cccc(-c3ccc4c(-c5c6ccccc6c(-c6cccc7oc8ccccc8c67)c6ccccc56)cccc4c3)c2)cc1 ; c1ccc2cc(-c3ccc4c(-c5c6ccccc6c(-c6cccc7oc8ccccc8c67)c6ccccc56)cccc4c3)ccc2c1]

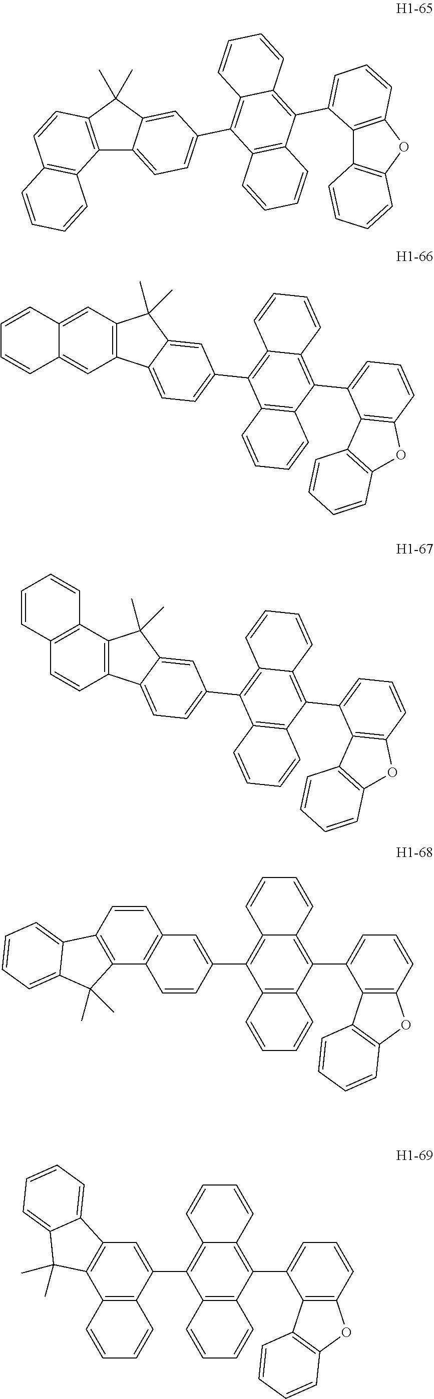 [SMILES: CC1(C)c2cc(-c3c4ccccc4c(-c4cccc5oc6ccccc6c45)c4ccccc34)ccc2-c2c1ccc1ccccc21 ; CC1(C)c2cc(-c3c4ccccc4c(-c4cccc5oc6ccccc6c45)c4ccccc34)ccc2-c2cc3ccccc3cc21 ; CC1(C)c2cc(-c3c4ccccc4c(-c4cccc5oc6ccccc6c45)c4ccccc34)ccc2-c2ccc3ccccc3c21 ; CC1(C)c2ccccc2-c2ccc3cc(-c4c5ccccc5c(-c5cccc6oc7ccccc7c56)c5ccccc45)ccc3c21 ; CC1(C)c2ccccc2-c2cc(-c3c4ccccc4c(-c4cccc5oc6ccccc6c45)c4ccccc34)c3ccccc3c21]

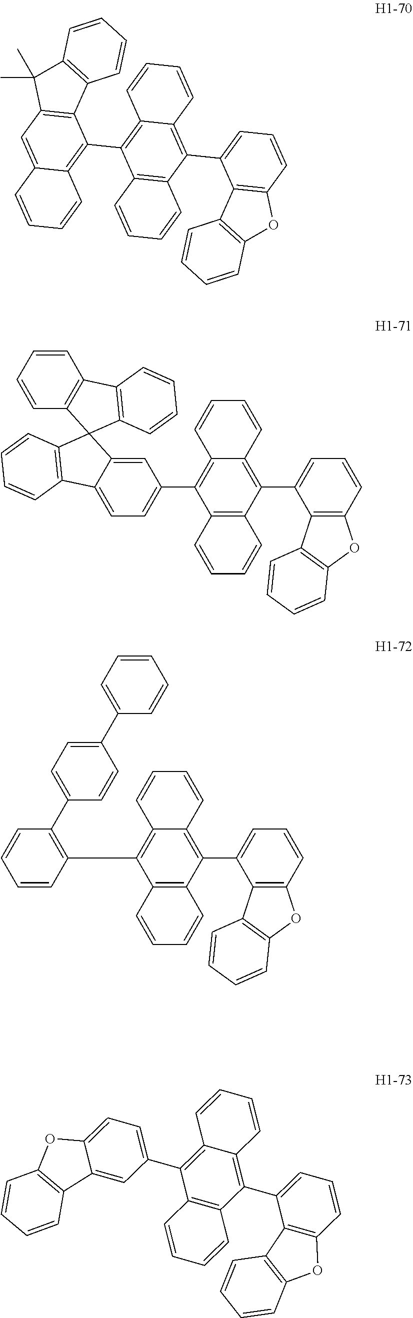 [SMILES: CC1(C)c2ccccc2-c2c1cc1ccccc1c2-c1c2ccccc2c(-c2cccc3oc4ccccc4c23)c2ccccc12 ; c1ccc2c(c1)-c1ccccc1C21c2ccccc2-c2ccc(-c3c4ccccc4c(-c4cccc5oc6ccccc6c45)c4ccccc34)cc21 ; c1ccc(-c2ccc(-c3ccccc3-c3c4ccccc4c(-c4cccc5oc6ccccc6c45)c4ccccc34)cc2)cc1 ; c1ccc2c(c1)oc1ccc(-c3c4ccccc4c(-c4cccc5oc6ccccc6c45)c4ccccc34)cc12]

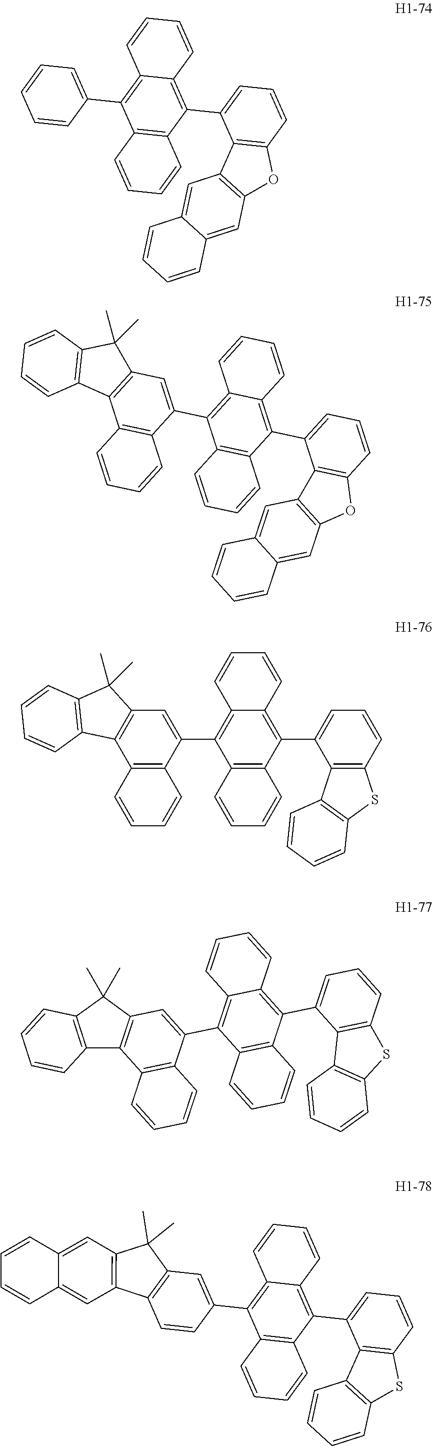 [SMILES: c1ccc(-c2c3ccccc3c(-c3cccc4oc5cc6ccccc6cc5c34)c3ccccc23)cc1 ; CC1(C)c2ccccc2-c2c1cc(-c1c3ccccc3c(-c3cccc4oc5cc6ccccc6cc5c34)c3ccccc13)c1ccccc21 ; CC1(C)c2ccccc2-c2c1cc(-c1c3ccccc3c(-c3cccc4sc5ccccc5c34)c3ccccc13)c1ccccc21 ; CC1(C)c2ccccc2-c2c1cc(-c1c3ccccc3c(-c3cccc4sc5ccccc5c34)c3ccccc13)c1ccccc21 ; CC1(C)c2cc(-c3c4ccccc4c(-c4cccc5sc6ccccc6c45)c4ccccc34)ccc2-c2cc3ccccc3cc21]

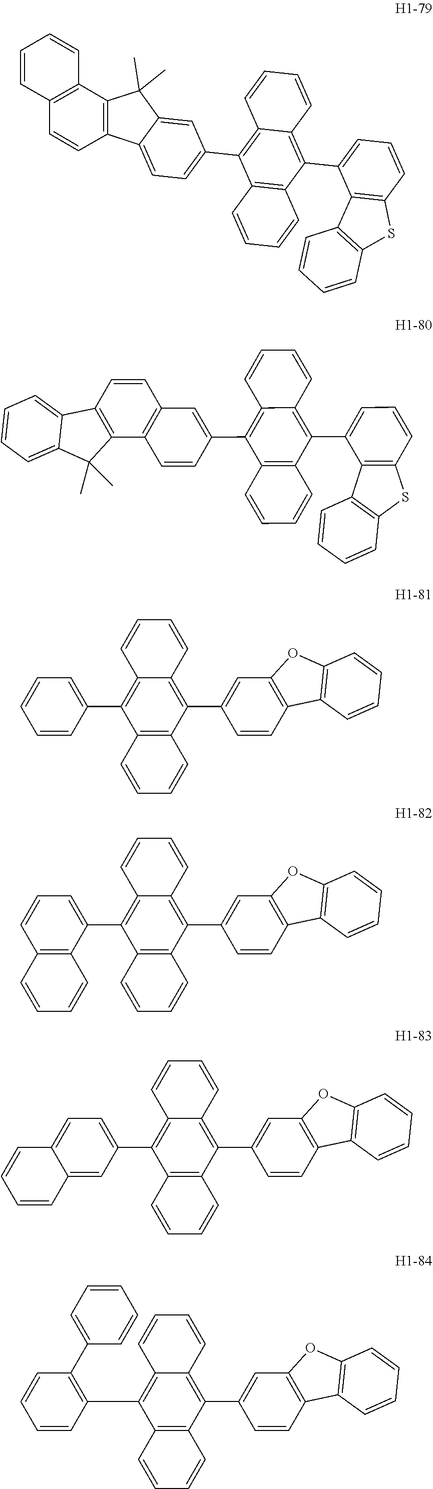

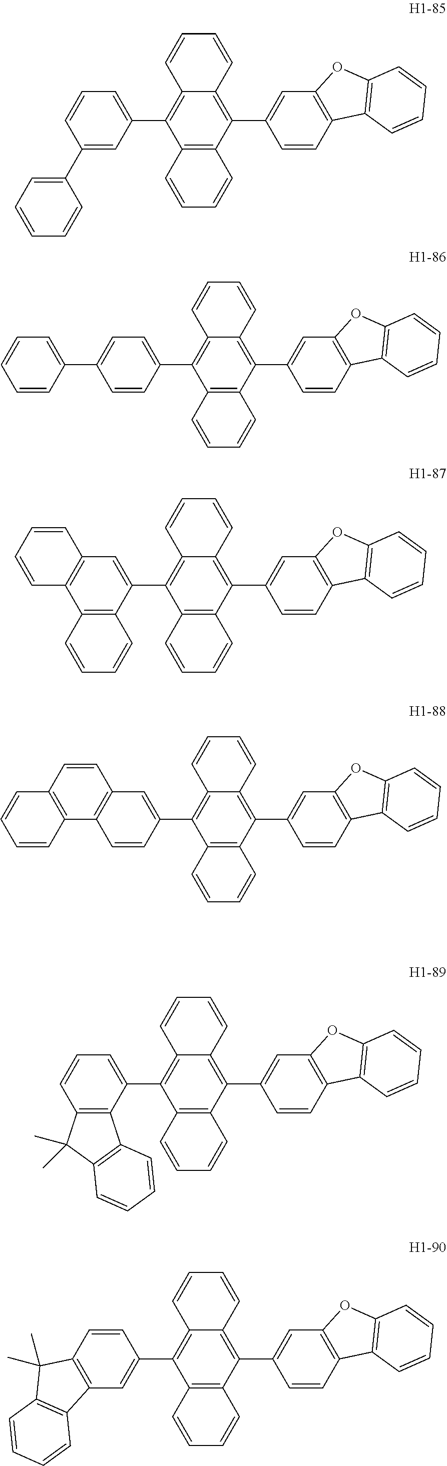 [SMILES: c1ccc(-c2cccc(-c3c4ccccc4c(-c4ccc5c(c4)oc4ccccc45)c4ccccc34)c2)cc1 ; c1ccc(-c2ccc(-c3c4ccccc4c(-c4ccc5c(c4)oc4ccccc45)c4ccccc34)cc2)cc1 ; c1ccc2c(c1)cc(-c1c3ccccc3c(-c3ccc4c(c3)oc3ccccc34)c3ccccc13)c1ccccc12 ; c1ccc2c(c1)ccc1cc(-c3c4ccccc4c(-c4ccc5c(c4)oc4ccccc45)c4ccccc34)ccc12 ; CC1(C)c2ccccc2-c2c(-c3c4ccccc4c(-c4ccc5c(c4)oc4ccccc45)c4ccccc34)cccc21 ; CC1(C)c2ccccc2-c2cc(-c3c4ccccc4c(-c4ccc5c(c4)oc4ccccc45)c4ccccc34)ccc21]

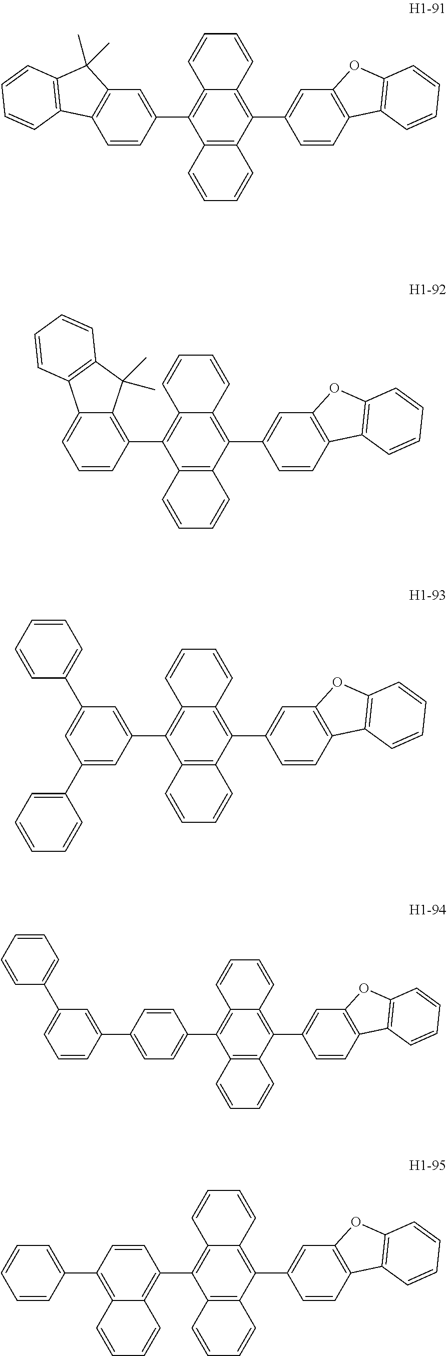 [SMILES: CC1(C)c2ccccc2-c2ccc(-c3c4ccccc4c(-c4ccc5c(c4)oc4ccccc45)c4ccccc34)cc21 ; CC1(C)c2ccccc2-c2cccc(-c3c4ccccc4c(-c4ccc5c(c4)oc4ccccc45)c4ccccc34)c21 ; c1ccc(-c2cc(-c3ccccc3)cc(-c3c4ccccc4c(-c4ccc5c(c4)oc4ccccc45)c4ccccc34)c2)cc1 ; c1ccc(-c2cccc(-c3ccc(-c4c5ccccc5c(-c5ccc6c(c5)oc5ccccc56)c5ccccc45)cc3)c2)cc1 ; c1ccc(-c2ccc(-c3c4ccccc4c(-c4ccc5c(c4)oc4ccccc45)c4ccccc34)c3ccccc23)cc1]

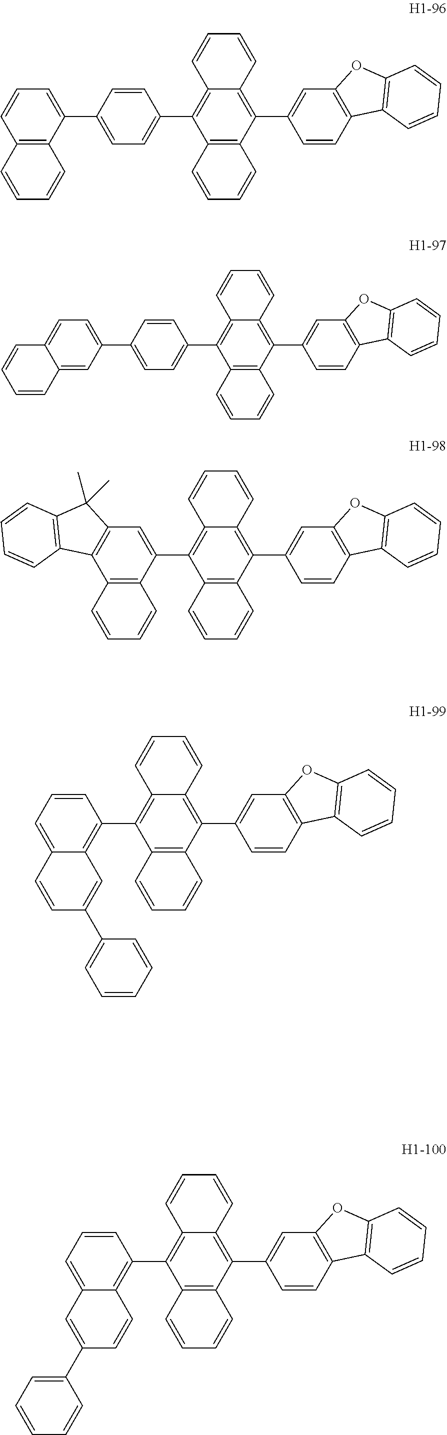 [SMILES: c1ccc2c(-c3ccc(-c4c5ccccc5c(-c5ccc6c(c5)oc5ccccc56)c5ccccc45)cc3)cccc2c1 ; c1ccc2cc(-c3ccc(-c4c5ccccc5c(-c5ccc6c(c5)oc5ccccc56)c5ccccc45)cc3)ccc2c1 ; CC1(C)c2ccccc2-c2c1cc(-c1c3ccccc3c(-c3ccc4c(c3)oc3ccccc34)c3ccccc13)c1ccccc21 ; c1ccc(-c2ccc3cccc(-c4c5ccccc5c(-c5ccc6c(c5)oc5ccccc56)c5ccccc45)c3c2)cc1 ; c1ccc(-c2ccc3c(-c4c5ccccc5c(-c5ccc6c(c5)oc5ccccc56)c5ccccc45)cccc3c2)cc1]

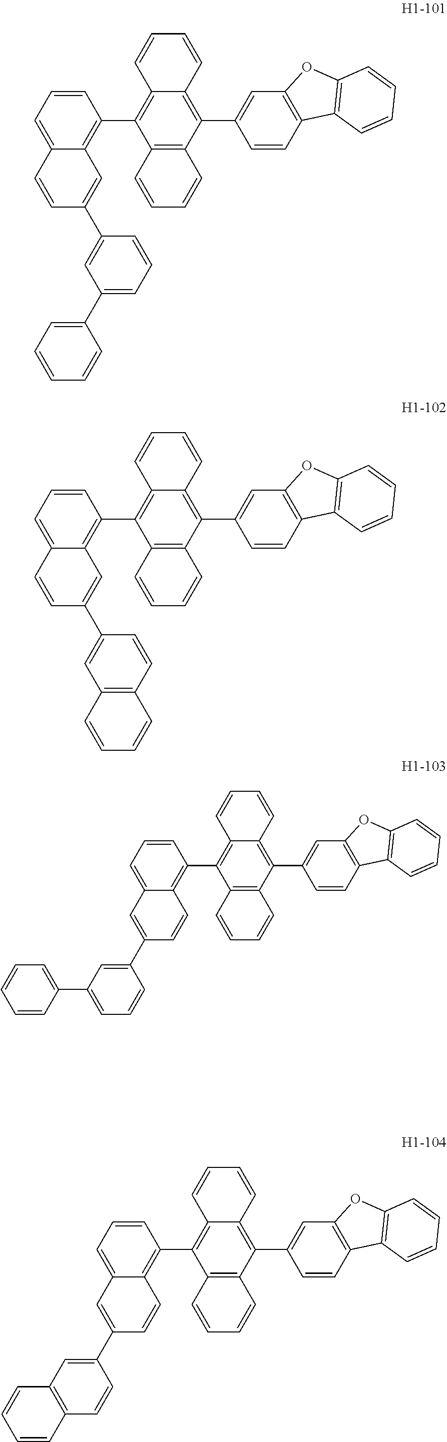 [SMILES: c1ccc(-c2cccc(-c3ccc4cccc(-c5c6ccccc6c(-c6ccc7c(c6)oc6ccccc67)c6ccccc56)c4c3)c2)cc1 ; c1ccc2cc(-c3ccc4cccc(-c5c6ccccc6c(-c6ccc7c(c6)oc6ccccc67)c6ccccc56)c4c3)ccc2c1 ; c1ccc(-c2cccc(-c3ccc4c(-c5c6ccccc6c(-c6ccc7c(c6)oc6ccccc67)c6ccccc56)cccc4c3)c2)cc1 ; c1ccc2cc(-c3ccc4c(-c5c6ccccc6c(-c6ccc7c(c6)oc6ccccc67)c6ccccc56)cccc4c3)ccc2c1]

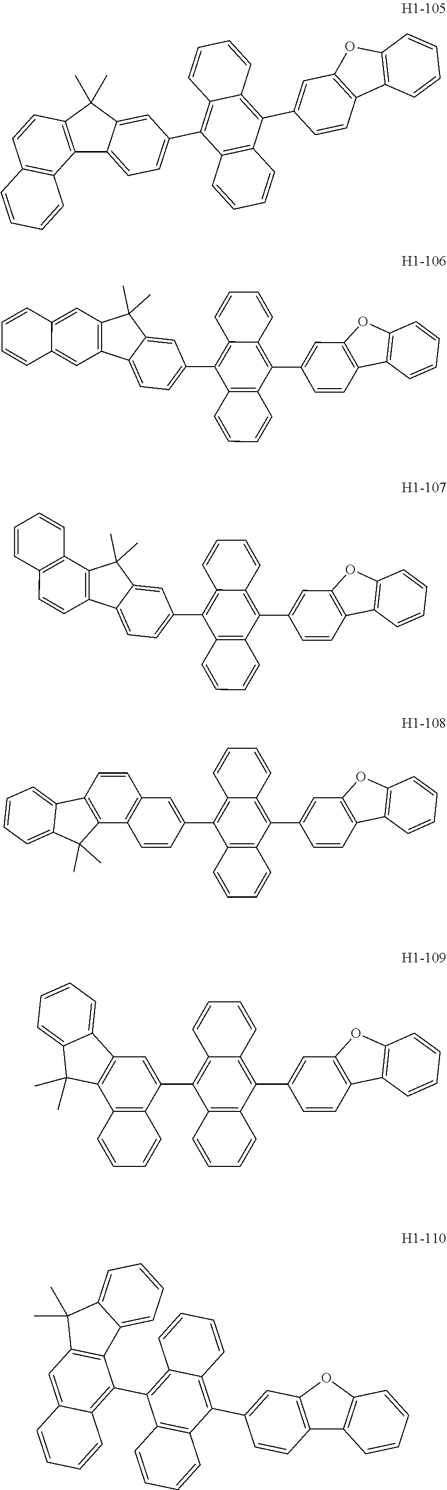 [SMILES: CC1(C)c2cc(-c3c4ccccc4c(-c4ccc5c(c4)oc4ccccc45)c4ccccc34)ccc2-c2c1ccc1ccccc21 ; CC1(C)c2cc(-c3c4ccccc4c(-c4ccc5c(c4)oc4ccccc45)c4ccccc34)ccc2-c2cc3ccccc3cc21 ; CC1(C)c2cc(-c3c4ccccc4c(-c4ccc5c(c4)oc4ccccc45)c4ccccc34)ccc2-c2ccc3ccccc3c21 ; CC1(C)c2ccccc2-c2ccc3cc(-c4c5ccccc5c(-c5ccc6c(c5)oc5ccccc56)c5ccccc45)ccc3c21 ; CC1(C)c2ccccc2-c2cc(-c3c4ccccc4c(-c4ccc5c(c4)oc4ccccc45)c4ccccc34)c3ccccc3c21 ; CC1(C)c2ccccc2-c2c1cc1ccccc1c2-c1c2ccccc2c(-c2ccc3c(c2)oc2ccccc23)c2ccccc12]

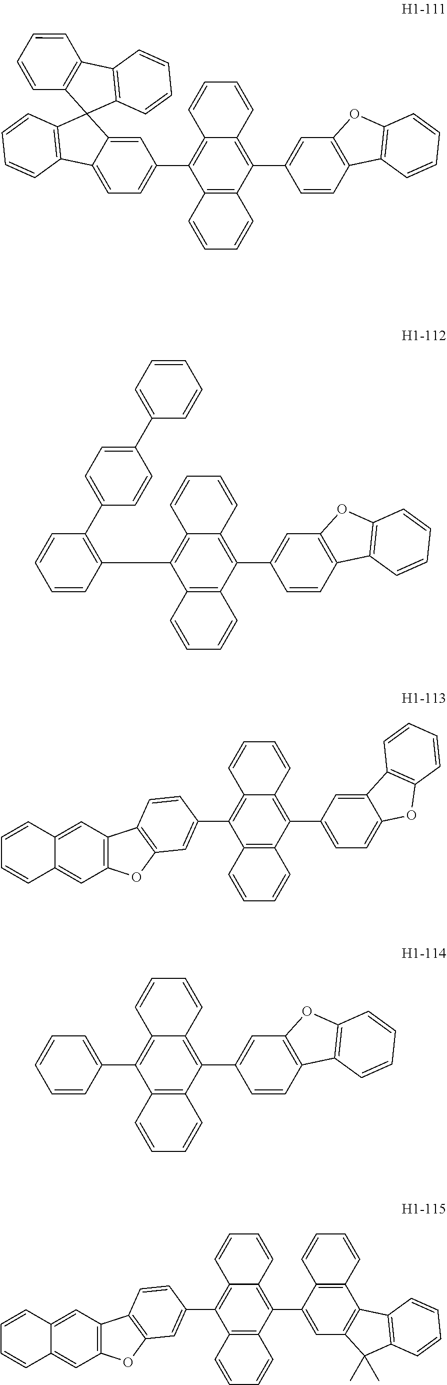 [SMILES: c1ccc2c(c1)-c1ccccc1C21c2ccccc2-c2ccc(-c3c4ccccc4c(-c4ccc5c(c4)oc4ccccc45)c4ccccc34)cc21 ; c1ccc(-c2ccc(-c3ccccc3-c3c4ccccc4c(-c4ccc5c(c4)oc4ccccc45)c4ccccc34)cc2)cc1 ; c1ccc2cc3c(cc2c1)oc1cc(-c2c4ccccc4c(-c4ccc5oc6ccccc6c5c4)c4ccccc24)ccc13 ; c1ccc(-c2c3ccccc3c(-c3ccc4c(c3)oc3ccccc34)c3ccccc23)cc1 ; CC1(C)c2ccccc2-c2c1cc(-c1c3ccccc3c(-c3ccc4c(c3)oc3cc5ccccc5cc34)c3ccccc13)c1ccccc21]

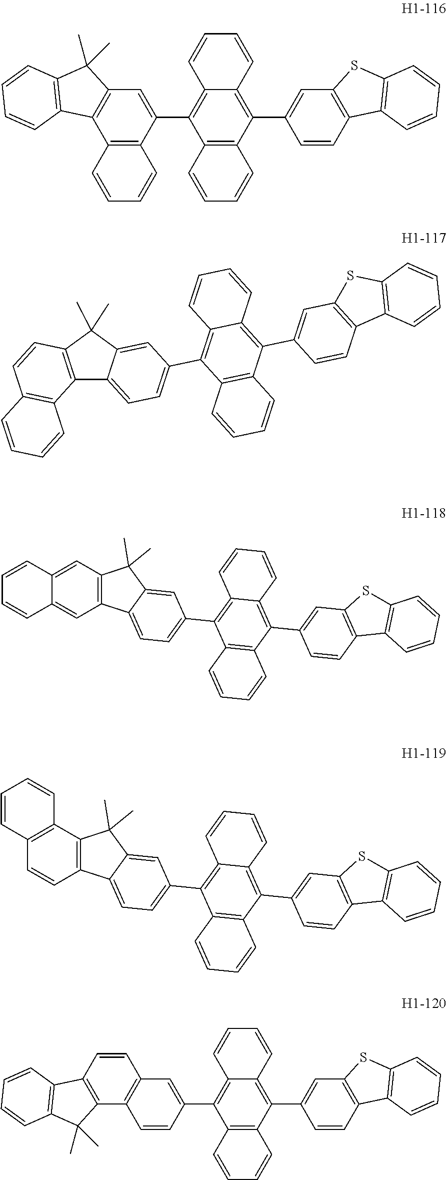 [SMILES: CC1(C)c2ccccc2-c2c1cc(-c1c3ccccc3c(-c3ccc4c(c3)sc3ccccc34)c3ccccc13)c1ccccc21 ; CC1(C)c2cc(-c3c4ccccc4c(-c4ccc5c(c4)sc4ccccc45)c4ccccc34)ccc2-c2c1ccc1ccccc21 ; CC1(C)c2cc(-c3c4ccccc4c(-c4ccc5c(c4)sc4ccccc45)c4ccccc34)ccc2-c2cc3ccccc3cc21 ; CC1(C)c2cc(-c3c4ccccc4c(-c4ccc5c(c4)sc4ccccc45)c4ccccc34)ccc2-c2ccc3ccccc3c21 ; CC1(C)c2ccccc2-c2ccc3cc(-c4c5ccccc5c(-c5ccc6c(c5)sc5ccccc56)c5ccccc45)ccc3c21]

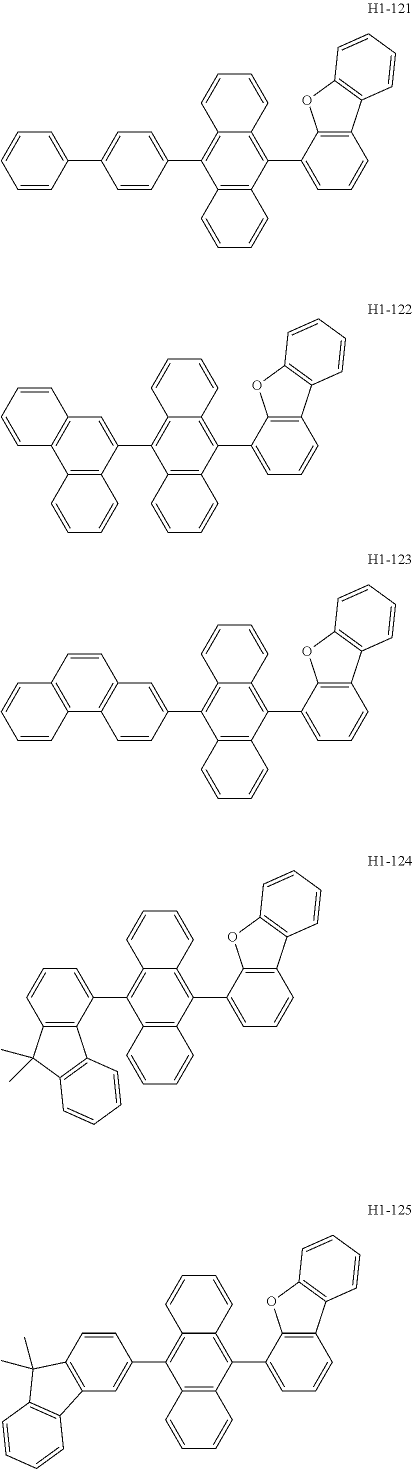 [SMILES: c1ccc(-c2ccc(-c3c4ccccc4c(-c4cccc5c4oc4ccccc45)c4ccccc34)cc2)cc1 ; c1ccc2c(c1)cc(-c1c3ccccc3c(-c3cccc4c3oc3ccccc34)c3ccccc13)c1ccccc12 ; c1ccc2c(c1)ccc1cc(-c3c4ccccc4c(-c4cccc5c4oc4ccccc45)c4ccccc34)ccc12 ; CC1(C)c2ccccc2-c2c(-c3c4ccccc4c(-c4cccc5c4oc4ccccc45)c4ccccc34)cccc21 ; CC1(C)c2ccccc2-c2cc(-c3c4ccccc4c(-c4cccc5c4oc4ccccc45)c4ccccc34)ccc21]

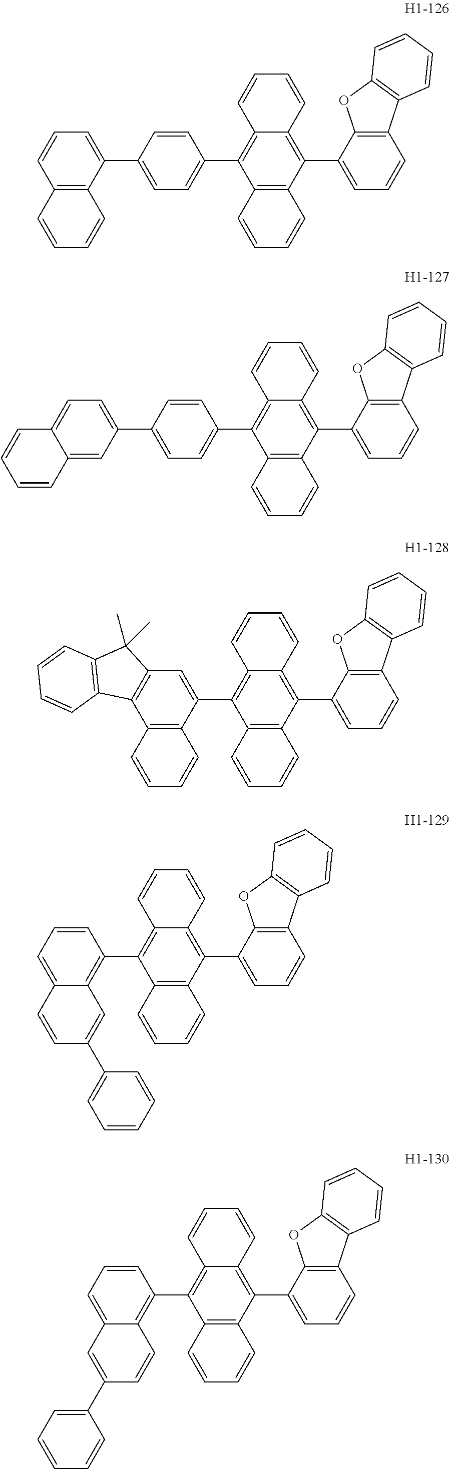 [SMILES: c1ccc2c(-c3ccc(-c4c5ccccc5c(-c5cccc6c5oc5ccccc56)c5ccccc45)cc3)cccc2c1 ; c1ccc2cc(-c3ccc(-c4c5ccccc5c(-c5cccc6c5oc5ccccc56)c5ccccc45)cc3)ccc2c1 ; CC1(C)c2ccccc2-c2c1cc(-c1c3ccccc3c(-c3cccc4c3oc3ccccc34)c3ccccc13)c1ccccc21 ; c1ccc(-c2ccc3cccc(-c4c5ccccc5c(-c5cccc6c5oc5ccccc56)c5ccccc45)c3c2)cc1 ; c1ccc(-c2ccc3c(-c4c5ccccc5c(-c5cccc6c5oc5ccccc56)c5ccccc45)cccc3c2)cc1]

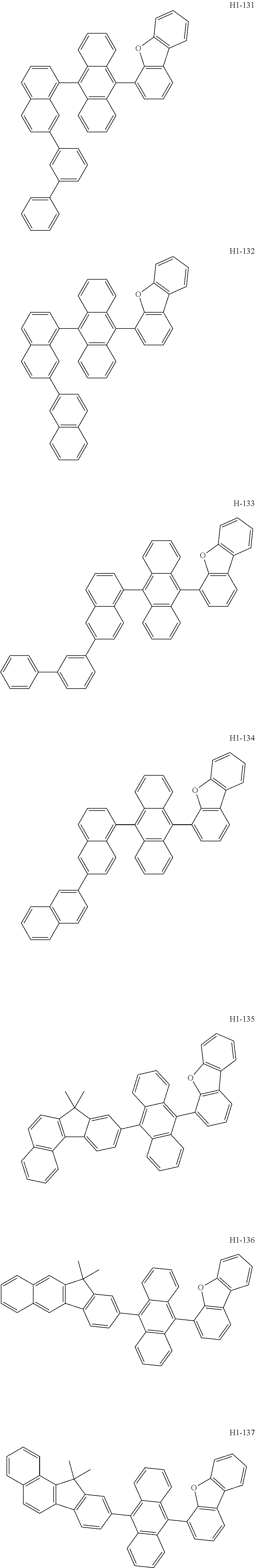

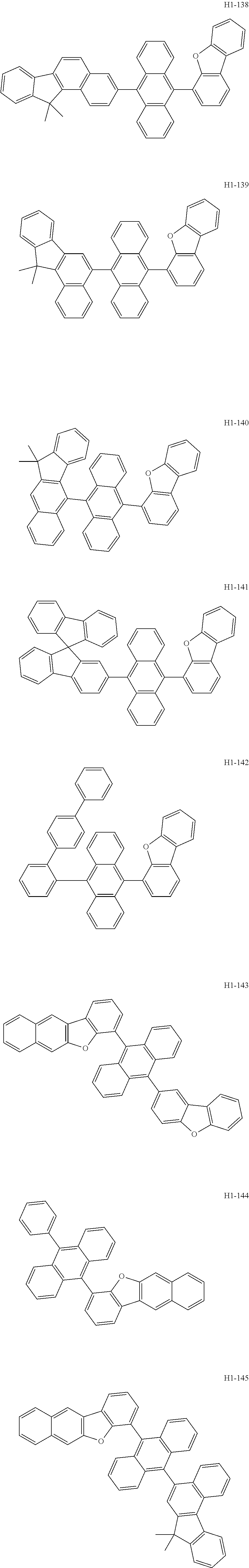

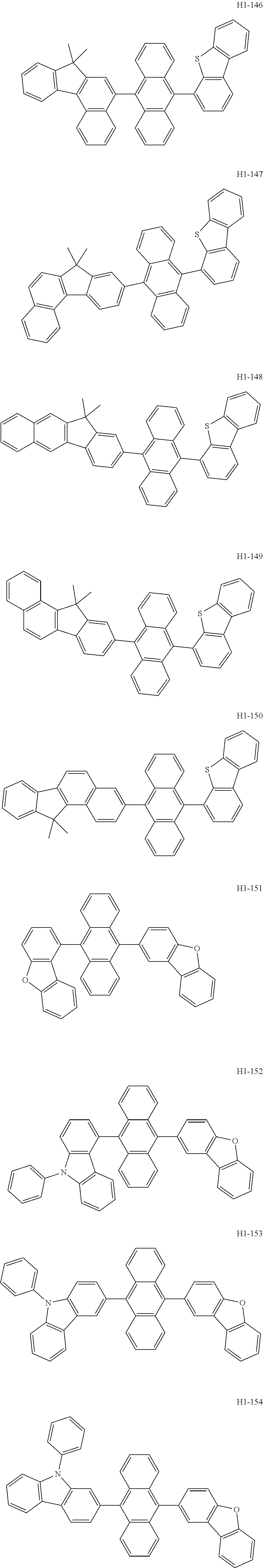

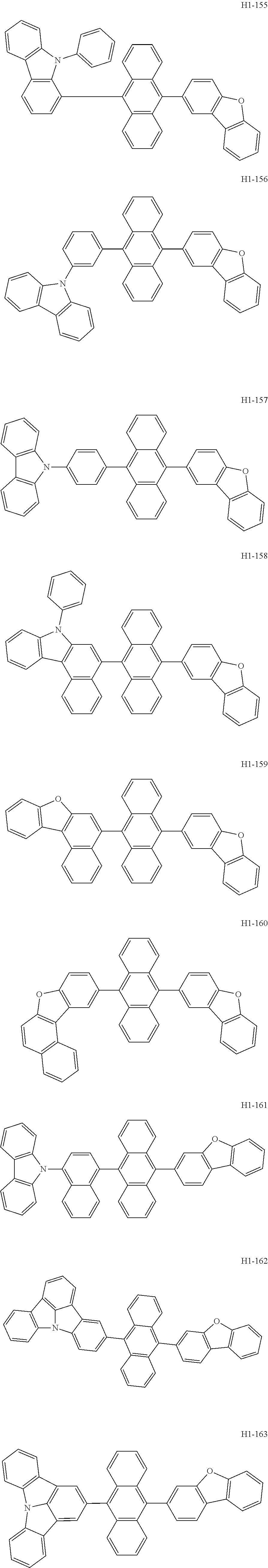

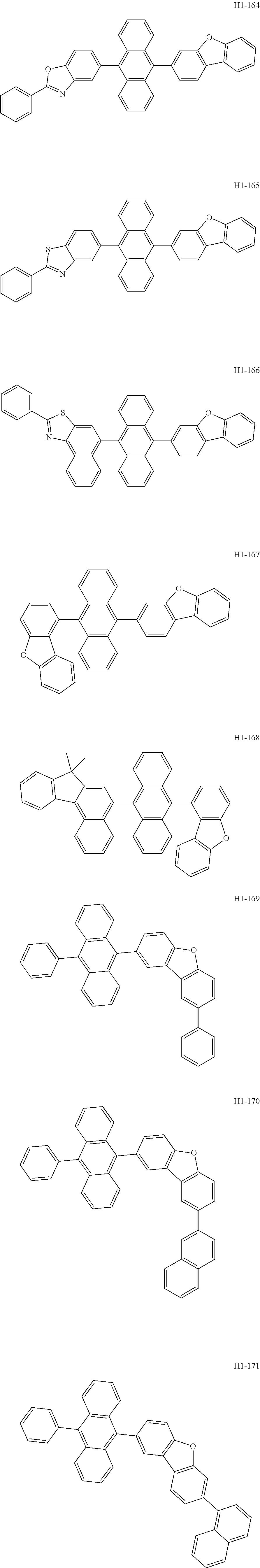

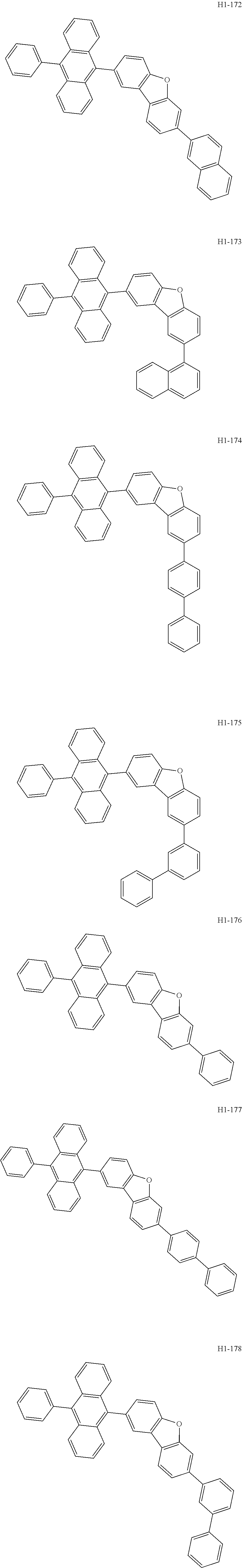

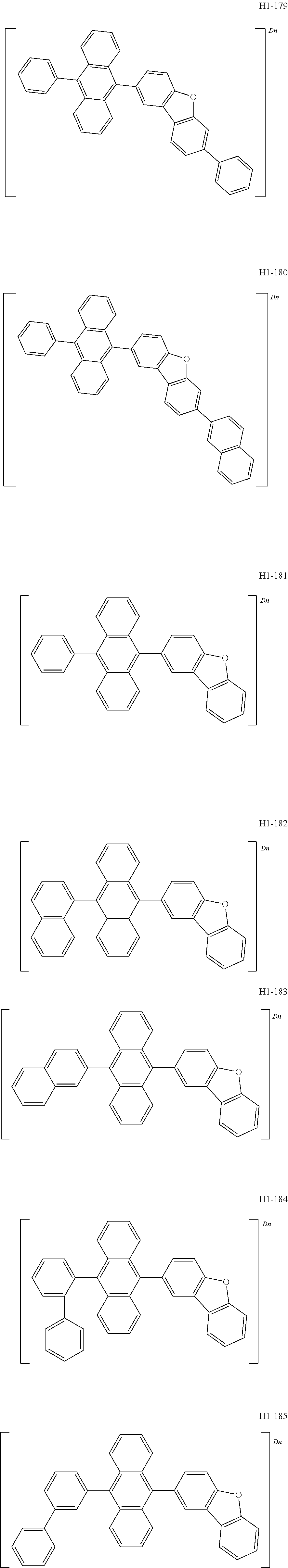

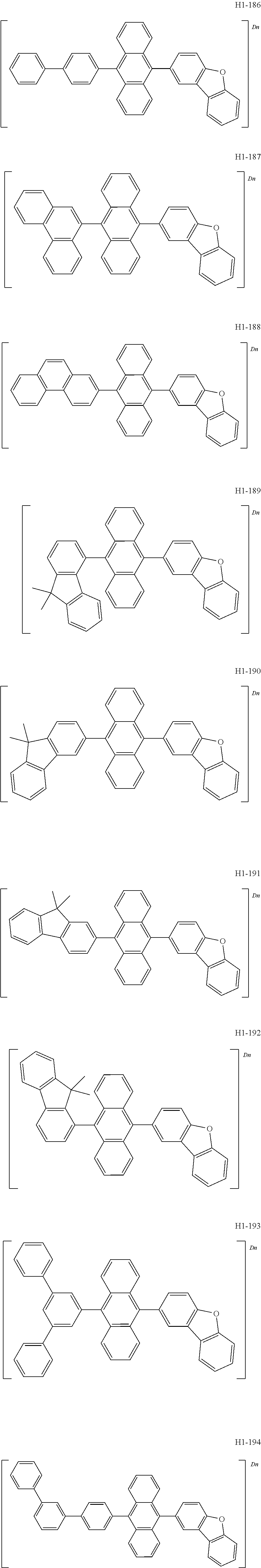

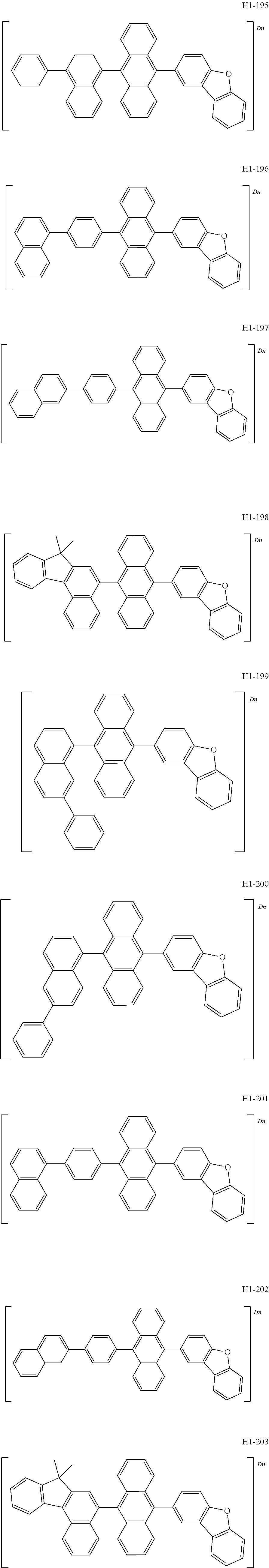

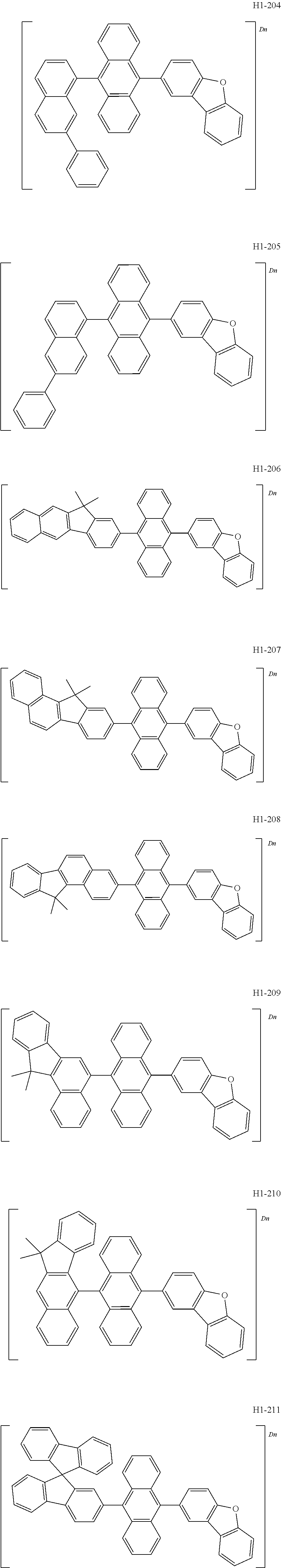

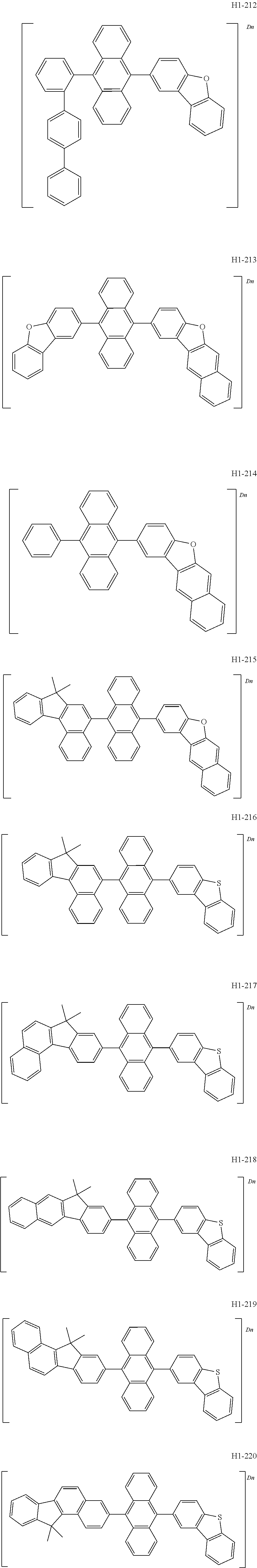

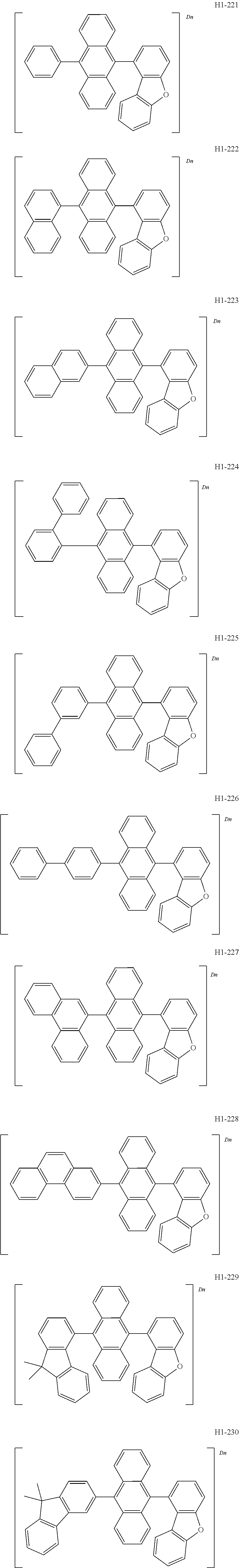

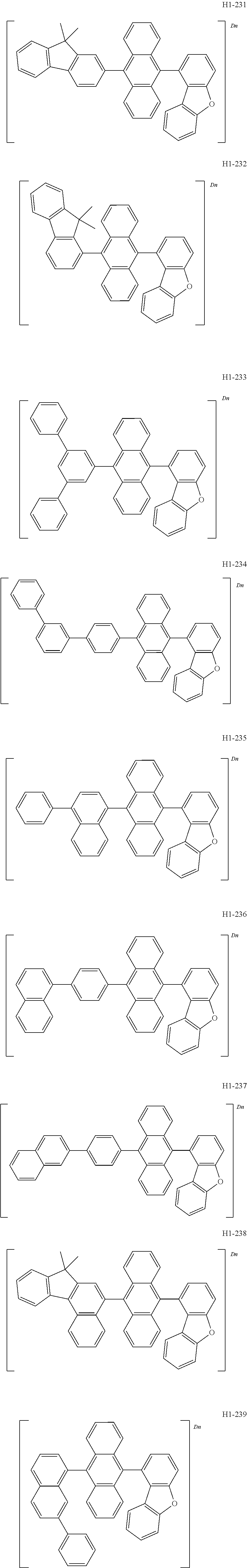

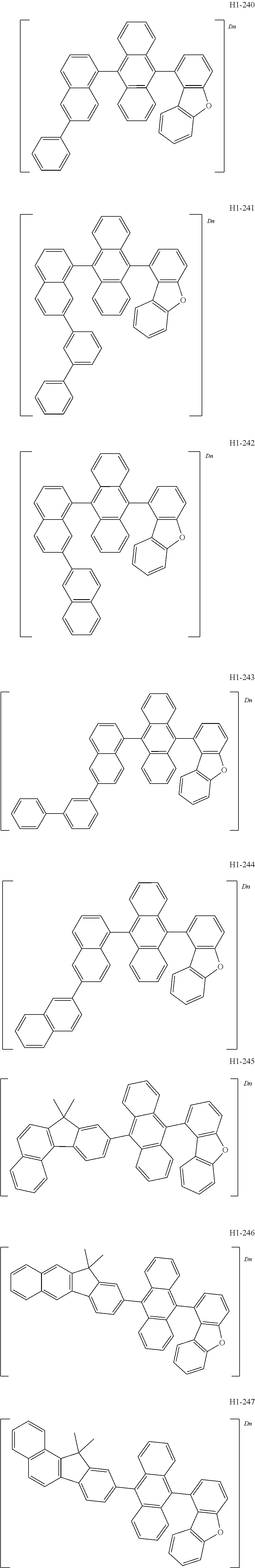

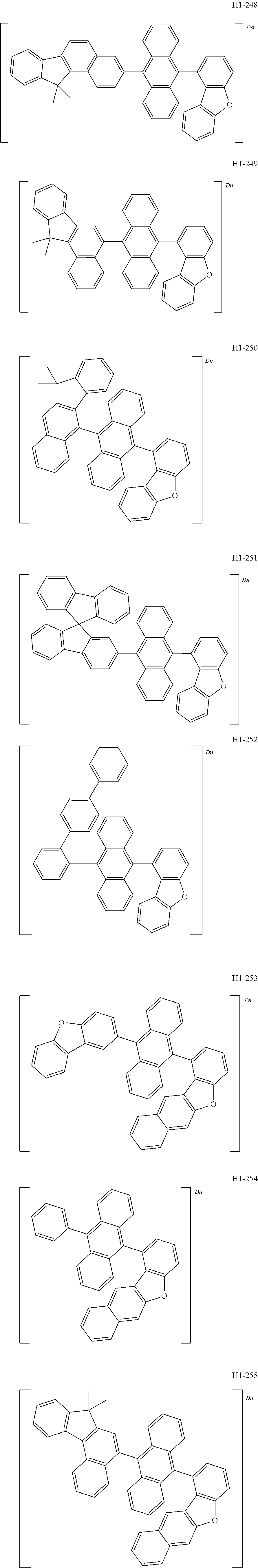

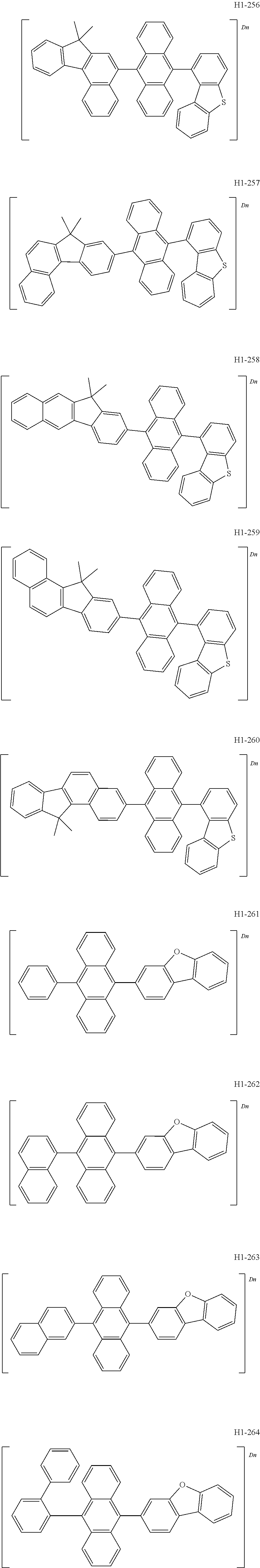

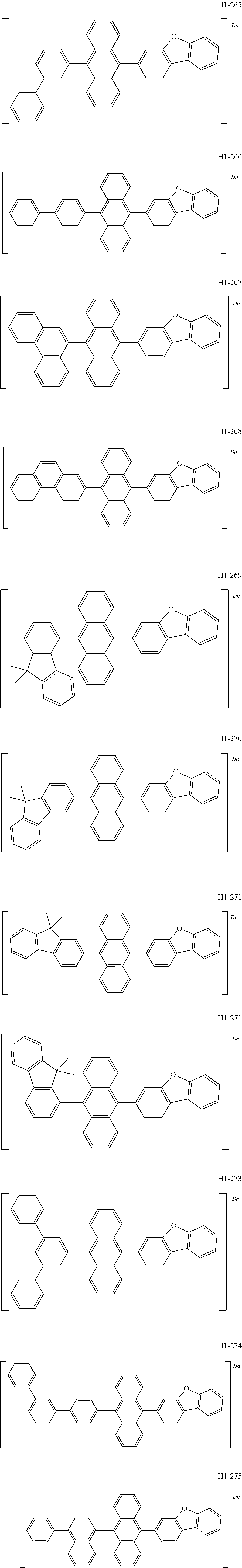

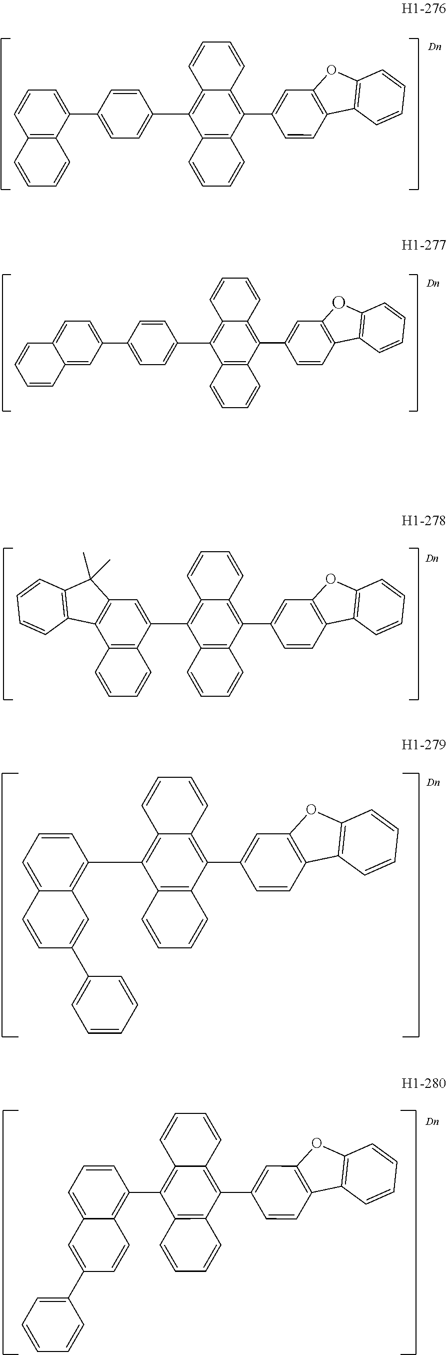

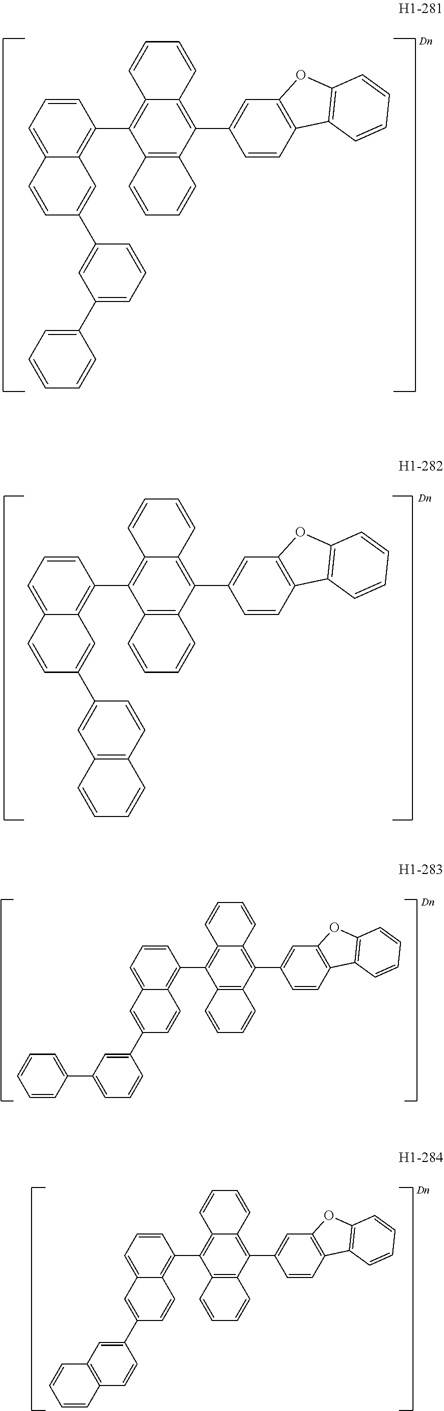

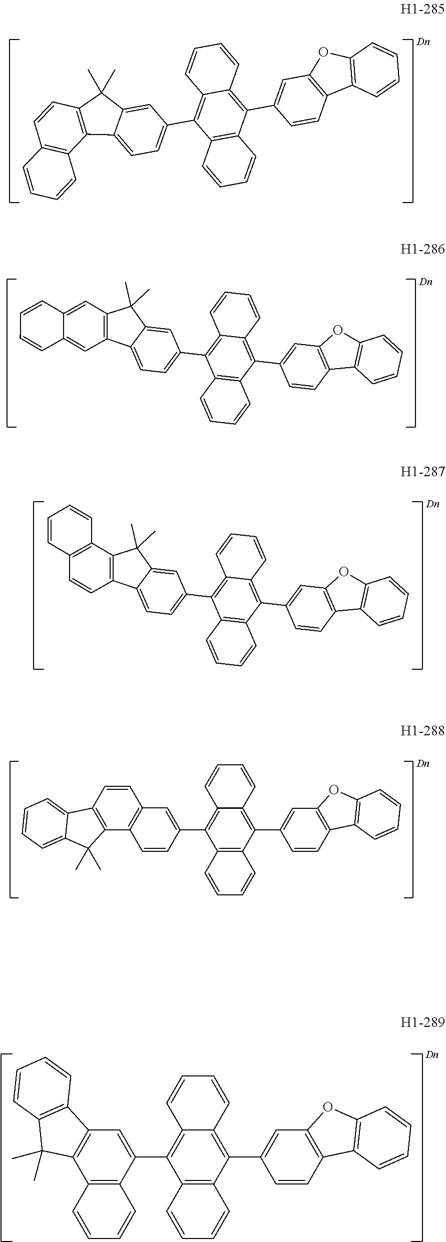

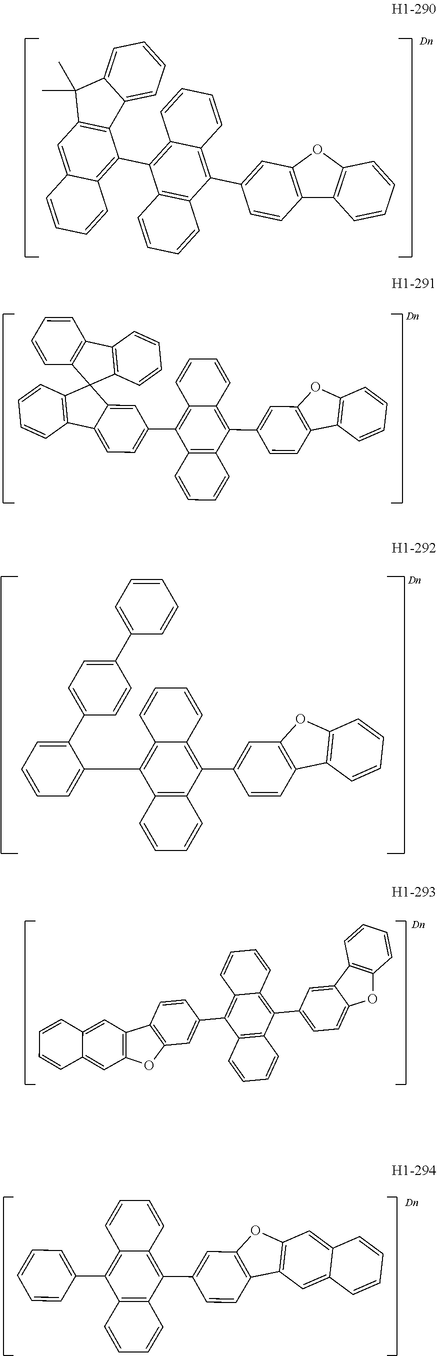

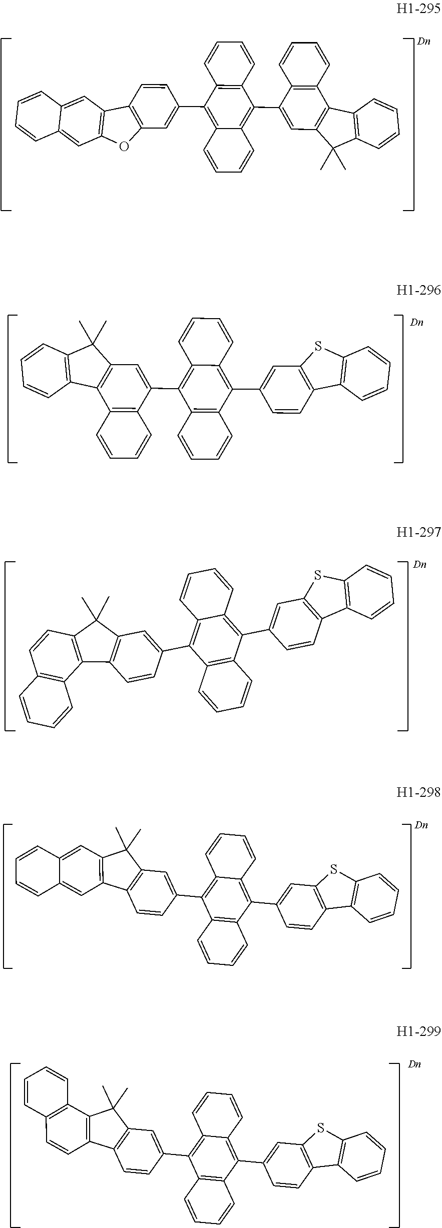

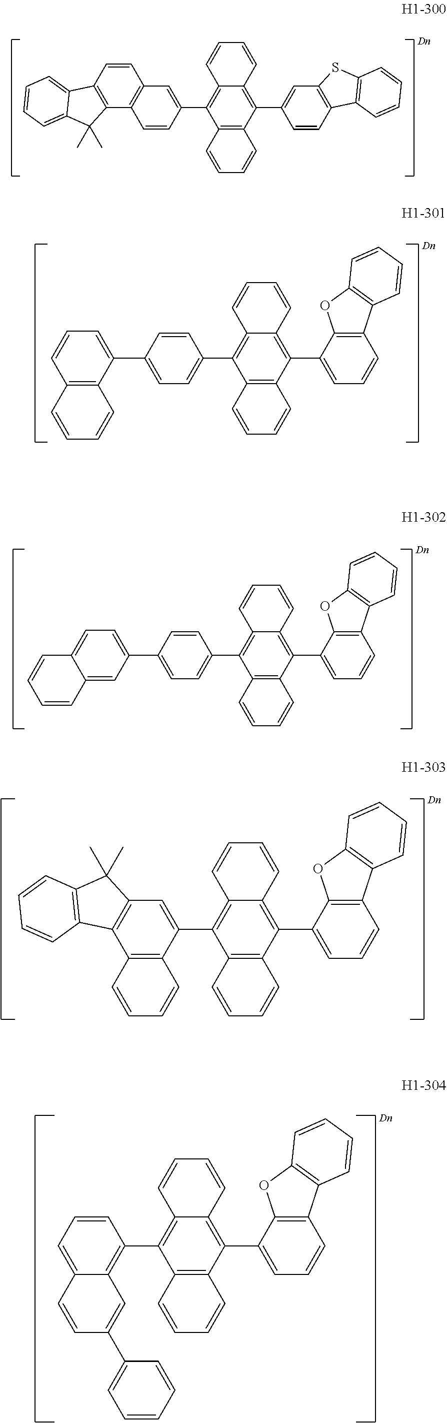

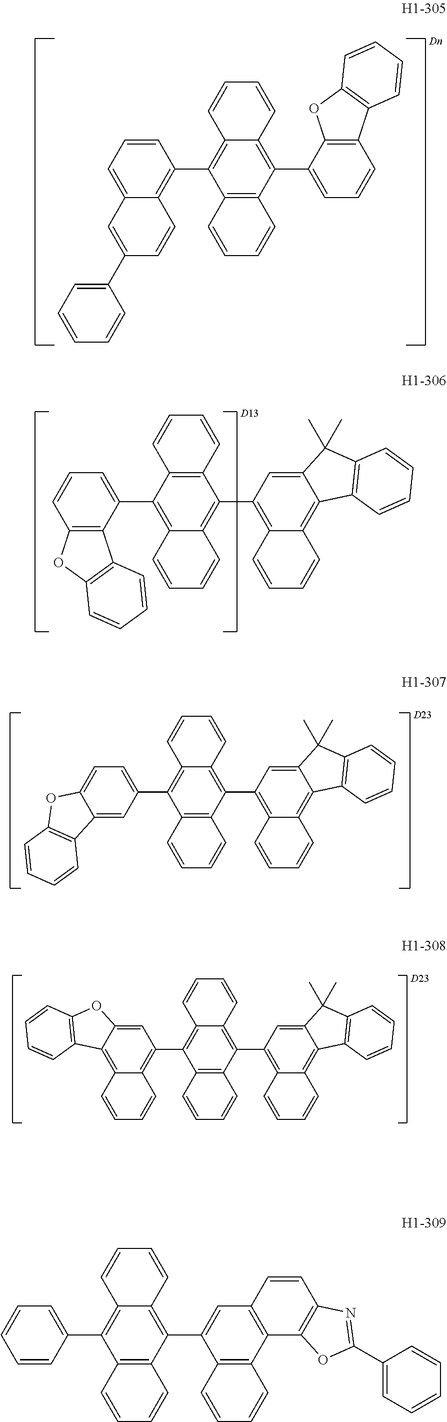

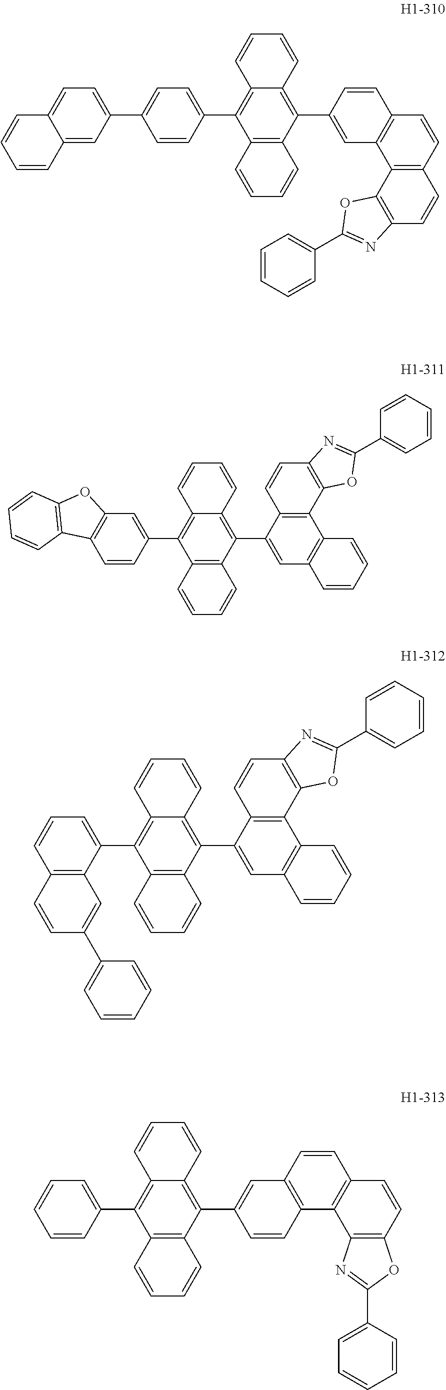 [SMILES: c1ccc(-c2nc3ccc4ccc5ccc(-c6c7ccccc7c(-c7ccc(-c8ccc9ccccc9c8)cc7)c7ccccc67)cc5c4c3o2)cc1 ; c1ccc(-c2nc3ccc4c(-c5c6ccccc6c(-c6ccc7c(c6)oc6ccccc67)c6ccccc56)cc5ccccc5c4c3o2)cc1 ; c1ccc(-c2ccc3cccc(-c4c5ccccc5c(-c5cc6ccccc6c6c5ccc5nc(-c7ccccc7)oc56)c5ccccc45)c3c2)cc1 ; c1ccc(-c2nc3c(ccc4ccc5cc(-c6c7ccccc7c(-c7ccccc7)c7ccccc67)ccc5c43)o2)cc1]

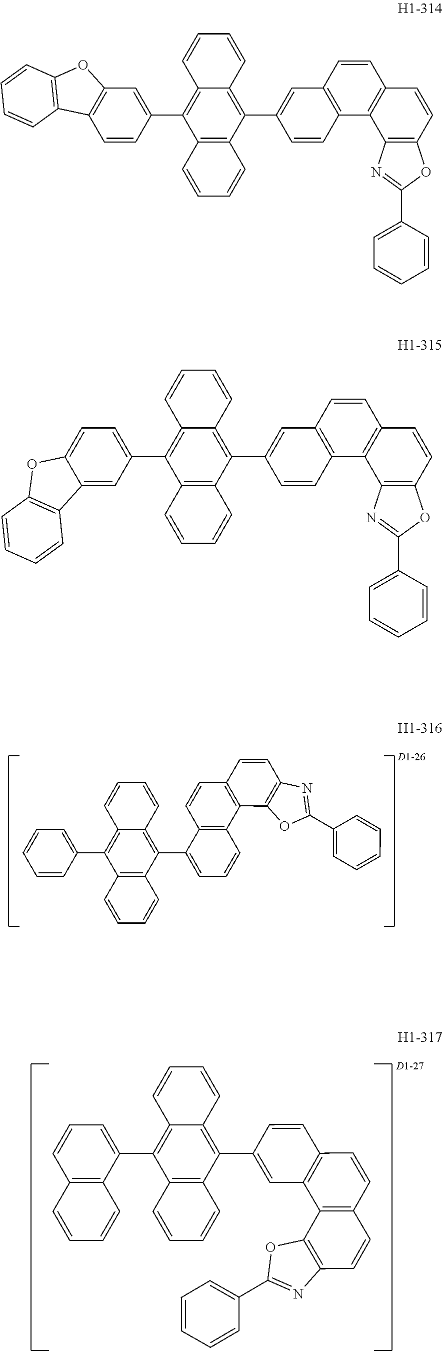

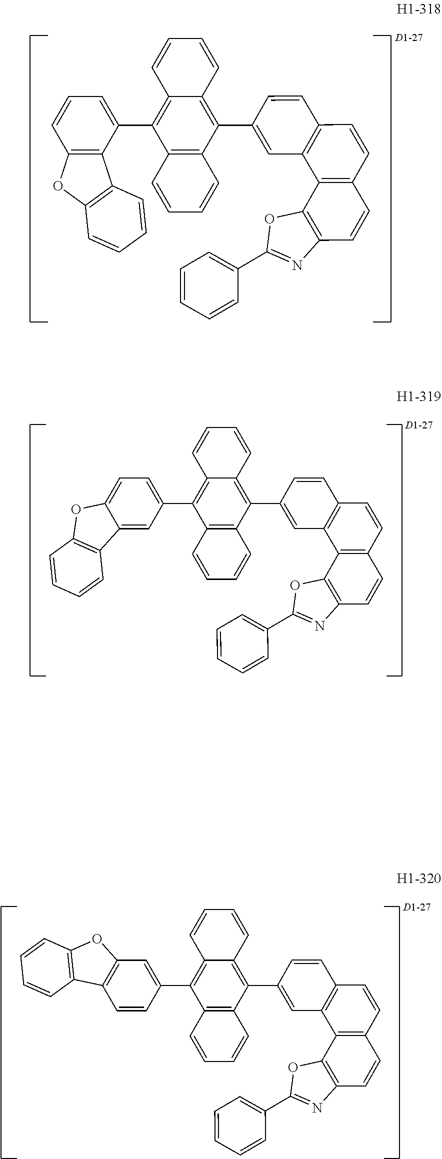

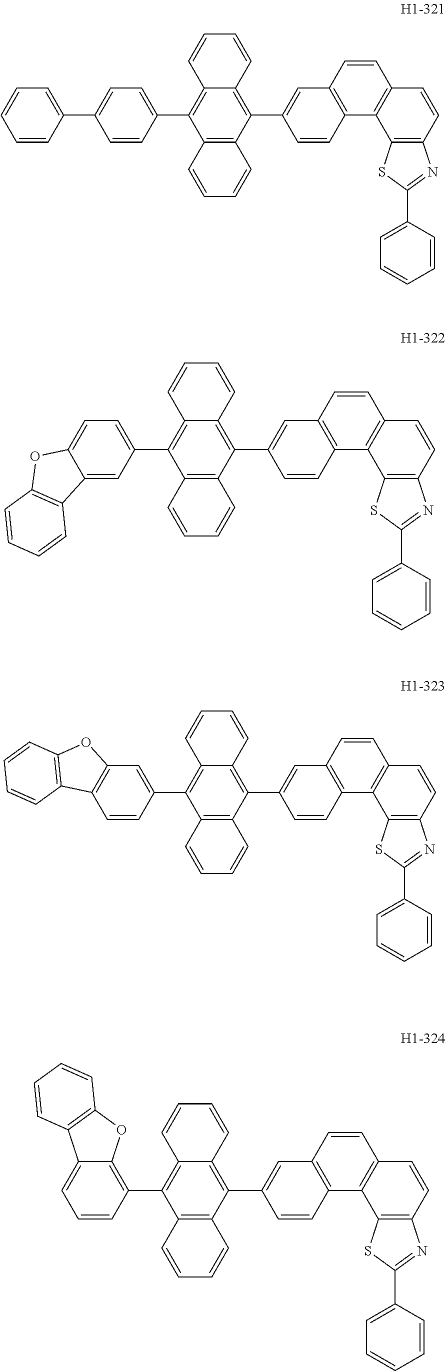 [SMILES: c1ccc(-c2ccc(-c3c4ccccc4c(-c4ccc5c(ccc6ccc7nc(-c8ccccc8)sc7c65)c4)c4ccccc34)cc2)cc1 ; c1ccc(-c2nc3ccc4ccc5cc(-c6c7ccccc7c(-c7ccc8oc9ccccc9c8c7)c7ccccc67)ccc5c4c3s2)cc1 ; c1ccc(-c2nc3ccc4ccc5cc(-c6c7ccccc7c(-c7ccc8c(c7)oc7ccccc78)c7ccccc67)ccc5c4c3s2)cc1 ; c1ccc(-c2nc3ccc4ccc5cc(-c6c7ccccc7c(-c7cccc8c7oc7ccccc78)c7ccccc67)ccc5c4c3s2)cc1]

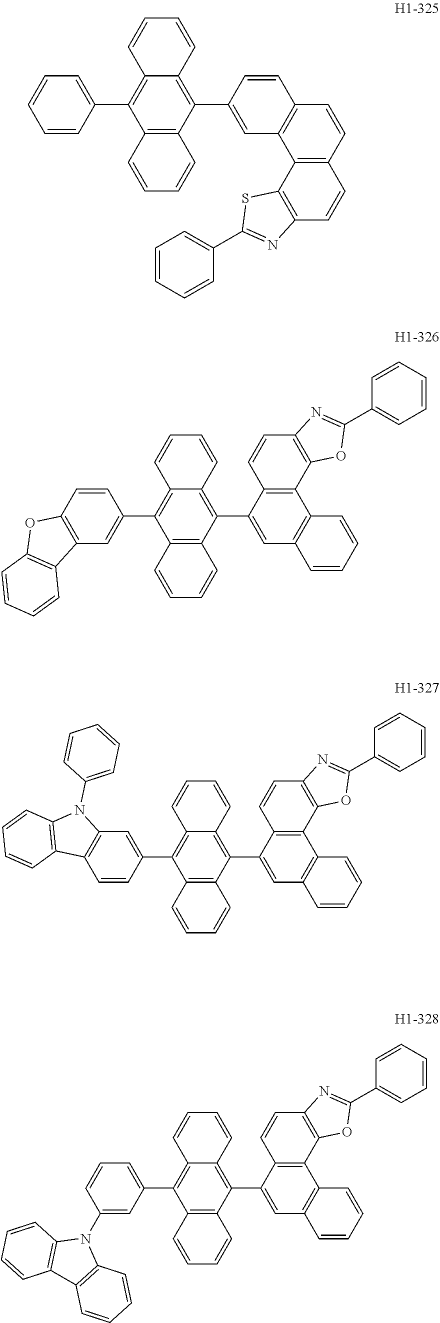 [SMILES: c1ccc(-c2nc3ccc4ccc5ccc(-c6c7ccccc7c(-c7ccccc7)c7ccccc67)cc5c4c3s2)cc1 ; c1ccc(-c2nc3ccc4c(-c5c6ccccc6c(-c6ccc7oc8ccccc8c7c6)c6ccccc56)cc5ccccc5c4c3o2)cc1 ; c1ccc(-c2nc3ccc4c(-c5c6ccccc6c(-c6ccc7c8ccccc8n(-c8ccccc8)c7c6)c6ccccc56)cc5ccccc5c4c3o2)cc1 ; c1ccc(-c2nc3ccc4c(-c5c6ccccc6c(-c6cccc(-n7c8ccccc8c8ccccc87)c6)c6ccccc56)cc5ccccc5c4c3o2)cc1]

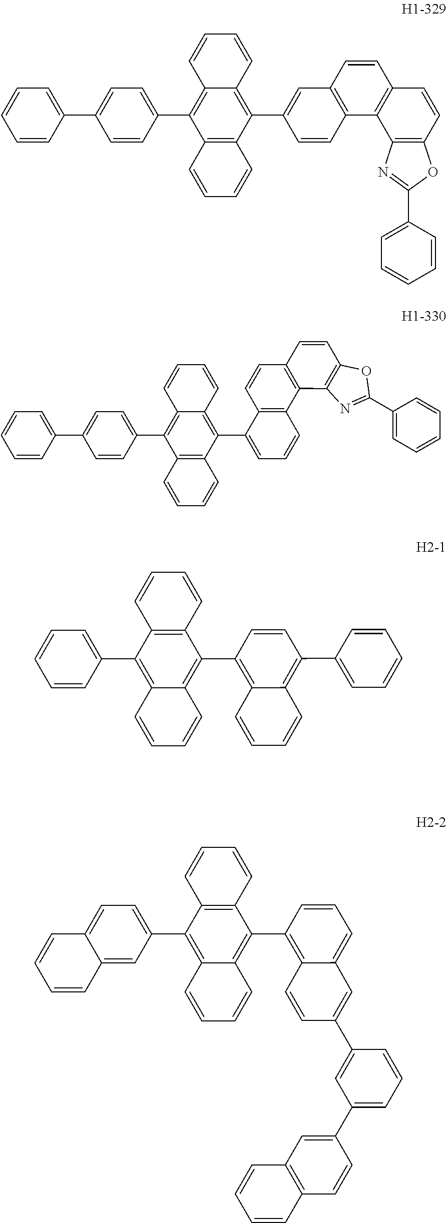

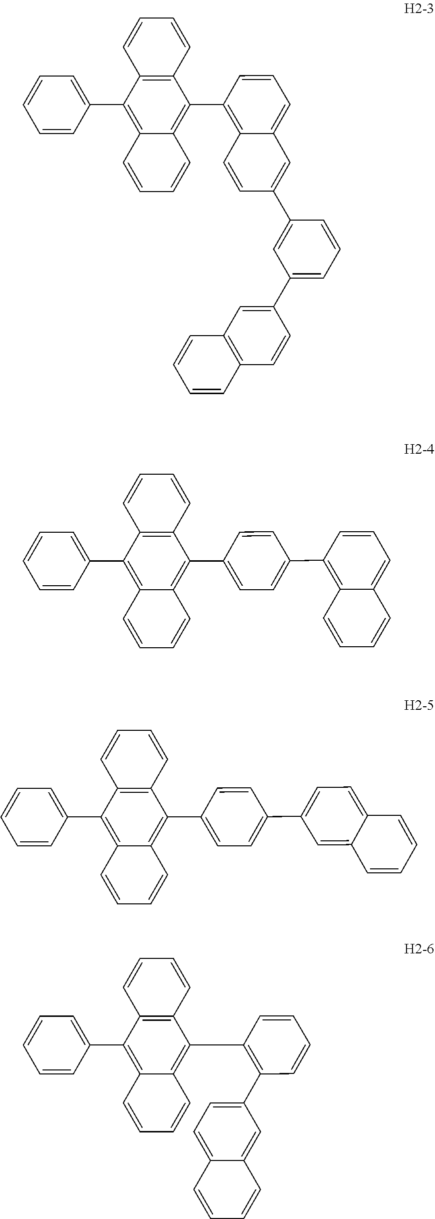

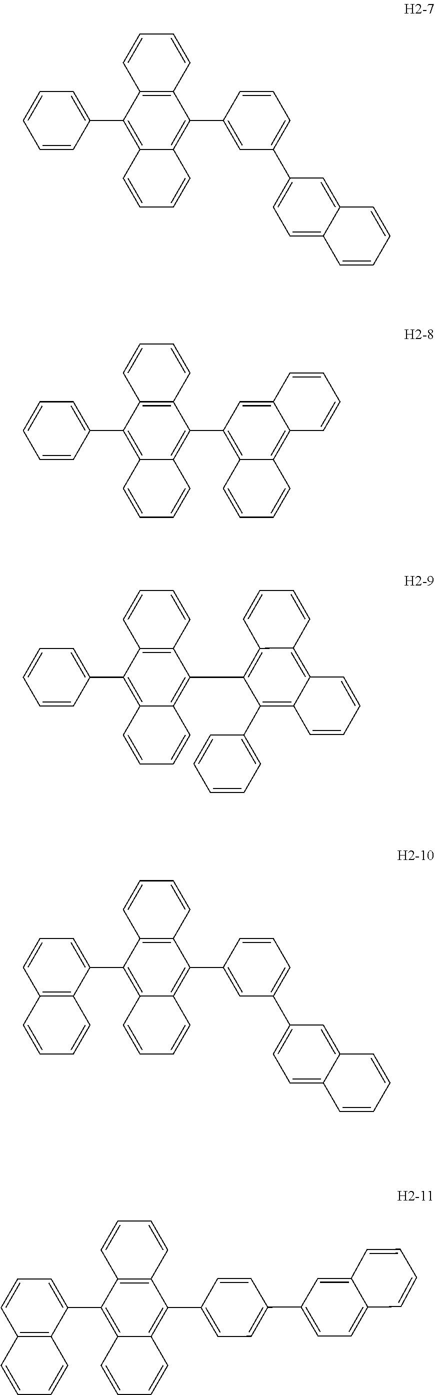

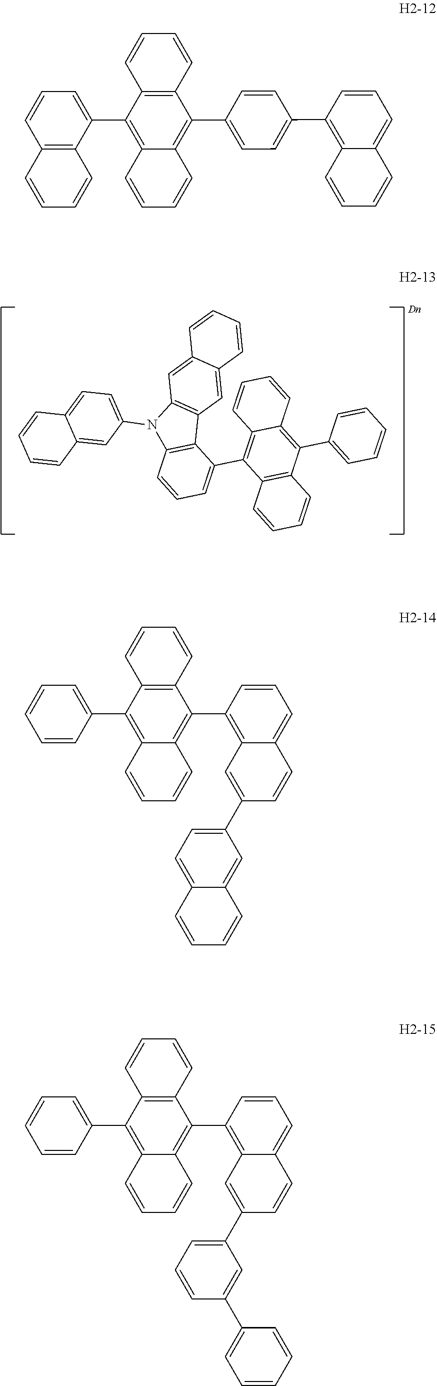

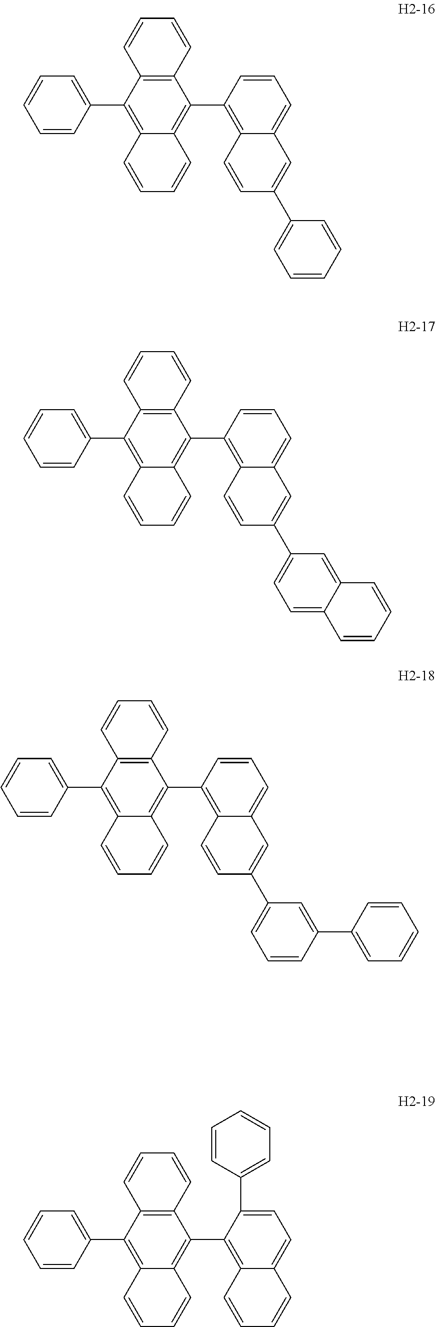

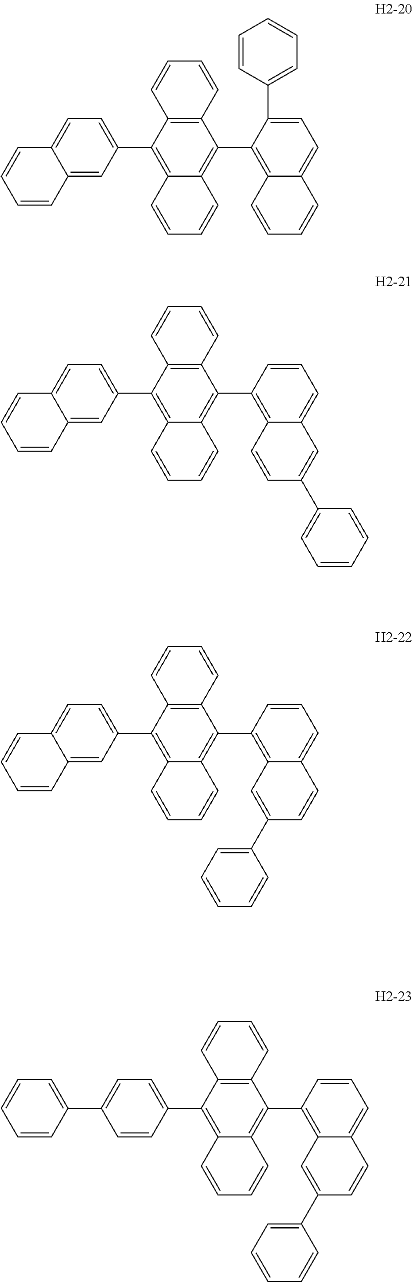

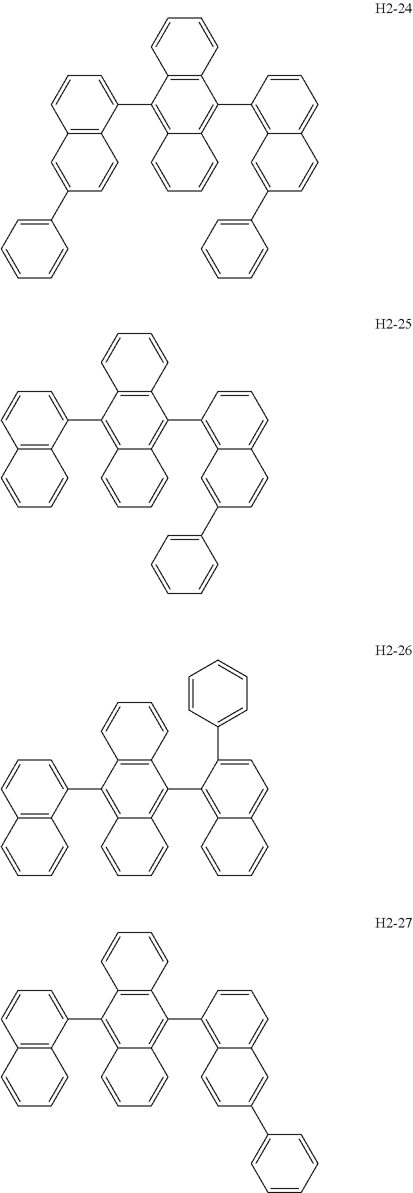

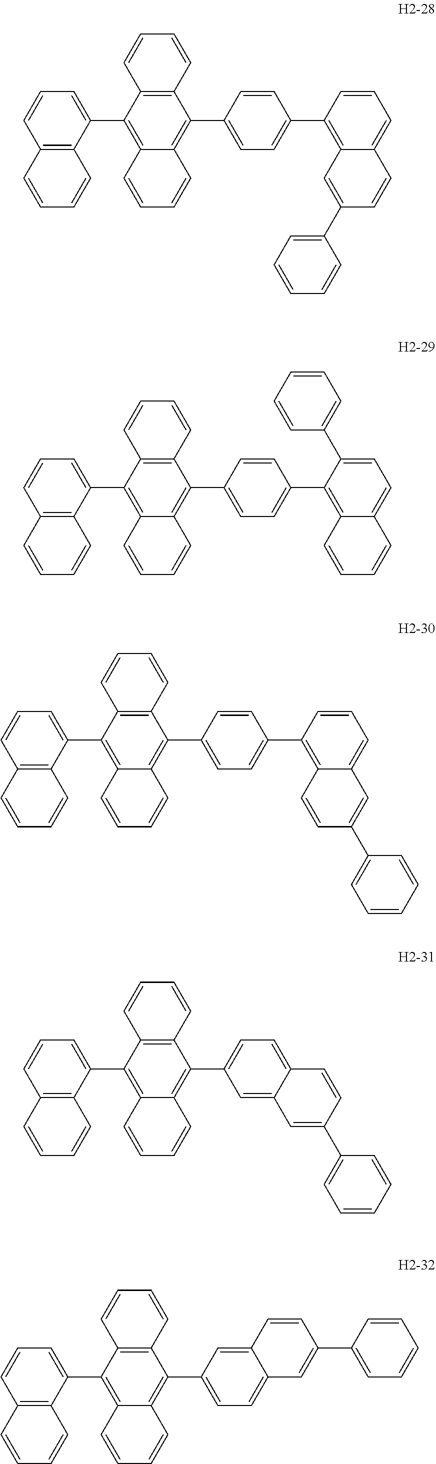

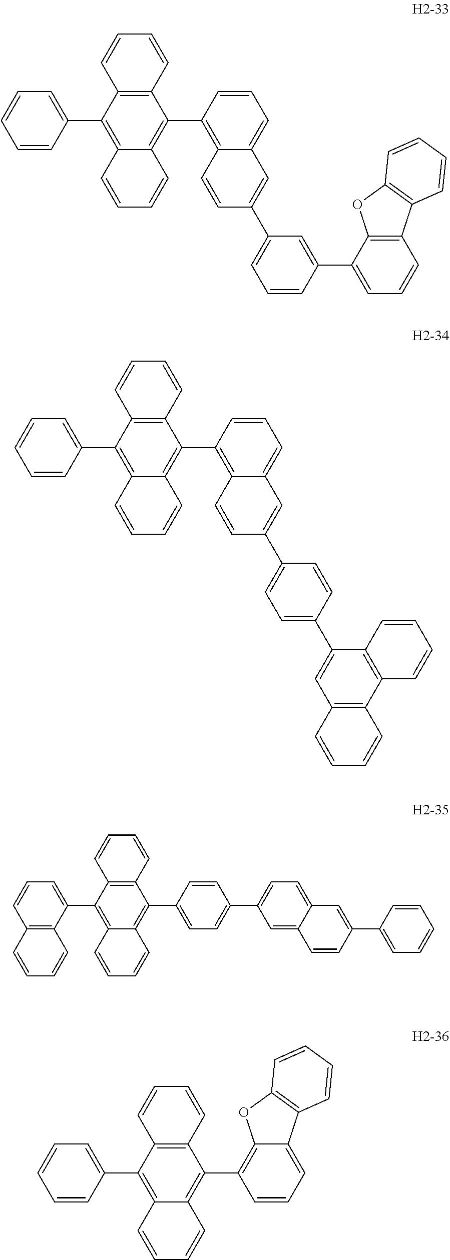

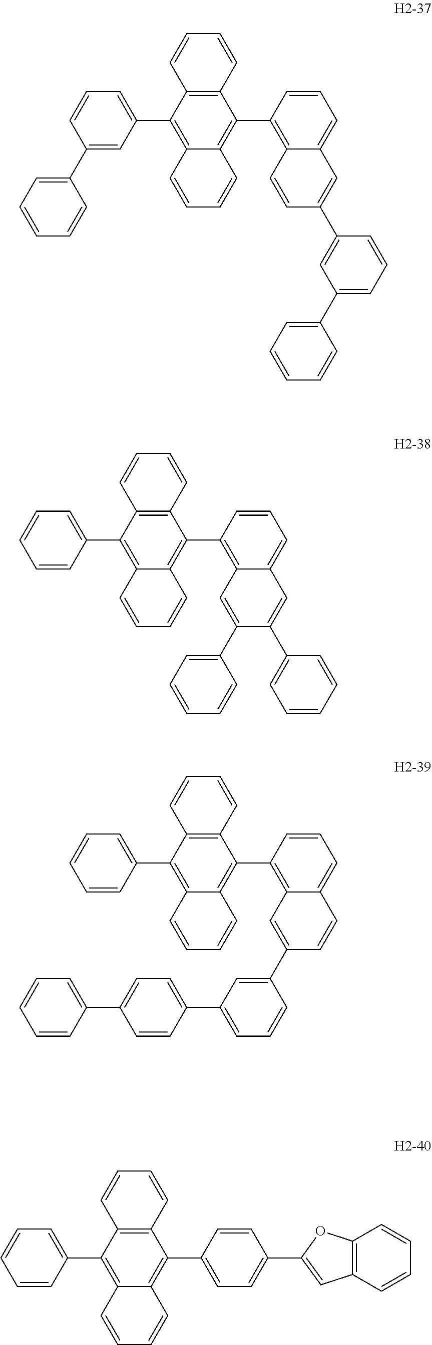

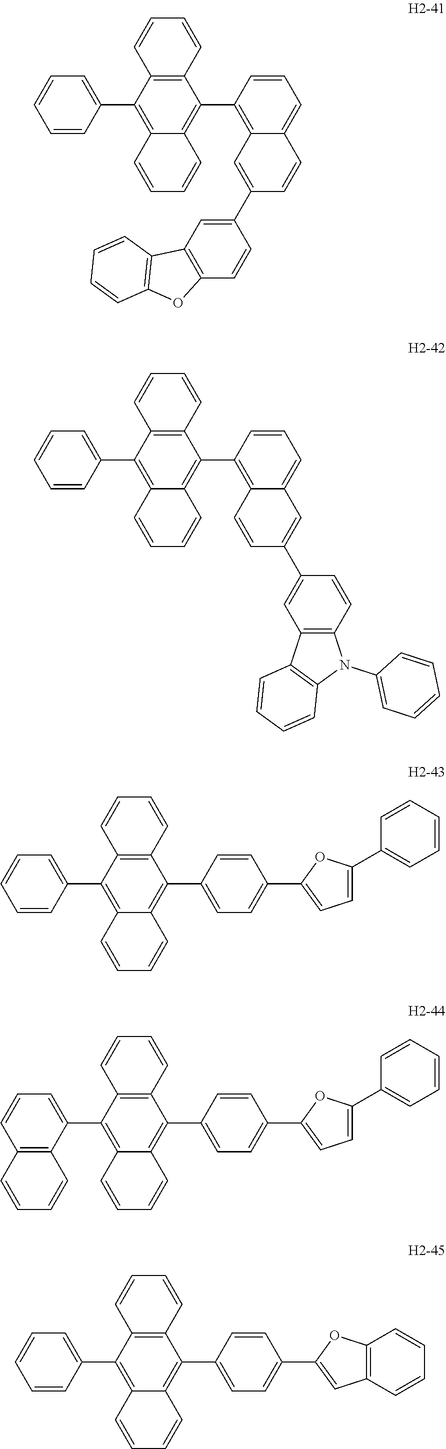 [SMILES: c1ccc(-c2c3ccccc3c(-c3cccc4ccc(-c5ccc6oc7ccccc7c6c5)cc34)c3ccccc23)cc1 ; c1ccc(-c2c3ccccc3c(-c3cccc4cc(-c5ccc6c(c5)c5ccccc5n6-c5ccccc5)ccc34)c3ccccc23)cc1 ; c1ccc(-c2ccc(-c3ccc(-c4c5ccccc5c(-c5ccccc5)c5ccccc45)cc3)o2)cc1 ; c1ccc(-c2ccc(-c3ccc(-c4c5ccccc5c(-c5cccc6ccccc56)c5ccccc45)cc3)o2)cc1 ; c1ccc(-c2c3ccccc3c(-c3ccc(-c4cc5ccccc5o4)cc3)c3ccccc23)cc1]

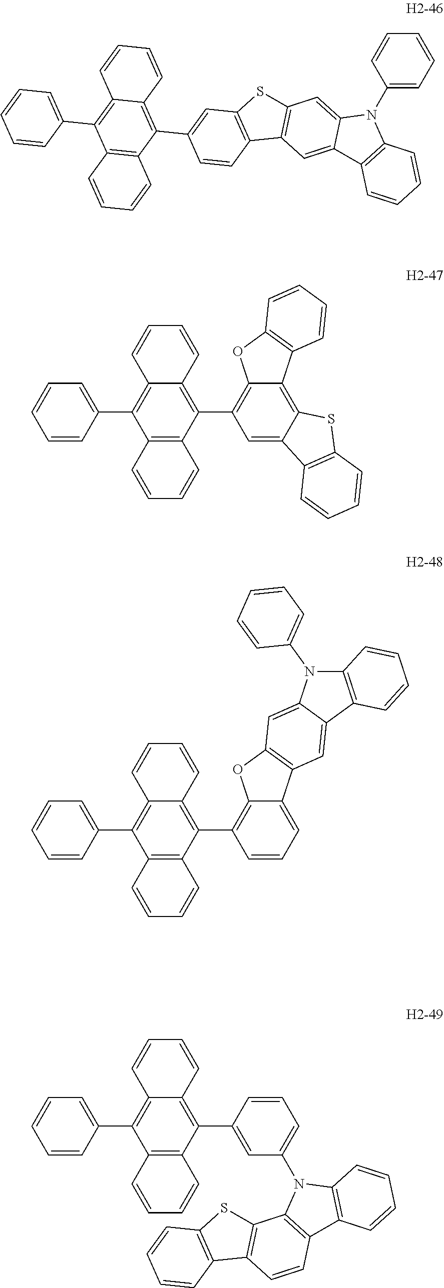 [SMILES: c1ccc(-c2c3ccccc3c(-c3ccc4c(c3)sc3cc5c(cc34)c3ccccc3n5-c3ccccc3)c3ccccc23)cc1 ; c1ccc(-c2c3ccccc3c(-c3cc4c5ccccc5sc4c4c3oc3ccccc34)c3ccccc23)cc1 ; c1ccc(-c2c3ccccc3c(-c3cccc4c3oc3cc5c(cc34)c3ccccc3n5-c3ccccc3)c3ccccc23)cc1 ; c1ccc(-c2c3ccccc3c(-c3cccc(-n4c5ccccc5c5ccc6c7ccccc7sc6c54)c3)c3ccccc23)cc1]

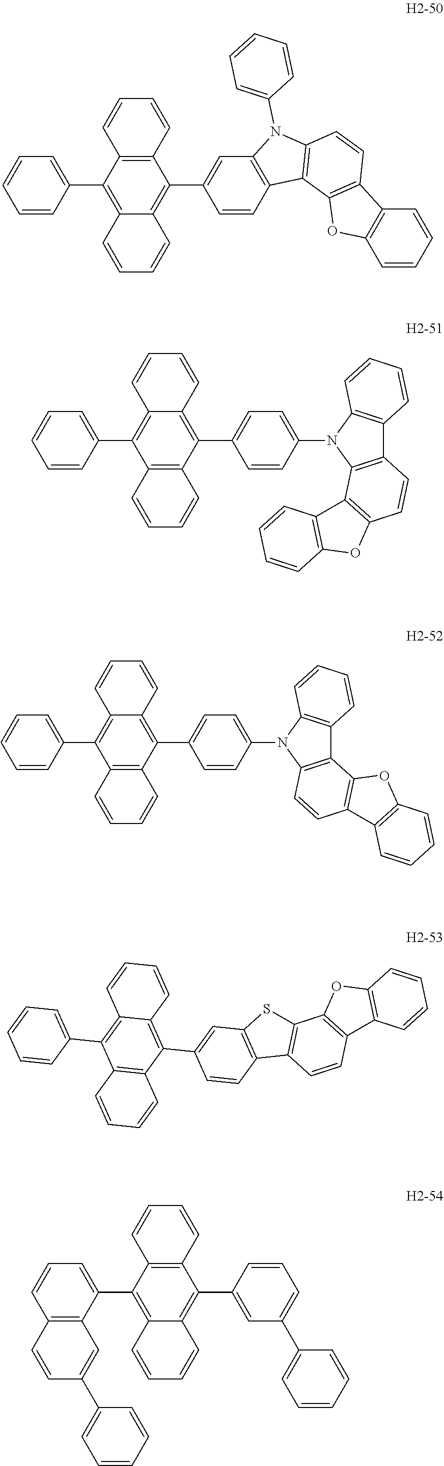

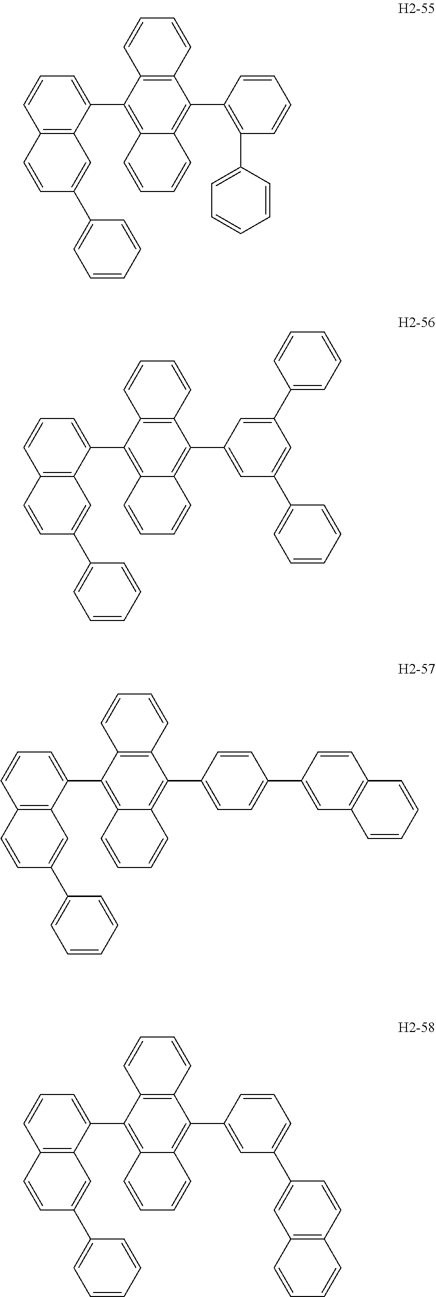

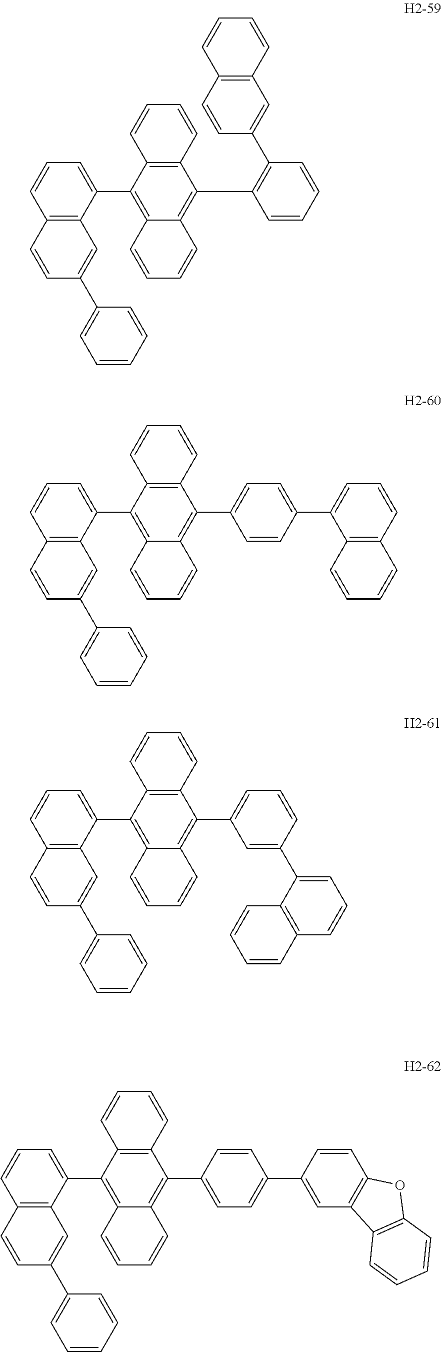

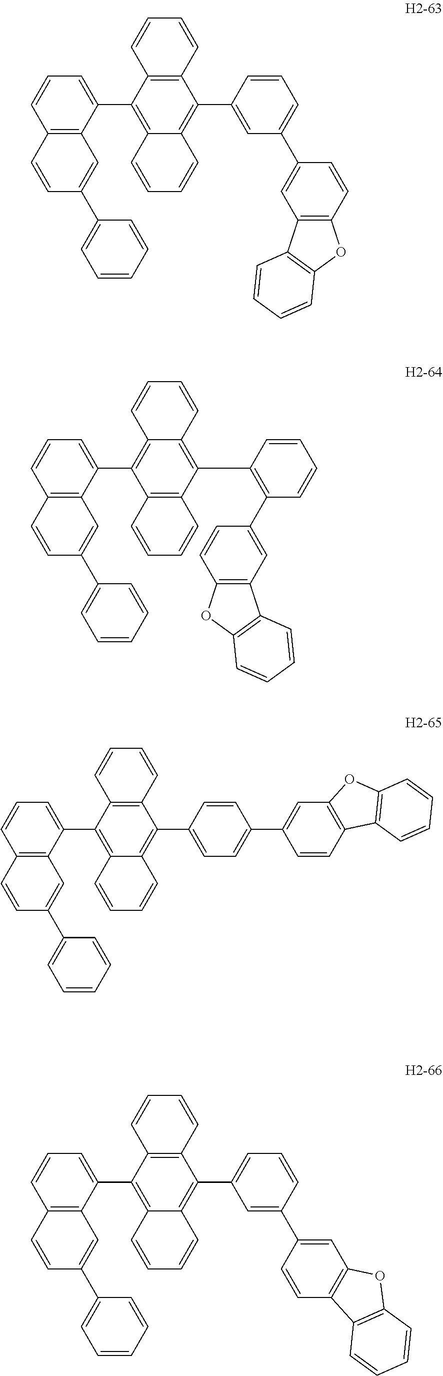 [SMILES: c1ccc(-c2ccc3cccc(-c4c5ccccc5c(-c5cccc(-c6ccc7oc8ccccc8c7c6)c5)c5ccccc45)c3c2)cc1 ; c1ccc(-c2ccc3cccc(-c4c5ccccc5c(-c5ccccc5-c5ccc6oc7ccccc7c6c5)c5ccccc45)c3c2)cc1 ; c1ccc(-c2ccc3cccc(-c4c5ccccc5c(-c5ccc(-c6ccc7c(c6)oc6ccccc67)cc5)c5ccccc45)c3c2)cc1 ; c1ccc(-c2ccc3cccc(-c4c5ccccc5c(-c5cccc(-c6ccc7c(c6)oc6ccccc67)c5)c5ccccc45)c3c2)cc1]

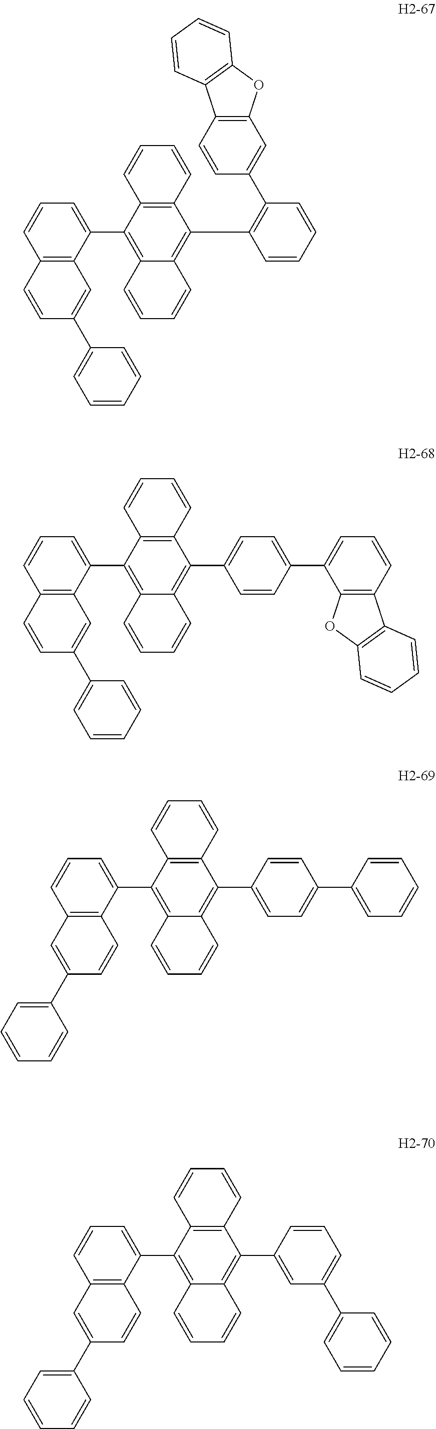

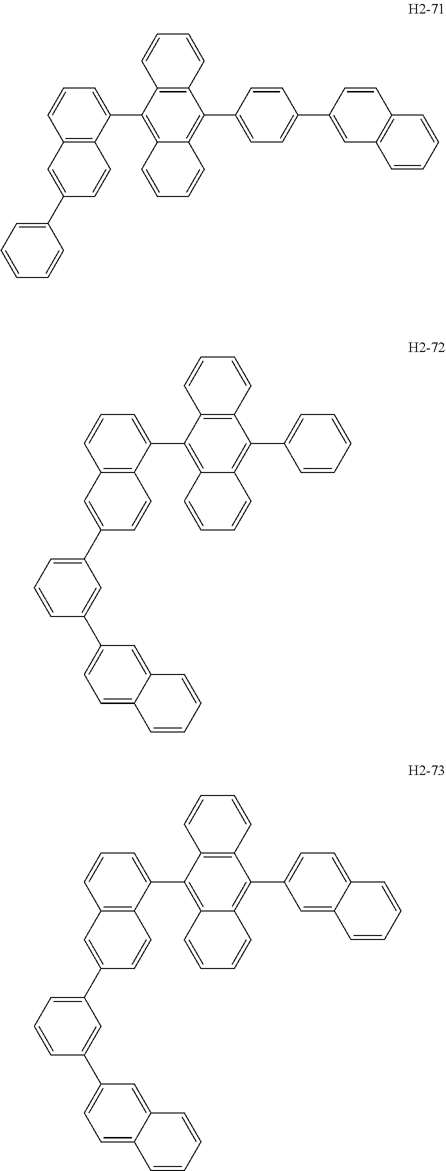

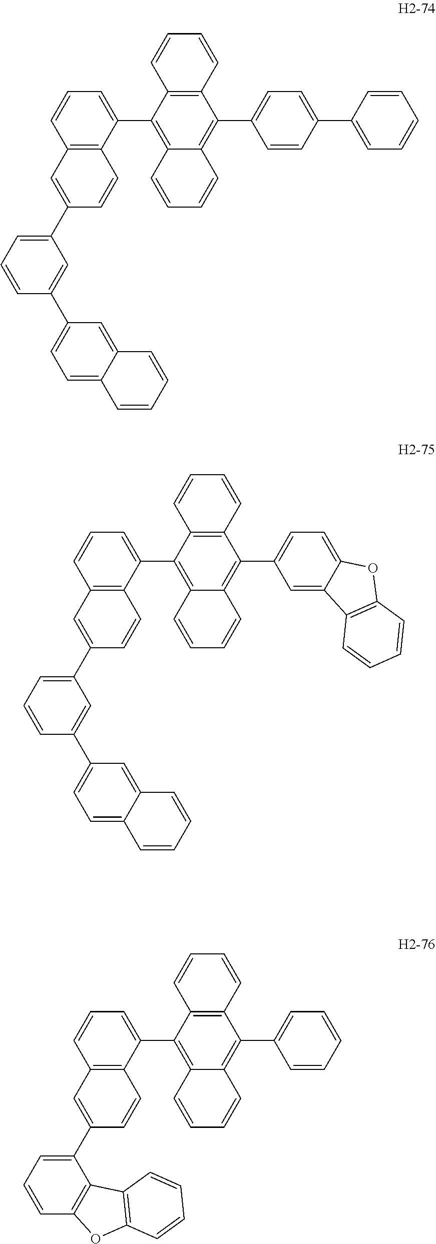

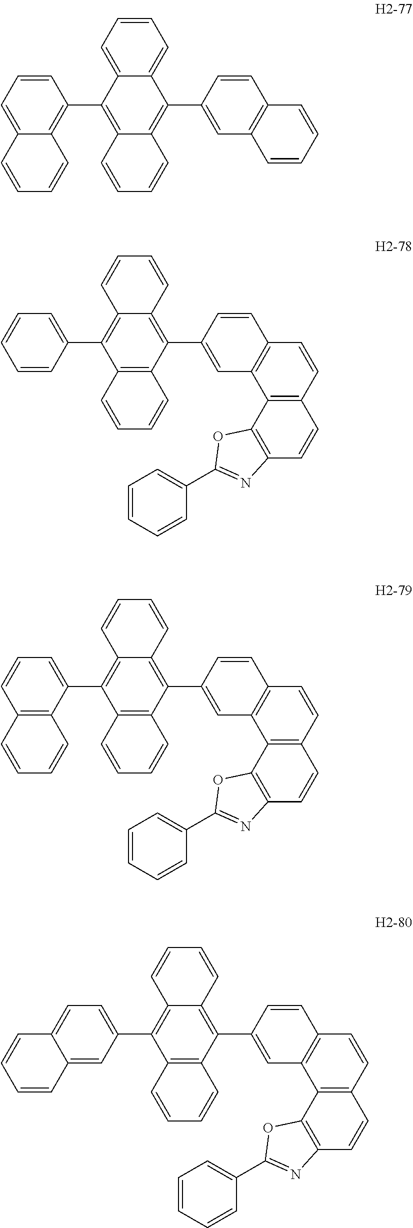

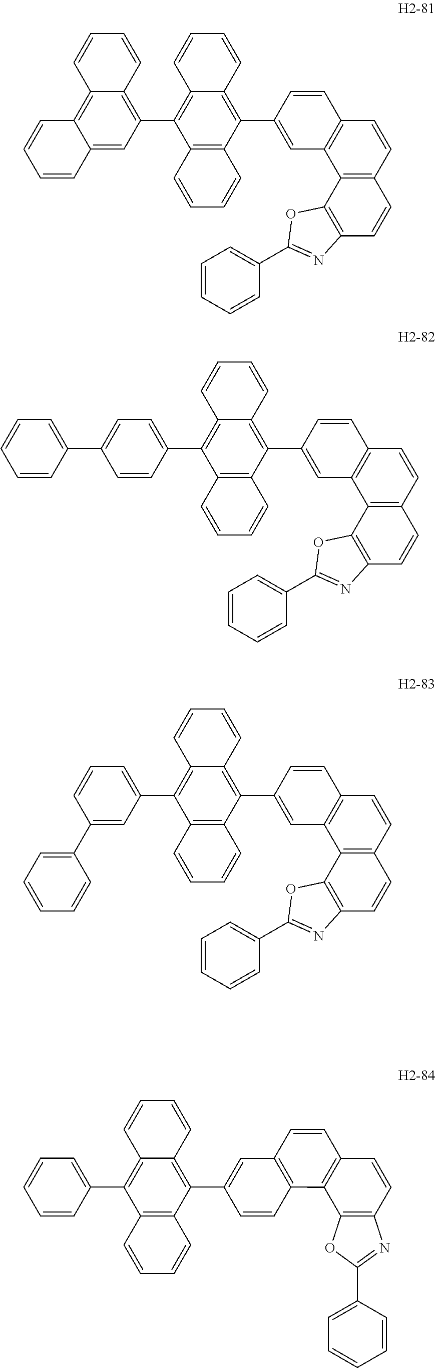 [SMILES: c1ccc(-c2nc3ccc4ccc5ccc(-c6c7ccccc7c(-c7cc8ccccc8c8ccccc78)c7ccccc67)cc5c4c3o2)cc1 ; c1ccc(-c2ccc(-c3c4ccccc4c(-c4ccc5ccc6ccc7nc(-c8ccccc8)oc7c6c5c4)c4ccccc34)cc2)cc1 ; c1ccc(-c2cccc(-c3c4ccccc4c(-c4ccc5ccc6ccc7nc(-c8ccccc8)oc7c6c5c4)c4ccccc34)c2)cc1 ; c1ccc(-c2nc3ccc4ccc5cc(-c6c7ccccc7c(-c7ccccc7)c7ccccc67)ccc5c4c3o2)cc1]

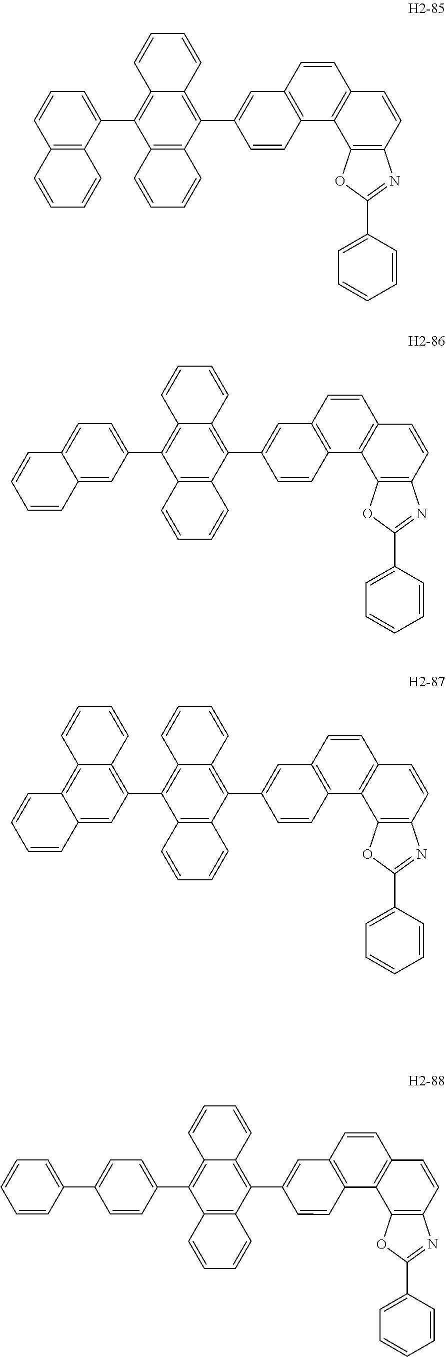 [SMILES: c1ccc(-c2nc3ccc4ccc5cc(-c6c7ccccc7c(-c7cccc8ccccc78)c7ccccc67)ccc5c4c3o2)cc1 ; c1ccc(-c2nc3ccc4ccc5cc(-c6c7ccccc7c(-c7ccc8ccccc8c7)c7ccccc67)ccc5c4c3o2)cc1 ; c1ccc(-c2nc3ccc4ccc5cc(-c6c7ccccc7c(-c7cc8ccccc8c8ccccc78)c7ccccc67)ccc5c4c3o2)cc1 ; c1ccc(-c2ccc(-c3c4ccccc4c(-c4ccc5c(ccc6ccc7nc(-c8ccccc8)oc7c65)c4)c4ccccc34)cc2)cc1]

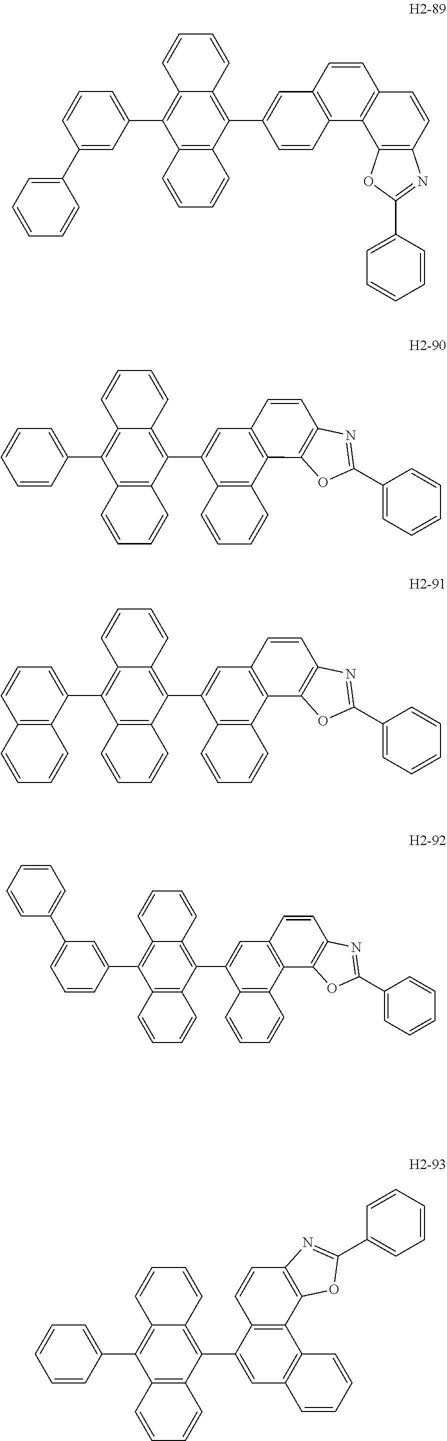 [SMILES: c1ccc(-c2cccc(-c3c4ccccc4c(-c4ccc5c(ccc6ccc7nc(-c8ccccc8)oc7c65)c4)c4ccccc34)c2)cc1 ; c1ccc(-c2nc3ccc4cc(-c5c6ccccc6c(-c6ccccc6)c6ccccc56)c5ccccc5c4c3o2)cc1 ; c1ccc(-c2nc3ccc4cc(-c5c6ccccc6c(-c6cccc7ccccc67)c6ccccc56)c5ccccc5c4c3o2)cc1 ; c1ccc(-c2cccc(-c3c4ccccc4c(-c4cc5ccc6nc(-c7ccccc7)oc6c5c5ccccc45)c4ccccc34)c2)cc1 ; c1ccc(-c2nc3ccc4c(-c5c6ccccc6c(-c6ccccc6)c6ccccc56)cc5ccccc5c4c3o2)cc1]

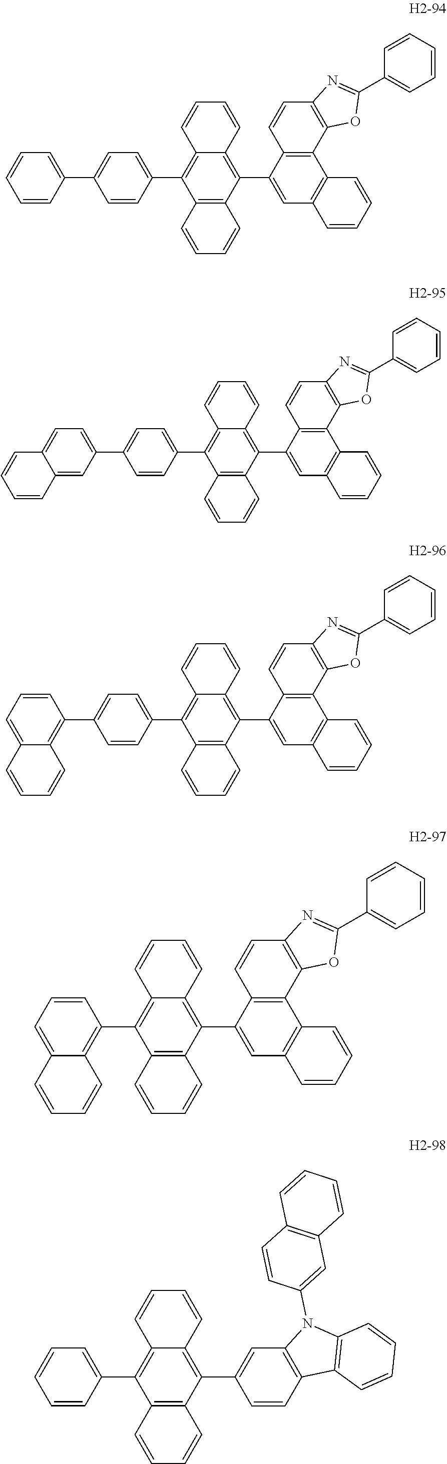 [SMILES: c1ccc(-c2ccc(-c3c4ccccc4c(-c4cc5ccccc5c5c4ccc4nc(-c6ccccc6)oc45)c4ccccc34)cc2)cc1 ; c1ccc(-c2nc3ccc4c(-c5c6ccccc6c(-c6ccc(-c7ccc8ccccc8c7)cc6)c6ccccc56)cc5ccccc5c4c3o2)cc1 ; c1ccc(-c2nc3ccc4c(-c5c6ccccc6c(-c6ccc(-c7cccc8ccccc78)cc6)c6ccccc56)cc5ccccc5c4c3o2)cc1 ; c1ccc(-c2nc3ccc4c(-c5c6ccccc6c(-c6cccc7ccccc67)c6ccccc56)cc5ccccc5c4c3o2)cc1 ; c1ccc(-c2c3ccccc3c(-c3ccc4c5ccccc5n(-c5ccc6ccccc6c5)c4c3)c3ccccc23)cc1]

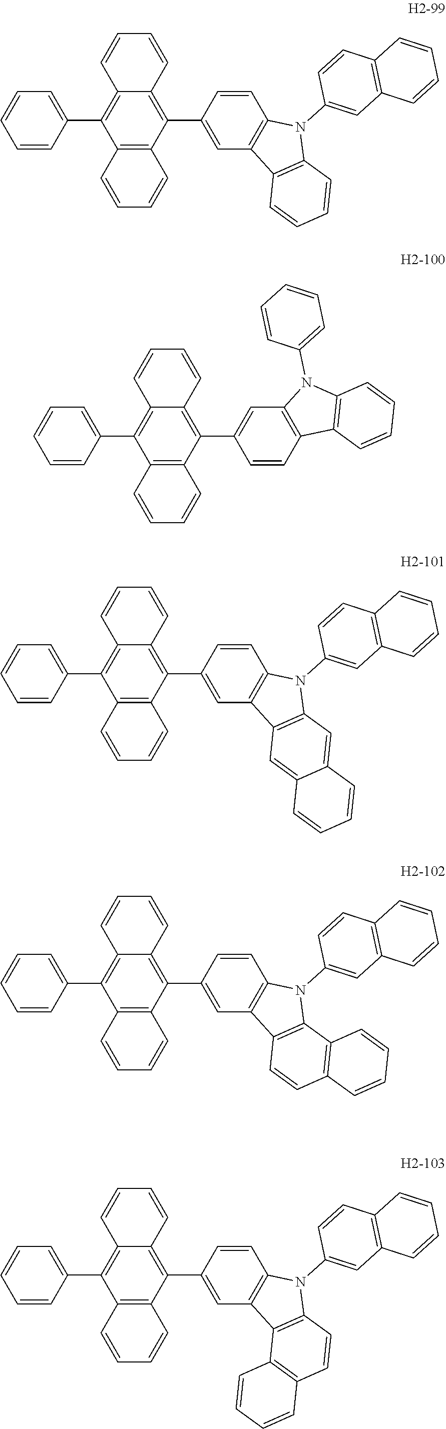 [SMILES: c1ccc(-c2c3ccccc3c(-c3ccc4c(c3)c3ccccc3n4-c3ccc4ccccc4c3)c3ccccc23)cc1 ; c1ccc(-c2c3ccccc3c(-c3ccc4c5ccccc5n(-c5ccccc5)c4c3)c3ccccc23)cc1 ; c1ccc(-c2c3ccccc3c(-c3ccc4c(c3)c3cc5ccccc5cc3n4-c3ccc4ccccc4c3)c3ccccc23)cc1 ; c1ccc(-c2c3ccccc3c(-c3ccc4c(c3)c3ccc5ccccc5c3n4-c3ccc4ccccc4c3)c3ccccc23)cc1 ; c1ccc(-c2c3ccccc3c(-c3ccc4c(c3)c3c5ccccc5ccc3n4-c3ccc4ccccc4c3)c3ccccc23)cc1]

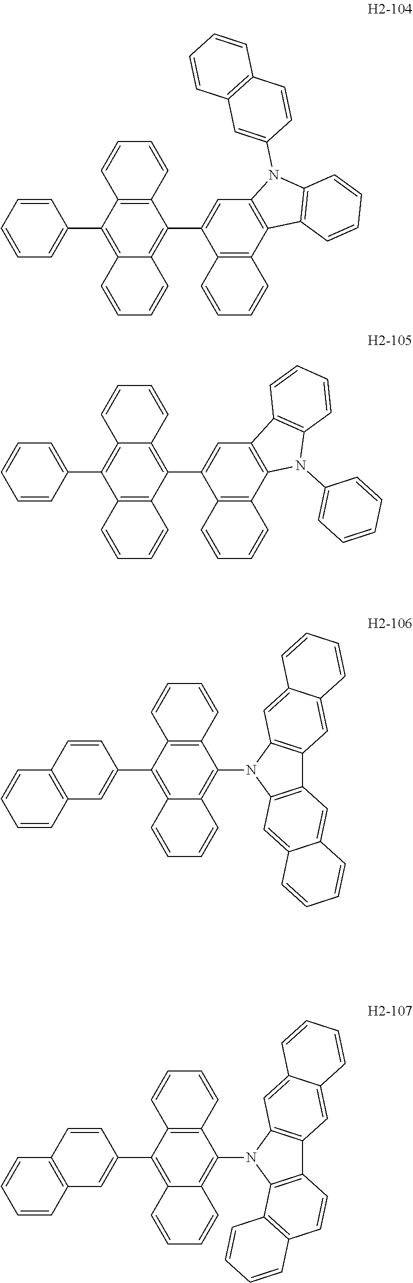 [SMILES: c1ccc(-c2c3ccccc3c(-c3cc4c(c5ccccc35)c3ccccc3n4-c3ccc4ccccc4c3)c3ccccc23)cc1 ; c1ccc(-c2c3ccccc3c(-c3cc4c5ccccc5n(-c5ccccc5)c4c4ccccc34)c3ccccc23)cc1 ; c1ccc2cc(-c3c4ccccc4c(-n4c5cc6ccccc6cc5c5cc6ccccc6cc54)c4ccccc34)ccc2c1 ; c1ccc2cc(-c3c4ccccc4c(-n4c5cc6ccccc6cc5c5ccc6ccccc6c54)c4ccccc34)ccc2c1]

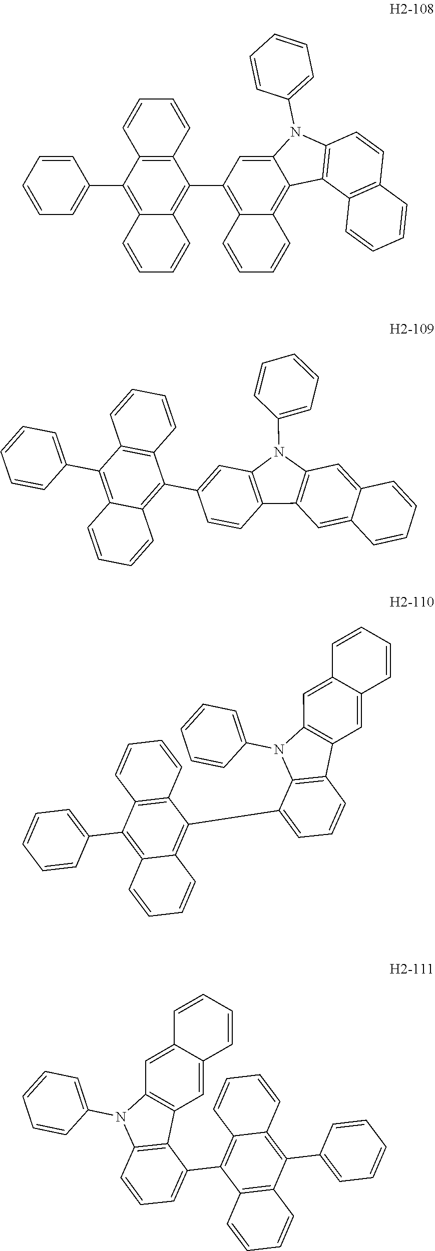 [SMILES: c1ccc(-c2c3ccccc3c(-c3cc4c(c5ccccc35)c3c5ccccc5ccc3n4-c3ccccc3)c3ccccc23)cc1 ; c1ccc(-c2c3ccccc3c(-c3ccc4c5cc6ccccc6cc5n(-c5ccccc5)c4c3)c3ccccc23)cc1 ; c1ccc(-c2c3ccccc3c(-c3cccc4c5cc6ccccc6cc5n(-c5ccccc5)c34)c3ccccc23)cc1 ; c1ccc(-c2c3ccccc3c(-c3cccc4c3c3cc5ccccc5cc3n4-c3ccccc3)c3ccccc23)cc1]

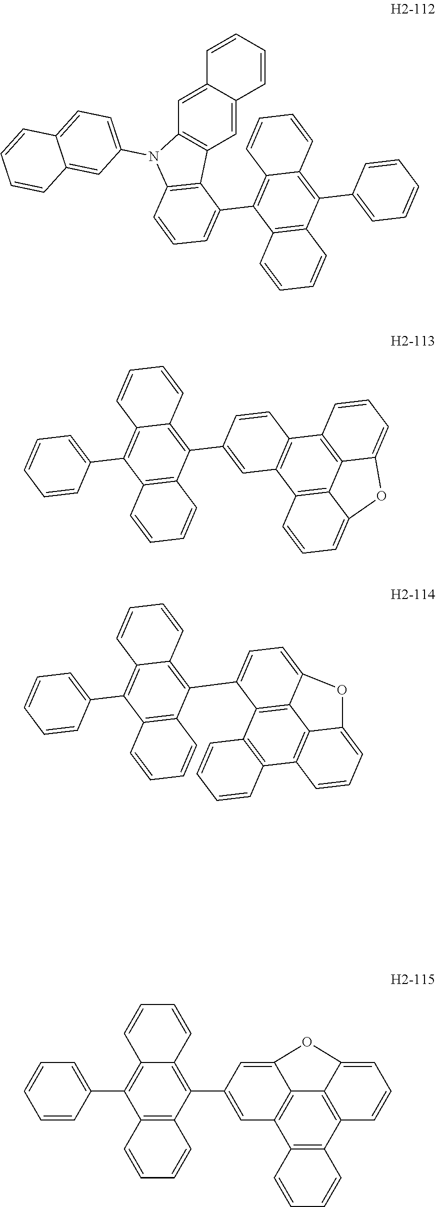 [SMILES: c1ccc(-c2c3ccccc3c(-c3cccc4c3c3cc5ccccc5cc3n4-c3ccc4ccccc4c3)c3ccccc23)cc1 ; c1ccc(-c2c3ccccc3c(-c3ccc4c(c3)c3cccc5oc6cccc4c6c53)c3ccccc23)cc1 ; c1ccc(-c2c3ccccc3c(-c3ccc4oc5cccc6c7ccccc7c3c4c56)c3ccccc23)cc1 ; c1ccc(-c2c3ccccc3c(-c3cc4oc5cccc6c7ccccc7c(c3)c4c56)c3ccccc23)cc1]

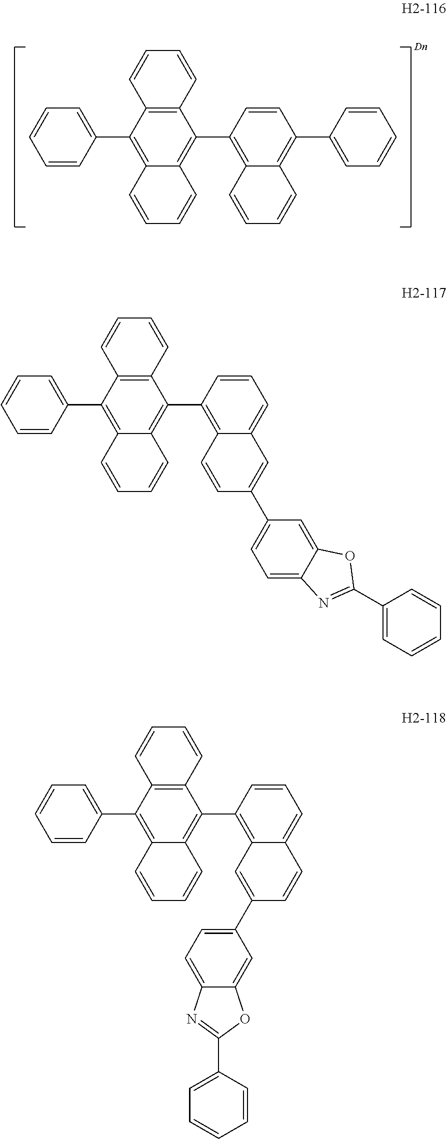

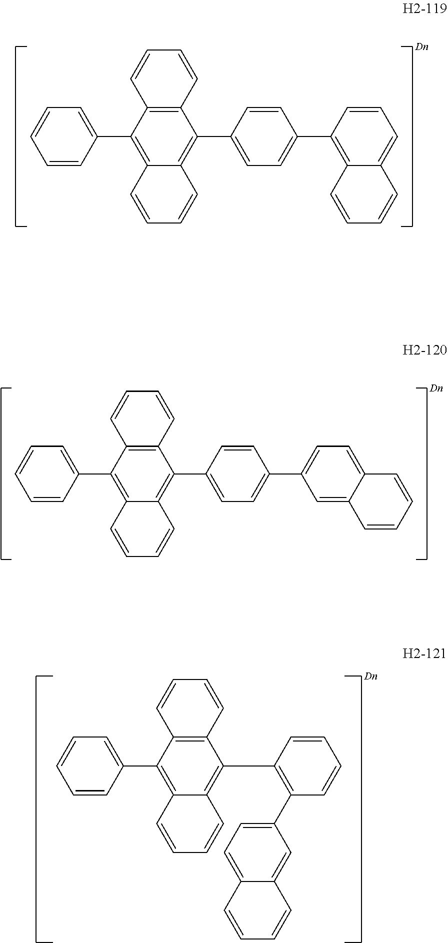

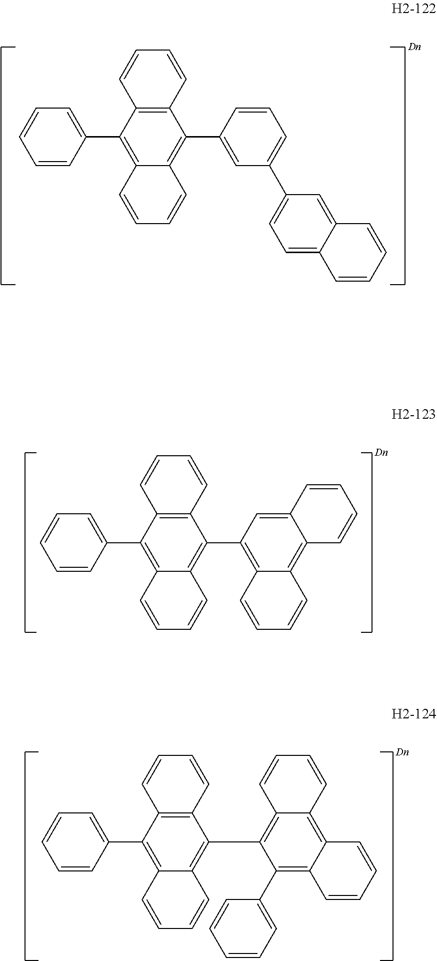

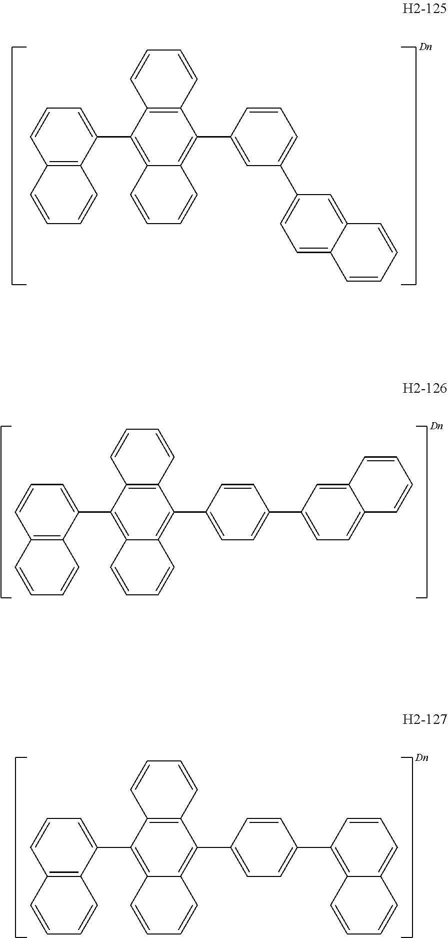

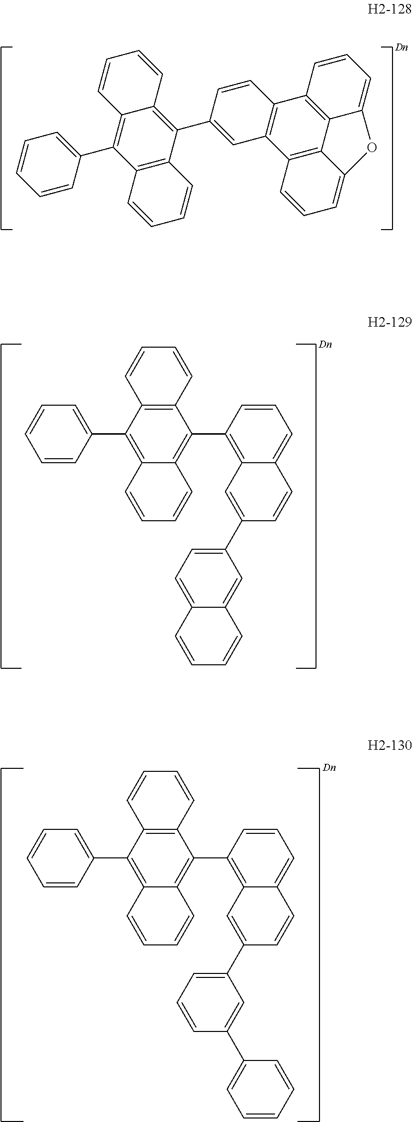

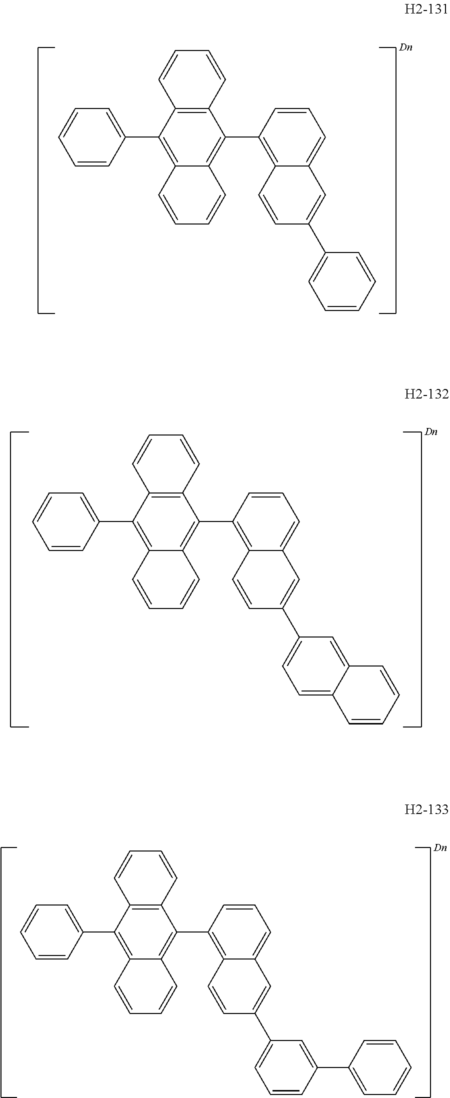

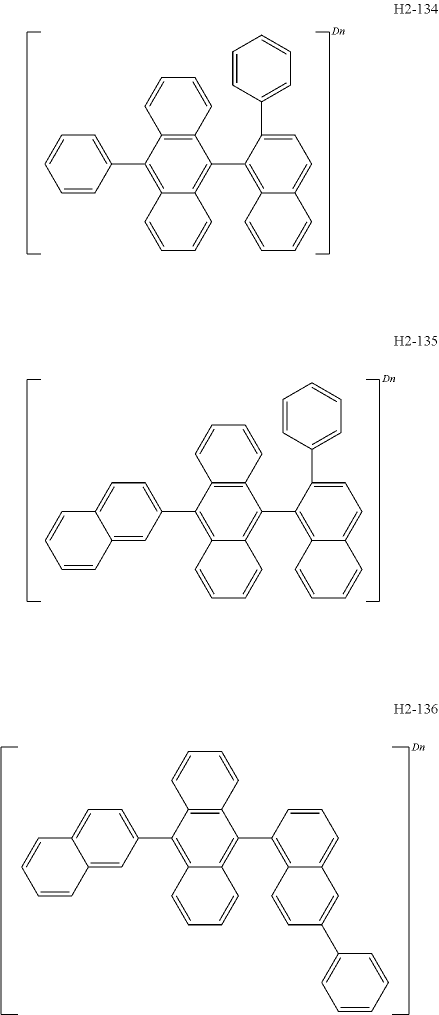

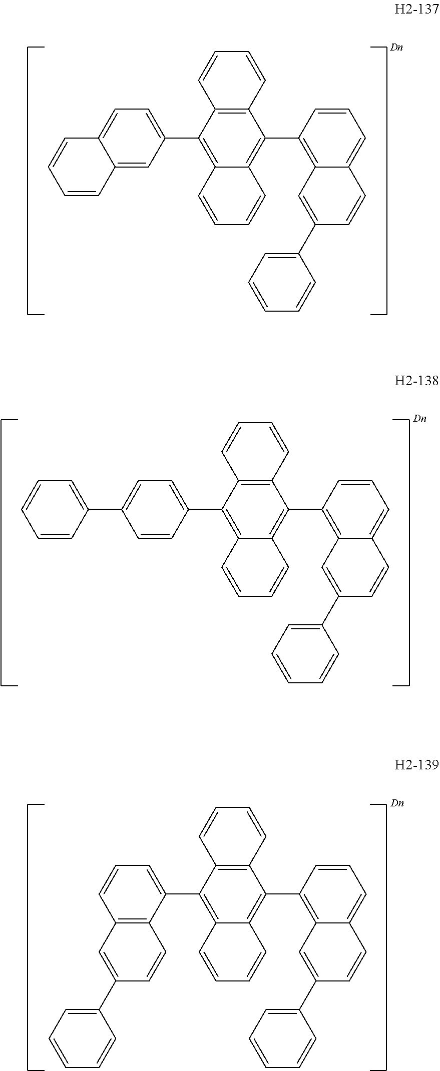

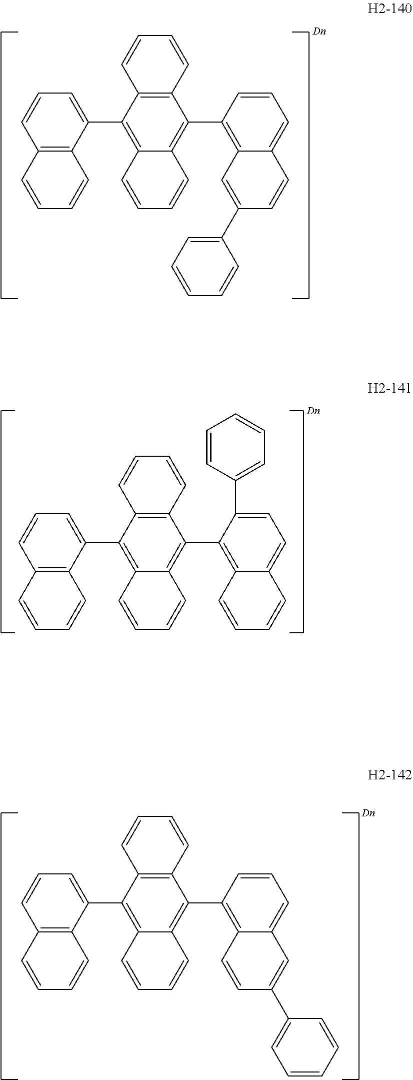

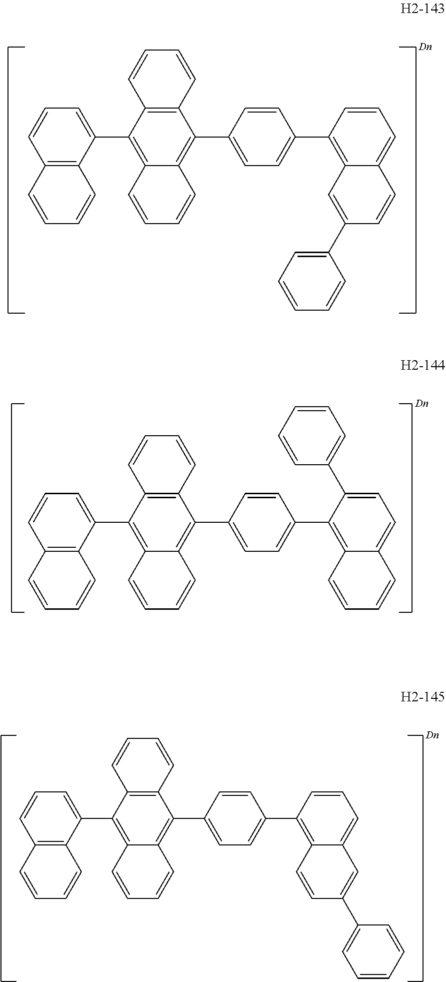

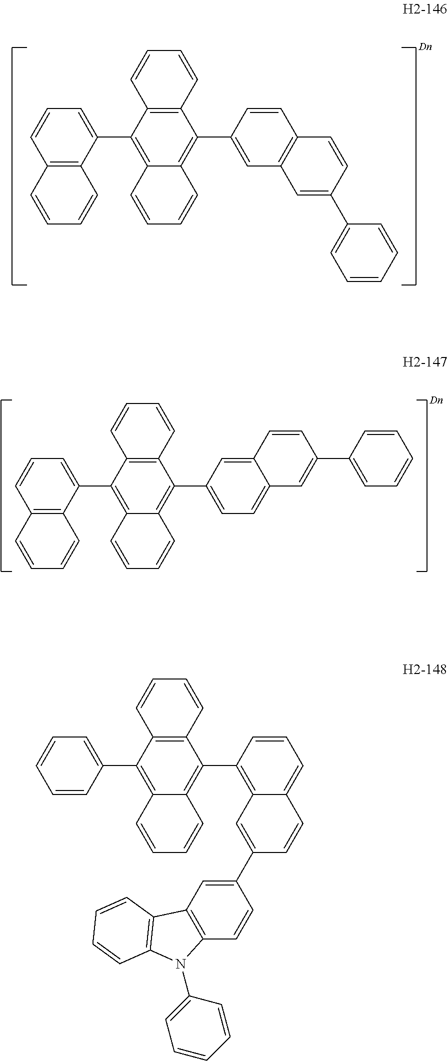

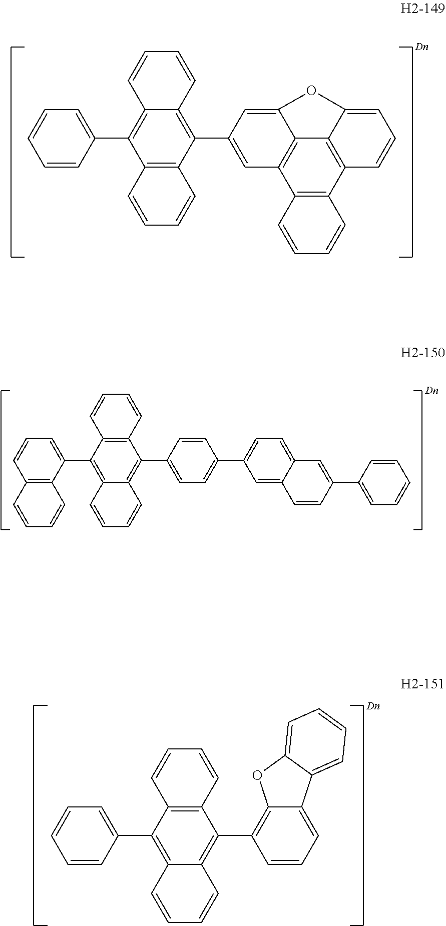

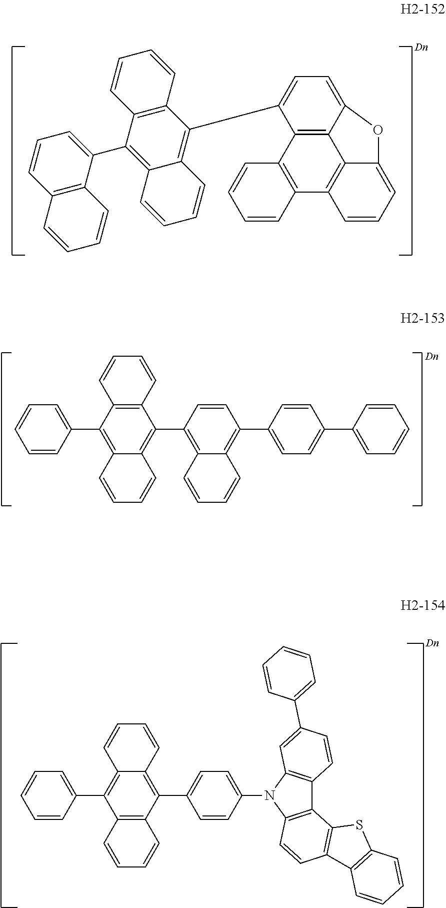

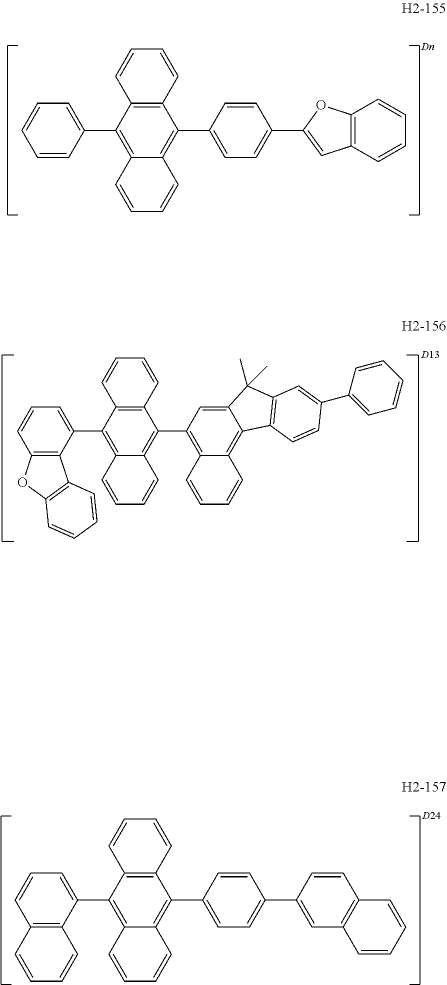

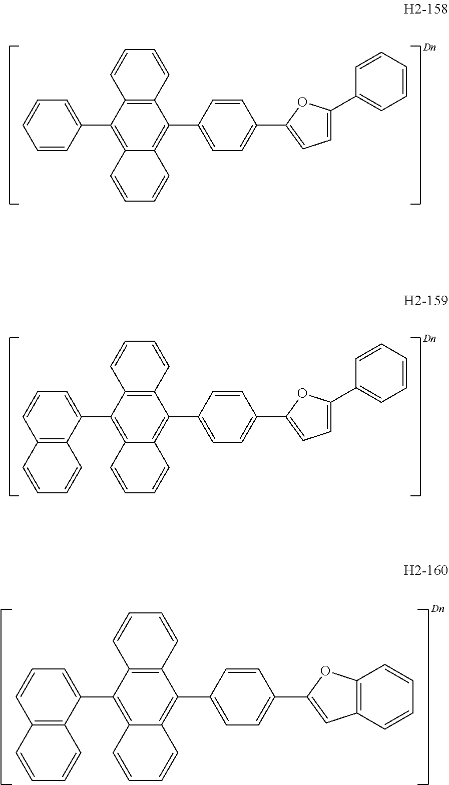

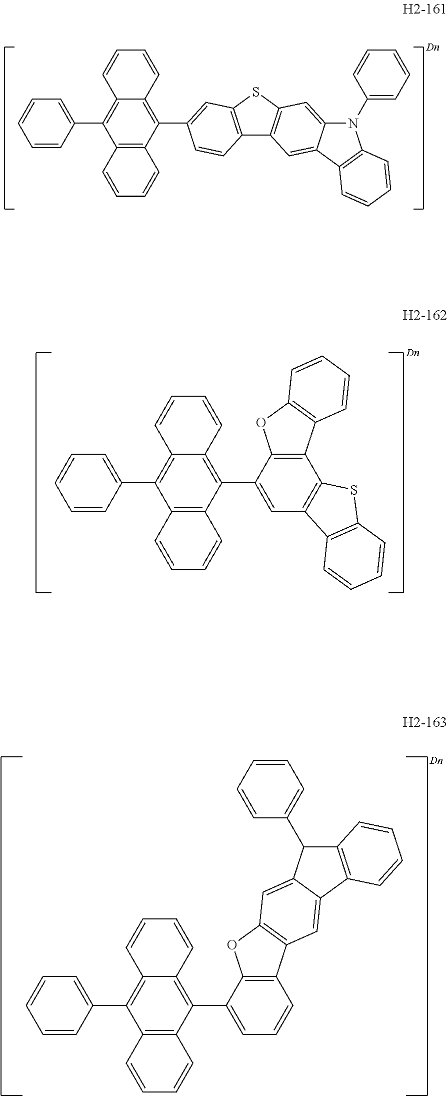

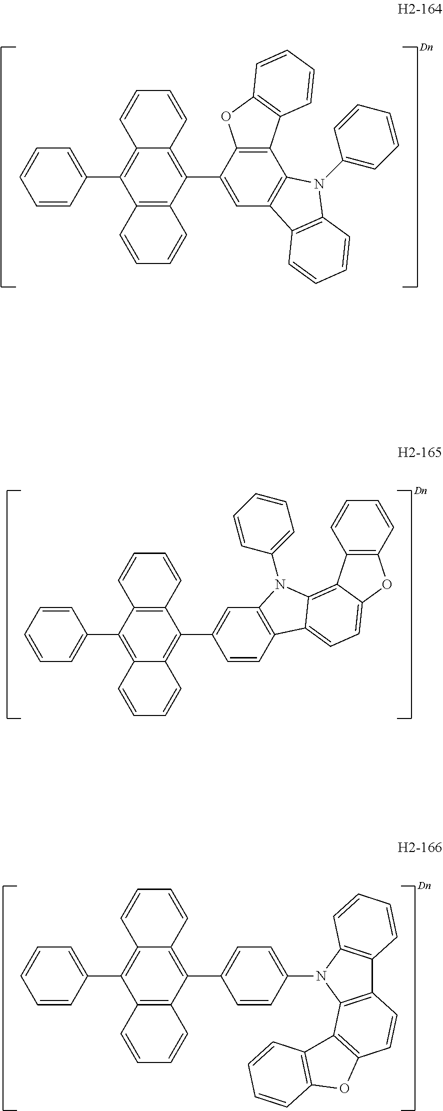

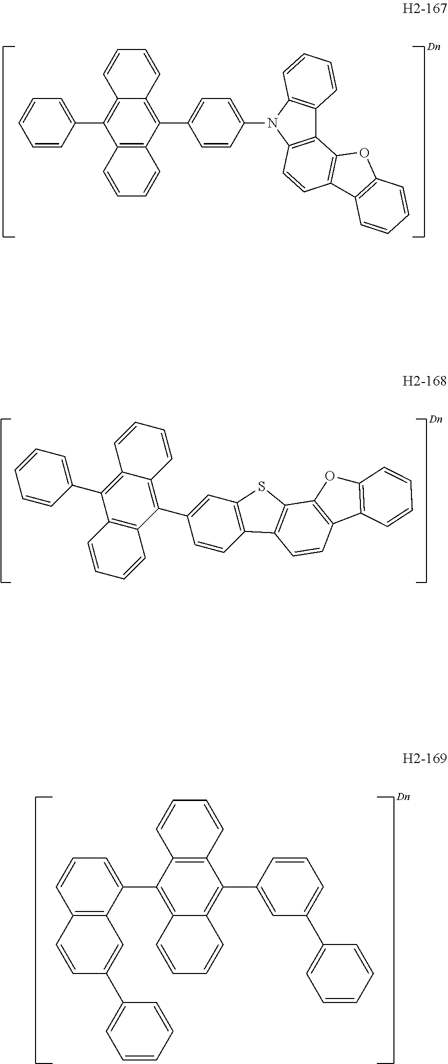

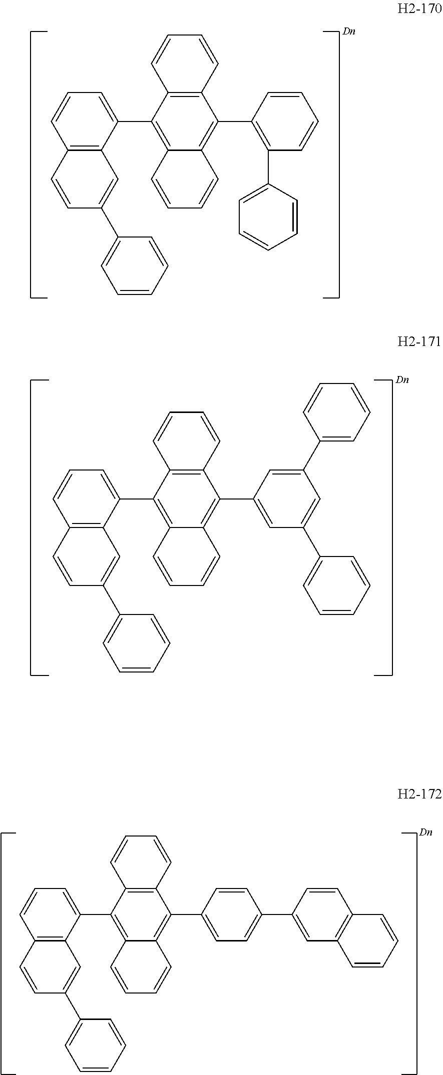

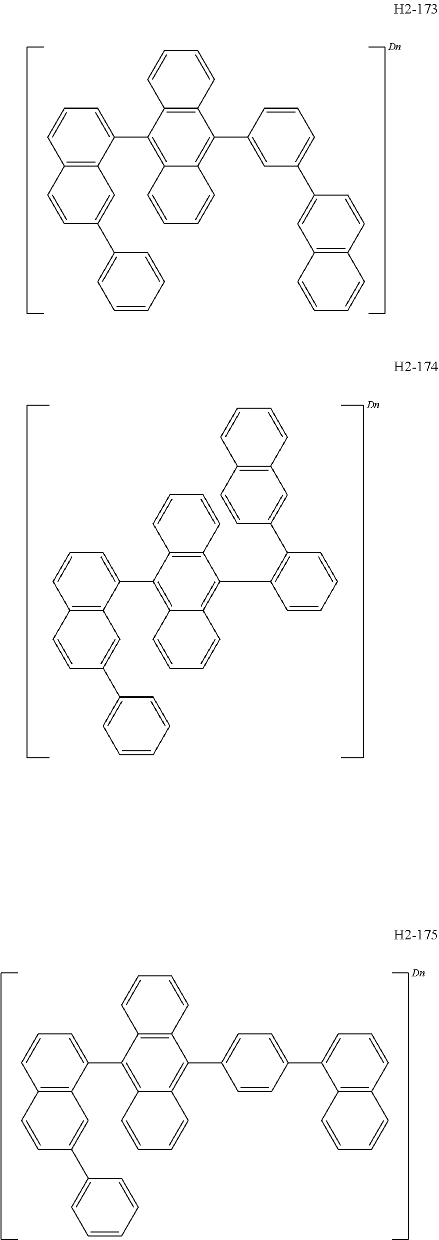

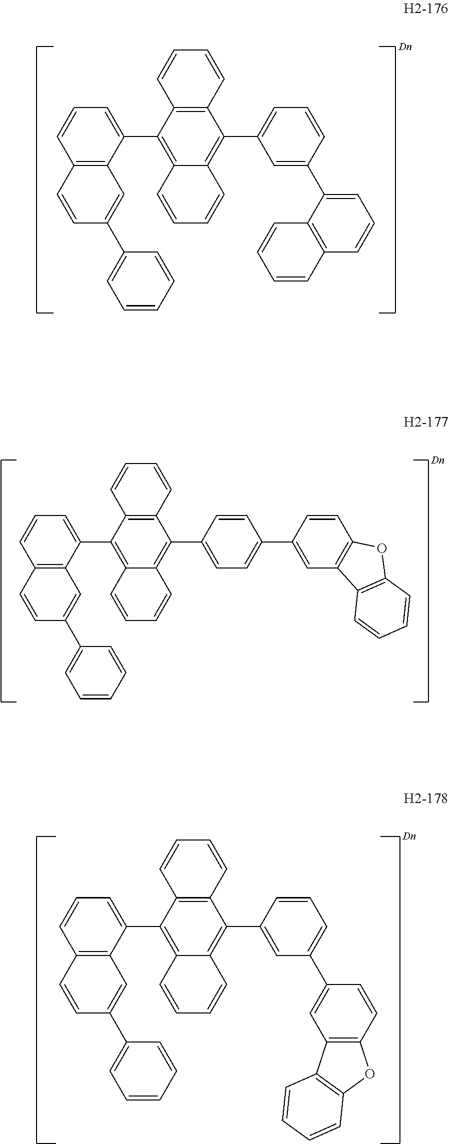

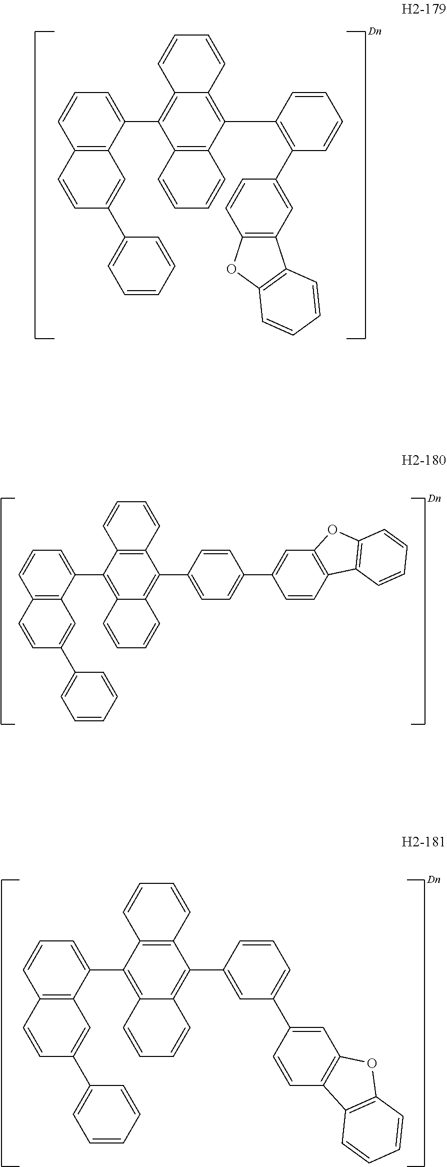

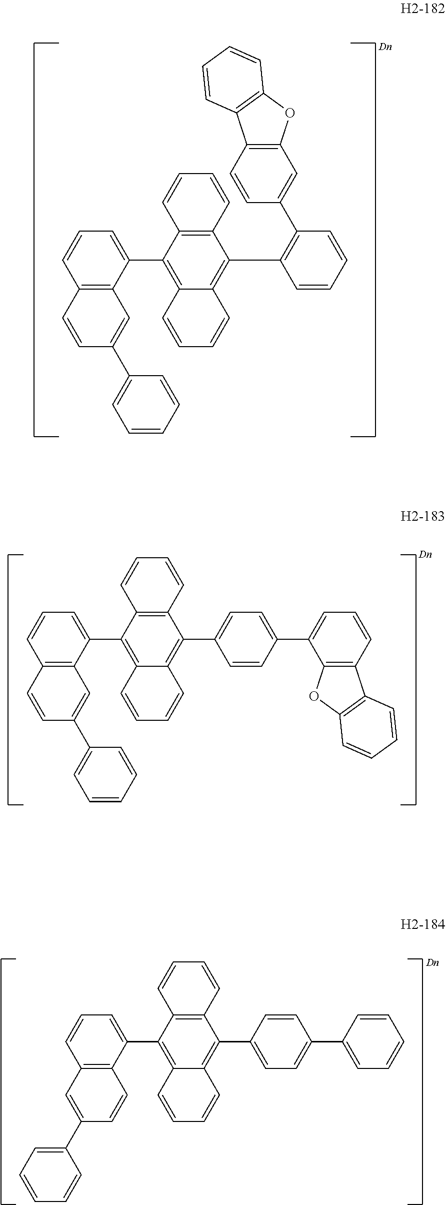

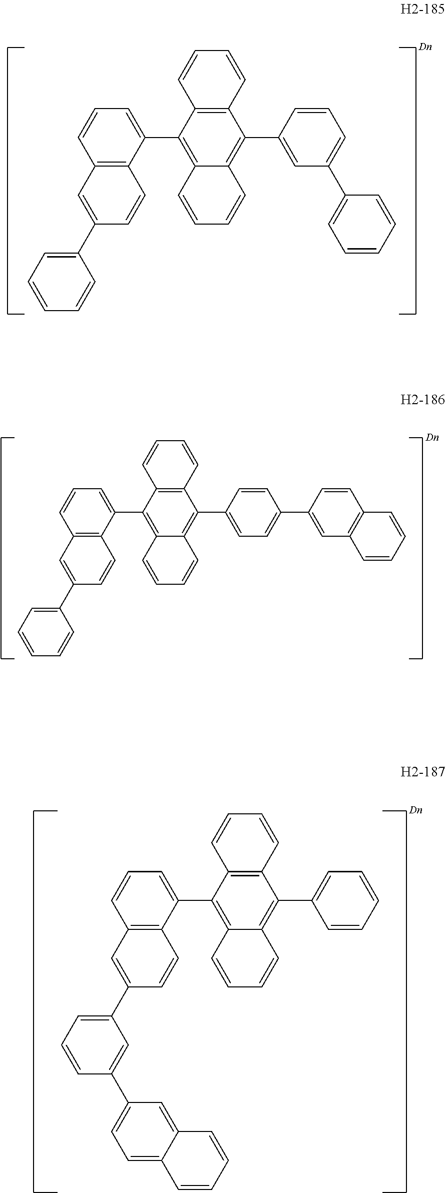

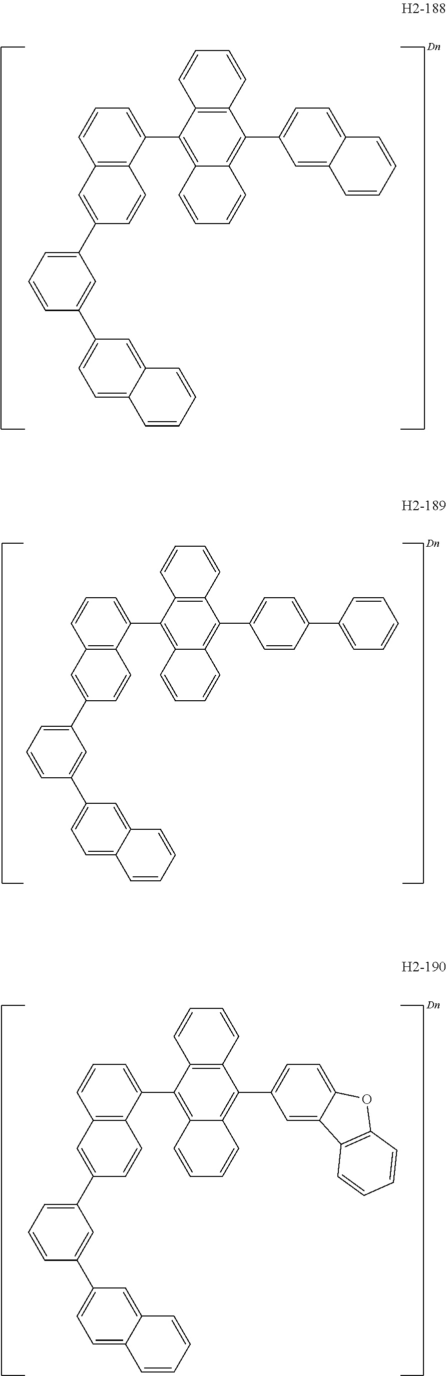

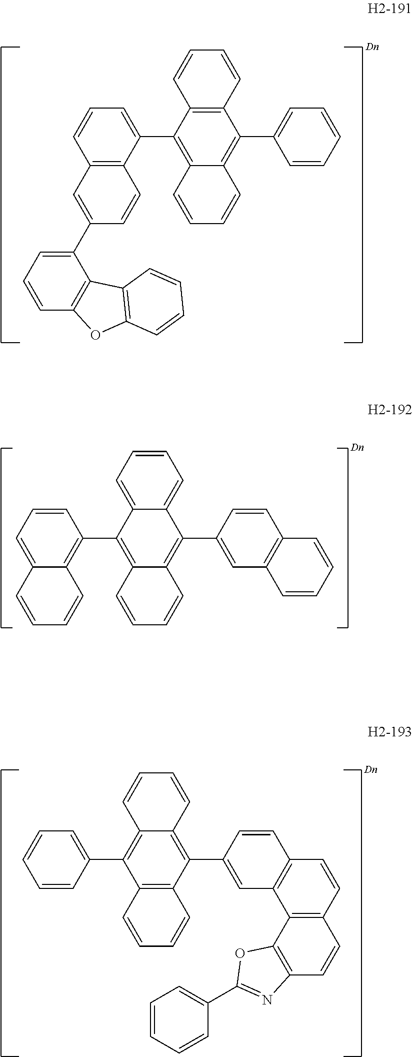

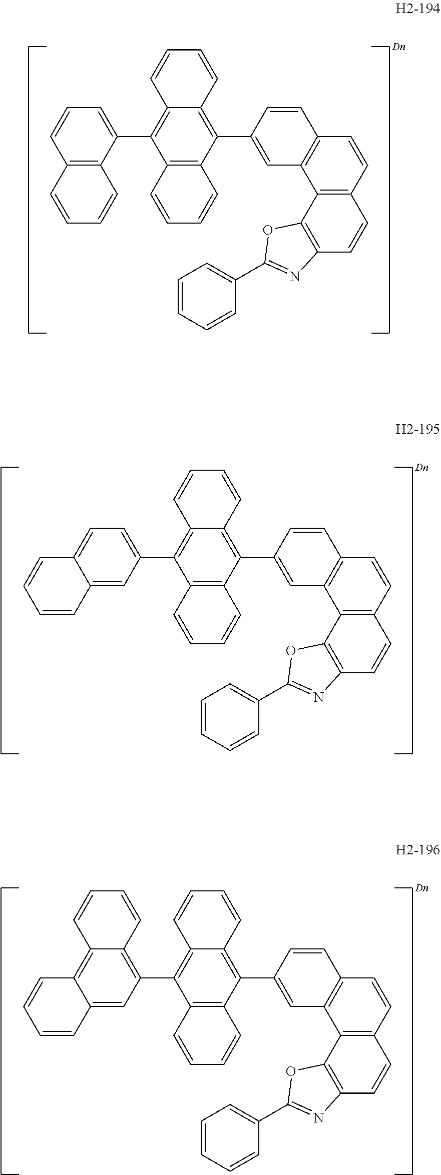

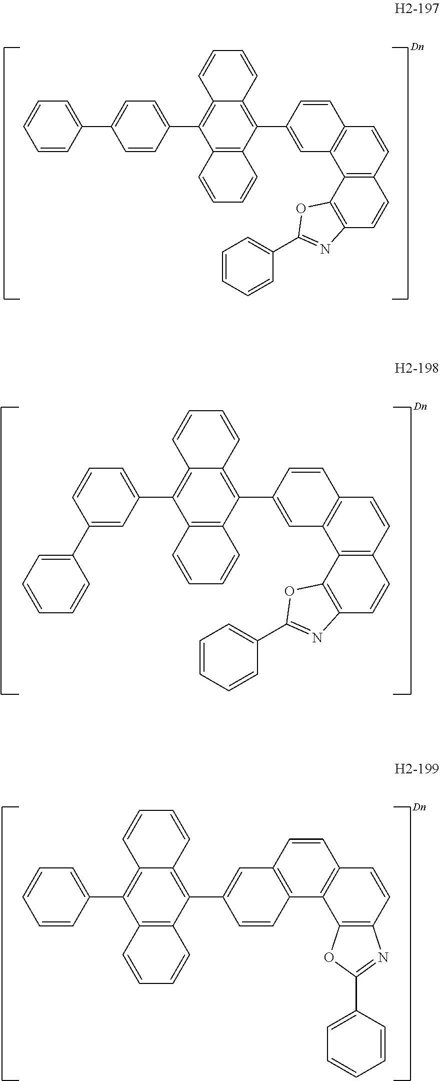

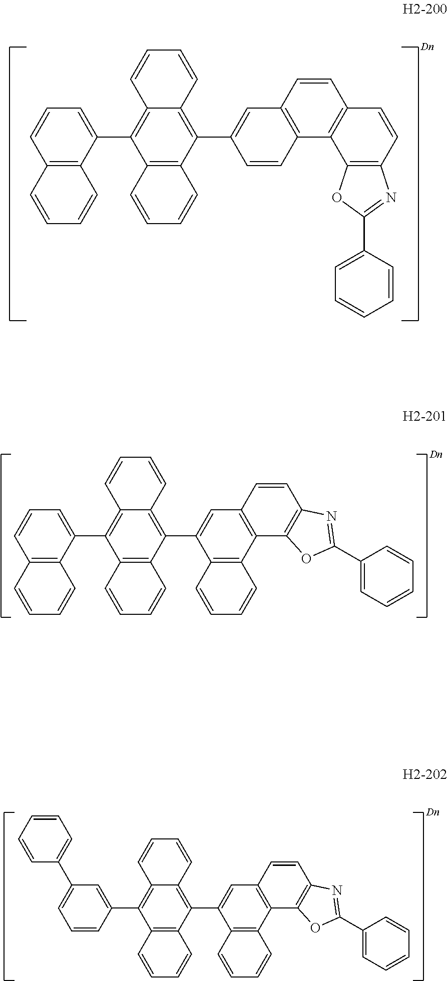

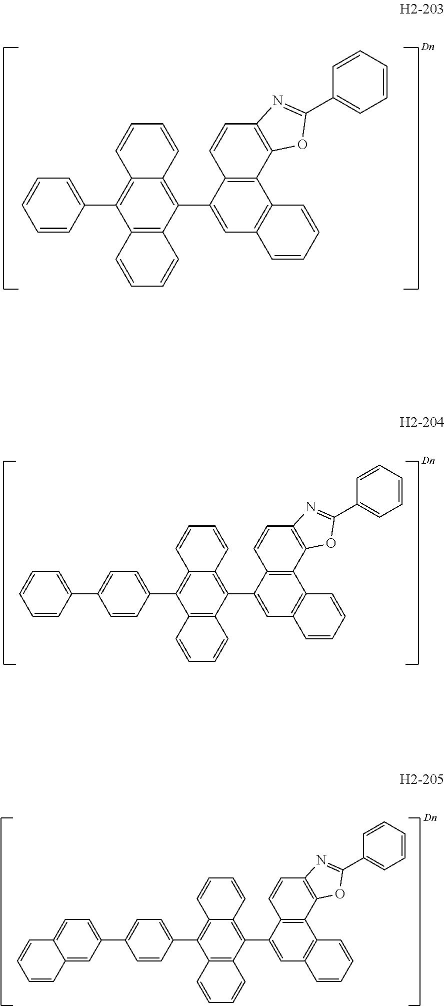

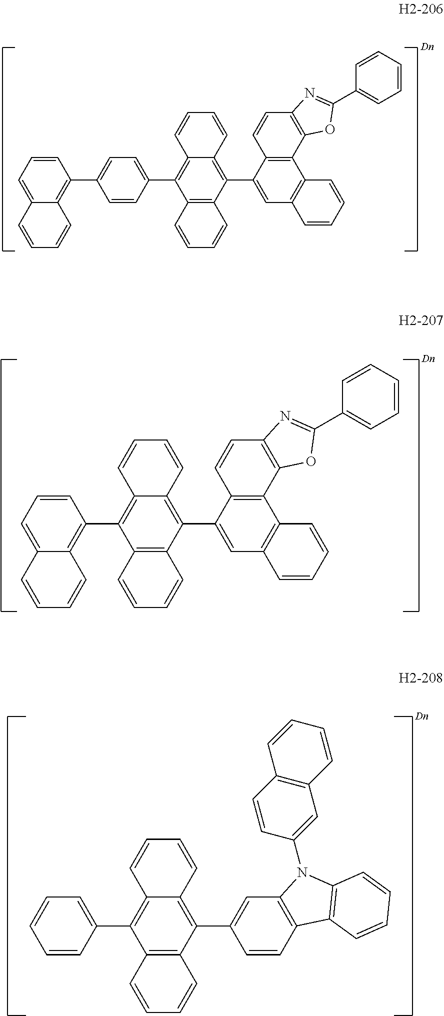

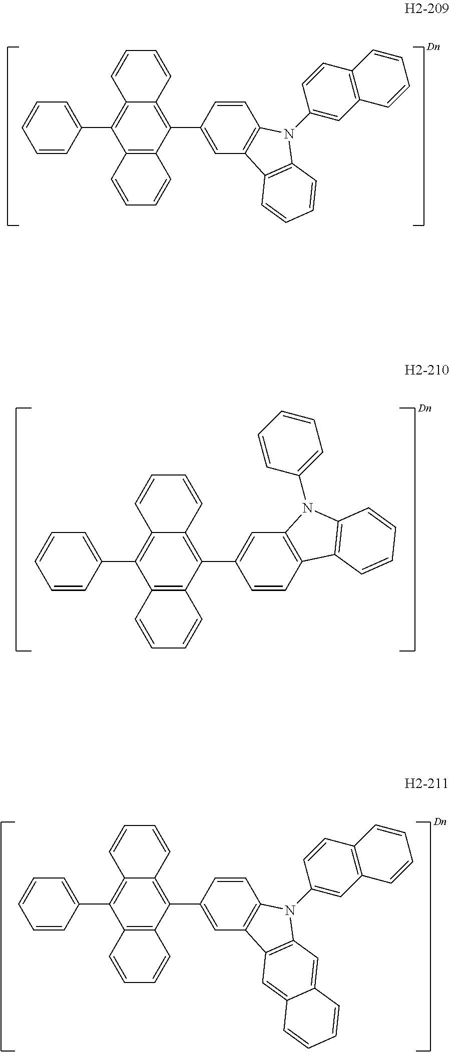

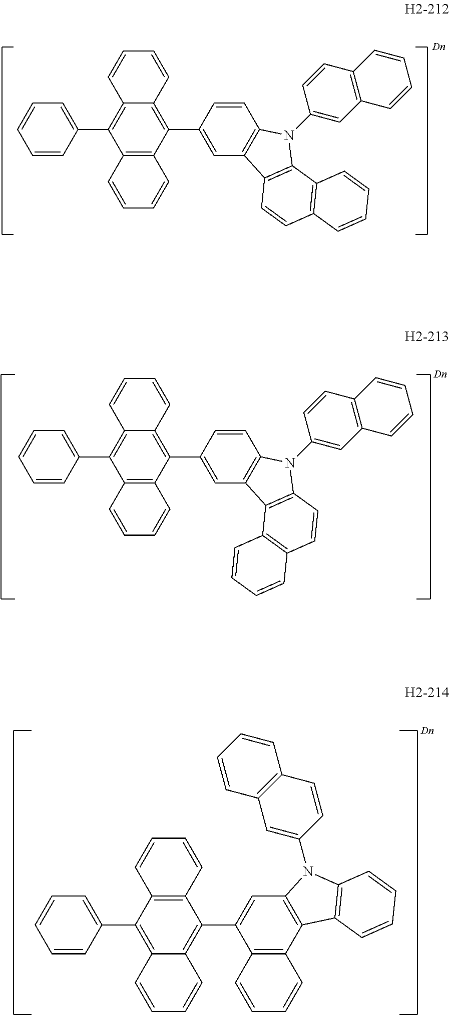

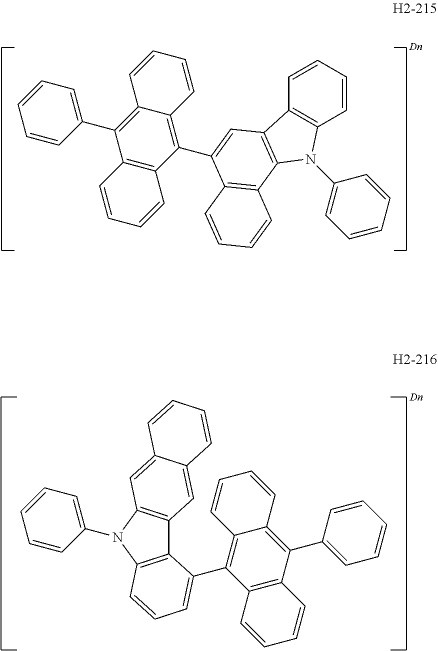

In the compounds above, Dn means that n number of hydrogens is replaced with deuterium, wherein n represents an integer of 1 or more. Wherein, the upper limit of n is determined by the number of hydrogens that can be substituted in each compound. According to one embodiment of the present disclosure, n is preferably an integer of 10 or more, more preferably an integer of 15 or more. When deuterated with a number equal to or higher than the lower limit, the bond dissociation energy according to deuteration increases, thereby exhibiting the improved lifespan property.

The compound represented by formula 1 according to the present disclosure can be prepared by a known synthetic method. Specifically, the non-deuterated compound of formula 1 can be prepared by known coupling and substitution reactions. For example, the non-deuterated compound of formula 1 may be prepared by referring to Korean Patent Application Laid-Open No. 2015-0010016 (Jan. 28, 2015), etc. The deuterated compound of formula 1 can be prepared using a deuterated precursor material in a similar manner, or more generally can be prepared by treating a non-deuterated compound with a deuterated solvent, D6-benzene in the presence of a Lewis acid H/D exchange catalyst such as aluminum trichloride or ethyl aluminum dichloride. In addition, the degree of deuterization can be controlled by varying reaction conditions such as reaction temperature. For example, the number of deuterium in formula 1 can be adjusted by controlling the reaction temperature and time, the equivalent of acid, etc.

According to one embodiment, a composition, comprising at least two compounds represented by formula 1 above can be provided.

Hereinafter, one embodiment of the composition comprising the compound represented by formula 1 above will be described.

The composition according to another embodiment of the present disclosure includes at least one first compound represented by formula 1 and at least one second compound comprising an anthracene-based moiety.

The second compound including an anthracene-based moiety according to one embodiment may be a compound represented by the following formula 11.

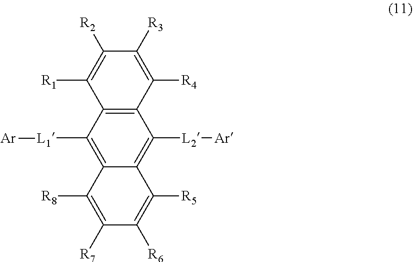

In formula 11,

L₁′ and L₂′ each independently represent a single bond or a substituted or unsubstituted (C6-C30)arylene;

Ar and Ar′ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, or a substituted or unsubstituted (C6-C30)aryl; and

R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

In one embodiment, L₁′ and L₂′ each independently may be a single bond or a substituted or unsubstituted (C6-C30)arylene, preferably, a single bond or a substituted or unsubstituted (C6-C25)arylene, more preferably, a single bond or a substituted or unsubstituted (C6-C18)arylene. For example, L₁′ and L₂′ each independently may be a single bond, a substituted or unsubstituted phenylene, a substituted or unsubstituted biphenylene, a substituted or unsubstituted naphthalenylene, or a substituted or unsubstituted phenanthrenylene.

In one embodiment, Ar and Ar′ each independently may be a substituted or unsubstituted (C6-C30)aryl, preferably, a substituted or unsubstituted (C6-C25)aryl. For example, Ar and Ar′ each independently may be a substituted or unsubstituted phenyl, a substituted or unsubstituted naphthyl, a substituted or unsubstituted m-biphenyl, a substituted or unsubstituted p-biphenyl, a substituted or unsubstituted m-terphenyl, a substituted or unsubstituted p-terphenyl, a substituted or unsubstituted triphenylenyl, or a substituted or unsubstituted phenanthrenyl.

In one embodiment, R₁ to R₈ each independently may be hydrogen or deuterium.

According to one embodiment, the compound represented by formula 11 above may be more specifically illustrated by the following compounds, but is not limited thereto.

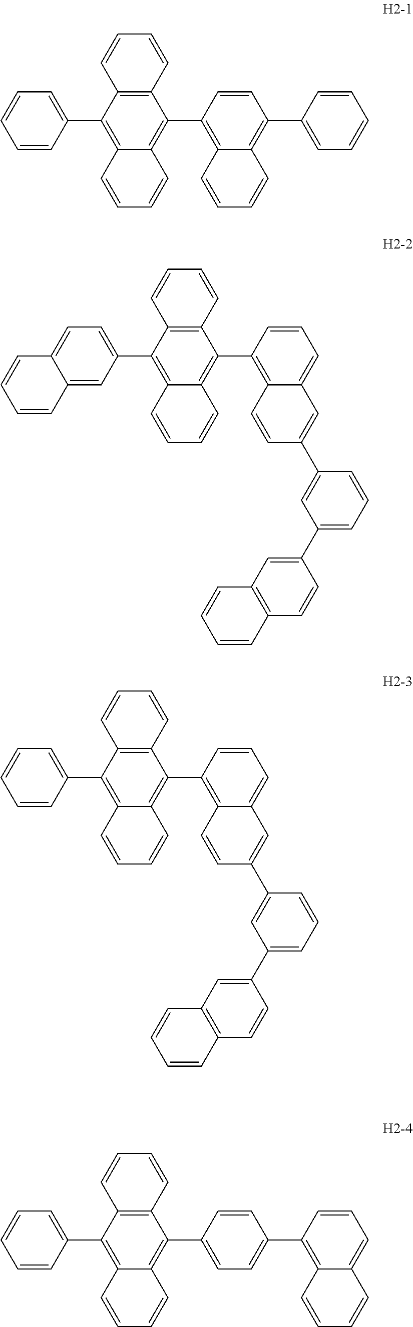

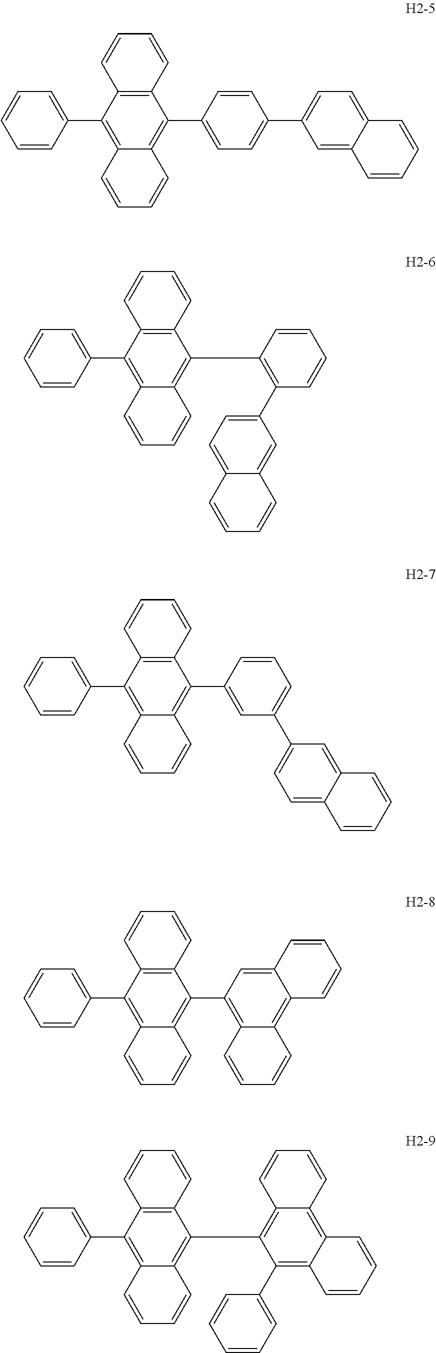

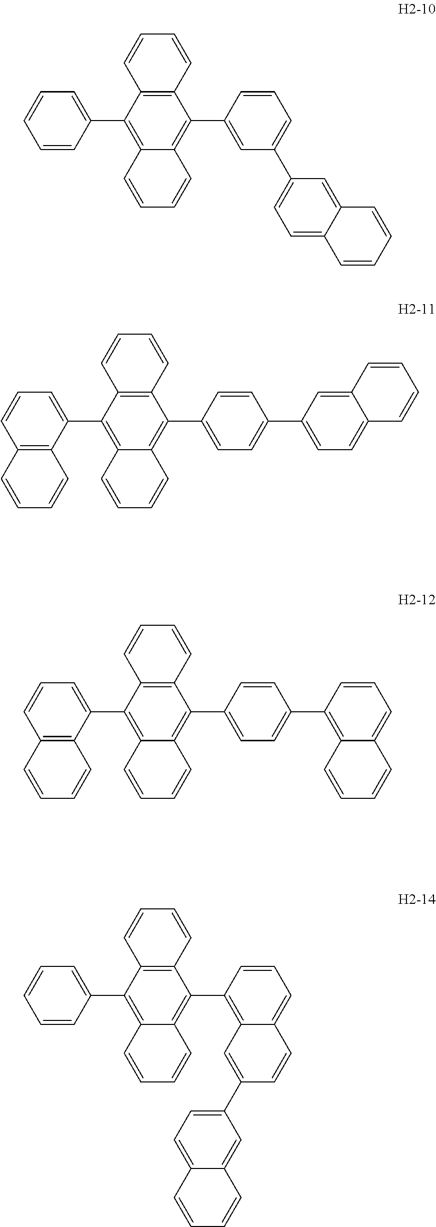

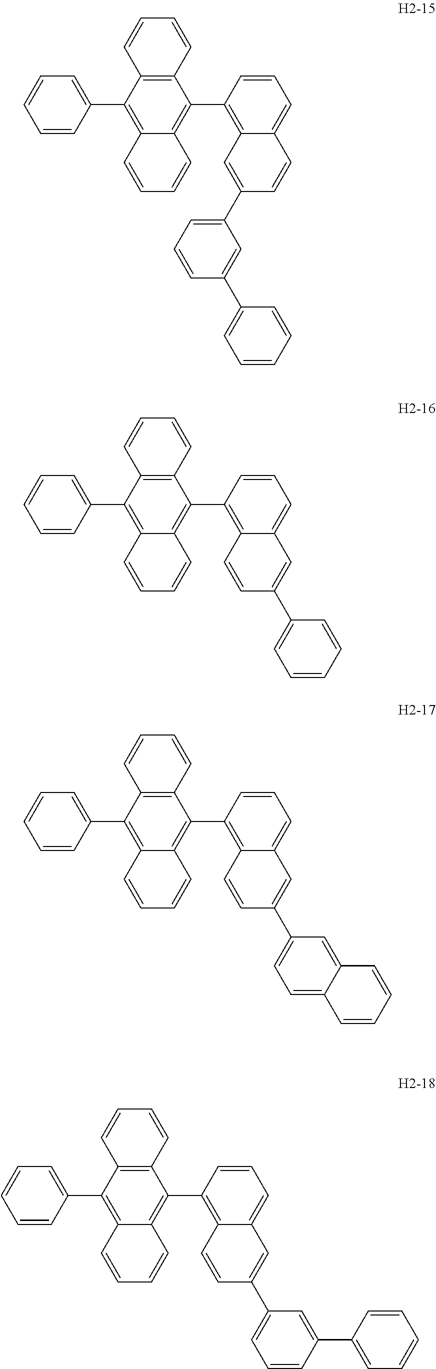

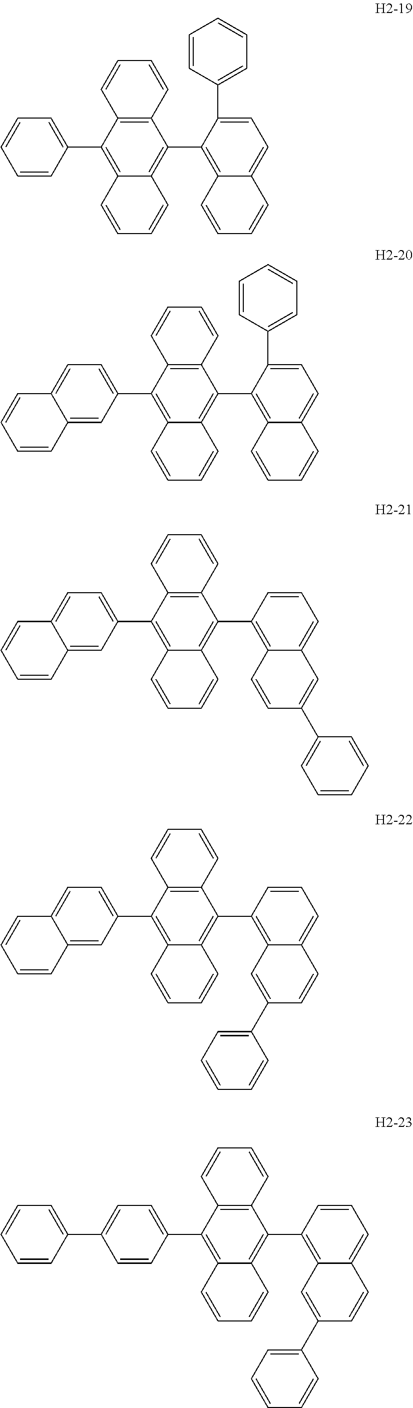

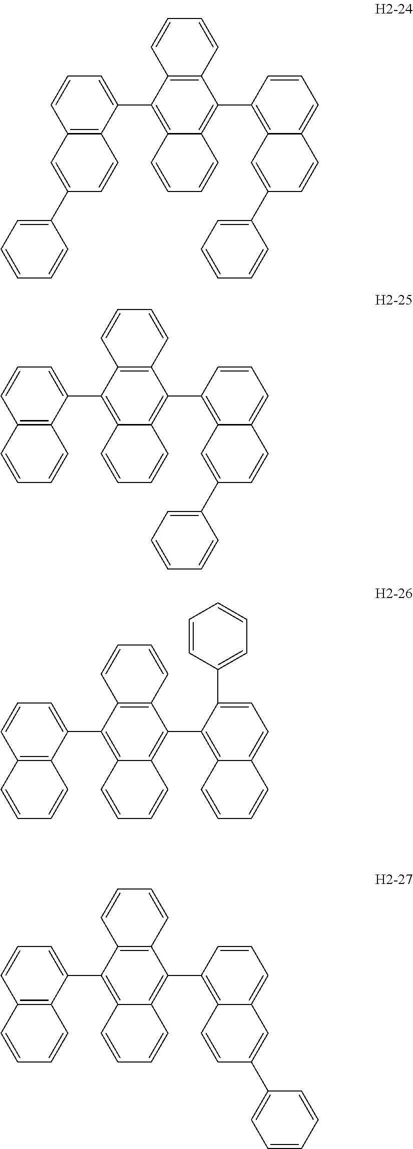

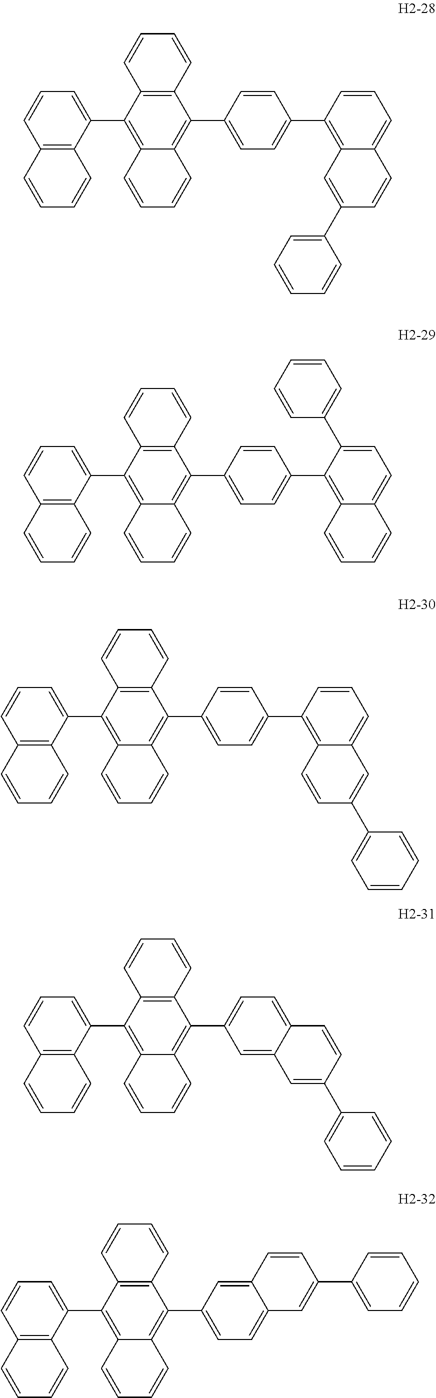

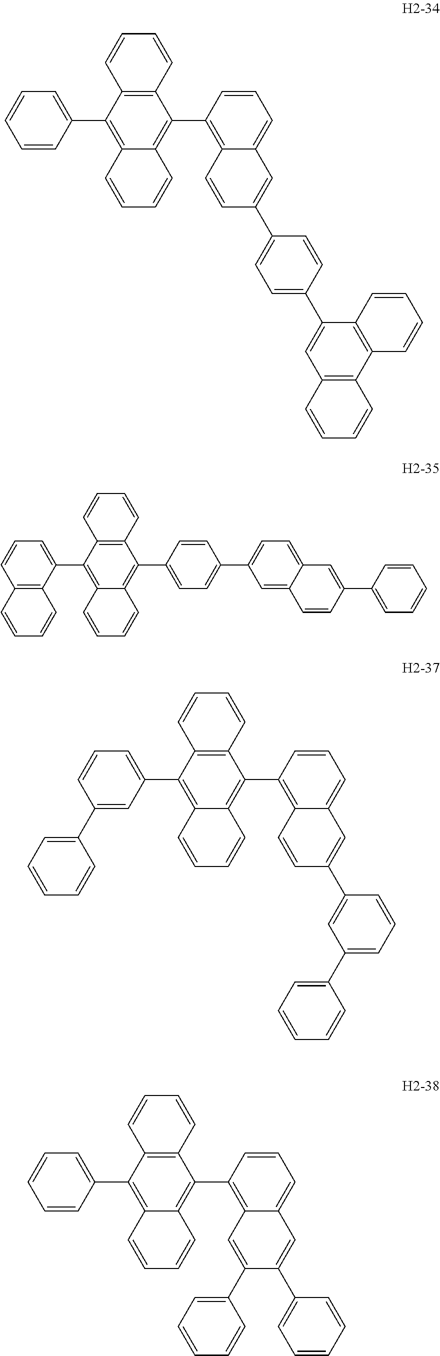

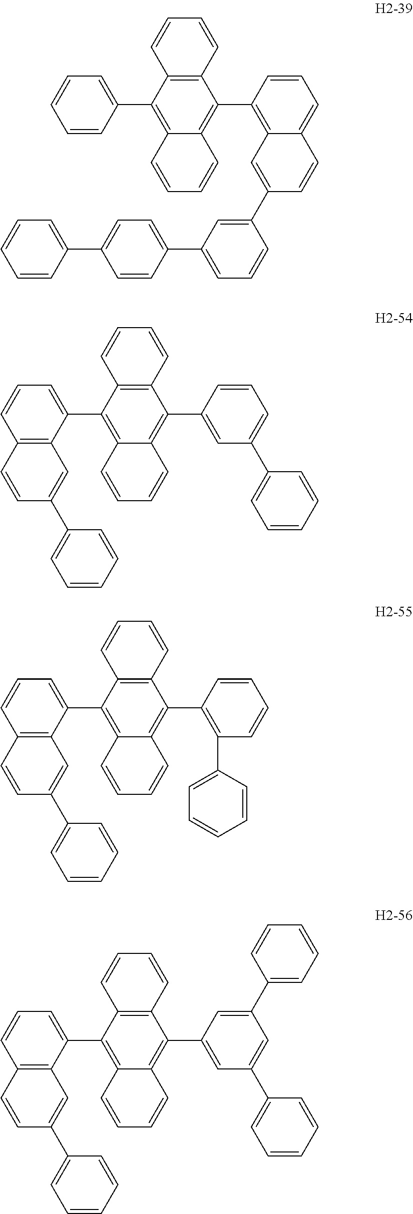

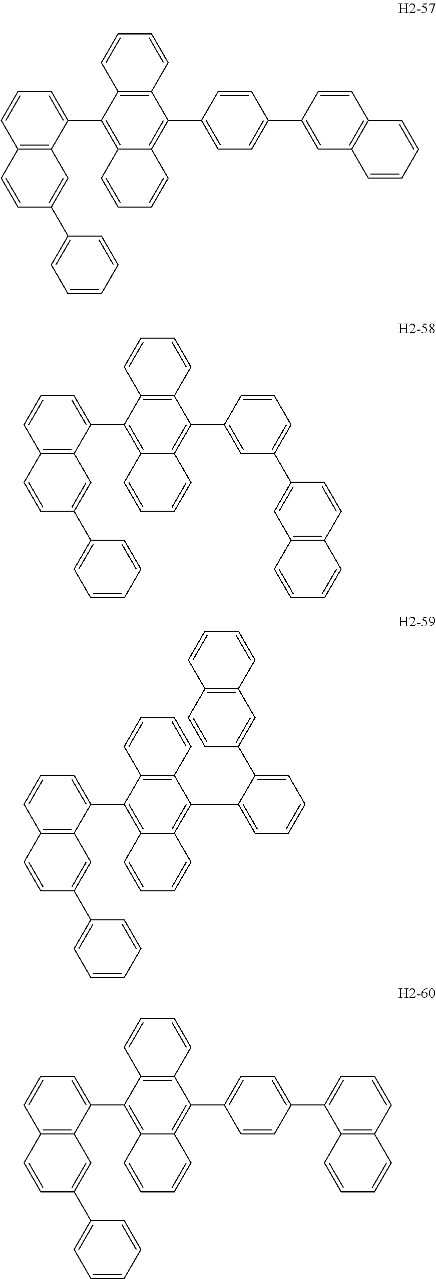

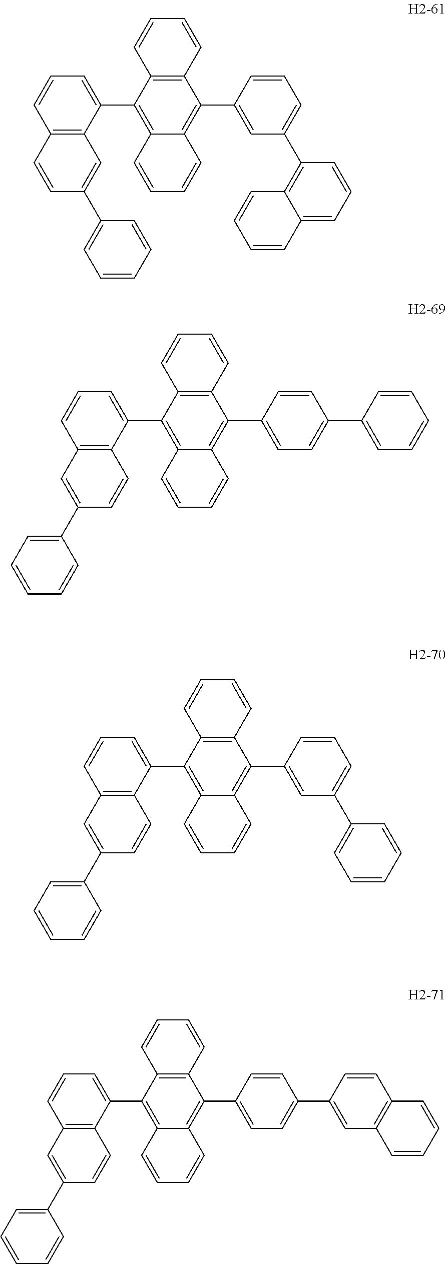

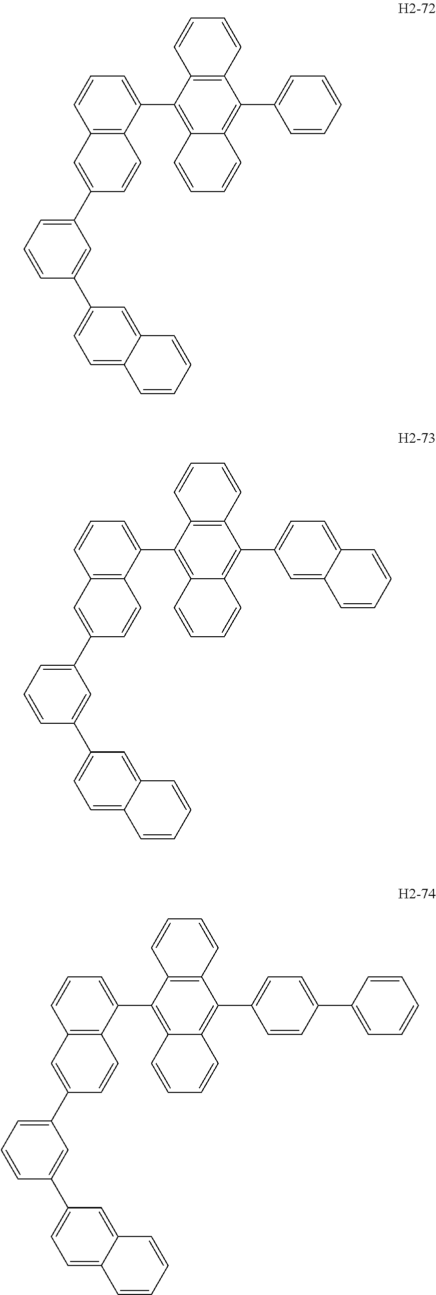

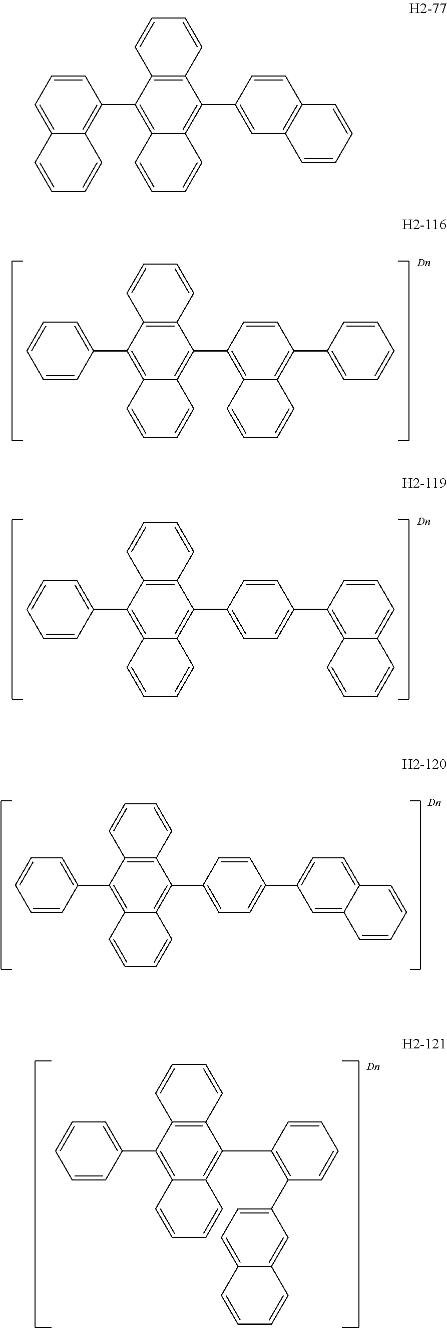

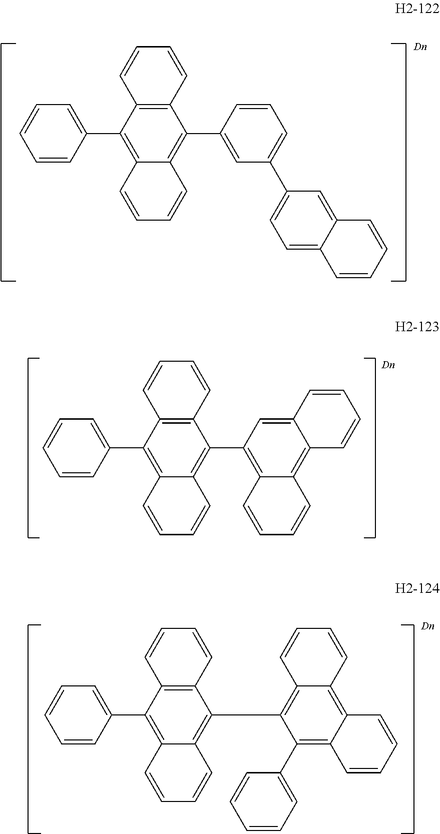

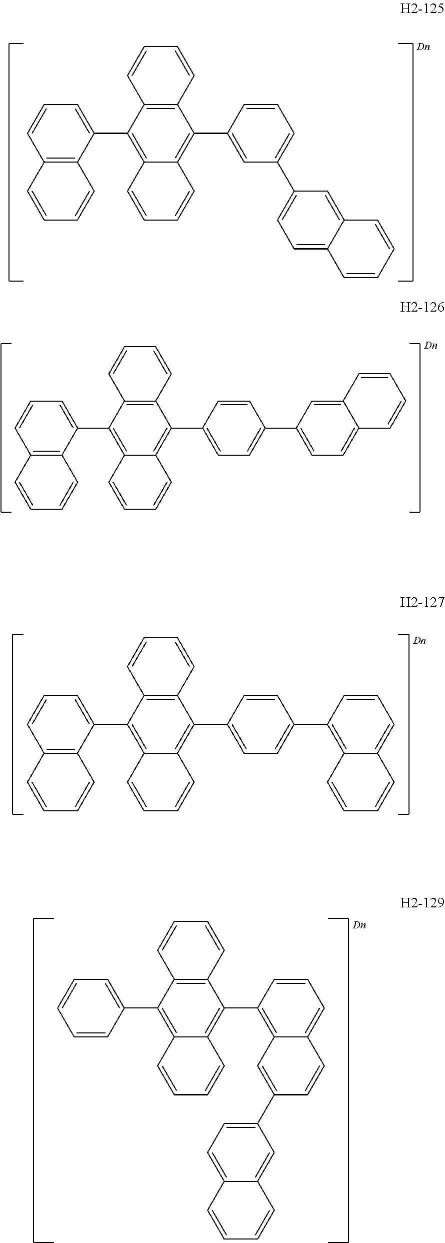

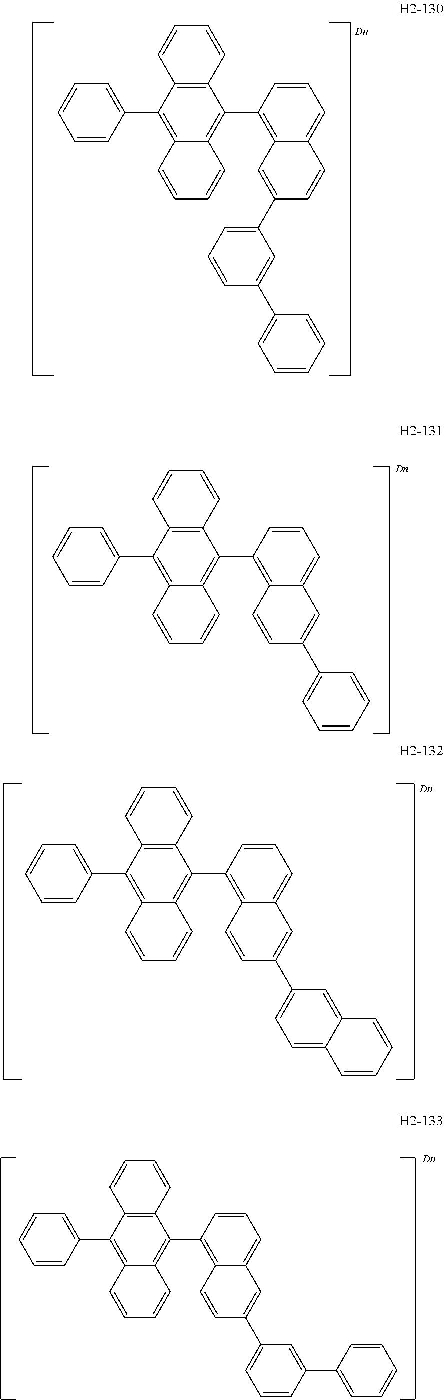

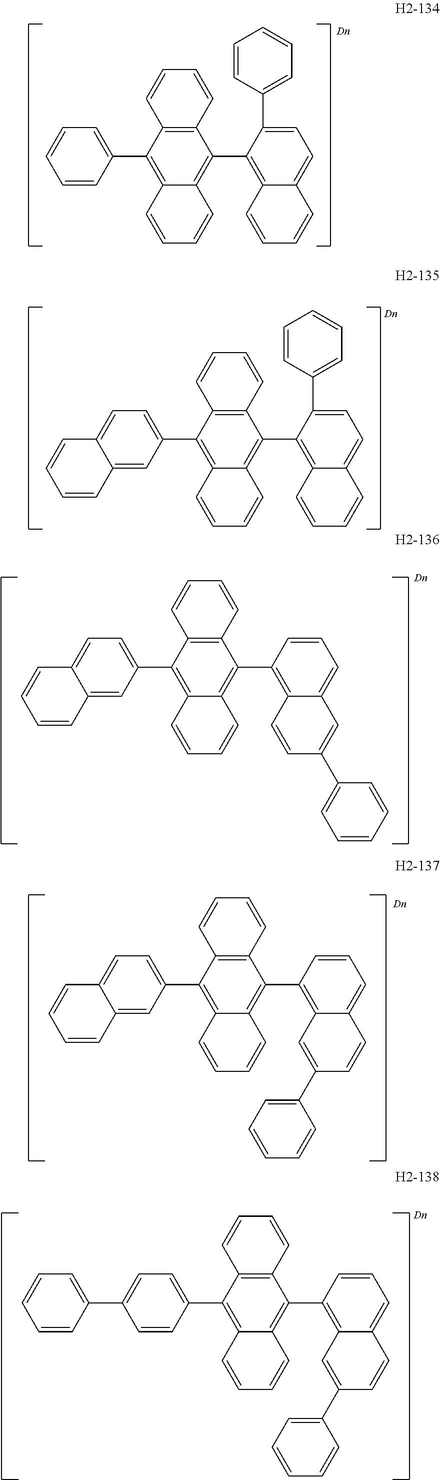

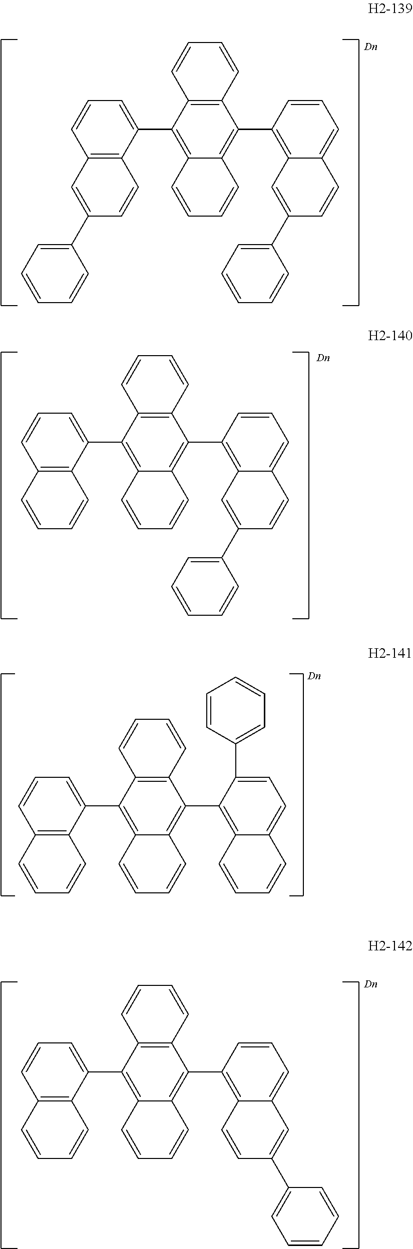

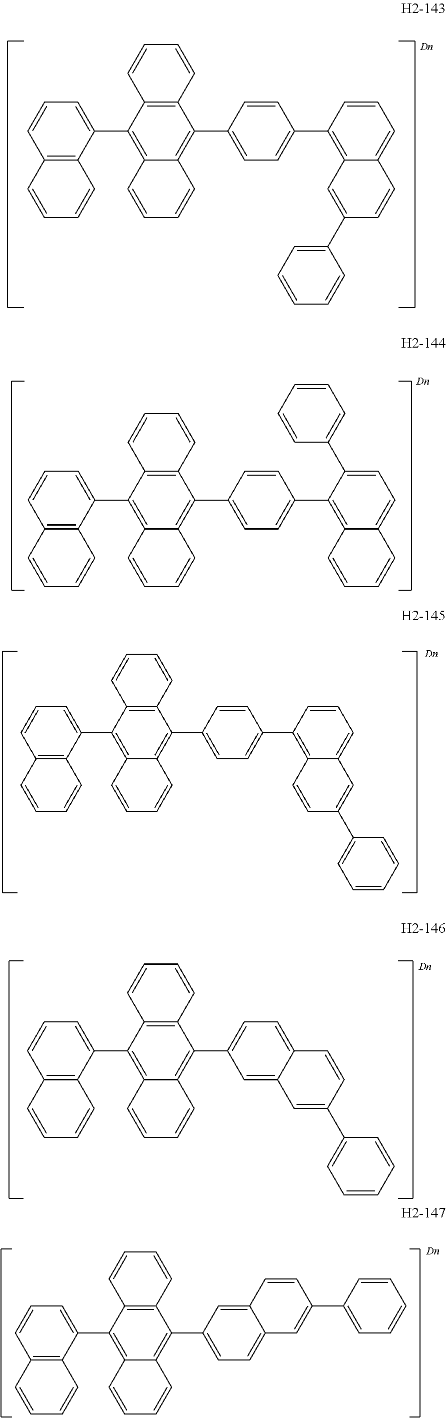

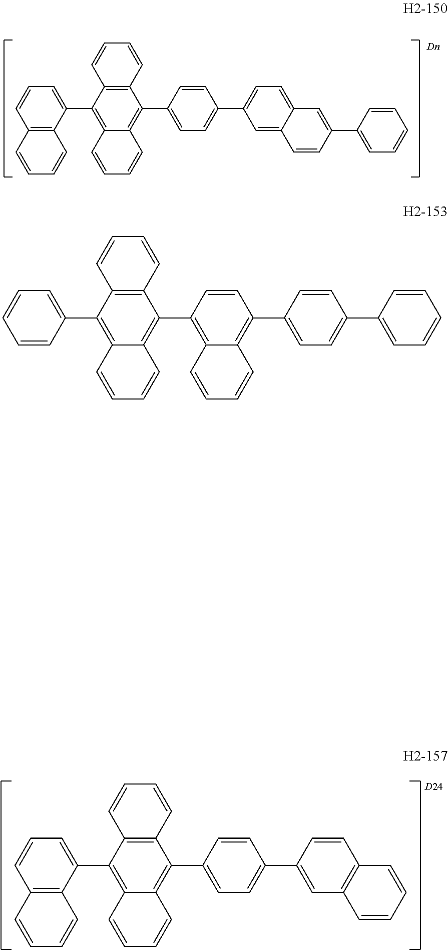

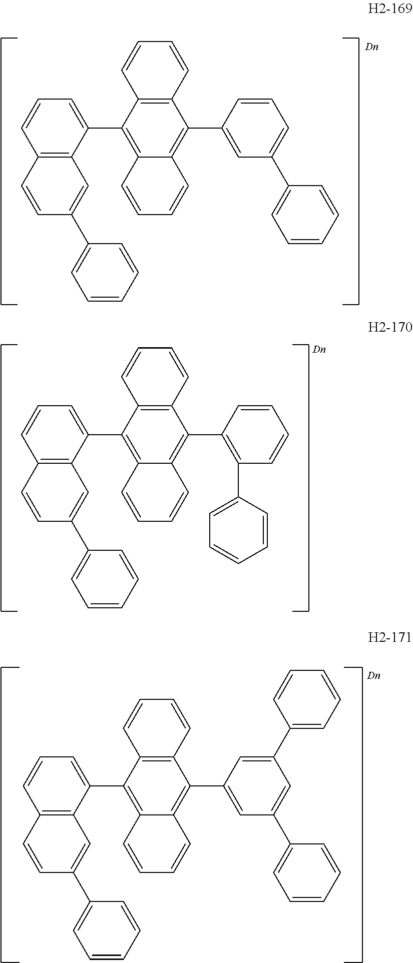

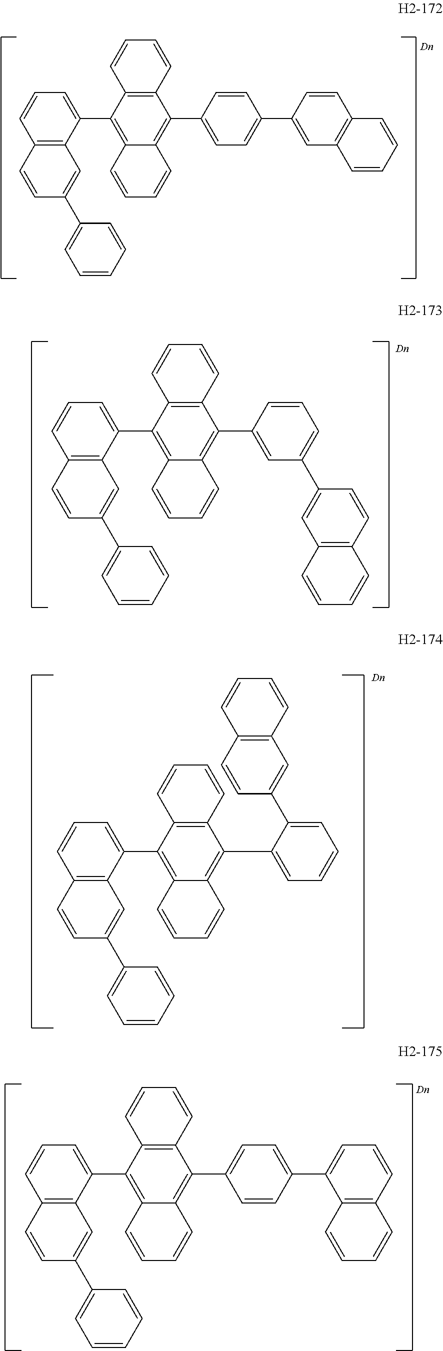

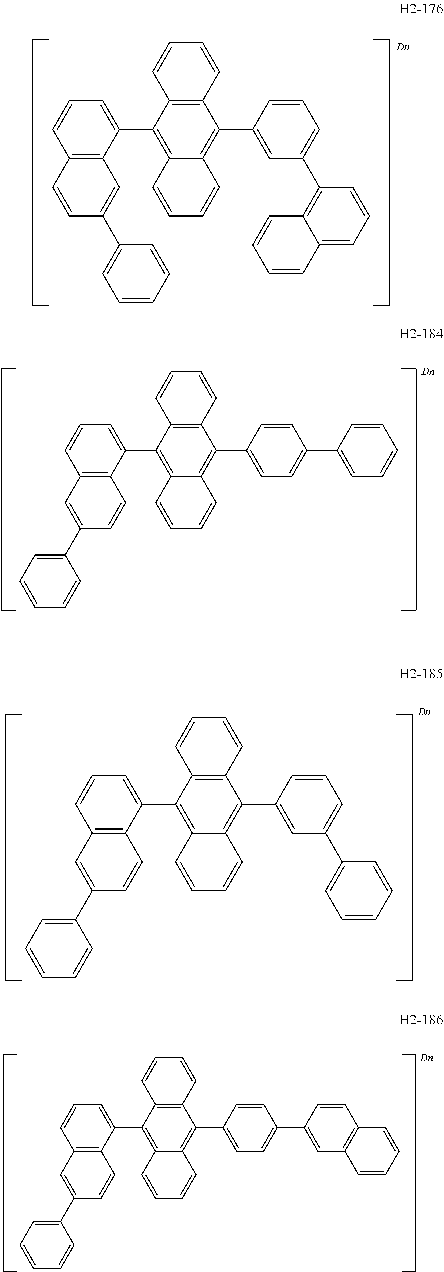

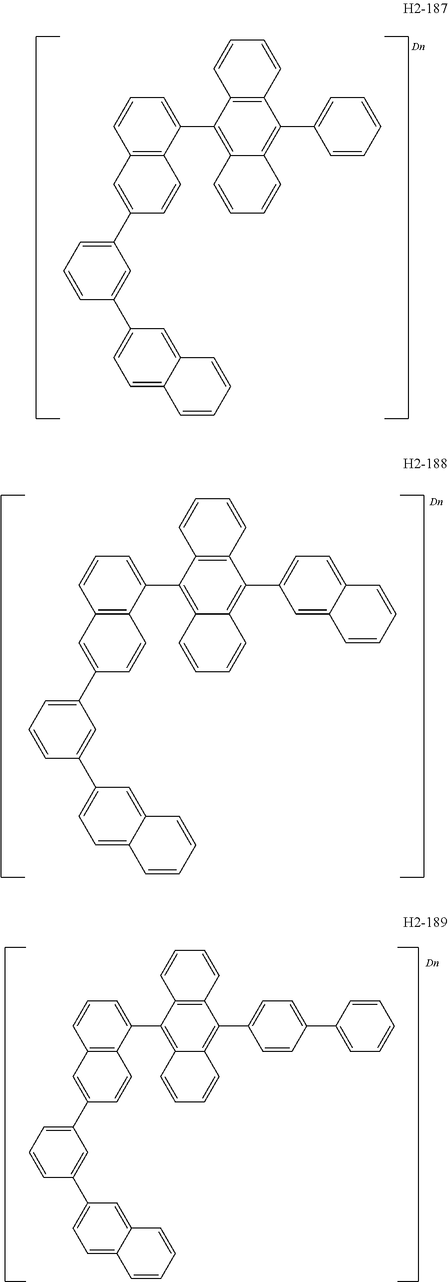

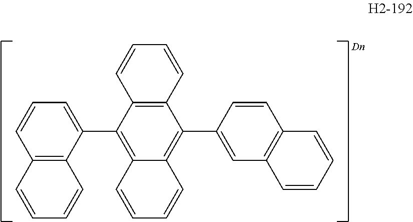

In the compounds above, Dn means that n number of hydrogens is replaced with deuterium, wherein n represents an integer of 1 to 50.

According to one embodiment, the present disclosure provides a composition for a light-emitting material of an organic electroluminescent device comprising a first compound represented by formula 1 above and a second compound represented by formula 11 above. Preferably, the composition may be used in the formation of a host of the light-emitting layer of the organic electroluminescent device.

At least one compound(s) of the first compound and/or the second compound included in the composition may be a melting material satisfying the equation (1), and two or more compounds included in the composition are in the mixed form in the form of powder, obtained by mixing the powdery material, melting and cooling them, prior to formation of the organic layer of the organic electroluminescent device.

The weight ratio of the first compound represented by formula 1 above and the second compound represented by formula 11 above in the composition may be 1:10 to 10:1, for example, 1:8 to 8:1, for example 1:5 to 5:1, for example, 1:2 to 2:1, but is not limited thereto.

The composition may further comprise materials known in the art, such as solvents, additives, etc.

Hereinafter, an organic electroluminescent device to which the aforementioned plurality of host materials and/or the composition comprising the same is(are) applied will be described.

The organic electroluminescent device according to one embodiment includes a first electrode; a second electrode; and at least one organic layer(s) interposed between the first electrode and the second electrode. The organic layer may include a light-emitting layer, wherein the light-emitting layer comprises a plurality of host materials, and the plurality of host materials includes at least one first compound as a melting material and at least one second compound comprising an anthracene-based moiety. Wherein the first compound is represented by formula 1 above, and the second compound is represented by formula 11. In addition, according to one embodiment of the present disclosure, the light-emitting layer may include a composition comprising at least one first compound represented by formula 1 above and at least one second compound comprising an anthracene-based moiety.

The light-emitting layer in the present disclosure is a layer in which light is emitted including a host and a dopant, and may be a single layer or a plurality of layers in which two or more layers are stacked. Wherein, the host mainly promotes recombination of electrons and holes, and has a function of confining excitons in the light-emitting layer, and the dopant has a function of efficiently emitting excitons obtained through recombination. The dopant compound of the light-emitting layer may be doped in an amount of less than 25% by weight, preferably, less than 20% by weight, more preferably, less than 17% by weight with respect to the total amount of host compound and the dopant compound.

The organic layer may further comprise at least one layer selected from a hole injection layer, a hole transport layer, a hole auxiliary layer, a light-emitting auxiliary layer, an electron transport layer, an electron injection layer, an interlayer, a hole blocking layer, an electron blocking layer, and an electron buffer layer, in addition to a light-emitting layer.

The organic layer may further comprise an amine-based compound and/or an azine-based compound, in addition to the light-emitting material of the present disclosure. Specifically, the hole injection layer, the hole transport layer, the hole auxiliary layer, the light-emitting layer, the light-emitting auxiliary layer, or the electron blocking layer may comprise an amine-based compound, for example, arylamine-based compound, a styrylarylamine-based compound, etc., as a hole injection material, a hole transport material, a hole auxiliary material, a light-emitting material, a light-emitting auxiliary material, and an electron blocking material. In addition, the electron transport layer, the electron injection layer, the electron buffer layer, and the hole blocking layer may comprise an azine-based compound as an electron transport material, an electron injection material, an electron buffer material, and a hole blocking material.

In addition, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising such a metal.

The plurality of host materials according to one embodiment may be used as light-emitting materials for a white organic light-emitting device. The white organic electroluminescent device has suggested various structures such as a parallel side-by-side arrangement method, a stacking arrangement method, or color conversion material (CCM) method, etc., according to the arrangement of R (Red), G (Green), YG (yellowish green), or B (Blue) light-emitting units.

In addition, the plurality of host materials according to one embodiment may also be applied to the organic electroluminescent device comprising a QD (quantum dot).

One of the first electrode and the second electrode may be an anode and the other may be a cathode. Wherein, the first electrode and the second electrode may each be formed as a transmissive conductive material, a transflective conductive material, or a reflective conductive material. The organic electroluminescent device may be a top emission type, a bottom emission type, or a both-sides emission type according to the kinds of the material forming the first electrode and the second electrode.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. In addition, the hole injection layer may be doped as a p-dopant. Also, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. The hole transport layer or the electron blocking layer may be multi-layers, and wherein each layer may use a plurality of compounds.

An electron buffer layer, a hole blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole blocking layer or the electron transport layer may also be multi-layers, wherein each layer may use a plurality of compounds. Also, the electron injection layer may be doped as an n-dopant.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby enabling the charge balance to be controlled. When an organic electroluminescent device includes two or more hole transport layers, the hole transport layer, which is further included, may be used as the hole auxiliary layer or the electron blocking layer. The light-emitting auxiliary layer, the hole auxiliary layer, or the electron blocking layer may have an effect of improving the efficiency and/or the lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both electrode(s). Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer.

Preferably, the chalcogenide includes SiO_{X}(1≤X≤2), AlO_{X}(1≤X≤1.5), SiON, SiAION, etc.; the halogenated metal includes LiF, MgF₂, CaF₂, a rare earth metal fluoride, etc.; and the metal oxide includes Cs₂O, Li₂O, MgO, SrO, BaO, CaO, etc.

Further, in the organic electroluminescent device of the present disclosure, preferably, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare-earth metals, and mixtures thereof. A reductive dopant layer may be employed as a charge generating layer to prepare an organic electroluminescent device having two or more light-emitting layers and emitting white light.

The organic electroluminescent device according to one embodiment may further include at least one dopant in the light-emitting layer. The dopant comprised in the organic electroluminescent device of the present disclosure may use the compound represented by the following formula 2, but is not limited thereto.

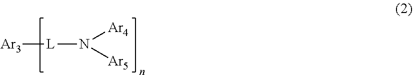

In formula 2,

L represents a single bond, a substituted or unsubstituted (C6-C30)arylene, or a substituted or unsubstituted (3- to 30-membered)heteroarylene;

Ar₄ and Ar₅ each independently represent a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(Ar₁₃)(Ar₁₄), or Ar₄ and Ar₅ may be linked to each other to form a ring;

n represents an integer of 0 to 2;

when n is 0, Ar₃ is represented by the following formula 2-1,

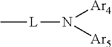

Ar₃ is represented by any one of the following formulas 2-1 to 2-5.

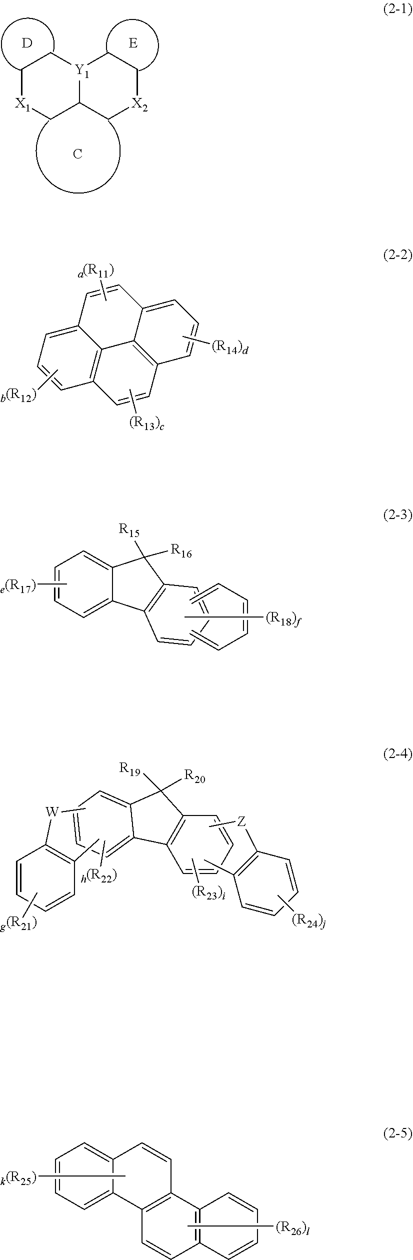

In formulas 2-1 to 2-5,

Y₁ represents B;

X₁ and X₂ each independently represent NR′, O, or S;

W and Z each independently represent 0, S, NR′, or CR₂₇R₂₈;

R′ represents hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄N(Ar₁₃)(Ar₁₄), or R′ may be directly linked to at least one of Ring C, Ring D, and Ring E, or may be linked via B, O, S, or CR₂₇R₂₈ as a linker, to form a ring;

Ring C, Ring D, and Ring E each independently represent a substituted or unsubstituted (C6-C30)aryl, or a substituted or unsubstituted (3- to 50-membered)heteroaryl; or Ring D and Ring E may be directly linked to each other, or may be linked via B, O, S, or CR₂₇R₂₈ as a linker, to form a ring;

R₁₁ to R₁₄, R₁₇, R₁₈, and R₂₁ to R₂₆ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄N(Ar₁₃)(Ar₄);

R₁₅, R₁₆, R₁₉, R₂₀, R₂₇, and R₂₈ each independently represent a substituted or unsubstituted (C1-C30)alkyl, a substituted or unsubstituted (C6-C30)aryl, or a substituted or unsubstituted (3- to 30-membered)heteroaryl, or at least one of R₁₅ and R₁₆, R₁₉ and R₂₀, and R₂₇ and R₂₈ may be fused to each other to form a spiro structure;

L₄ represents a single bond, a substituted or unsubstituted (C6-C30)arylene, a substituted or unsubstituted (3- to 30-membered)heteroarylene, a substituted or unsubstituted divalent (C2-C30) aliphatic hydrocarbon group, or a substituted or unsubstituted fused ring of divalent (C3-C30) aliphatic ring and (C6-C30) aromatic ring;

Ar₁₃ and Ar₁₄ each independently represent a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl;

a, c, h, and i each independently represent an integer of 1 or 2; b and d each independently represent an integer of 1 to 3; f, k, and l each independently represent an integer of 1 to 6; e, g, and j each independently represent an integer of 1 to 4; and when a to l are an integer of 2 or more, each of R₁₁ to R₁₄, R₁₇, R₁₈, and R₂₁ to R₂₆ may be the same or different; and

Ring C, Ring D, Ring E, R₁₁ to R₁₄, R₁₇, R₁₈, and R₂₁ to R₂₆ may have a position linked to L in formula 2 above.

In one embodiment, L may be a single bond, a substituted or unsubstituted (C6-C30)arylene, or a substituted or unsubstituted (3- to 30-membered)heteroarylene. According to one embodiment of the present disclosure, L may be a single bond, or a substituted or unsubstituted (C6-C25)arylene. According to another embodiment of the present disclosure, L may be a single bond, or (C6-C25)arylene unsubstituted or substituted with at least one (C1-C10)alkyl. For example, L may be a single bond, phenylene, naphthylene, or fluorenylene substituted with at least one ethyl, etc.

In one embodiment, Ar₄ and Ar₅ each independently may be a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(Ar₁₃)(Ar₁₄), or Ar₄ and Ar₅ may be linked to each other to form a ring. According to one embodiment of the present disclosure, Ar₄ and Ar₅ each independently may be a substituted or unsubstituted (C6-C25)aryl, or a substituted or unsubstituted (5- to 25-membered)heteroaryl, or Ar₄ and Ar₅ may be linked to each other to form a ring. According to another embodiment of the present disclosure, Ar₄ and Ar₅ each independently may be (C6-C18)aryl unsubstituted or substituted with at least one of deuterium, halogen, cyano, (C1-C10)alkyl, tri(C1-C10)alkylsilyl, (C1-C30)alkyldi(C6-C30)arylsilyl, and tri(C6-C30)arylsilyl; or (5- to 20-membered)heteroaryl unsubstituted or substituted with (C6-C18)aryl, or Ar₄ and Ar₅ may be linked to each other to form a ring. For example, Ar₄ and Ar₅ each independently may be phenyl unsubstituted or substituted with at least one of deuterium, fluorene, cyano, methyl, methyl substituted with fluorene, tert-butyl, trimethylsilyl, triphenylsilyl, and diphenylmethylsilyl; naphthyl; biphenyl unsubstituted or substituted with at least one of deuterium, fluorene and cyano; naphthylphenyl unsubstituted or substituted with at least one of fluorene and cyano; dimethylfluorenyl; terphenyl unsubstituted or substituted with at least one of fluorene, cyano and methyl; or carbazolyl substituted with phenyl, etc., or Ar₄ and Ar₅ may be linked to each other to form a ring, such as indole ring unsubstituted or substituted with at least one of fluorene, cyano and methyl; tetrahydroquinoline ring unsubstituted or substituted with at least one of cyano and methyl; or unsubstituted carbazole ring.

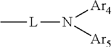

In one embodiment of the formula 2-1, Y₁ represents B; X₁ and X₂ each independently may be NR′, O, or S. According to one embodiment of the present disclosure, X₁ and X₂ each independently may be NR′ or O.

In one embodiment of the formula 2-1, Ring C, Ring D, and Ring E each independently may be a substituted or unsubstituted (C6-C30)aryl, or a substituted or unsubstituted (3- to 50-membered)heteroaryl. According to one embodiment of the present disclosure, Ring C, Ring D, and Ring E each independently may be a substituted or unsubstituted (C6-C25)aryl, or a substituted or unsubstituted (5- to 30-membered)heteroaryl; or at least one of Ring C, Ring D, and Ring E may be directly linked to R′, or may be linked via B, O, S, or CR₂₇R₂₈ as a linker, to form a ring; or Ring D and Ring E may be directly linked to each other, or may be linked via B, O, S, or CR₂₇R₂₈ as a linker, to form a ring. According to another embodiment of the present disclosure, Ring C, Ring D, and Ring E each independently may be (C6-C18)aryl unsubstituted or substituted with at least one of deuterium, (C1-C10)alkyl, (C6-C18)aryl, (5- to 20-membered)heteroaryl, di(C6-C18)arylamino and (C6-C18)aryl(5- to 20-membered)heteroaryl; or (5- to 25-membered)heteroaryl unsubstituted or substituted with at least one of (C6-C18)aryl and di(C6-C18)arylamino. For example, Ring C may be a substituted or unsubstituted benzene ring, or unsubstituted naphthyl ring; the substituent of the substituted benzene ring may be at least one selected from the group consisting of deuterium; methyl unsubstituted or substituted with deuterium; tert-butyl; phenyl unsubstituted or substituted with at least one of methyl, carbazolyl, dibenzofuranyl, phenoxazinyl, phenothiazinyl, 9,10-dihydro-9,9-dimethylacridinyl and diphenylamino: naphthyl; biphenyl; terphenyl; triphenylenyl; carbazolyl; phenoxazinyl; phenothiazinyl; 9,10-dihydro-9,9-dimethylacridinyl; diphenylamino unsubstituted or substituted with at least one of deuterium, methyl and tert-butyl; phenylnaphthylamino; phenylbiphenylamino unsubstituted or substituted with tert-butyl; dinaphthylamino; dibiphenylamino; and phenyldibenzofuranylamino. For example, Ring D and Ring E each independently may be a substituted or unsubstituted benzene ring; naphthalene ring; dibenzofuran ring; carbazole ring substituted with at least one of phenyl and diphenylamino; or 21-membered heteroaryl ring substituted with at least one of methyl and phenyl, etc., or Ring D and Ring E may be directly linked to each other, or may be linked via B, O, S, or CR₂₇R₂₈ as a linker to from a ring. The substituent of the substituted benzene ring may be at least one selected from the group consisting of deuterium, methyl, tert-butyl, phenyl, naphthyl, diphenylamino unsubstituted or substituted with diphenylamino, phenylnaphthylamino, dibiphenylamino, phenylcarbazolylphenylamino and dibenzofuranylphenylamino.

In one embodiment, R′ may be hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(Ar₁₃)(Ar₁₄), or R′ may be directly linked to at least one of Ring C, Ring D, and Ring E, or may be linked via B, O, S, or CR₂₇R₂₈ as a linker, to form a ring. According to one embodiment of the present disclosure, R′ may be a substituted or unsubstituted (C1-C20)alkyl, a substituted or unsubstituted (C6-C25)aryl, or a substituted or unsubstituted (5- to 25-membered)heteroaryl. According to another embodiment of the present disclosure, R′ may be unsubstituted (C1-C10)alkyl; (C6-C18)aryl unsubstituted or substituted with at least one of deuterium, (C1-C10)alkyl and di(C6-C18)arylamino, or (5- to 20-membered)heteroaryl unsubstituted or substituted with (C6-C18)aryl. For example, R′ each independently may be methyl; phenyl unsubstituted or substituted with at least one of deuterium, methyl, tert-butyl and diphenylamino; naphthyl; biphenyl; or carbazolyl substituted with phenyl, etc; or R′ may be directly linked to at least one of Ring C, Ring D, and Ring E, or may be linked via B, O, S, or CR₂₇R₂₈ as a linker, to form a ring.

In one embodiment of the formula 2-4, W and Z each independently may be O, S, NR′, or CR₂₇R₂₈. According to another embodiment of the present disclosure, W and Z each independently may be O or S.

In one embodiment of the formulas 2-2 to 2-5, R₁₁ to R₁₄, R₁₇, R₁₈, and R₂₁ to R₂₆ each independently may be hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(A₁₃)(A₁₄). According to one embodiment of the present disclosure, R₁₁ to R₁₄, R₁₇, R₁₈, and R₂₁ to R₂₆ each independently may be hydrogen, a substituted or unsubstituted (C6-C25)aryl, or a substituted or unsubstituted (5- to 25-membered)heteroaryl. According to another embodiment of the present disclosure, R₁₁ to R₁₄, R₁₇, R₁₈, and R₂₁ to R₂₆ each independently may be hydrogen, (C6-C18)aryl unsubstituted or substituted with deuterium, or (5- to 20-membered)heteroaryl unsubstituted or substituted with (C6-C18)aryl. For example, R₁₇, R₁₆, and R₂₁ to R₂₆ may be hydrogen; R₁₁ to R₁₄ each independently may be hydrogen; phenyl unsubstituted or substituted with deuterium; or a substituted carbazolyl, etc., and the substituent of the substituted carbazolyl may be phenyl substituted with tert-butyl, etc.

In one embodiment of the formulas 2-1 to 2-5, R₁₅, R₁₆, R₁₉, R₂₀, R₂₇, and R₂₈ each independently may be a substituted or unsubstituted (C1-C30)alkyl, a substituted or unsubstituted (C6-C30)aryl, or a substituted or unsubstituted (3- to 30-membered)heteroaryl, or at least one of R₁₅ and R₁₆, R₁₉ and R₂₀, and R₂₇ and R₂₆ may be fused to each other to form a spiro structure. According to one embodiment of the present disclosure, R₁₅, R₁₆, R₁₉, R₂₀, R₂₇, and R₂₈ each independently may be a substituted or unsubstituted (C1-C20)alkyl, or a substituted or unsubstituted (C6-C25)aryl, or at least one of R₁₅ and R₁₆, R₁₉ and R₂₀, and R₂₇ and R₂₆ may be fused to each other to form a spiro structure. According to another embodiment of the present disclosure, R₁₅, R₁₈, R₁₉, R₂₀, R₂₇, and R₂₈ each independently may be unsubstituted (C1-C10)alkyl, or unsubstituted (C6-C18)aryl, or at least one of R₁₅ and R₁₆, R₁₉ and R₂₀, and R₂₇ and R₂₆ may be fused to each other to form a spiro structure. For example, R₁₅; and R₁₆ each independently may be methyl or phenyl, or R₁₅ and R₁₆ may be fused to each other to form a spiro structure, for example fluorene ring. For example, R₁₉ and R₂₀ each independently may be phenyl, or R₁₉ and R₂₀ may be fused to each other to form a spiro structure, for example fluorene ring. R₂₇ and R₂₆ each independently may be methyl.

In one embodiment, L₄ may be a single bond, a substituted or unsubstituted (C6-C30)arylene, a substituted or unsubstituted (3- to 30-membered)heteroarylene, a substituted or unsubstituted divalent (C2-C30) aliphatic hydrocarbon group, or a substituted or unsubstituted fused ring of divalent (C3-C30) aliphatic ring and (C6-C30) aromatic ring. For example, L₄ may be a single bond.

In one embodiment, Ar₁₃ and Ar₁₄ each independently may be a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl. According to one embodiment of the present disclosure, Ar₁₃ and Ar₄ each independently may be a substituted or unsubstituted (C6-C25)aryl, or a substituted or unsubstituted (5- to 25-membered)heteroaryl. According to another embodiment of the present disclosure, Ar₁₃ and Ar₁₄ each independently may be (C6-C18)aryl unsubstituted or substituted with at least one of deuterium, (C1-C10)alkyl and di(C6-C18)arylamino; or (5- to 20-membered)heteroaryl unsubstituted or substituted with (C6-C18)aryl. For example, Ar₁₃ and Ar₁₄ each independently may be phenyl unsubstituted or substituted with at least one of deuterium, methyl, tert-butyl and diphenylamino; naphthyl; biphenyl unsubstituted or substituted with tert-butyl; carbazolyl substituted with phenyl; or dibenzofuranyl, etc.

In one embodiment of the formulas 2-2 to 2-5, a, c, h, and i each independently may be an integer of 1 or 2; b and d each independently may be an integer of 1 to 3; f, k, and l each independently may be an integer of 1 to 6; e, g, and j each independently may be an integer of 1 to 4; and when a to l are an integer of 2 or more, each of R₁₁ to R₁₄, R₁₇, R₁₅, and R₂₁ to R₂₆ may be the same or different.

The compound represented by formula 2 according to one embodiment may be represented by any one of the following formulas 2-11 to 2-18:

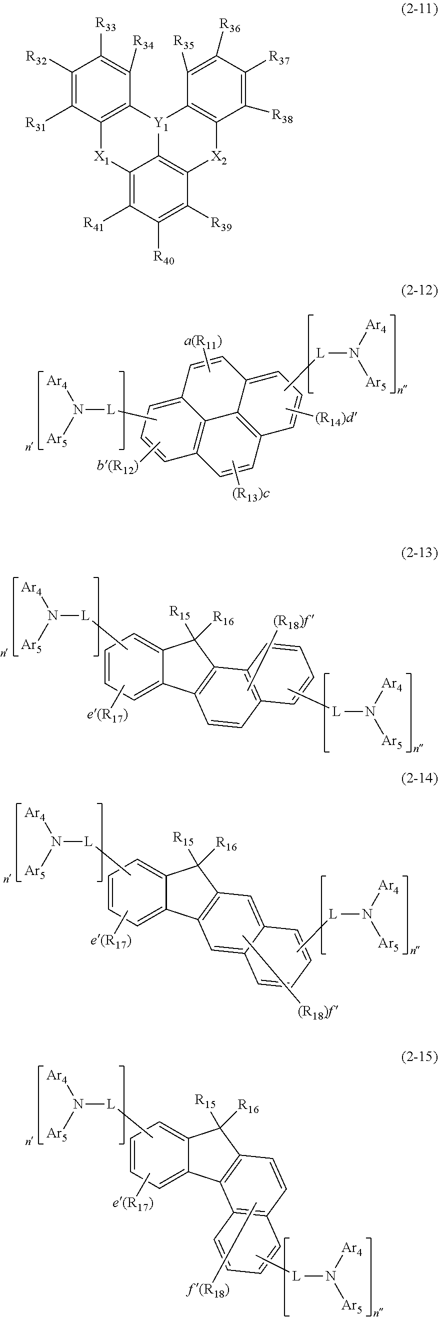

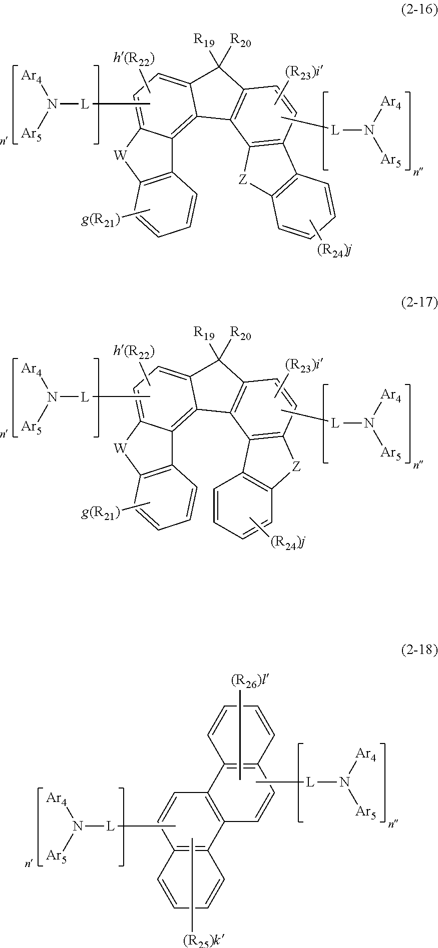

In formulas 2-11 to 2-18,

R₃₁ to R₄₁ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(Ar₁₃)(Ar₁₄), or the adjacent of at least two of R₃₁ to R₄₁ and R′ may be directly linked to each other, or may be linked via B, O, S, or CR₂₇R₂₈ as a linker, to form a ring;

n′ and n″ each independently represent 0 or 1, and at least one of n′ and n″ is 1;

b′ and d′ each independently represent an integer of 1 to 3, e′ represents an integer of 1 to 4, f′, k′, and l′ each independently represent an integer of 1 to 6, and h′ and i′ each independently represent an integer of 1 or 2; and

Y₁, X₁, X₂, R₁₁ to R₂₈, L₄, Ar₁₃, Ar₁₄, a, c, g, and j are as defined in formulas 2-1 to 2-5 above.

In one embodiment, R₃₁ to R₄₁ each independently may be hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, or -L₄-N(Ar₁₃)(Ar₁₄), or the adjacent of at least two of R₃₁ to R₄₁ and R′ may be directly linked to each other, or may be linked via B, O, S, or CR₂₇R₂₈ as a linker, to form a ring. According to one embodiment of the present disclosure, R₃₁ to R₄₁ each independently may be hydrogen, deuterium, a substituted or unsubstituted (C1-C20)alkyl, a substituted or unsubstituted (C6-C25)aryl, a substituted or unsubstituted (5- to 25-membered)heteroaryl, or -L₄-N(Ar₁₃)(Ar₁₄), or the adjacent of at least two of R₃₁ to R₄₁ and R′ may be directly linked to each other, or may be linked via B, O, S, or CR₂₇R₂₈ as a linker, to form a ring. According to another embodiment of the present disclosure, R₃₁ to R₄₁ each independently may be hydrogen; deuterium; (C1-C10)alkyl unsubstituted or substituted with deuterium; (C6-C18)aryl unsubstituted or substituted with at least one of (C1-C10)alkyl, (5- to 20-membered)heteroaryl and di(C6-C18)arylamino; or -L₄-N(Ar₁₃)(Ar₁₄); or the adjacent of at least two of R₃₁ to R₄₁ and R′ may be directly linked to each other, or may be linked via B, O, S, or CR₂₇R₂₈ as a linker, to form a ring. For example, R₃₁ to R₄₁ each independently may be hydrogen, deuterium, methyl unsubstituted or substituted with deuterium, tert-butyl, a substituted or unsubstituted phenyl, naphthyl, biphenyl, terphenyl, triphenylenyl, carbazolyl, phenoxazinyl, phenothiazinyl, 9,10-dihydro-9,9-dimethylacridinyl, or -L₄-N(Ar₁₃)(Ar₁₄), or the adjacent of at least two of R₃₁ to R₄₁, and R′ may be directly linked to each other, or may be linked via B, O, S, or CR₂₇R₂₈ as a linker, to form a ring such as benzene ring; indole ring substituted with at least one of phenyl and diphenylamino; benzofuran ring; benzoxazine ring; benzothiazine ring; or (17- to 18-membered)heteroaryl ring substituted with methyl and phenyl, etc. The substituent of the substituted phenyl may be at least one of methyl, carbazolyl, dibenzofuranyl, phenoxazinyl, phenothiazinyl, 9,10-dihydro-9,9-dimethylacridinyl and diphenylamino.

In one embodiment, n′ and n″ each independently may be 0 or 1, and at least one of n′ and n″ is 1

In one embodiment, b and d′ each independently may be an integer of 1 or 2; e′ may be an integer of 1 to 3; f′, k′ and l′ each independently may be an integer of 1 to 5; and h′ and i′ each independently may be an integer of 1.

In one embodiment, Y₁, X₁, X₂, R₁₁ to R₂₈, L₄, Ar₁₃, Ar₁₄, a, c, g, and j are as defined in formulas 2-1 to 2-5.

According to one embodiment, the compound represented by formula 2 may be more specifically illustrated by the following compounds, but is not limited thereto.

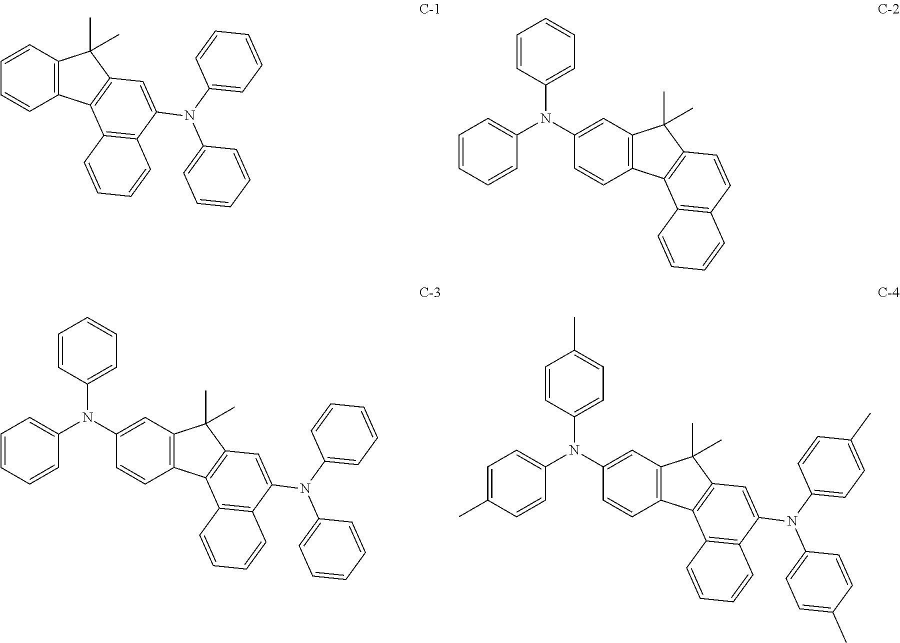

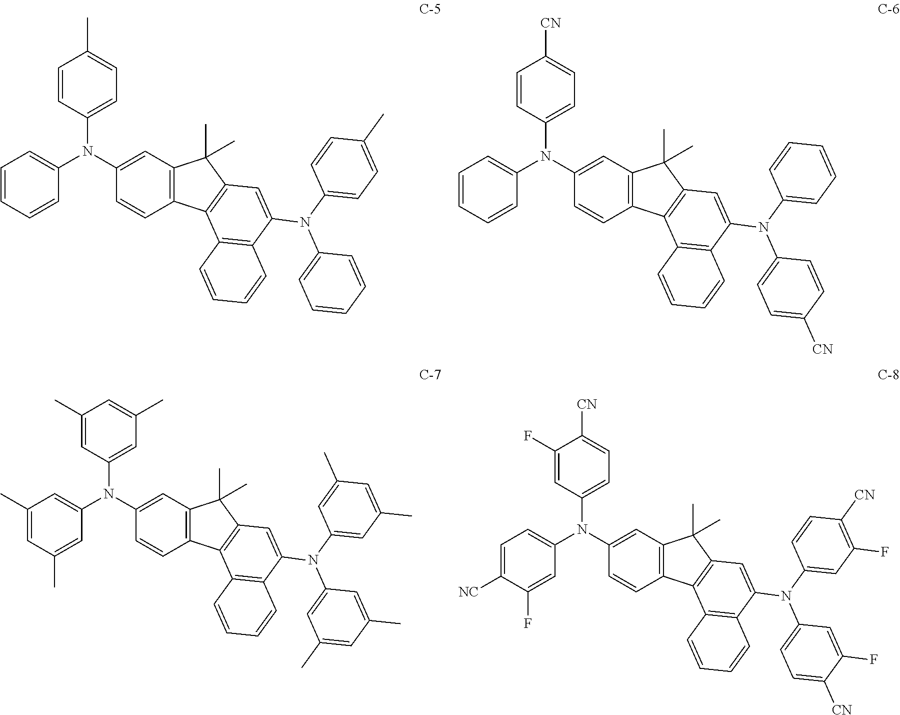

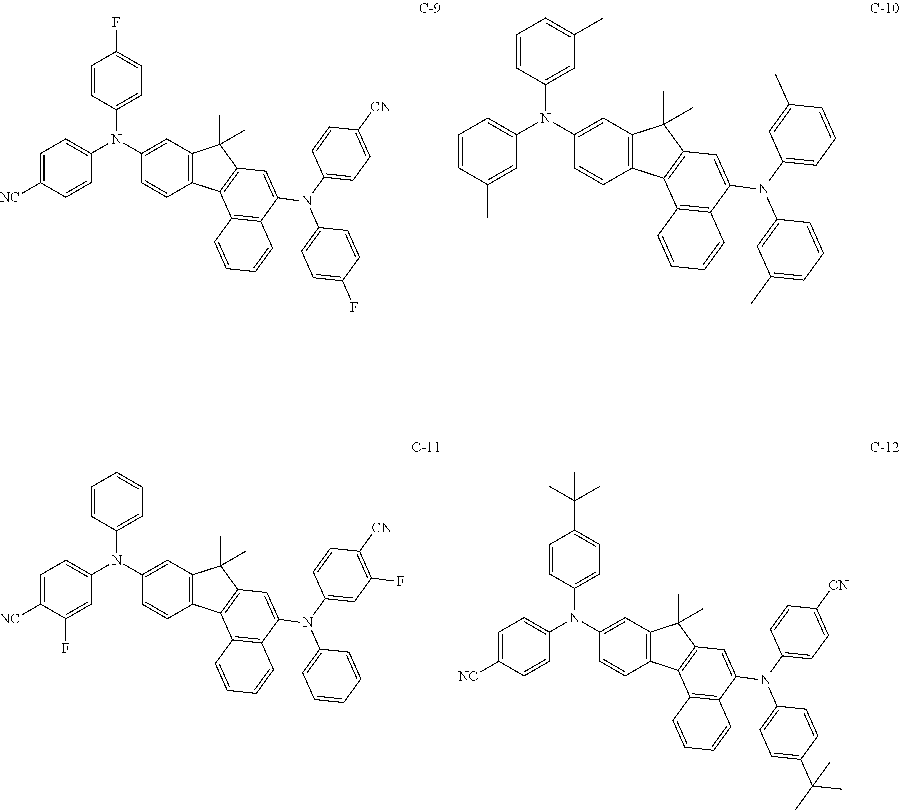 [SMILES: CC1(C)c2cc(N(c3ccc(F)cc3)c3ccc(C#N)cc3)ccc2-c2c1cc(N(c1ccc(F)cc1)c1ccc(C#N)cc1)c1ccccc21 ; Cc1cccc(N(c2cccc(C)c2)c2ccc3c(c2)C(C)(C)c2cc(N(c4cccc(C)c4)c4cccc(C)c4)c4ccccc4c2-3)c1 ; CC1(C)c2cc(N(c3ccccc3)c3ccc(C#N)c(F)c3)ccc2-c2c1cc(N(c1ccccc1)c1ccc(C#N)c(F)c1)c1ccccc21 ; CC(C)(C)c1ccc(N(c2ccc(C#N)cc2)c2ccc3c(c2)C(C)(C)c2cc(N(c4ccc(C#N)cc4)c4ccc(C(C)(C)C)cc4)c4ccccc4c2-3)cc1]

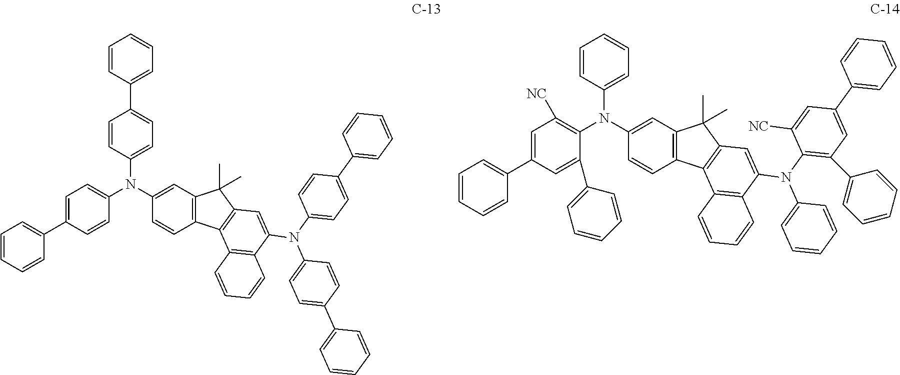 [SMILES: CC1(C)c2cc(N(c3ccc(-c4ccccc4)cc3)c3ccc(-c4ccccc4)cc3)ccc2-c2c1cc(N(c1ccc(-c3ccccc3)cc1)c1ccc(-c3ccccc3)cc1)c1ccccc21 ; CC1(C)c2cc(N(c3ccccc3)c3c(C#N)cc(-c4ccccc4)cc3-c3ccccc3)ccc2-c2c1cc(N(c1ccccc1)c1c(C#N)cc(-c3ccccc3)cc1-c1ccccc1)c1ccccc21]

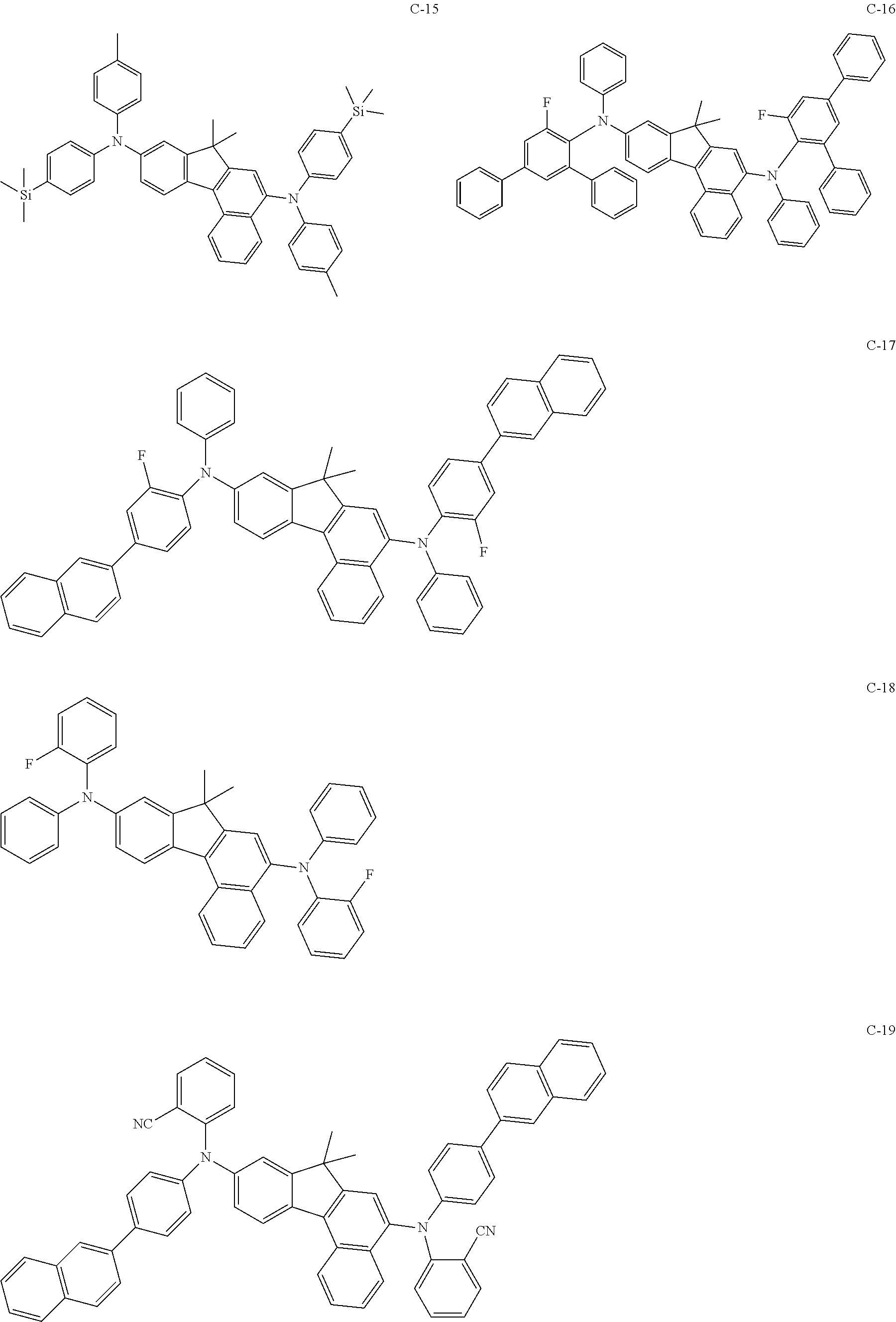

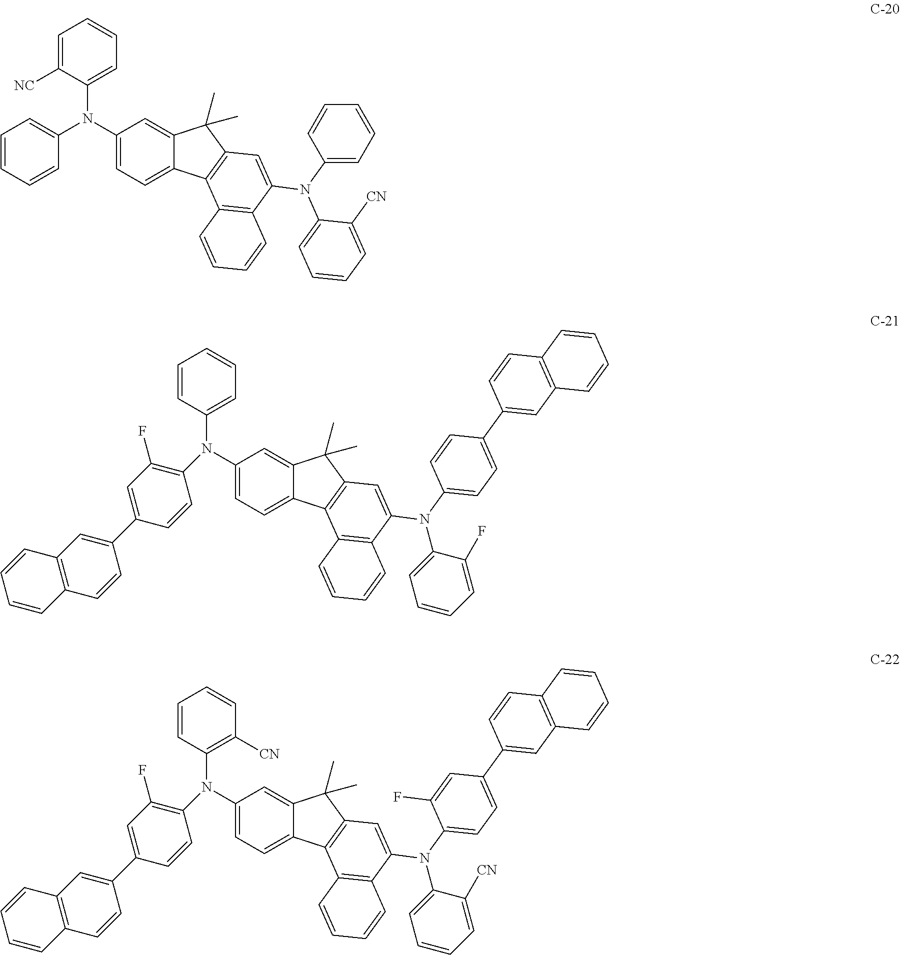 [SMILES: CC1(C)c2cc(N(c3ccccc3)c3ccccc3C#N)ccc2-c2c1cc(N(c1ccccc1)c1ccccc1C#N)c1ccccc21 ; CC1(C)c2cc(N(c3ccccc3)c3ccc(-c4ccc5ccccc5c4)cc3F)ccc2-c2c1cc(N(c1ccc(-c3ccc4ccccc4c3)cc1)c1ccccc1F)c1ccccc21 ; CC1(C)c2cc(N(c3ccc(-c4ccc5ccccc5c4)cc3F)c3ccccc3C#N)ccc2-c2c1cc(N(c1ccc(-c3ccc4ccccc4c3)cc1F)c1ccccc1C#N)c1ccccc21]

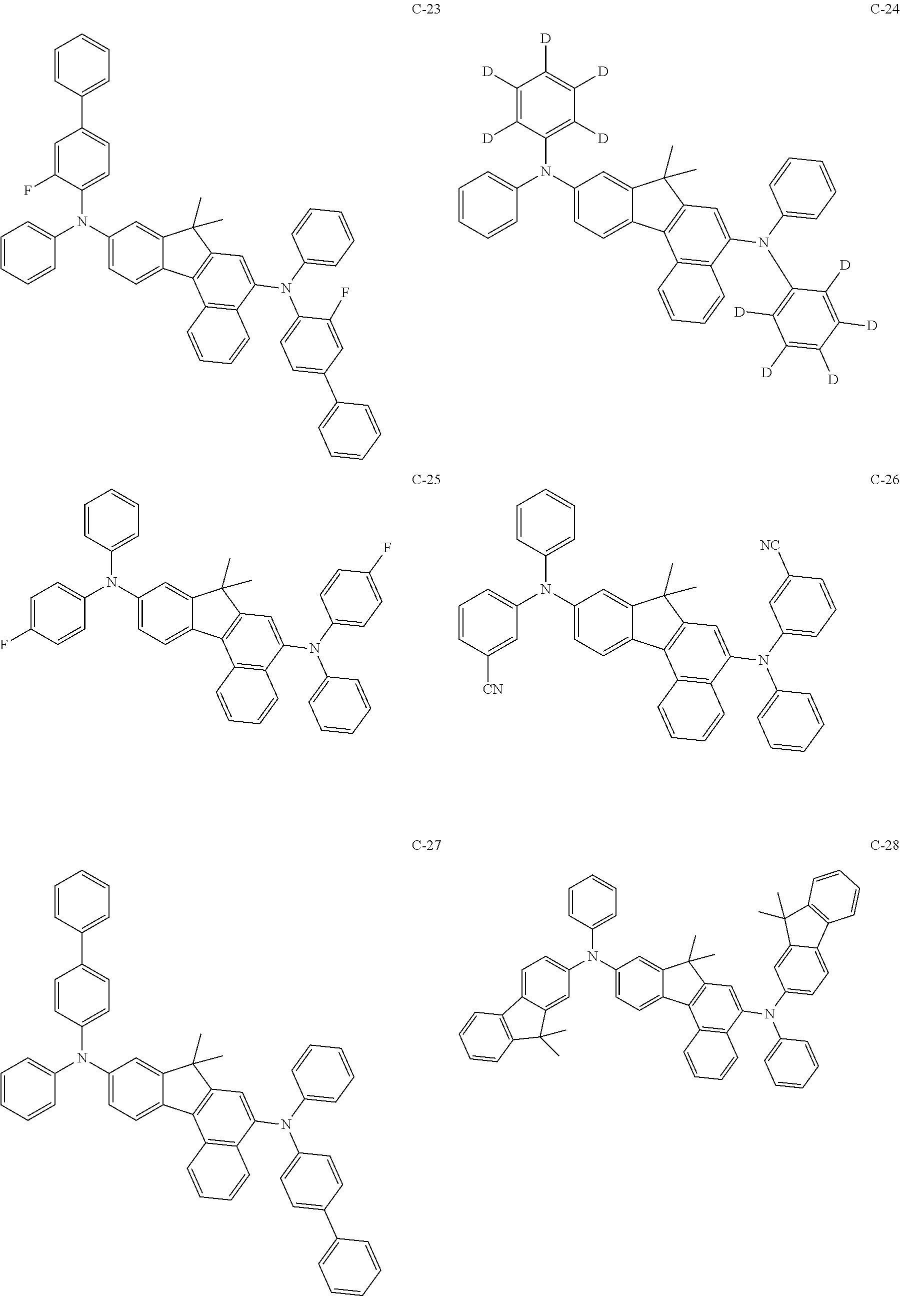

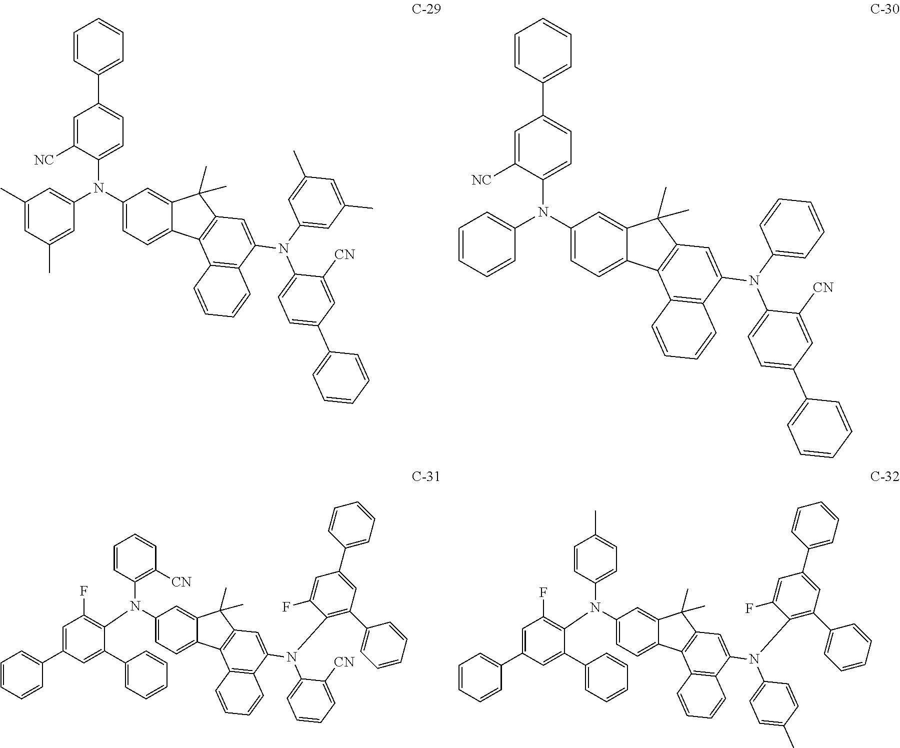

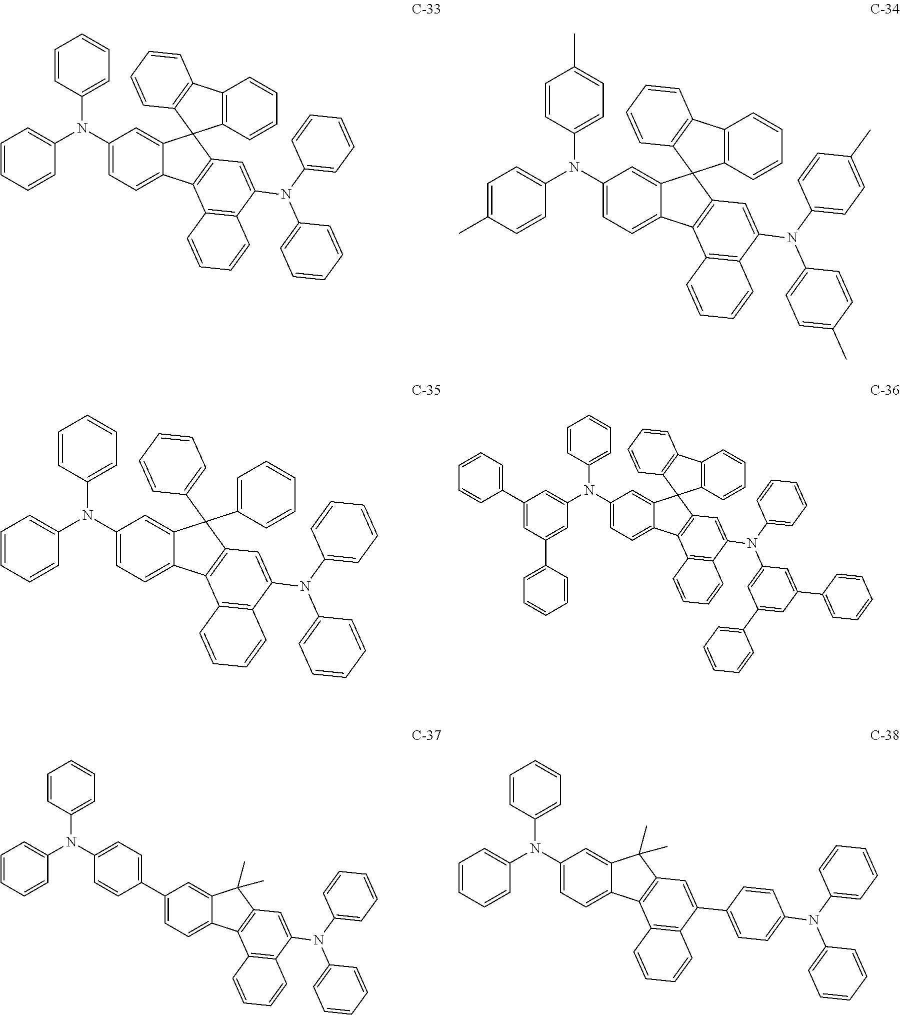

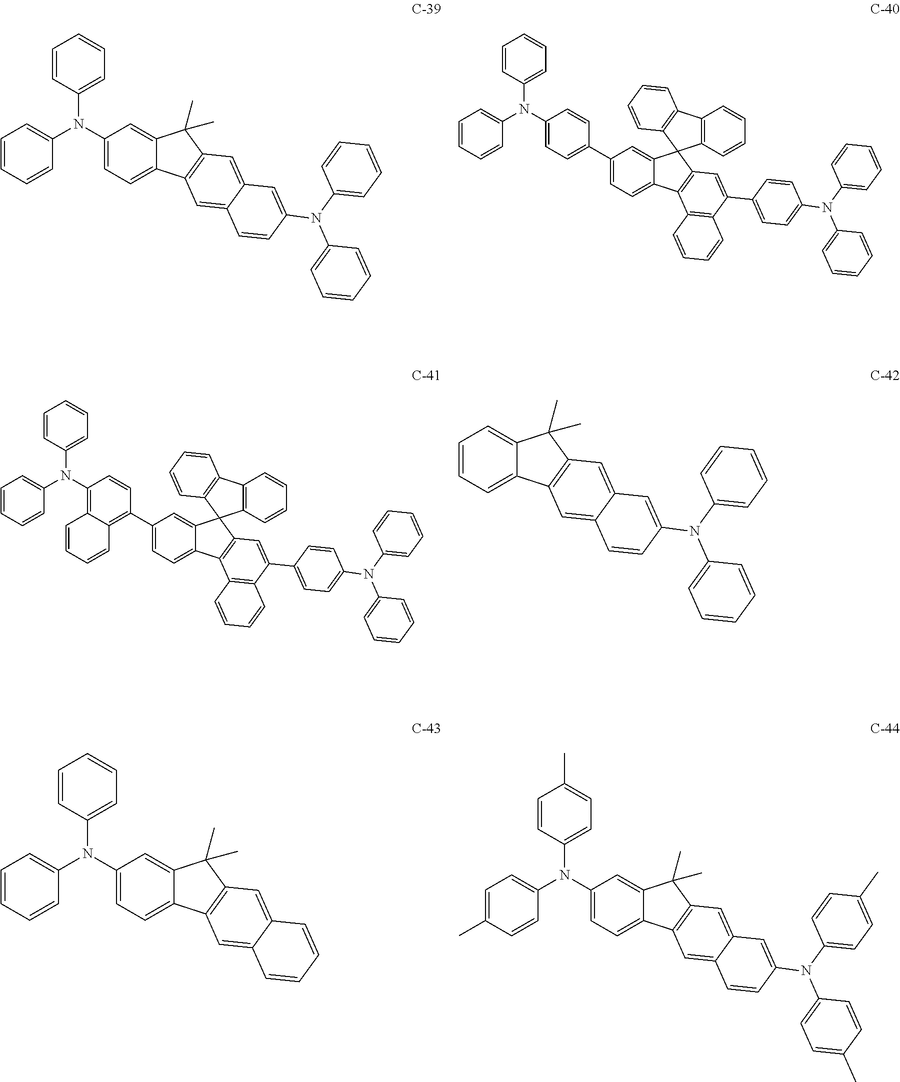

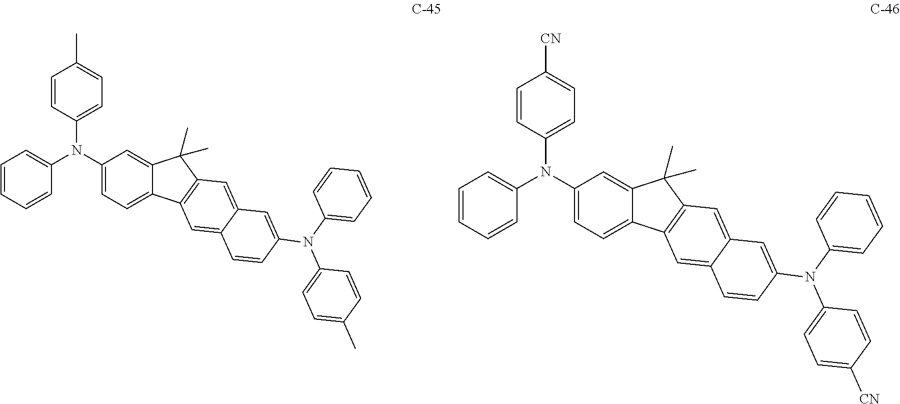 [SMILES: Cc1ccc(N(c2ccccc2)c2ccc3c(c2)C(C)(C)c2cc4cc(N(c5ccccc5)c5ccc(C)cc5)ccc4cc2-3)cc1 ; CC1(C)c2cc(N(c3ccccc3)c3ccc(C#N)cc3)ccc2-c2cc3ccc(N(c4ccccc4)c4ccc(C#N)cc4)cc3cc21]

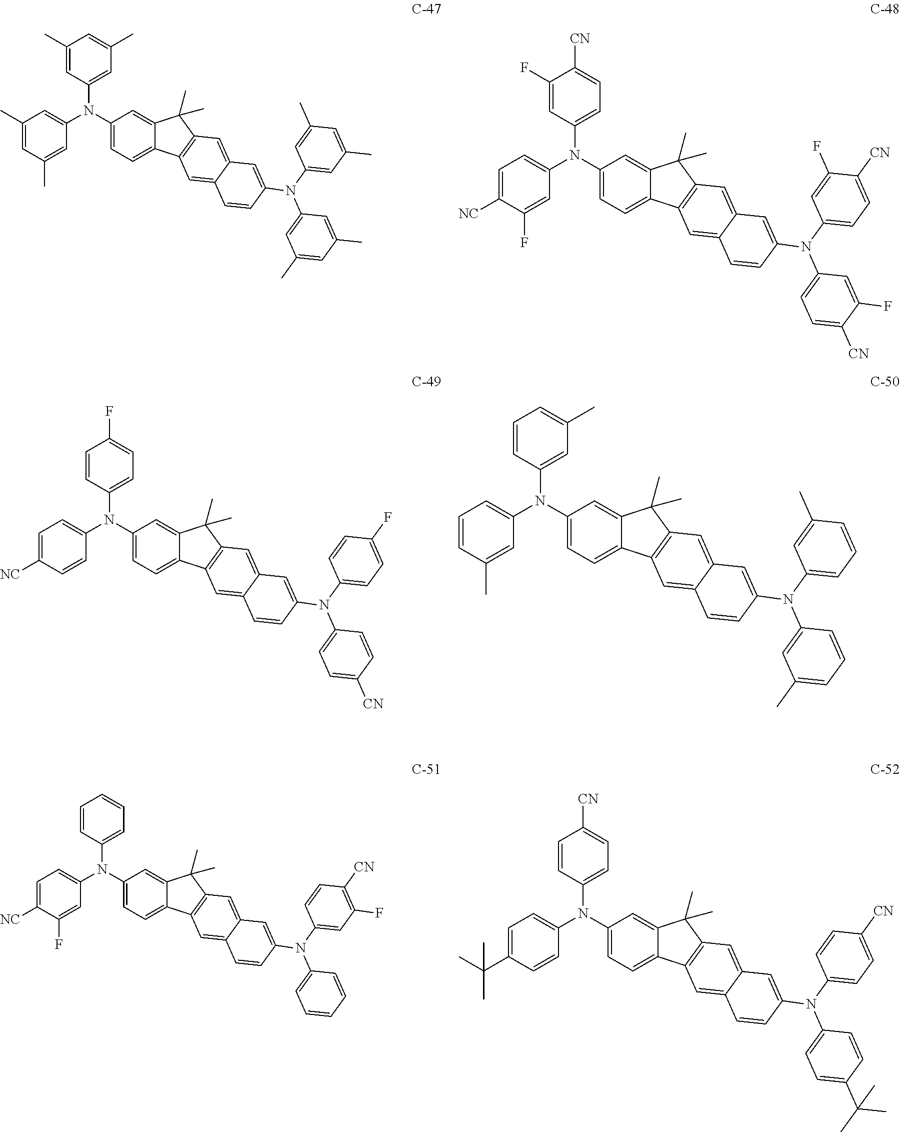

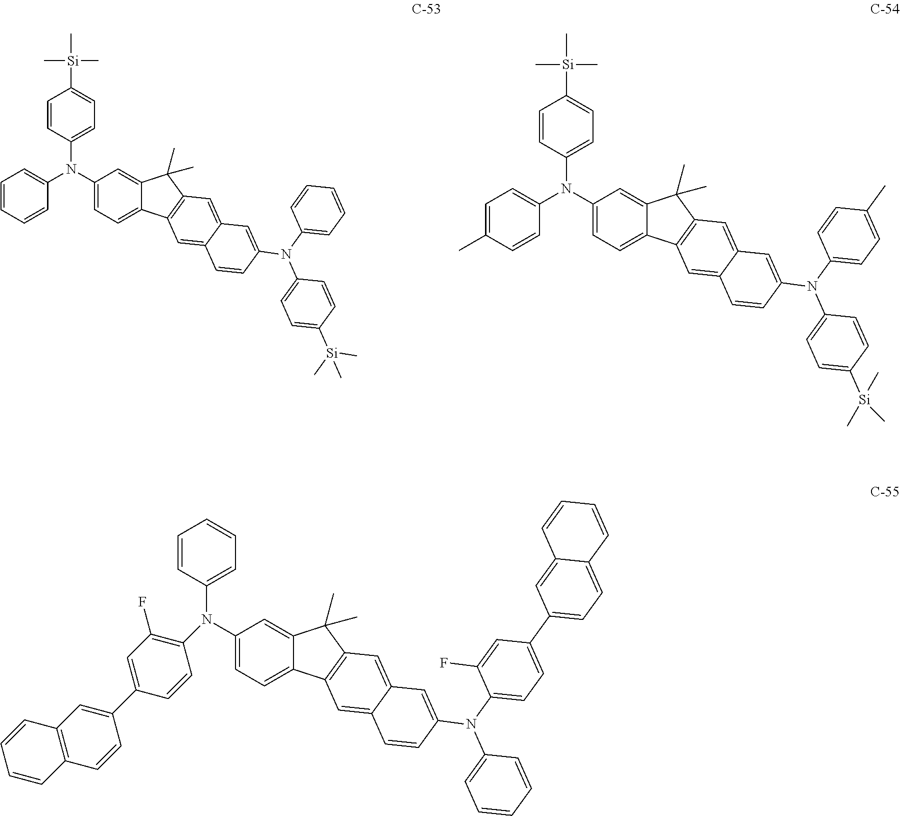

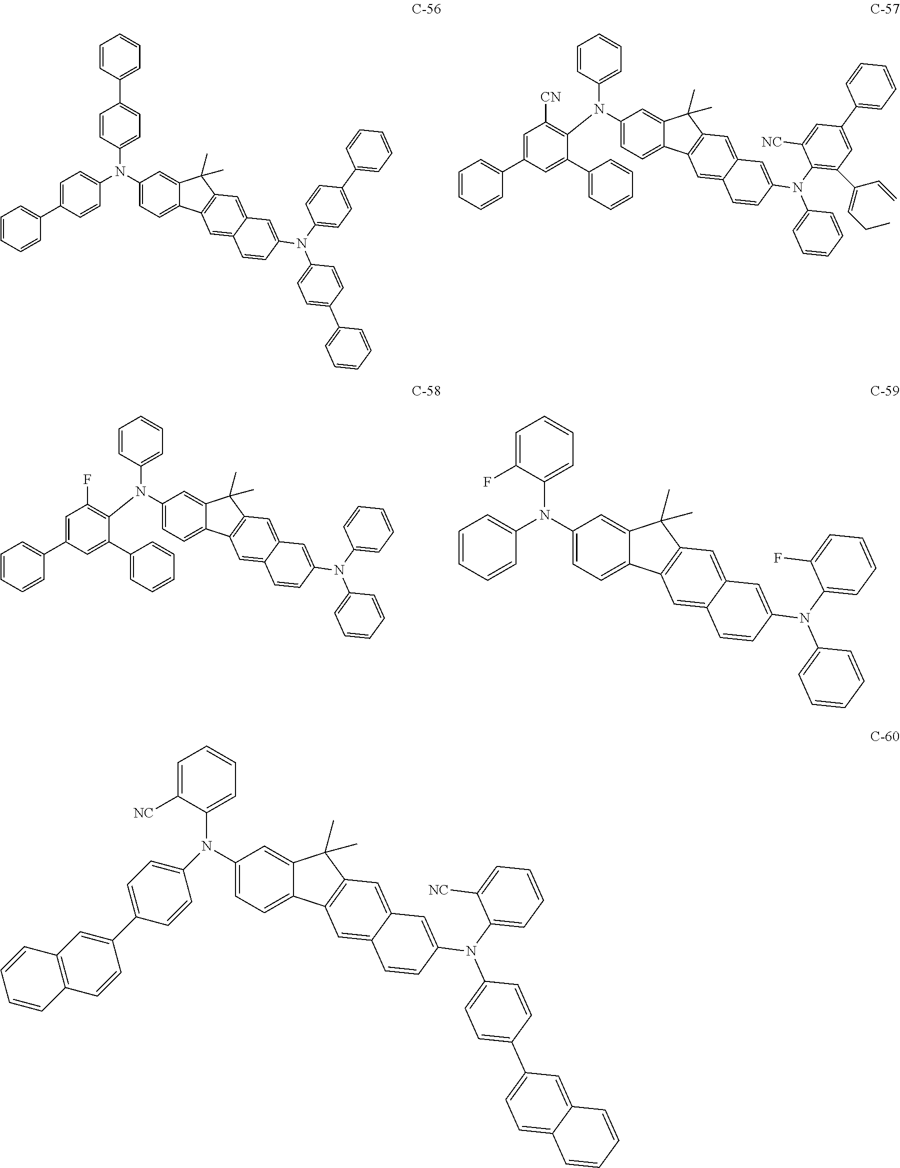

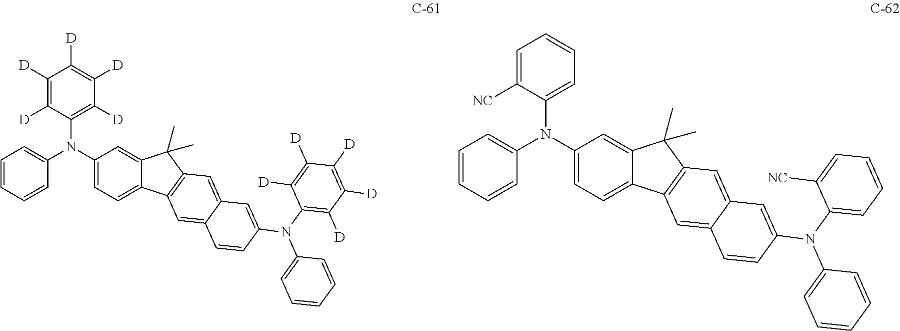 [SMILES: [2H]c1c([2H])c([2H])c(N(c2ccccc2)c2ccc3c(c2)C(C)(C)c2cc4cc(N(c5ccccc5)c5c([2H])c([2H])c([2H])c([2H])c5[2H])ccc4cc2-3)c([2H])c1[2H] ; CC1(C)c2cc(N(c3ccccc3)c3ccccc3C#N)ccc2-c2cc3ccc(N(c4ccccc4)c4ccccc4C#N)cc3cc21]

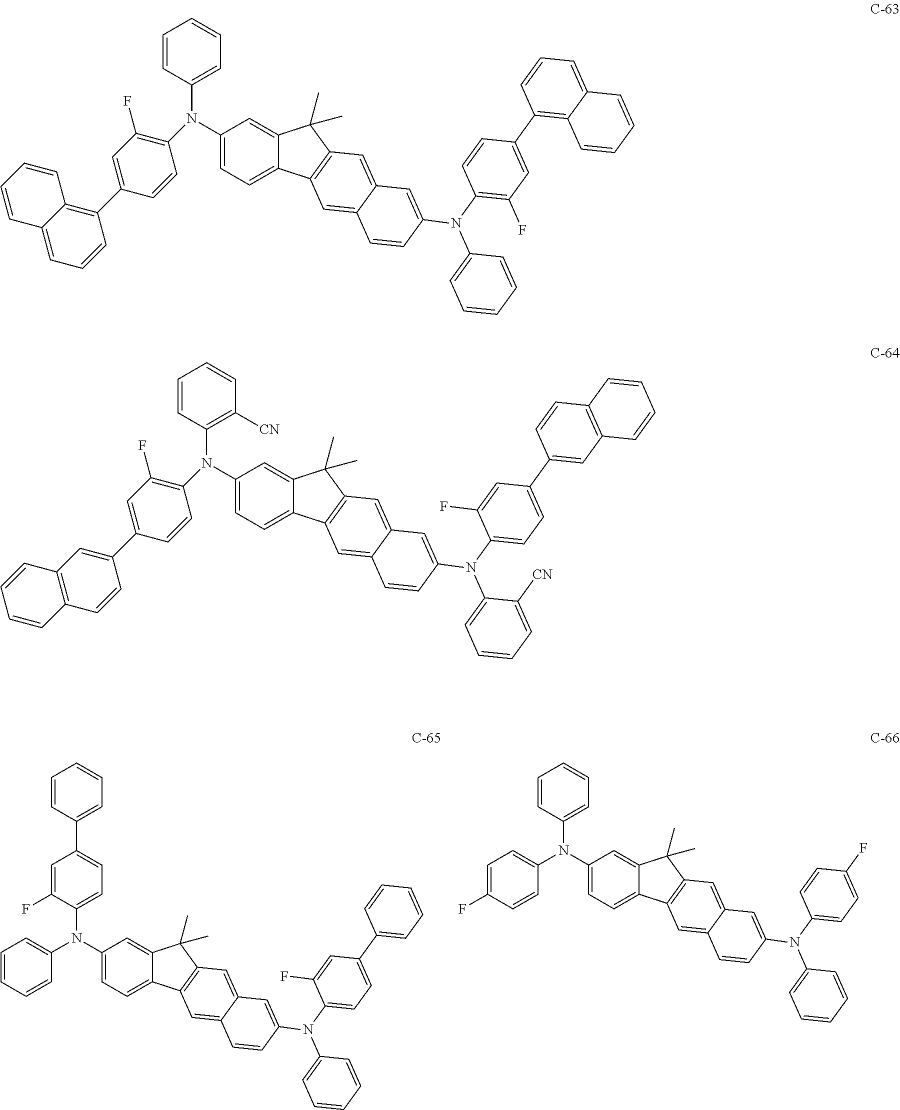

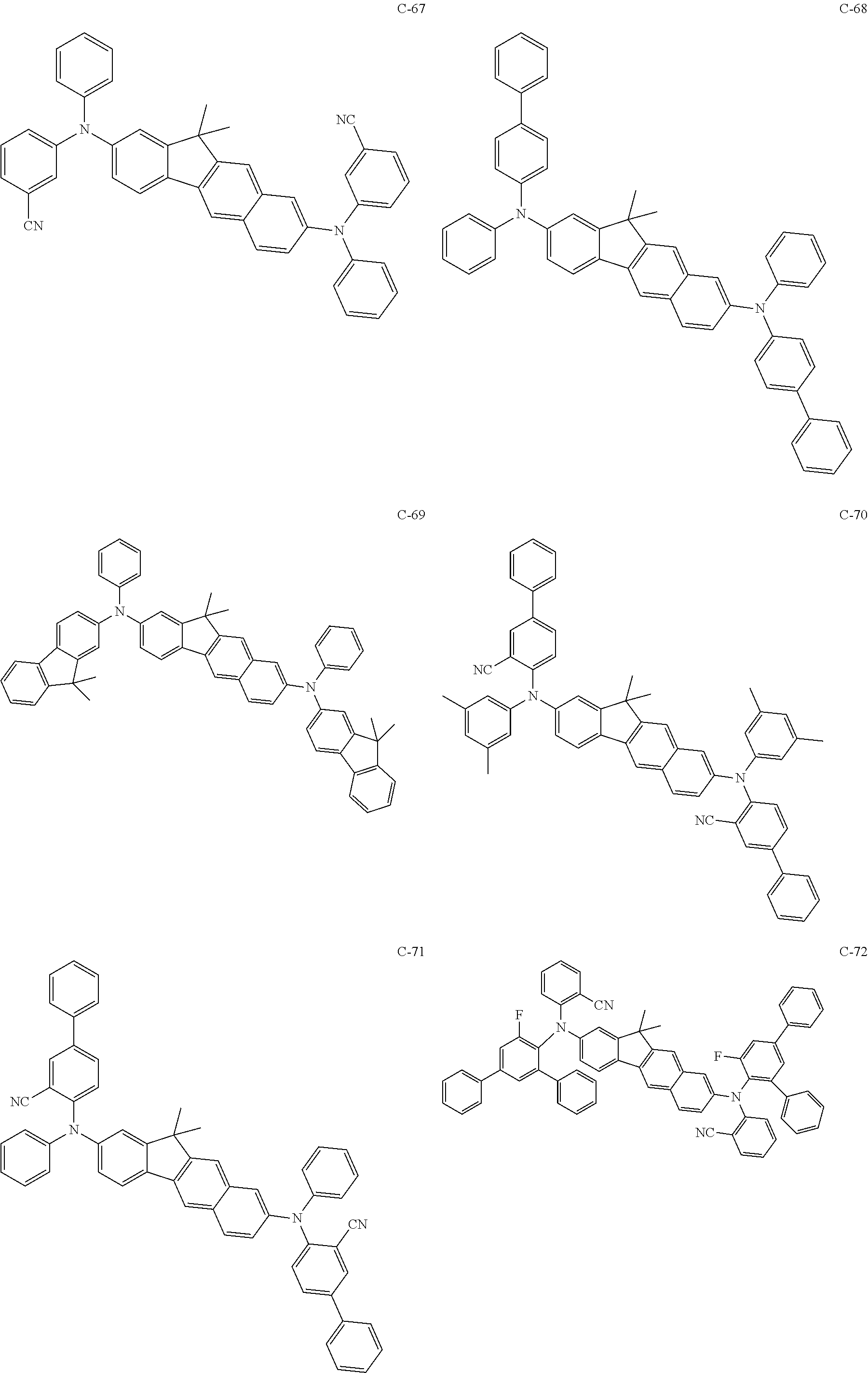

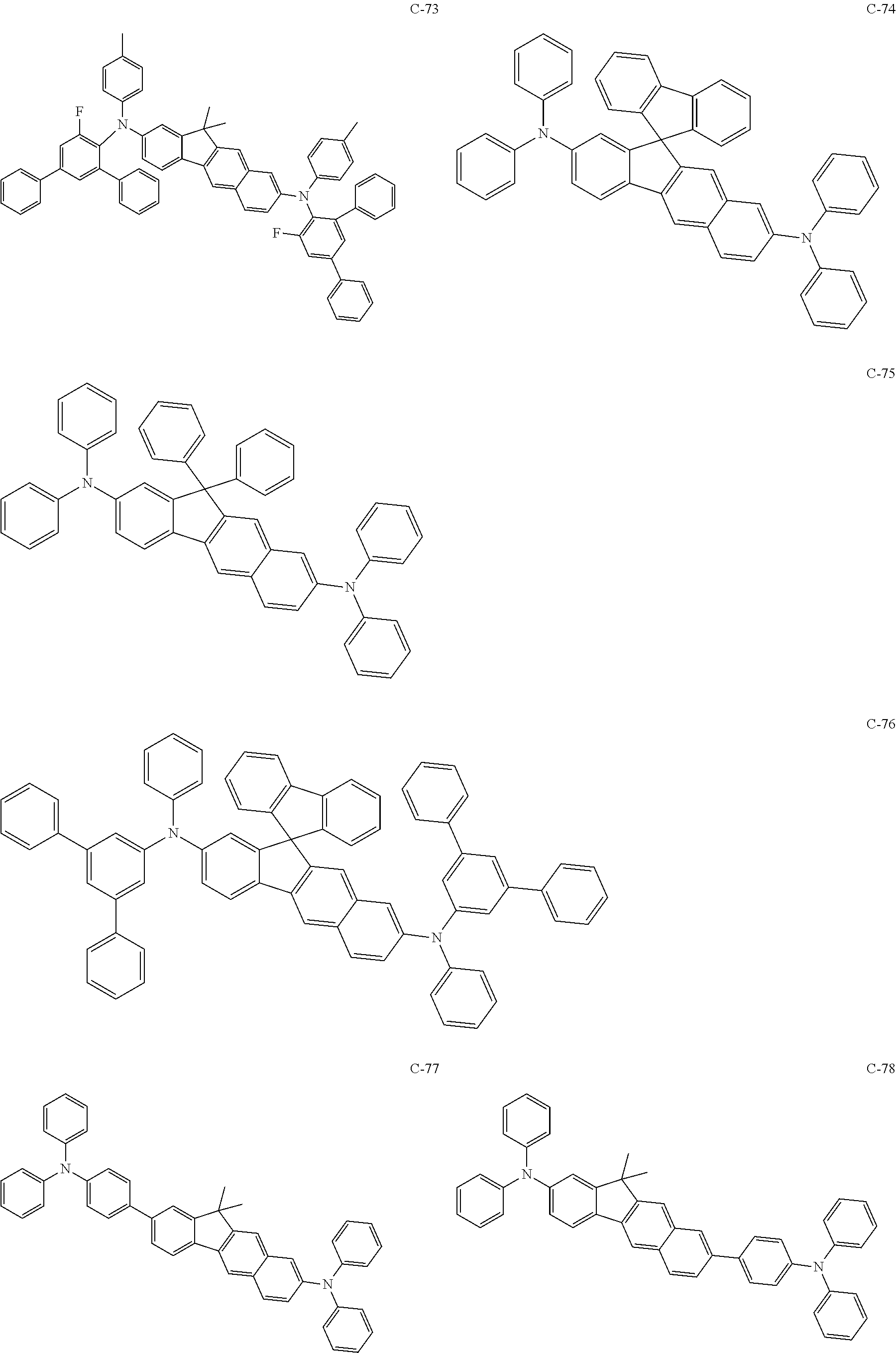

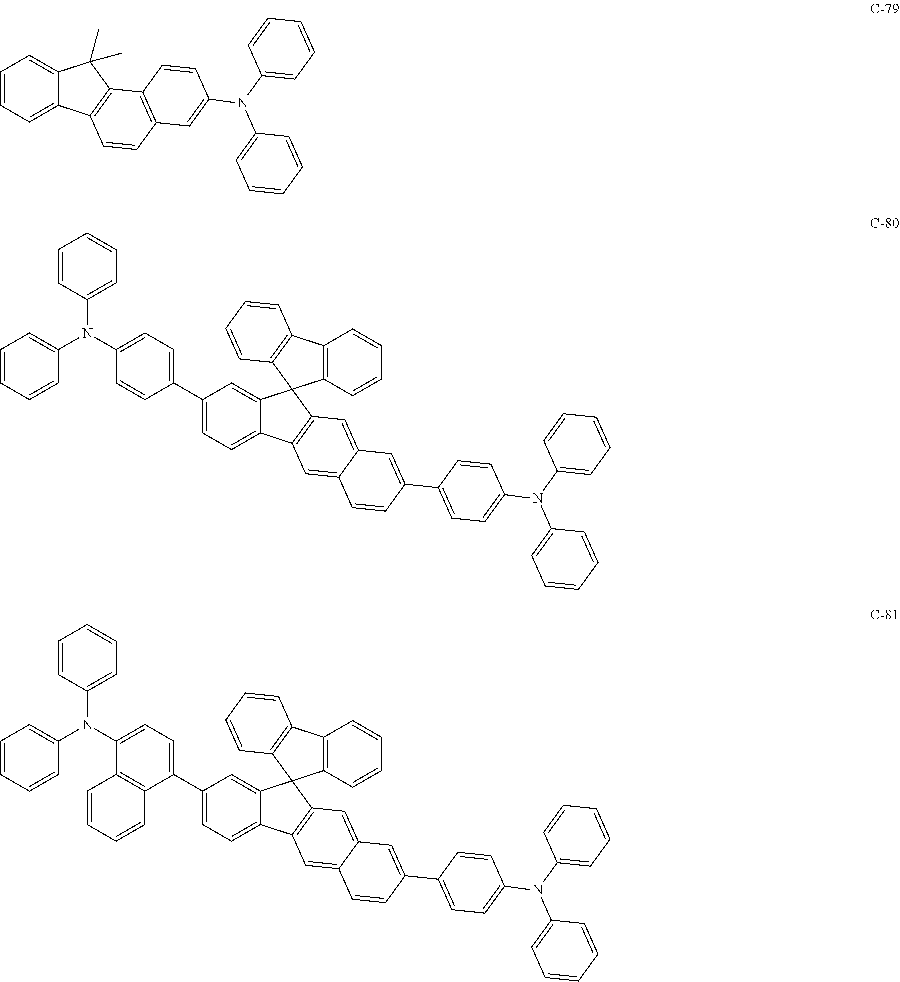 [SMILES: CC1(C)c2ccccc2-c2ccc3cc(N(c4ccccc4)c4ccccc4)ccc3c21 ; c1ccc(N(c2ccccc2)c2ccc(-c3ccc4c(c3)C3(c5ccccc5-c5ccccc53)c3cc5cc(-c6ccc(N(c7ccccc7)c7ccccc7)cc6)ccc5cc3-4)cc2)cc1 ; c1ccc(N(c2ccccc2)c2ccc(-c3ccc4cc5c(cc4c3)C3(c4ccccc4-c4ccccc43)c3cc(-c4ccc(N(c6ccccc6)c6ccccc6)c6ccccc46)ccc3-5)cc2)cc1]

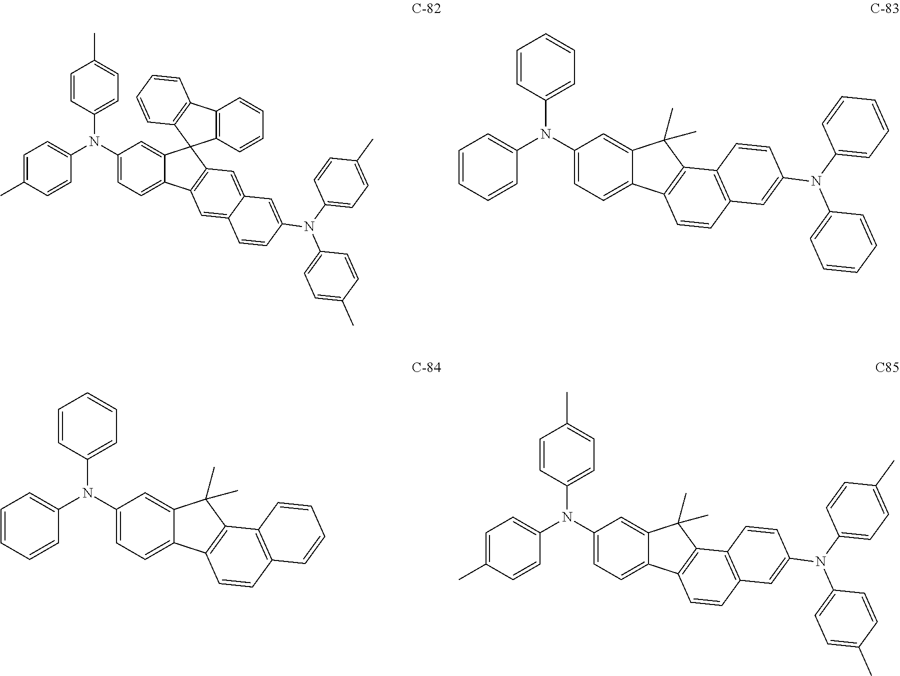

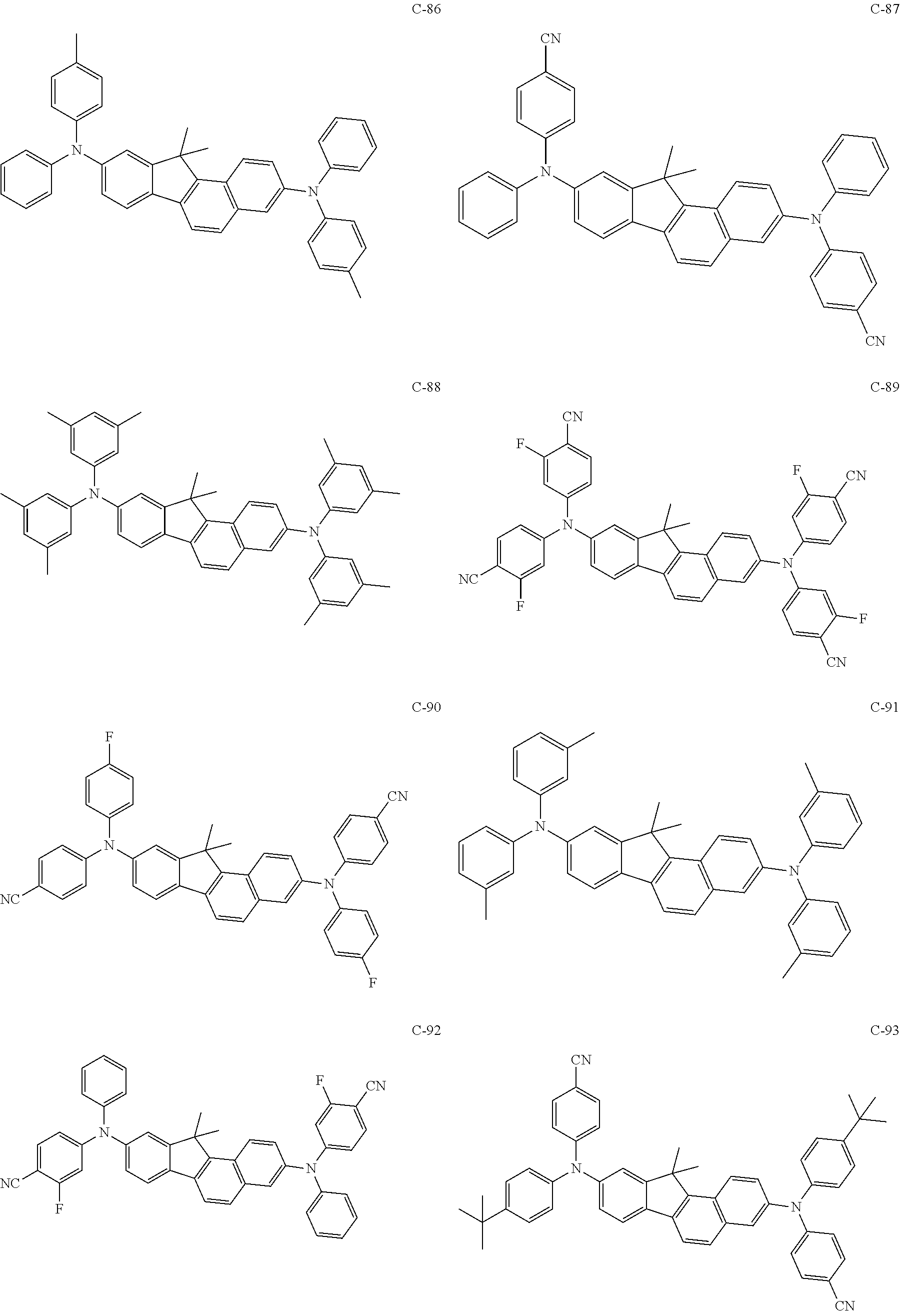

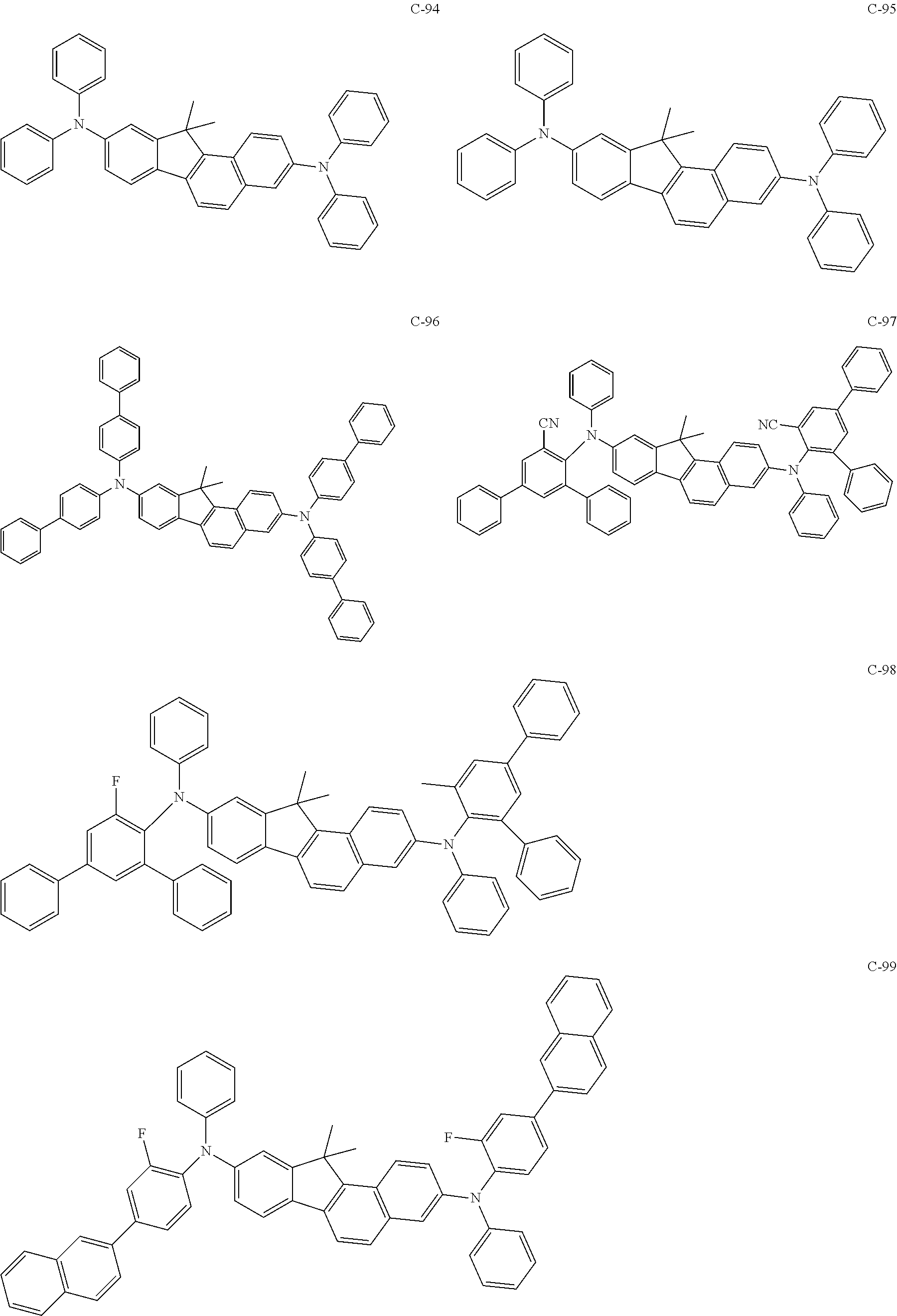

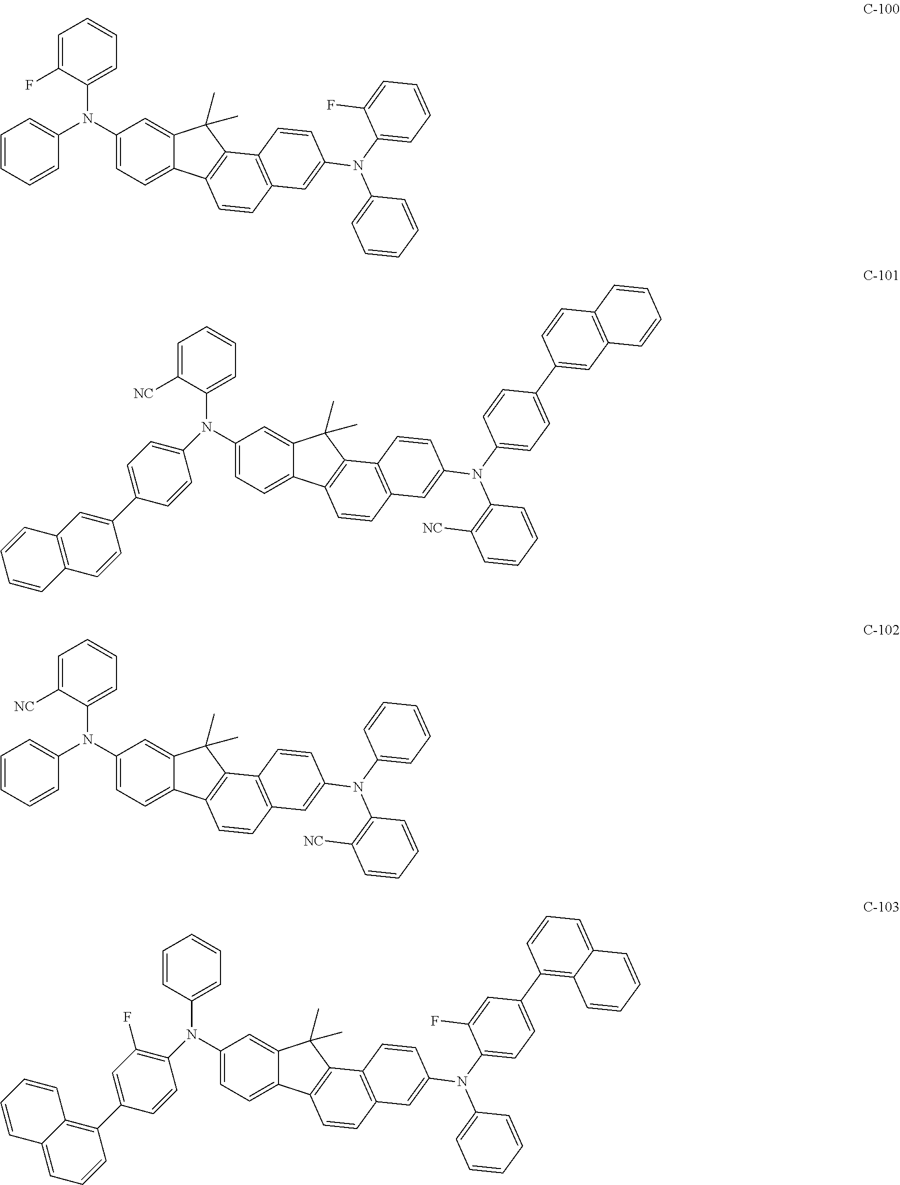 [SMILES: CC1(C)c2cc(N(c3ccccc3)c3ccccc3F)ccc2-c2ccc3cc(N(c4ccccc4)c4ccccc4F)ccc3c21 ; CC1(C)c2cc(N(c3ccc(-c4ccc5ccccc5c4)cc3)c3ccccc3C#N)ccc2-c2ccc3cc(N(c4ccc(-c5ccc6ccccc6c5)cc4)c4ccccc4C#N)ccc3c21 ; CC1(C)c2cc(N(c3ccccc3)c3ccccc3C#N)ccc2-c2ccc3cc(N(c4ccccc4)c4ccccc4C#N)ccc3c21 ; CC1(C)c2cc(N(c3ccccc3)c3ccc(-c4cccc5ccccc45)cc3F)ccc2-c2ccc3cc(N(c4ccccc4)c4ccc(-c5cccc6ccccc56)cc4F)ccc3c21]

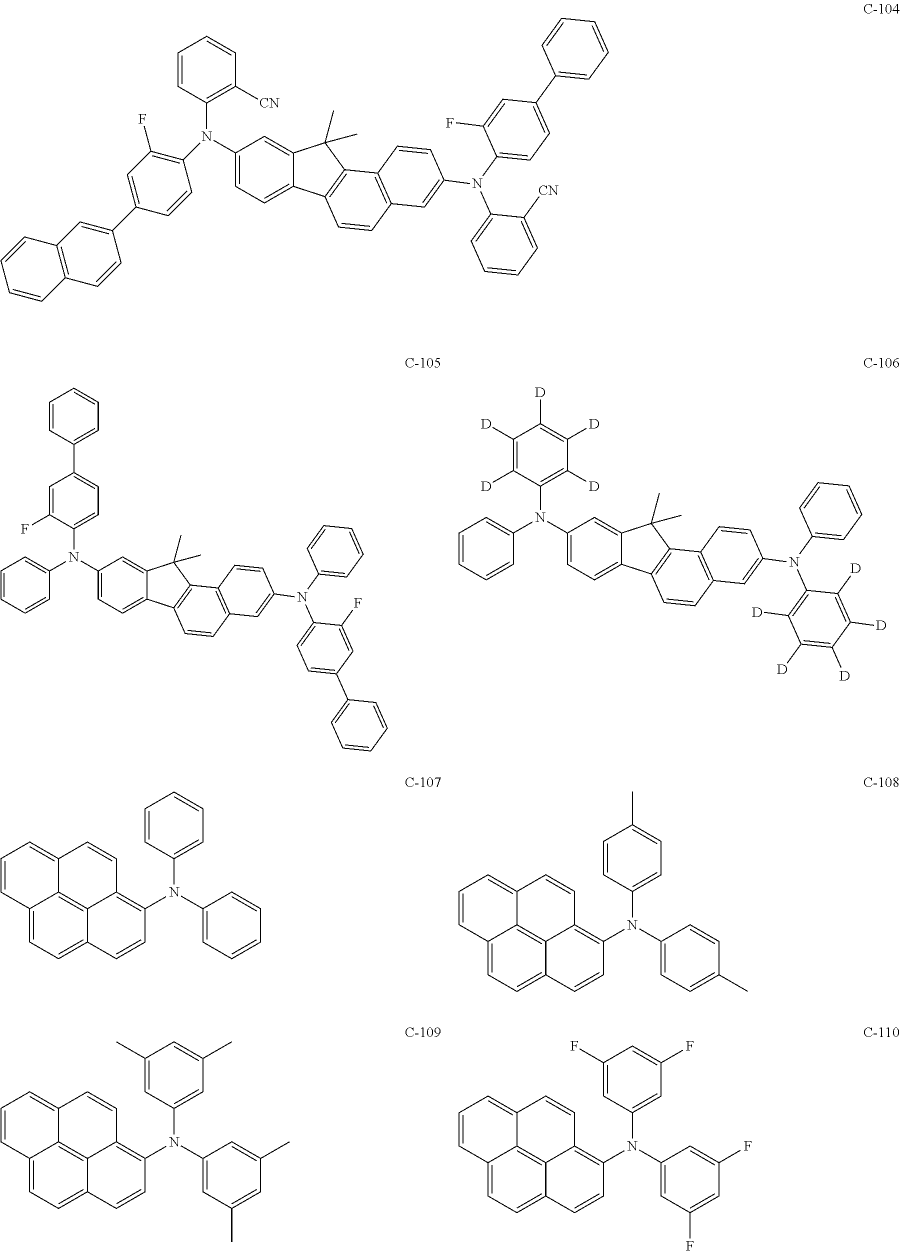

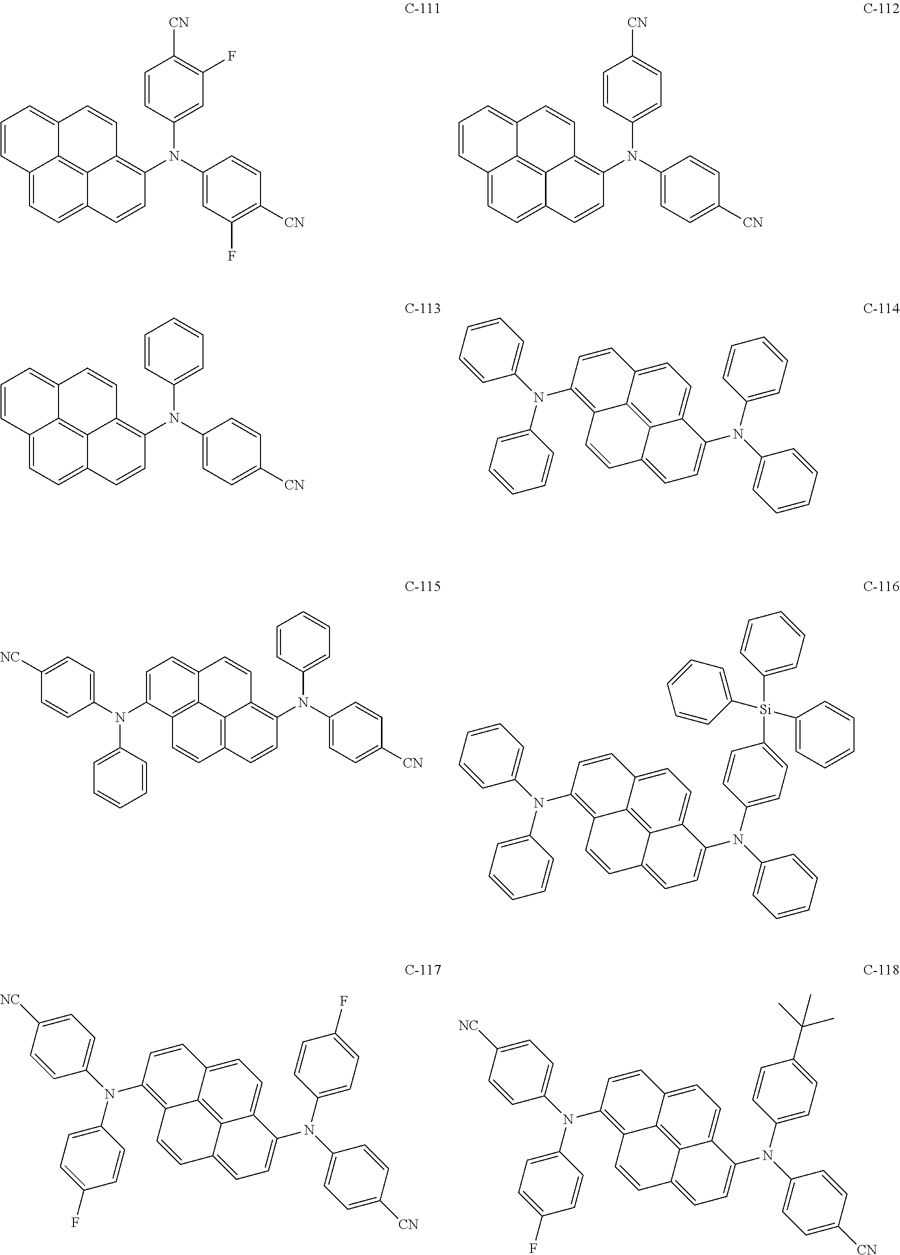

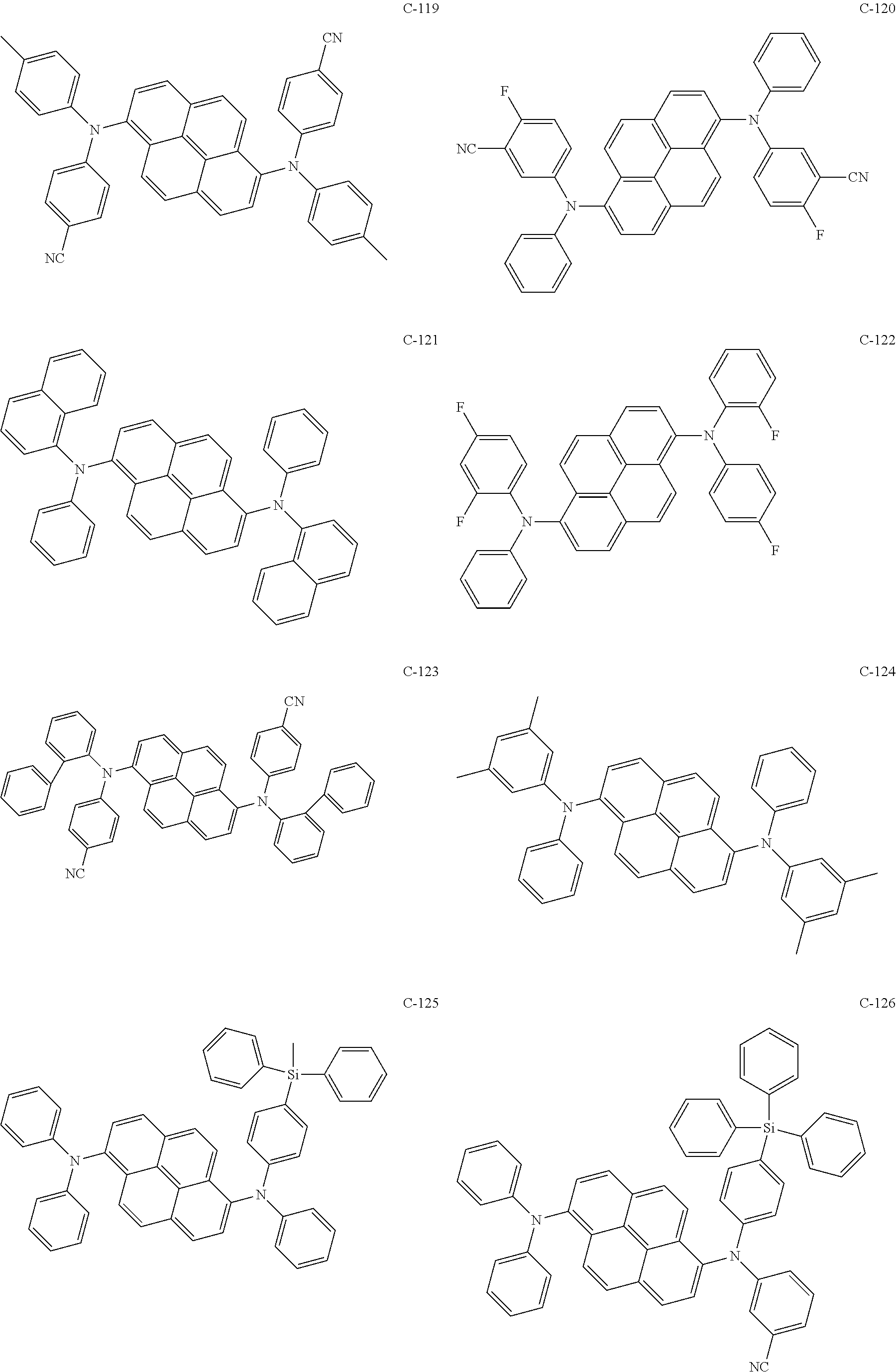

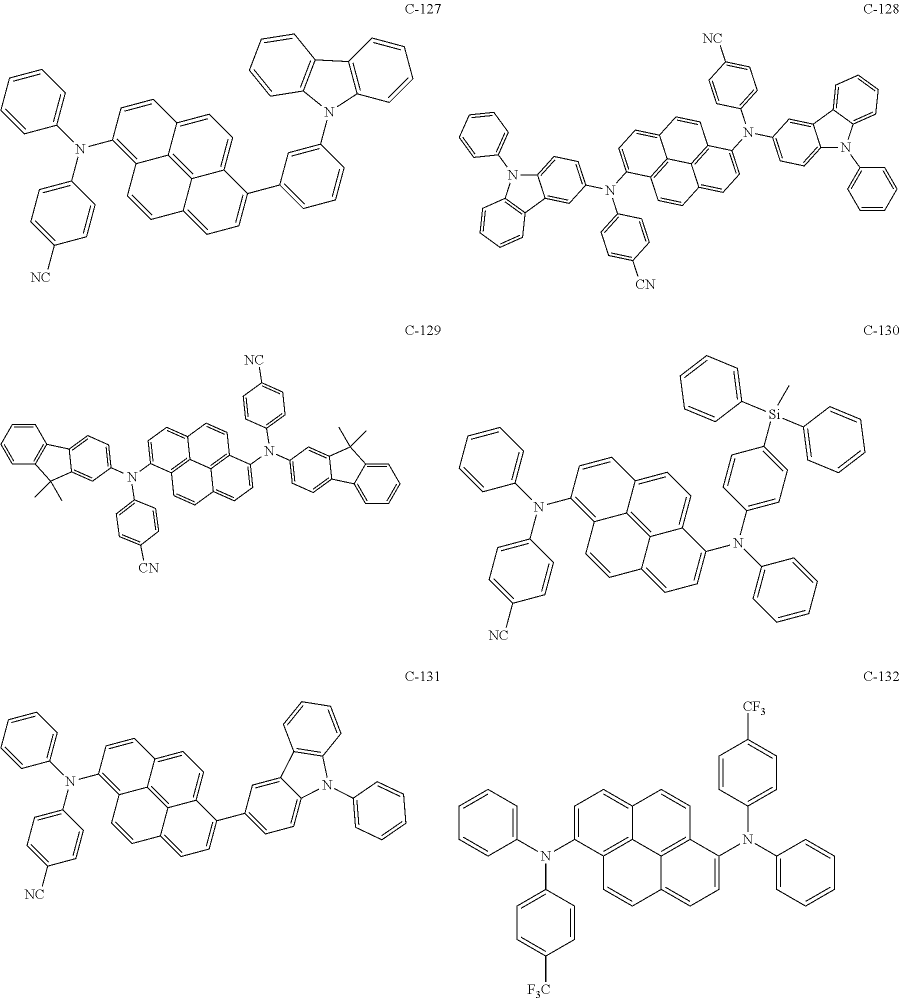

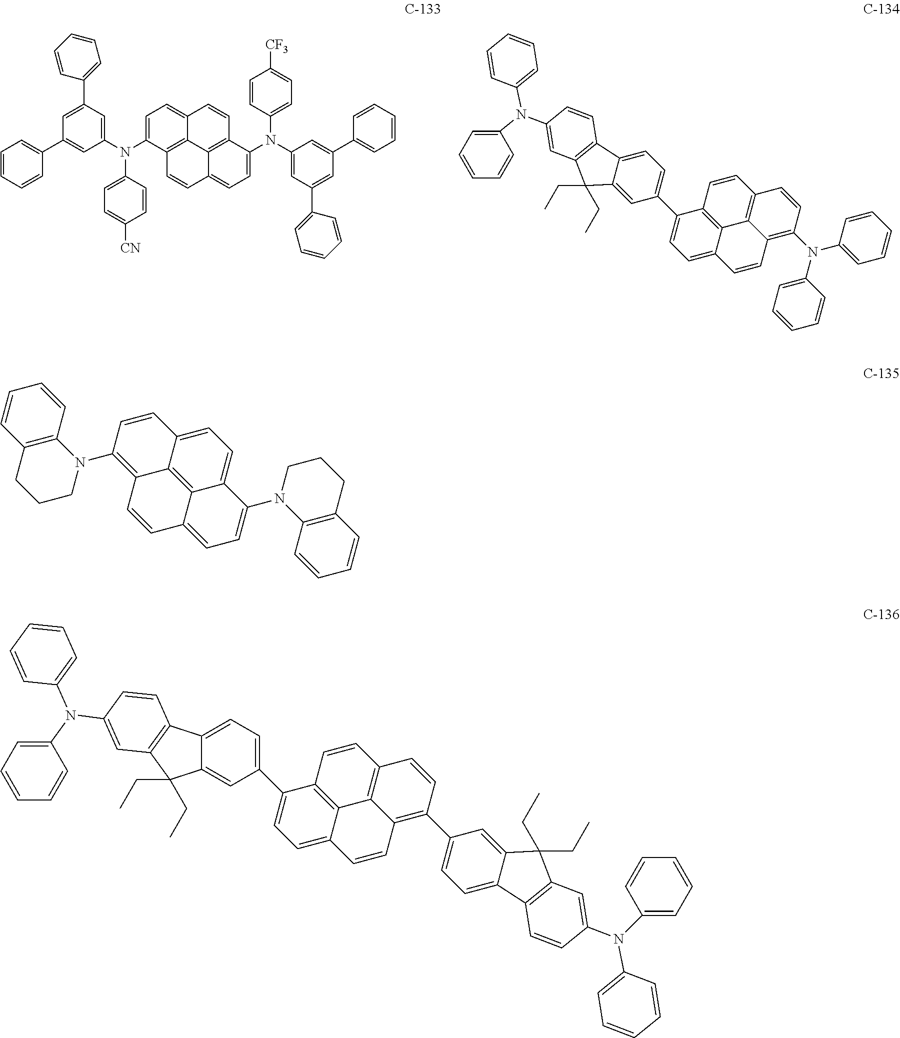 [SMILES: N#Cc1ccc(N(c2cc(-c3ccccc3)cc(-c3ccccc3)c2)c2ccc3ccc4c(N(c5ccc(C(F)(F)F)cc5)c5cc(-c6ccccc6)cc(-c6ccccc6)c5)ccc5ccc2c3c54)cc1 ; CCC1(CC)c2cc(-c3ccc4ccc5c(N(c6ccccc6)c6ccccc6)ccc6ccc3c4c65)ccc2-c2ccc(N(c3ccccc3)c3ccccc3)cc21 ; c1ccc2c(c1)CCCN2c1ccc2ccc3c(N4CCCc5ccccc54)ccc4ccc1c2c43 ; CCC1(CC)c2cc(-c3ccc4ccc5c(-c6ccc7c(c6)C(CC)(CC)c6cc(N(c8ccccc8)c8ccccc8)ccc6-7)ccc6ccc3c4c65)ccc2-c2ccc(N(c3ccccc3)c3ccccc3)cc21]

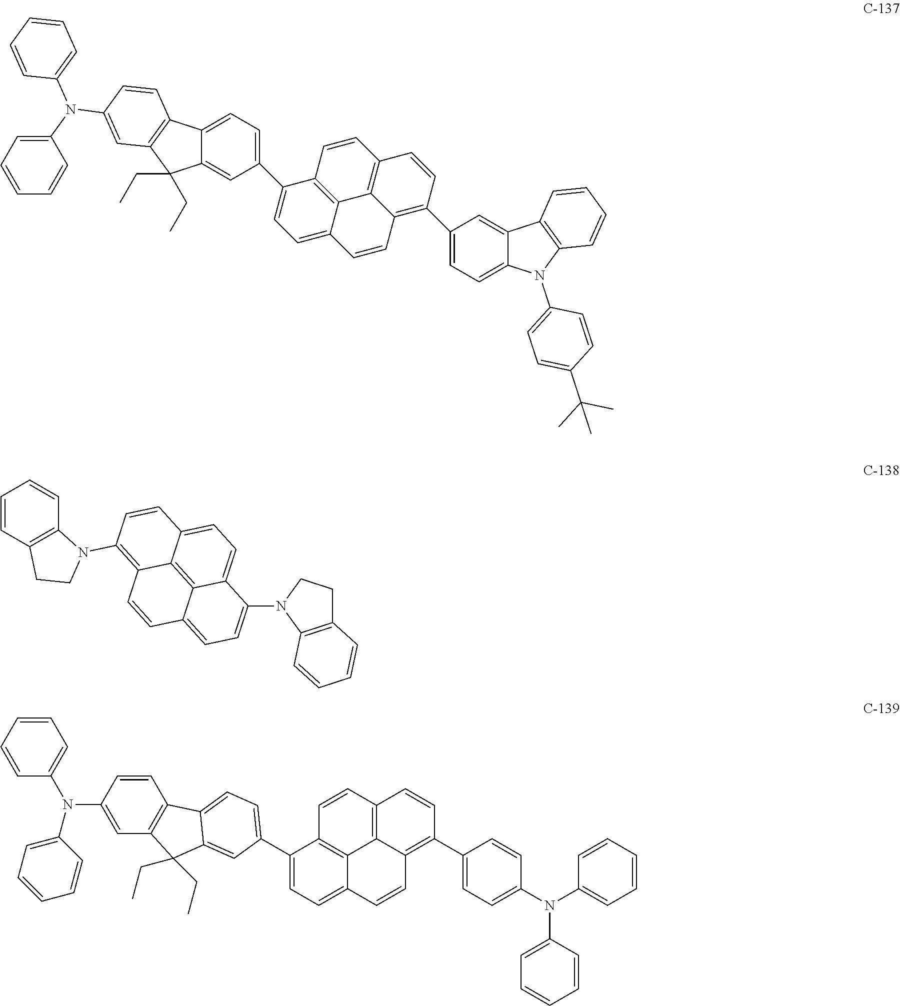 [SMILES: CCC1(CC)c2cc(-c3ccc4ccc5c(-c6ccc7c(c6)c6ccccc6n7-c6ccc(C(C)(C)C)cc6)ccc6ccc3c4c65)ccc2-c2ccc(N(c3ccccc3)c3ccccc3)cc21 ; c1ccc2c(c1)CCN2c1ccc2ccc3c(N4CCc5ccccc54)ccc4ccc1c2c43 ; CCC1(CC)c2cc(-c3ccc4ccc5c(-c6ccc(N(c7ccccc7)c7ccccc7)cc6)ccc6ccc3c4c65)ccc2-c2ccc(N(c3ccccc3)c3ccccc3)cc21]

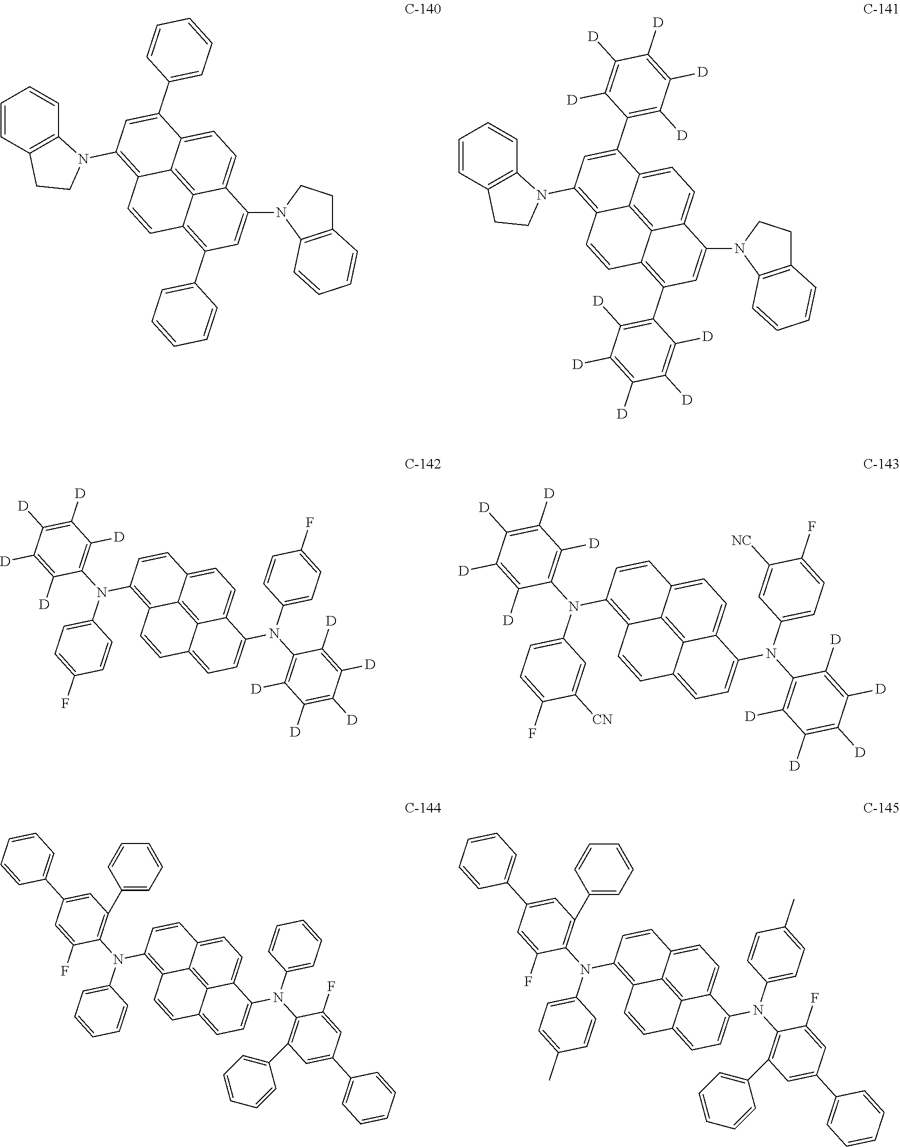

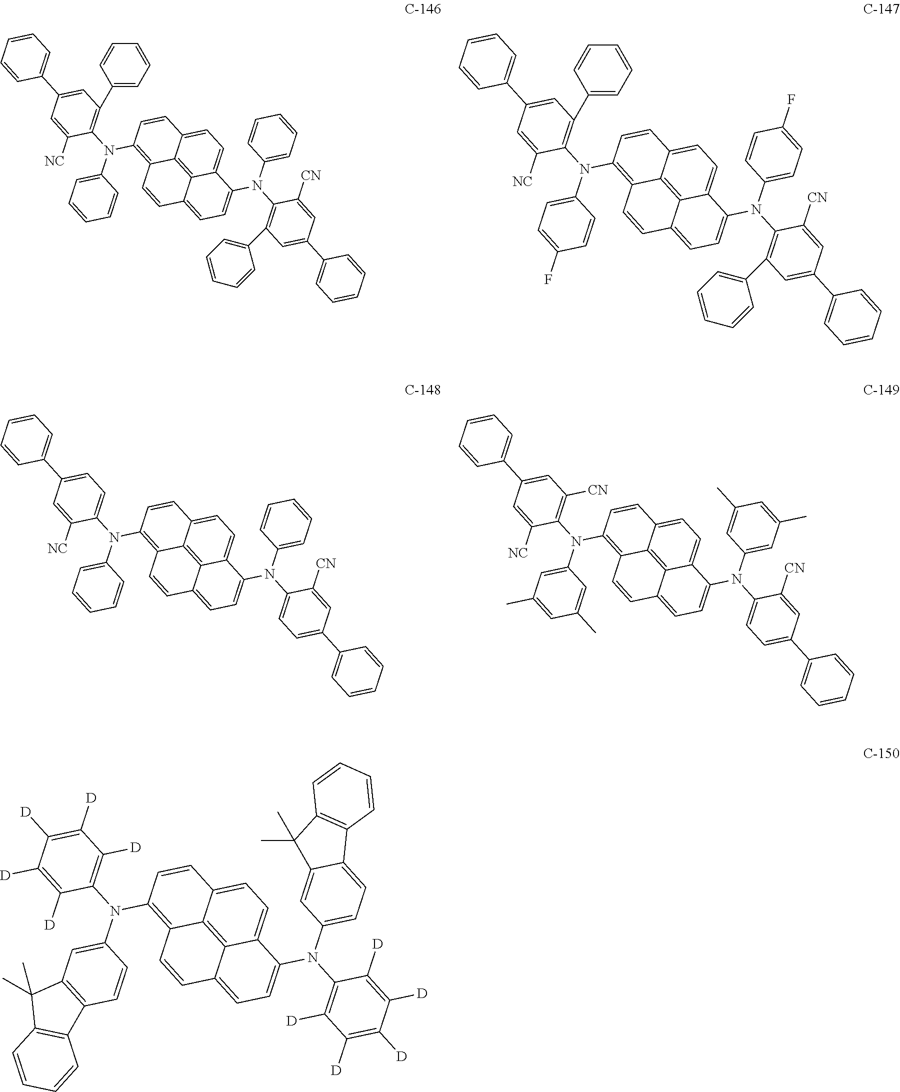

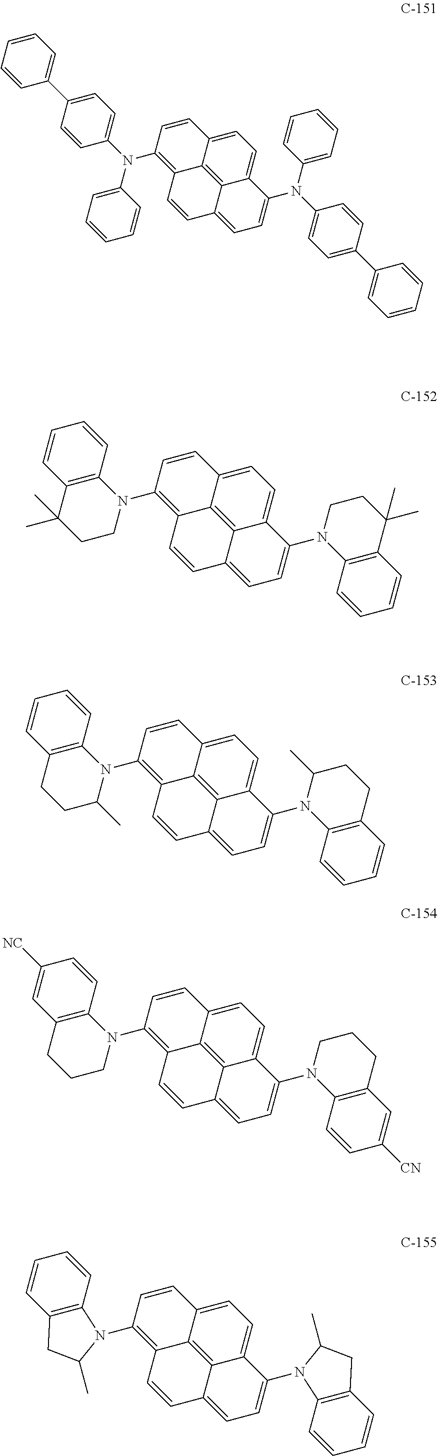

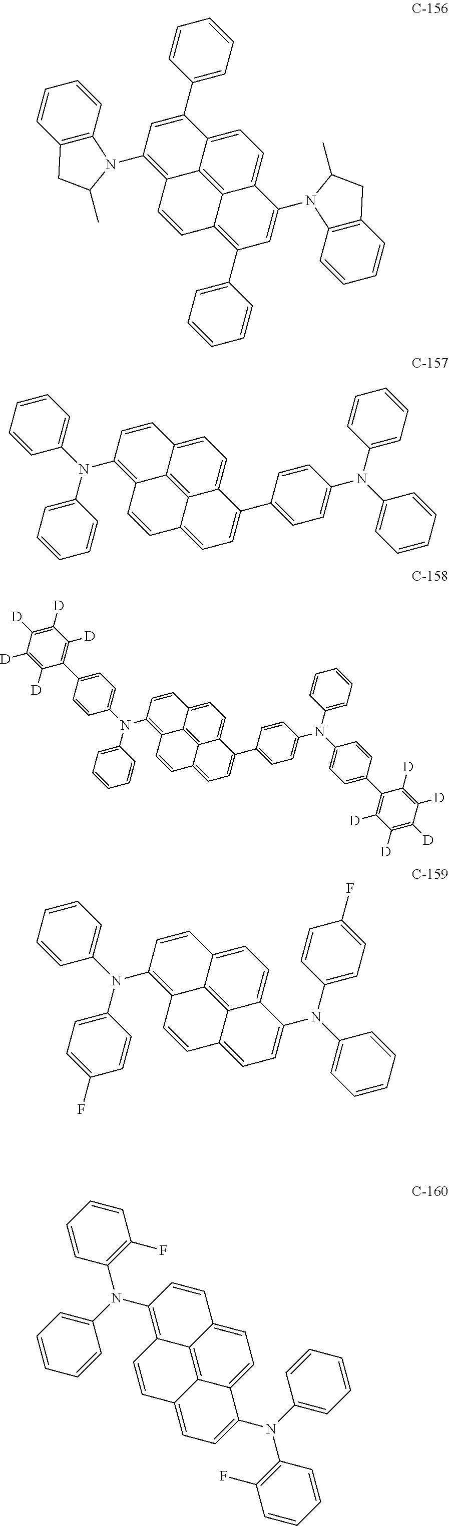

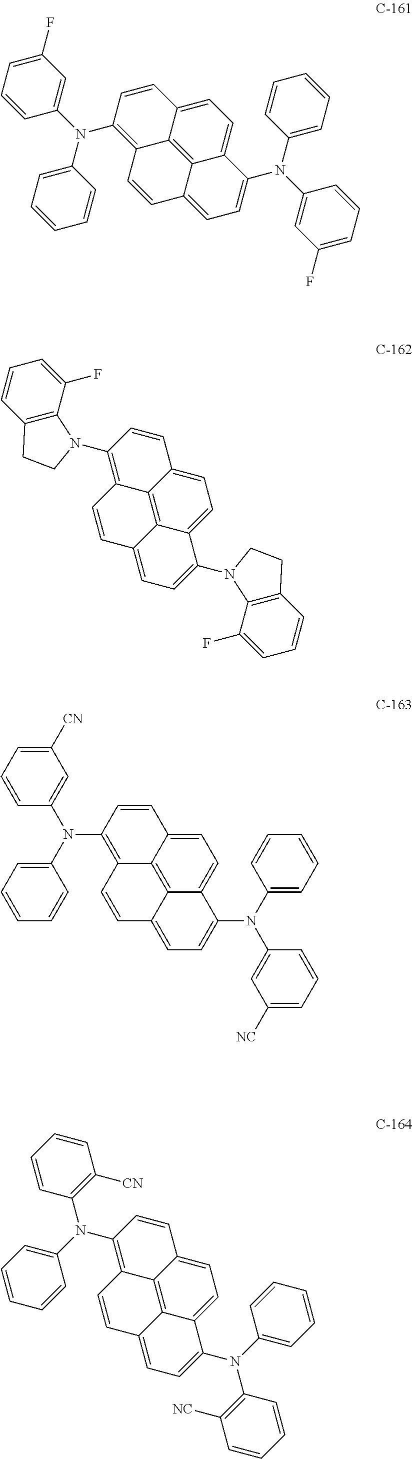 [SMILES: Fc1cccc(N(c2ccccc2)c2ccc3ccc4c(N(c5ccccc5)c5cccc(F)c5)ccc5ccc2c3c54)c1 ; Fc1cccc2c1N(c1ccc3ccc4c(N5CCc6cccc(F)c65)ccc5ccc1c3c54)CC2 ; N#Cc1cccc(N(c2ccccc2)c2ccc3ccc4c(N(c5ccccc5)c5cccc(C#N)c5)ccc5ccc2c3c54)c1 ; N#Cc1ccccc1N(c1ccccc1)c1ccc2ccc3c(N(c4ccccc4)c4ccccc4C#N)ccc4ccc1c2c43]

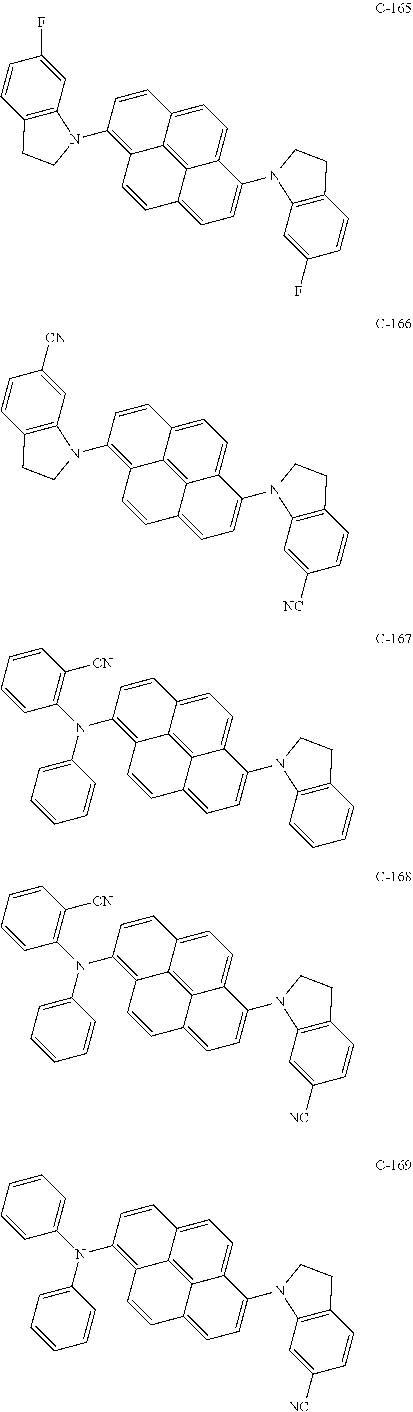 [SMILES: Fc1ccc2c(c1)N(c1ccc3ccc4c(N5CCc6ccc(F)cc65)ccc5ccc1c3c54)CC2 ; N#Cc1ccc2c(c1)N(c1ccc3ccc4c(N5CCc6ccc(C#N)cc65)ccc5ccc1c3c54)CC2 ; N#Cc1ccccc1N(c1ccccc1)c1ccc2ccc3c(N4CCc5ccccc54)ccc4ccc1c2c43 ; N#Cc1ccc2c(c1)N(c1ccc3ccc4c(N(c5ccccc5)c5ccccc5C#N)ccc5ccc1c3c54)CC2 ; N#Cc1ccc2c(c1)N(c1ccc3ccc4c(N(c5ccccc5)c5ccccc5)ccc5ccc1c3c54)CC2]

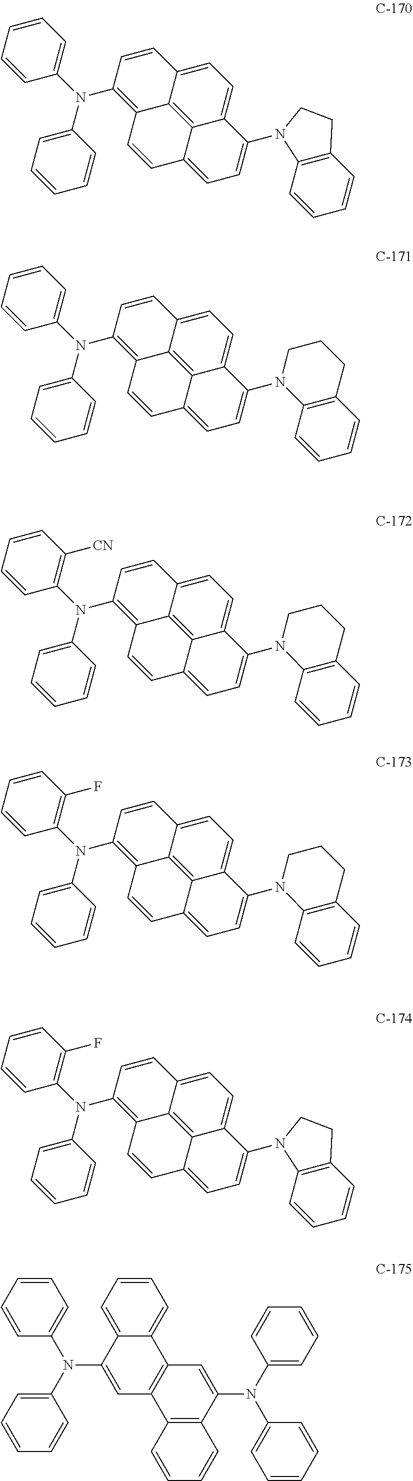 [SMILES: c1ccc(N(c2ccccc2)c2ccc3ccc4c(N5CCc6ccccc65)ccc5ccc2c3c54)cc1 ; c1ccc(N(c2ccccc2)c2ccc3ccc4c(N5CCCc6ccccc65)ccc5ccc2c3c54)cc1 ; N#Cc1ccccc1N(c1ccccc1)c1ccc2ccc3c(N4CCCc5ccccc54)ccc4ccc1c2c43 ; Fc1ccccc1N(c1ccccc1)c1ccc2ccc3c(N4CCCc5ccccc54)ccc4ccc1c2c43 ; Fc1ccccc1N(c1ccccc1)c1ccc2ccc3c(N4CCc5ccccc54)ccc4ccc1c2c43 ; c1ccc(N(c2ccccc2)c2cc3c4ccccc4c(N(c4ccccc4)c4ccccc4)cc3c3ccccc23)cc1]

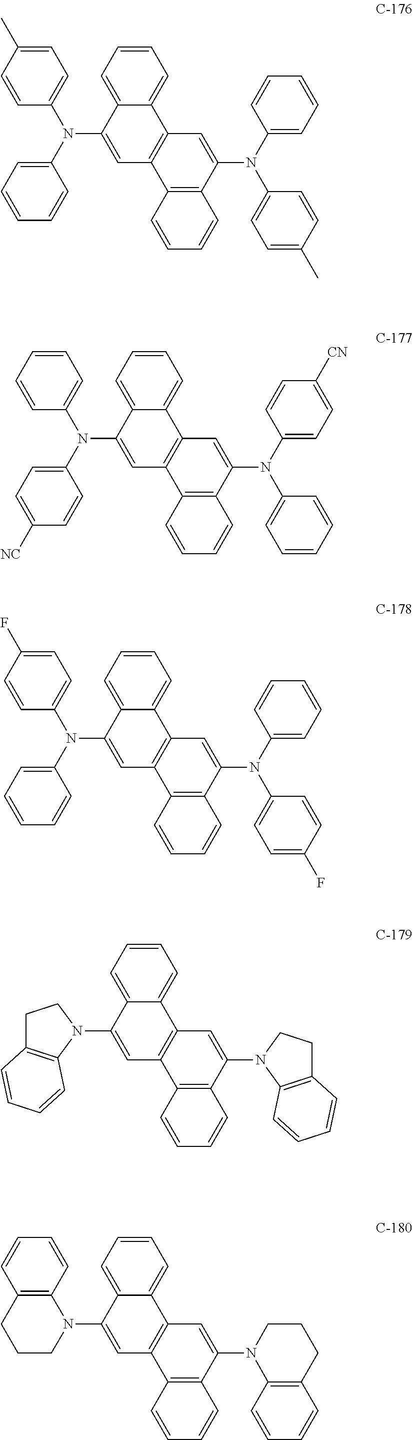

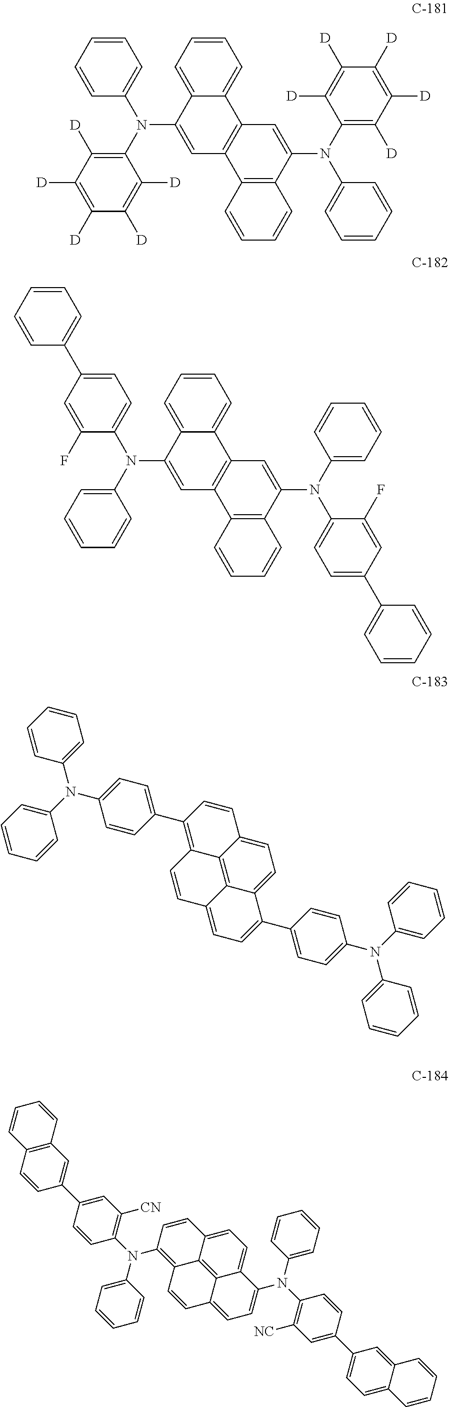 [SMILES: [2H]c1c([2H])c([2H])c(N(c2ccccc2)c2cc3c4ccccc4c(N(c4ccccc4)c4c([2H])c([2H])c([2H])c([2H])c4[2H])cc3c3ccccc23)c([2H])c1[2H] ; Fc1cc(-c2ccccc2)ccc1N(c1ccccc1)c1cc2c3ccccc3c(N(c3ccccc3)c3ccc(-c4ccccc4)cc3F)cc2c2ccccc12 ; c1ccc(N(c2ccccc2)c2ccc(-c3ccc4ccc5c(-c6ccc(N(c7ccccc7)c7ccccc7)cc6)ccc6ccc3c4c65)cc2)cc1 ; N#Cc1cc(-c2ccc3ccccc3c2)ccc1N(c1ccccc1)c1ccc2ccc3c(N(c4ccccc4)c4ccc(-c5ccc6ccccc6c5)cc4C#N)ccc4ccc1c2c43]

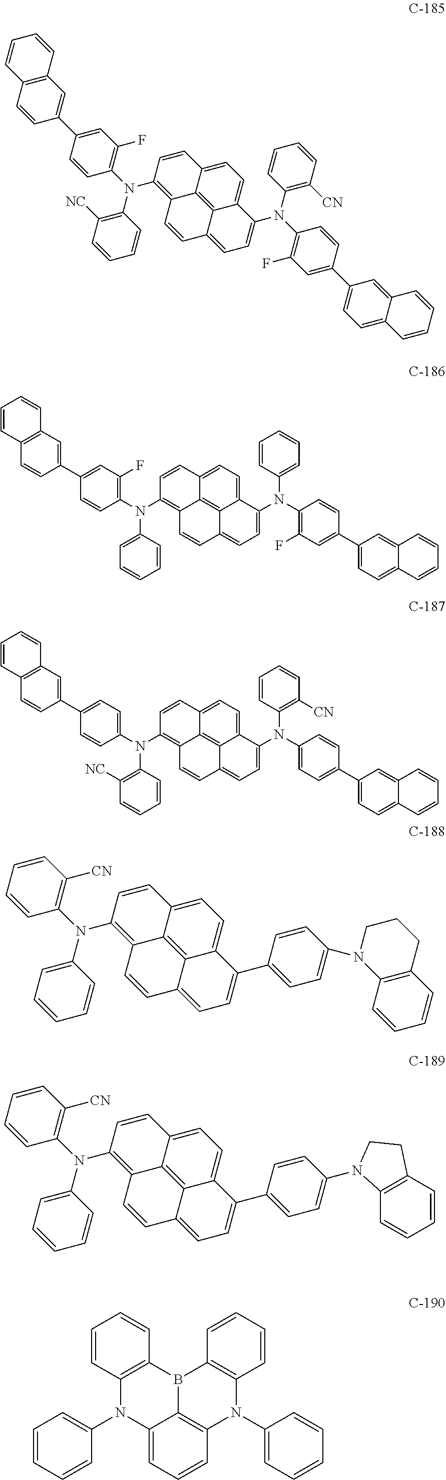

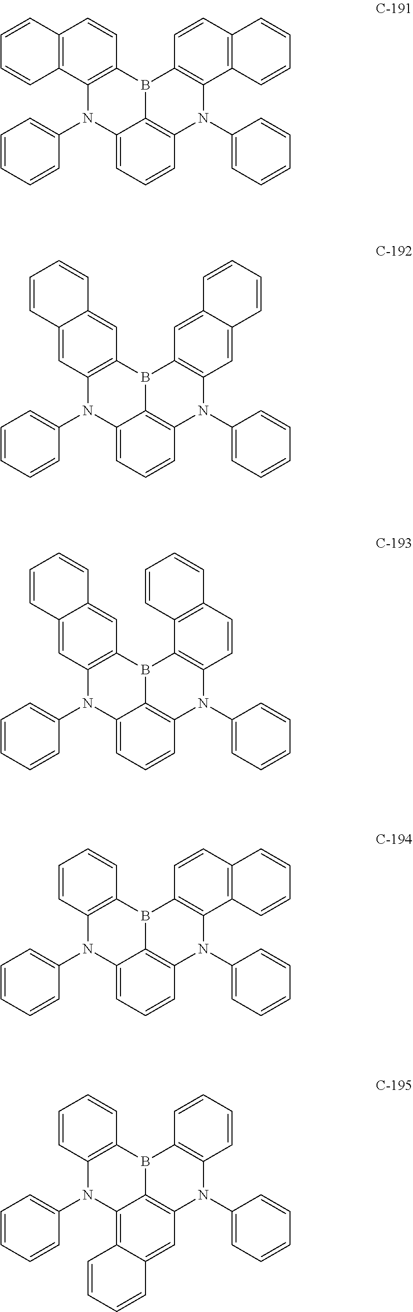 [SMILES: c1ccc(N2c3cccc4c3B(c3ccc5ccccc5c32)c2ccc3ccccc3c2N4c2ccccc2)cc1 ; c1ccc(N2c3cc4ccccc4cc3B3c4cc5ccccc5cc4N(c4ccccc4)c4cccc2c43)cc1 ; c1ccc(N2c3cc4ccccc4cc3B3c4c2cccc4N(c2ccccc2)c2ccc4ccccc4c23)cc1 ; c1ccc(N2c3ccccc3B3c4ccc5ccccc5c4N(c4ccccc4)c4cccc2c43)cc1 ; c1ccc(N2c3ccccc3B3c4ccccc4N(c4ccccc4)c4c3c2cc2ccccc42)cc1]

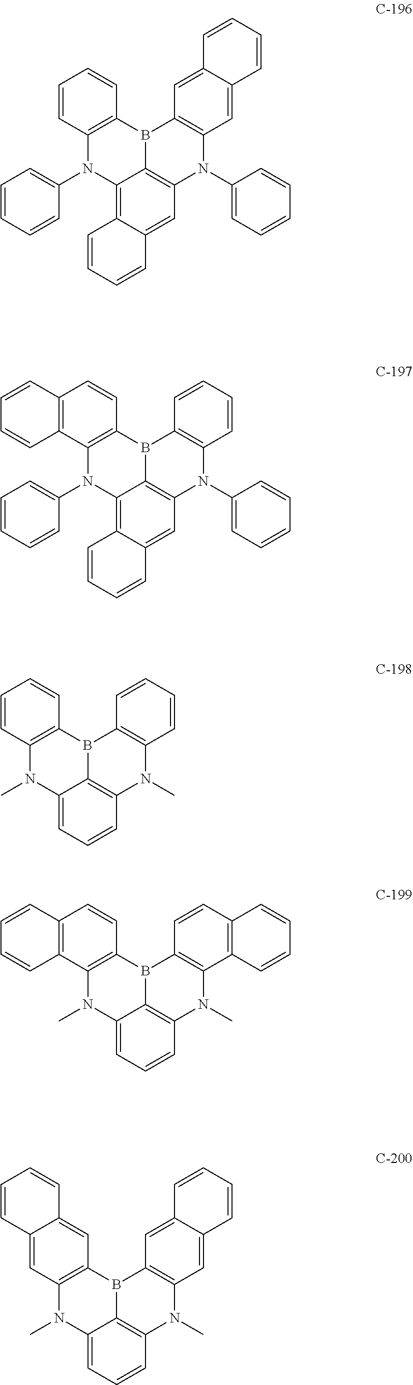 [SMILES: c1ccc(N2c3cc4ccccc4cc3B3c4ccccc4N(c4ccccc4)c4c3c2cc2ccccc42)cc1 ; c1ccc(N2c3ccccc3B3c4ccc5ccccc5c4N(c4ccccc4)c4c3c2cc2ccccc42)cc1 ; CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32]

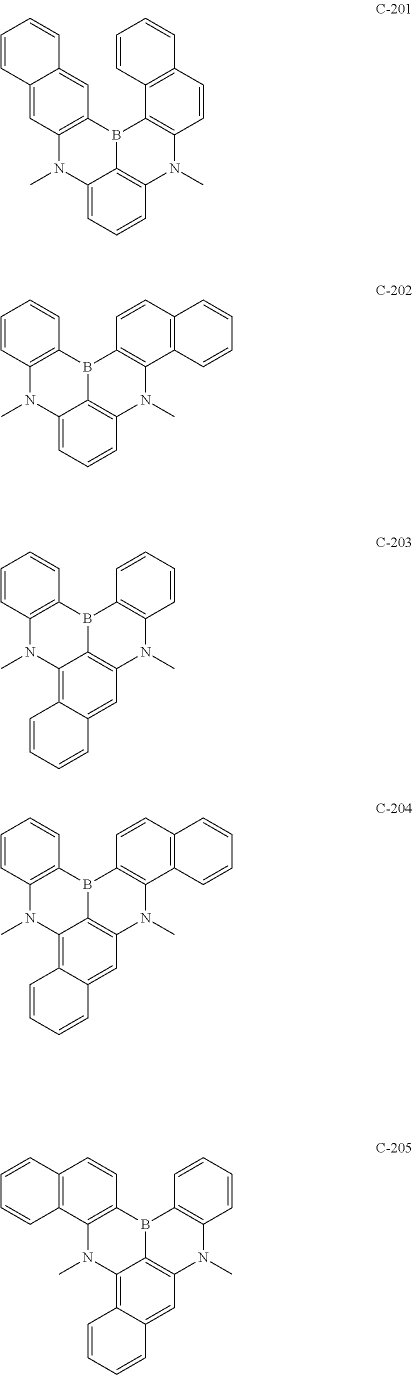 [SMILES: CN1c2cc3ccccc3cc2B2c3c1cccc3N(C)c1ccc3ccccc3c12 ; CN1c2ccccc2B2c3ccc4ccccc4c3N(C)c3cccc1c32 ; CN1c2ccccc2B2c3ccccc3N(C)c3c2c1cc1ccccc31 ; CN1c2cc3ccccc3c3c2B(c2ccccc2N3C)c2ccc3ccccc3c21 ; CN1c2ccccc2B2c3ccc4ccccc4c3N(C)c3c2c1cc1ccccc31]

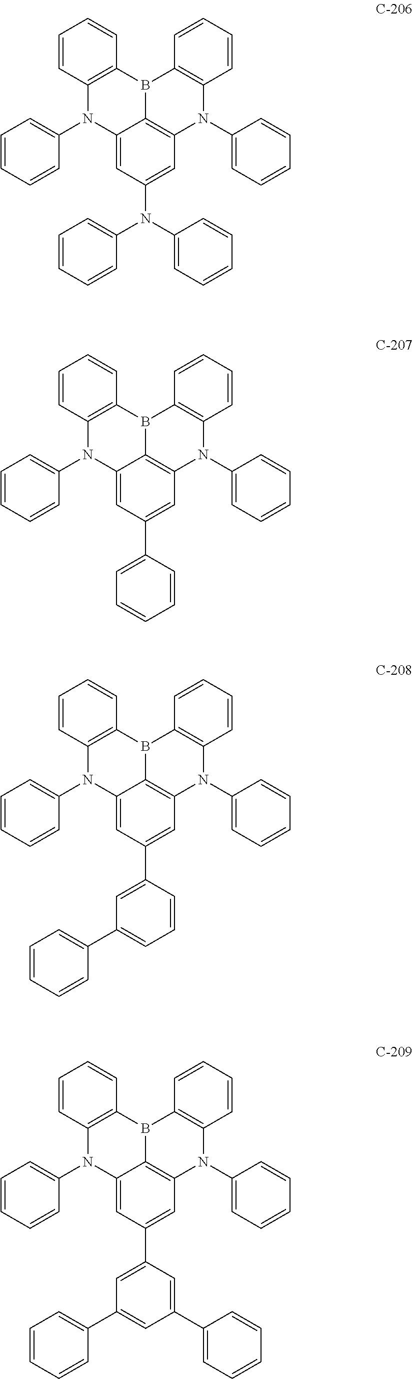 [SMILES: c1ccc(N(c2ccccc2)c2cc3c4c(c2)N(c2ccccc2)c2ccccc2B4c2ccccc2N3c2ccccc2)cc1 ; c1ccc(-c2cc3c4c(c2)N(c2ccccc2)c2ccccc2B4c2ccccc2N3c2ccccc2)cc1 ; c1ccc(-c2cccc(-c3cc4c5c(c3)N(c3ccccc3)c3ccccc3B5c3ccccc3N4c3ccccc3)c2)cc1 ; c1ccc(-c2cc(-c3ccccc3)cc(-c3cc4c5c(c3)N(c3ccccc3)c3ccccc3B5c3ccccc3N4c3ccccc3)c2)cc1]

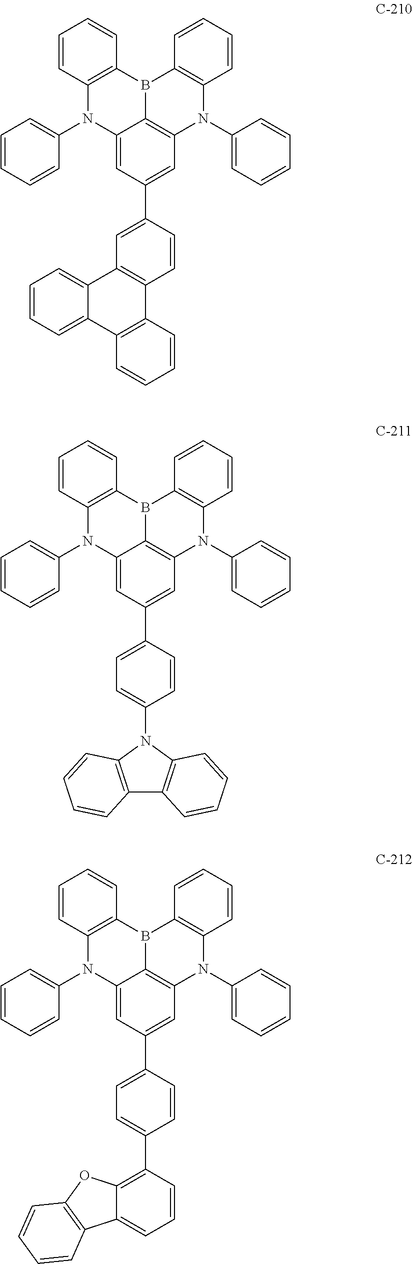 [SMILES: c1ccc(N2c3ccccc3B3c4ccccc4N(c4ccccc4)c4cc(-c5ccc6c7ccccc7c7ccccc7c6c5)cc2c43)cc1 ; c1ccc(N2c3ccccc3B3c4ccccc4N(c4ccccc4)c4cc(-c5ccc(-n6c7ccccc7c7ccccc76)cc5)cc2c43)cc1 ; c1ccc(N2c3ccccc3B3c4ccccc4N(c4ccccc4)c4cc(-c5ccc(-c6cccc7c6oc6ccccc67)cc5)cc2c43)cc1]

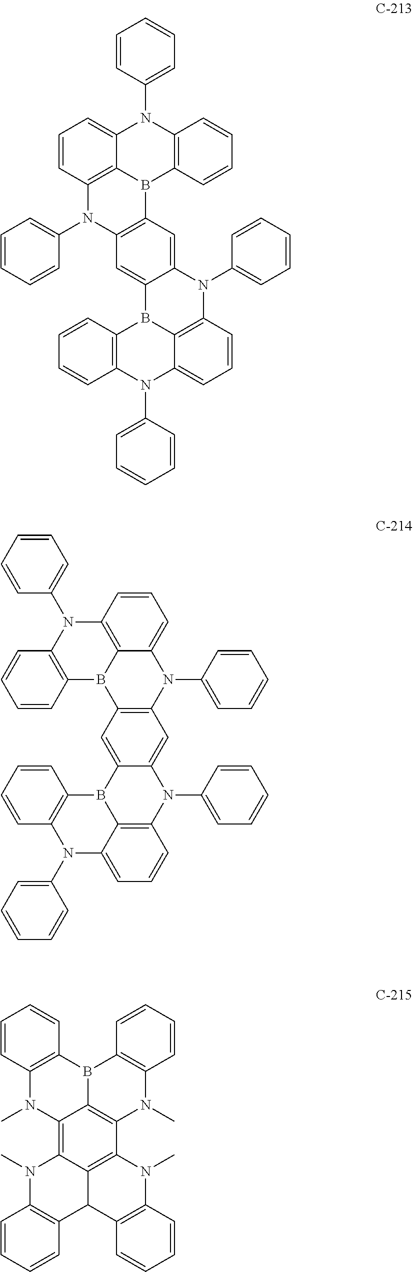 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1 ; CN1c2ccccc2B2c3ccccc3N(C)c3c2c1c1c2c3N(C)c3ccccc3C2c2ccccc2N1C]

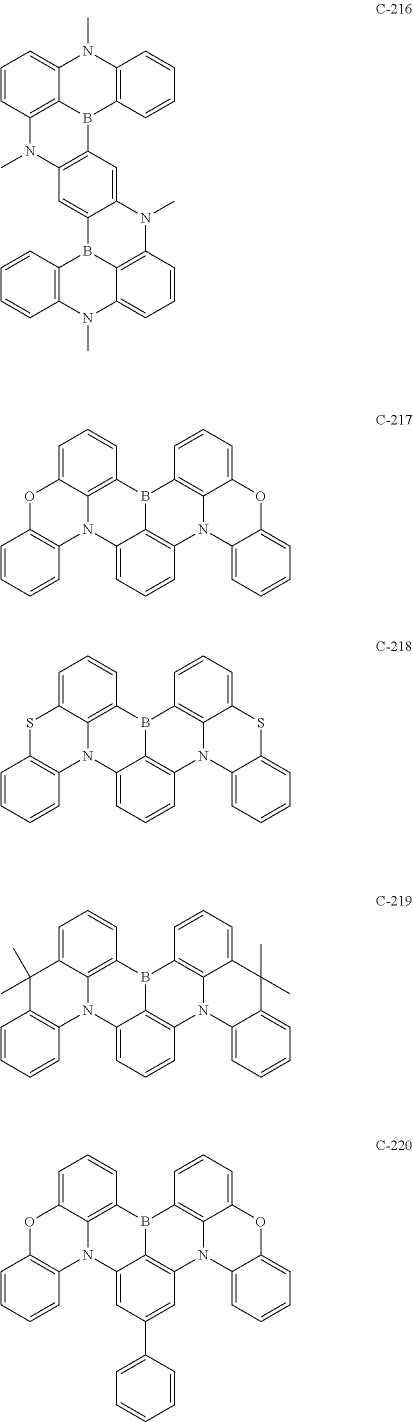 [SMILES: CN1c2ccccc2B2c3cc4c(cc3N(C)c3cccc1c32)B1c2ccccc2N(C)c2cccc(c21)N4C ; c1ccc2c(c1)Oc1cccc3c1N2c1cccc2c1B3c1cccc3c1N2c1ccccc1O3 ; c1ccc2c(c1)Sc1cccc3c1N2c1cccc2c1B3c1cccc3c1N2c1ccccc1S3 ; CC1(C)c2ccccc2N2c3cccc4c3B(c3cccc1c32)c1cccc2c1N4c1ccccc1C2(C)C ; c1ccc(-c2cc3c4c(c2)N2c5ccccc5Oc5cccc(c52)B4c2cccc4c2N3c2ccccc2O4)cc1]

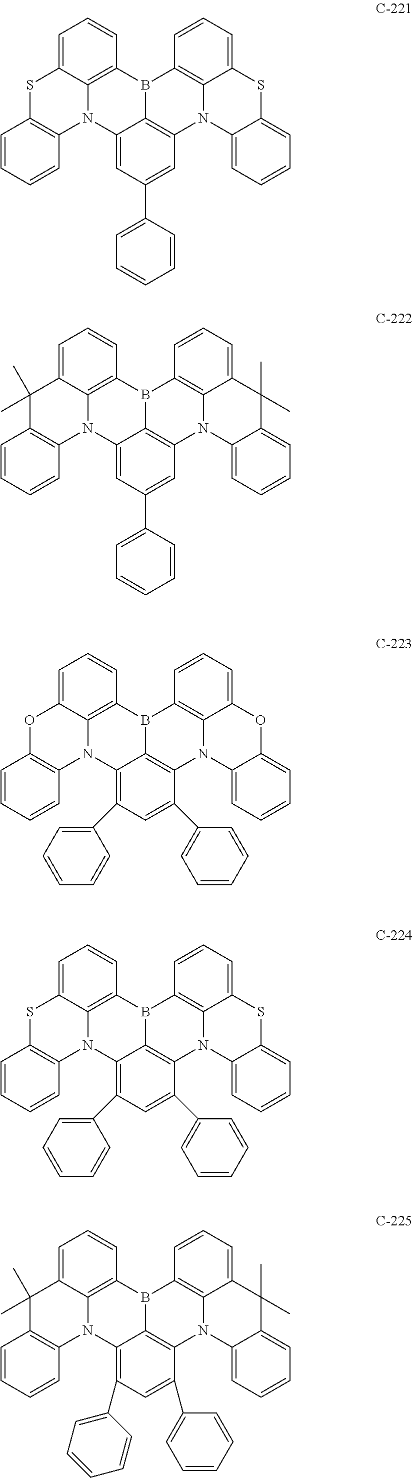 [SMILES: c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccccc4)cc4c3B(c3cccc1c32)c1cccc2c1N4c1ccccc1C2(C)C ; c1ccc(-c2cc(-c3ccccc3)c3c4c2N2c5ccccc5Oc5cccc(c52)B4c2cccc4c2N3c2ccccc2O4)cc1 ; c1ccc(-c2cc(-c3ccccc3)c3c4c2N2c5ccccc5Sc5cccc(c52)B4c2cccc4c2N3c2ccccc2S4)cc1 ; CC1(C)c2ccccc2N2c3c(cccc31)B1c3cccc4c3N(c3ccccc3C4(C)C)c3c(-c4ccccc4)cc(-c4ccccc4)c2c31]

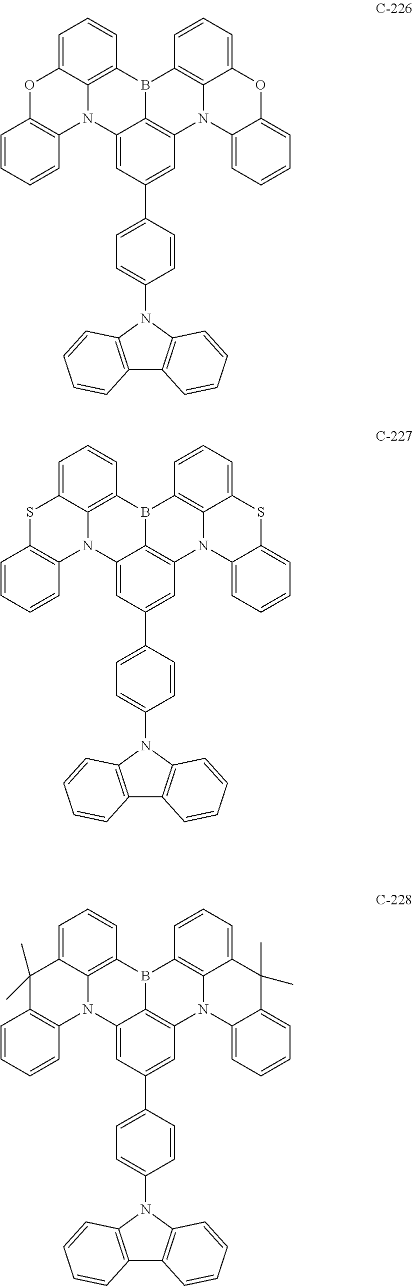 [SMILES: c1ccc2c(c1)Oc1cccc3c1N2c1cc(-c2ccc(-n4c5ccccc5c5ccccc54)cc2)cc2c1B3c1cccc3c1N2c1ccccc1O3 ; c1ccc2c(c1)Sc1cccc3c1N2c1cc(-c2ccc(-n4c5ccccc5c5ccccc54)cc2)cc2c1B3c1cccc3c1N2c1ccccc1S3 ; CC1(C)c2ccccc2N2c3cc(-c4ccc(-n5c6ccccc6c6ccccc65)cc4)cc4c3B(c3cccc1c32)c1cccc2c1N4c1ccccc1C2(C)C]

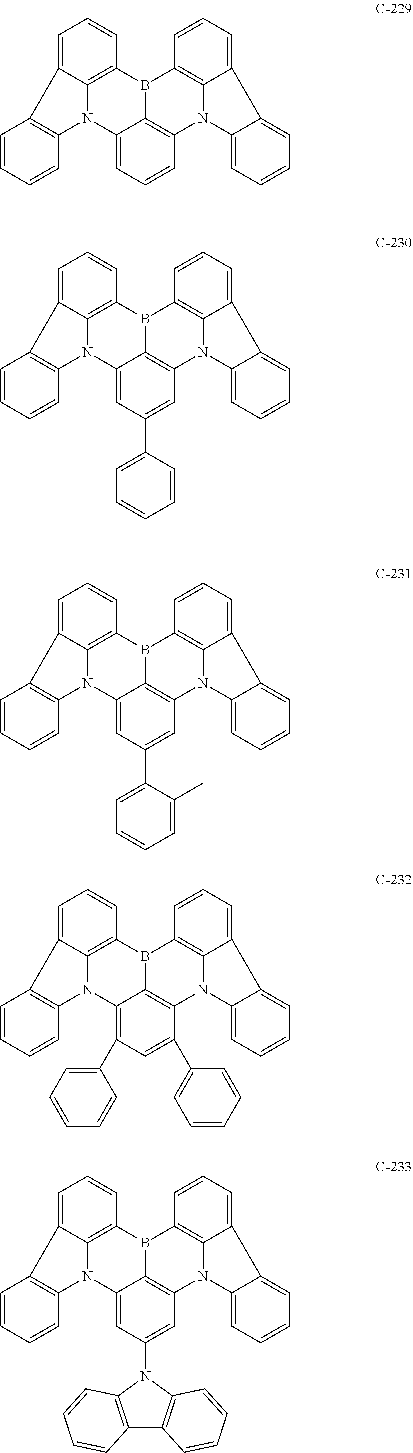 [SMILES: c1cc2c3c(c1)-n1c4ccccc4c4cccc(c41)B3c1cccc3c4ccccc4n-2c13 ; c1ccc(-c2cc3c4c(c2)-n2c5ccccc5c5cccc(c52)B4c2cccc4c5ccccc5n-3c24)cc1 ; Cc1ccccc1-c1cc2c3c(c1)-n1c4ccccc4c4cccc(c41)B3c1cccc3c4ccccc4n-2c13 ; c1ccc(-c2cc(-c3ccccc3)c3c4c2-n2c5ccccc5c5cccc(c52)B4c2cccc4c5ccccc5n-3c24)cc1 ; c1ccc2c(c1)c1ccccc1n2-c1cc2c3c(c1)-n1c4ccccc4c4cccc(c41)B3c1cccc3c4ccccc4n-2c13]

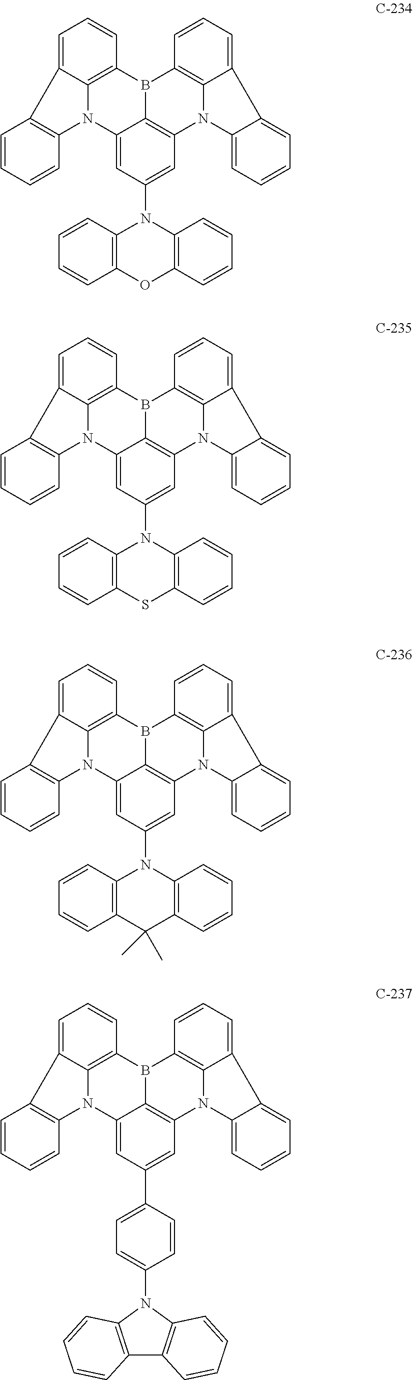 [SMILES: c1ccc2c(c1)Oc1ccccc1N2c1cc2c3c(c1)-n1c4ccccc4c4cccc(c41)B3c1cccc3c4ccccc4n-2c13 ; c1ccc2c(c1)Sc1ccccc1N2c1cc2c3c(c1)-n1c4ccccc4c4cccc(c41)B3c1cccc3c4ccccc4n-2c13 ; CC1(C)c2ccccc2N(c2cc3c4c(c2)-n2c5ccccc5c5cccc(c52)B4c2cccc4c5ccccc5n-3c24)c2ccccc21 ; c1ccc2c(c1)c1ccccc1n2-c1ccc(-c2cc3c4c(c2)-n2c5ccccc5c5cccc(c52)B4c2cccc4c5ccccc5n-3c24)cc1]

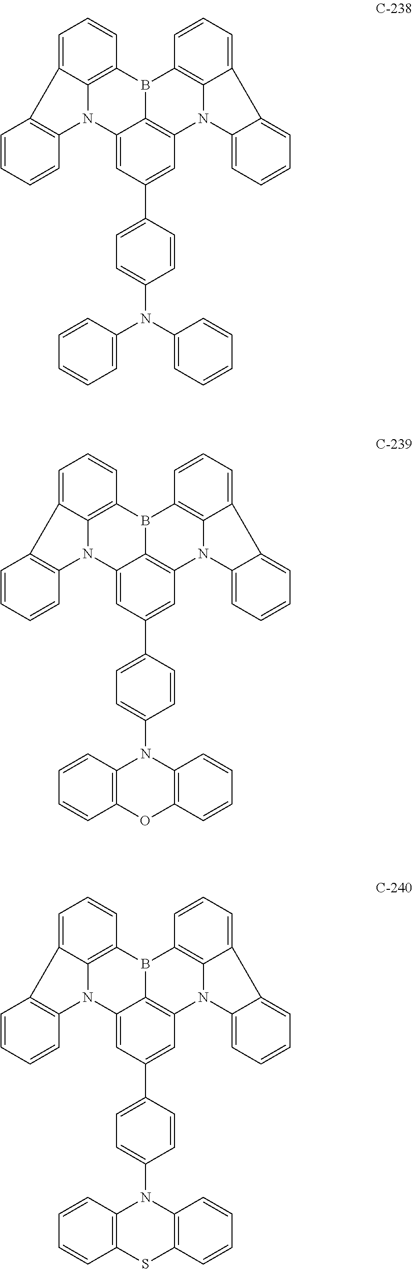 [SMILES: c1ccc(N(c2ccccc2)c2ccc(-c3cc4c5c(c3)-n3c6ccccc6c6cccc(c63)B5c3cccc5c6ccccc6n-4c35)cc2)cc1 ; c1ccc2c(c1)Oc1ccccc1N2c1ccc(-c2cc3c4c(c2)-n2c5ccccc5c5cccc(c52)B4c2cccc4c5ccccc5n-3c24)cc1 ; c1ccc2c(c1)Sc1ccccc1N2c1ccc(-c2cc3c4c(c2)-n2c5ccccc5c5cccc(c52)B4c2cccc4c5ccccc5n-3c24)cc1]

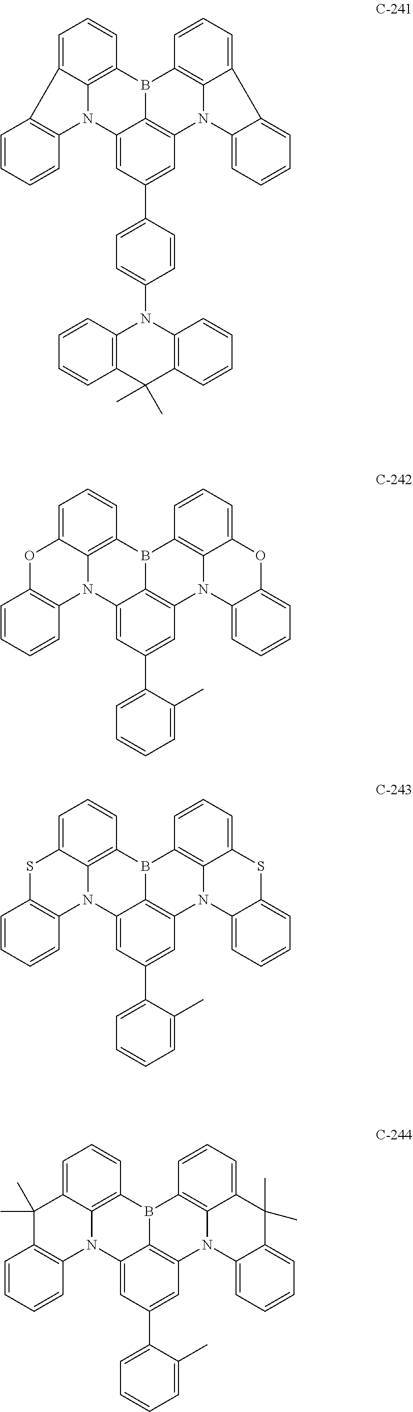

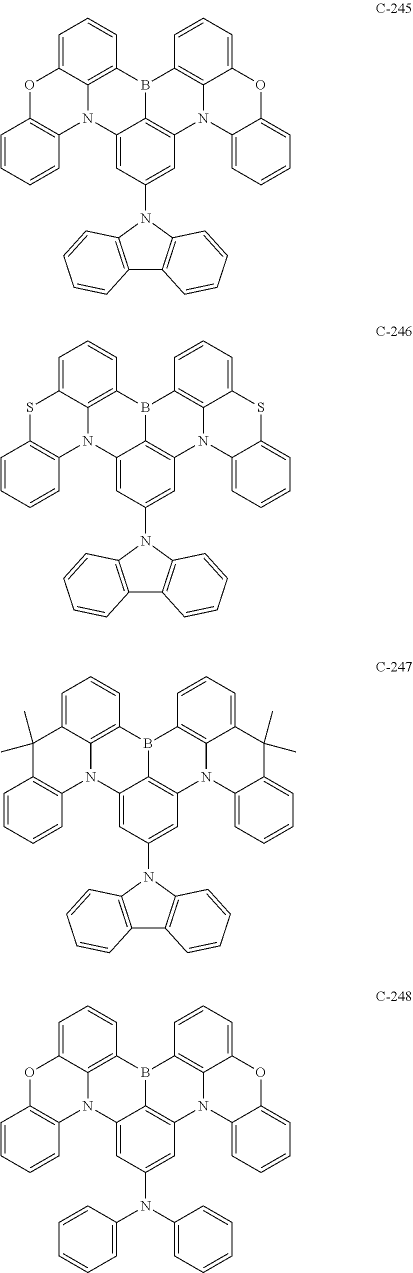

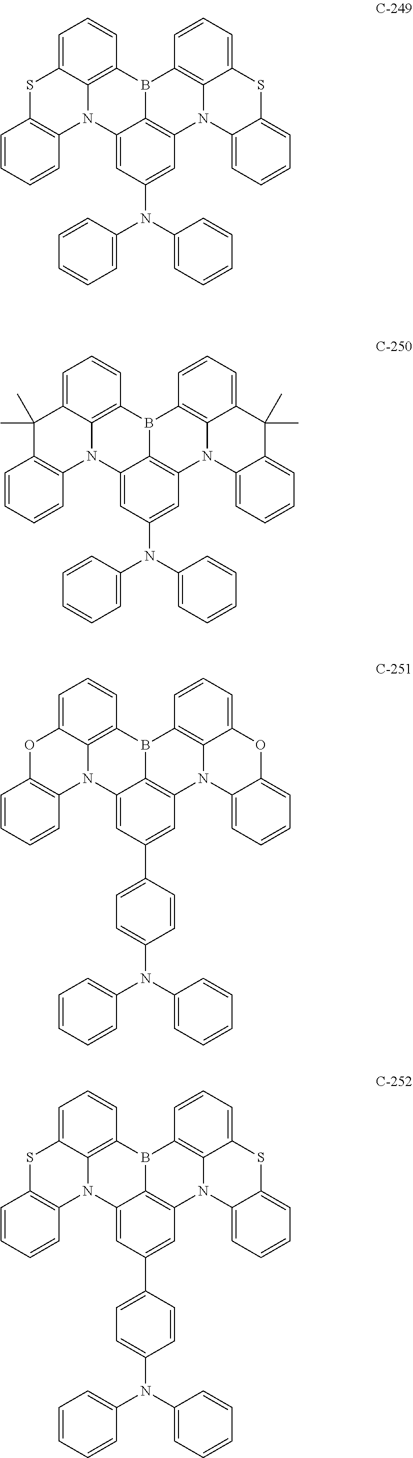

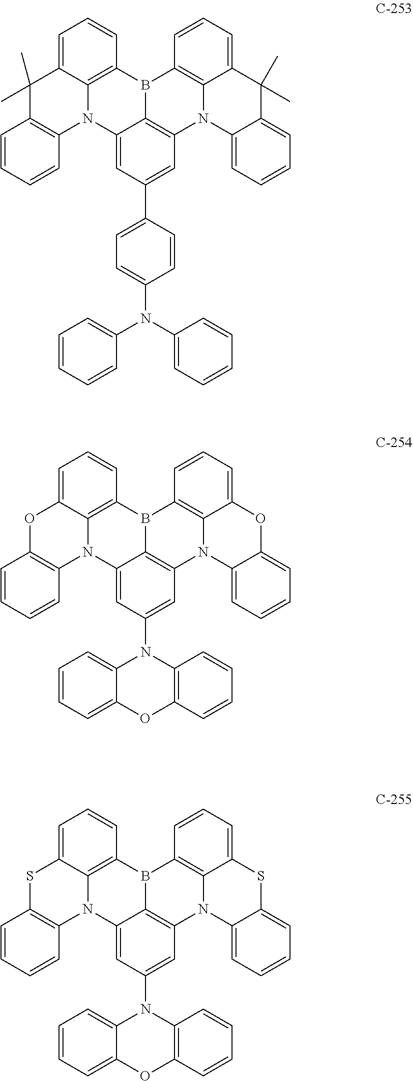 [SMILES: CC1(C)c2ccccc2N2c3cc(-c4ccc(N(c5ccccc5)c5ccccc5)cc4)cc4c3B(c3cccc1c32)c1cccc2c1N4c1ccccc1C2(C)C ; c1ccc2c(c1)Oc1ccccc1N2c1cc2c3c(c1)N1c4ccccc4Oc4cccc(c41)B3c1cccc3c1N2c1ccccc1O3 ; c1ccc2c(c1)Oc1ccccc1N2c1cc2c3c(c1)N1c4ccccc4Sc4cccc(c41)B3c1cccc3c1N2c1ccccc1S3]

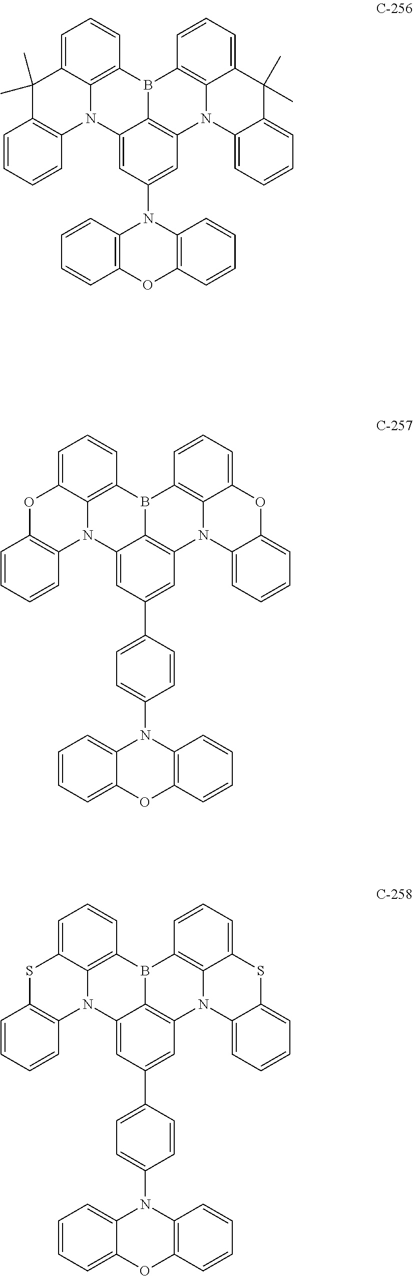

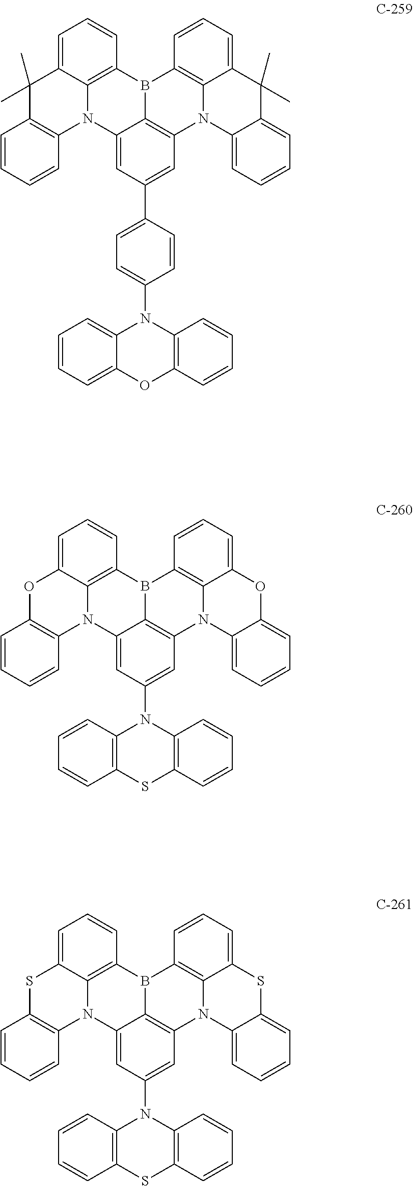 [SMILES: CC1(C)c2ccccc2N2c3cc(-c4ccc(N5c6ccccc6Oc6ccccc65)cc4)cc4c3B(c3cccc1c32)c1cccc2c1N4c1ccccc1C2(C)C ; c1ccc2c(c1)Oc1cccc3c1N2c1cc(N2c4ccccc4Sc4ccccc42)cc2c1B3c1cccc3c1N2c1ccccc1O3 ; c1ccc2c(c1)Sc1ccccc1N2c1cc2c3c(c1)N1c4ccccc4Sc4cccc(c41)B3c1cccc3c1N2c1ccccc1S3]

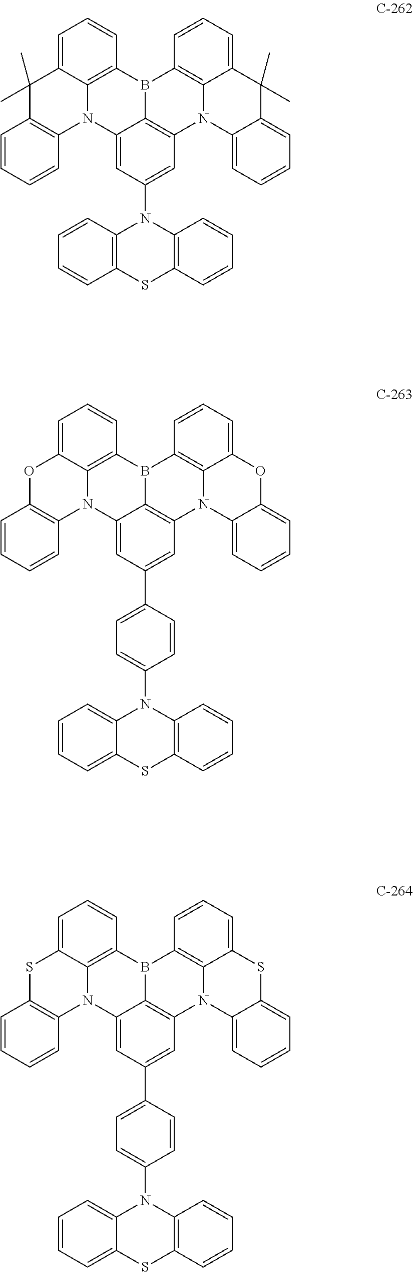 [SMILES: CC1(C)c2ccccc2N2c3cc(N4c5ccccc5Sc5ccccc54)cc4c3B(c3cccc1c32)c1cccc2c1N4c1ccccc1C2(C)C ; c1ccc2c(c1)Oc1cccc3c1N2c1cc(-c2ccc(N4c5ccccc5Sc5ccccc54)cc2)cc2c1B3c1cccc3c1N2c1ccccc1O3 ; c1ccc2c(c1)Sc1ccccc1N2c1ccc(-c2cc3c4c(c2)N2c5ccccc5Sc5cccc(c52)B4c2cccc4c2N3c2ccccc2S4)cc1]

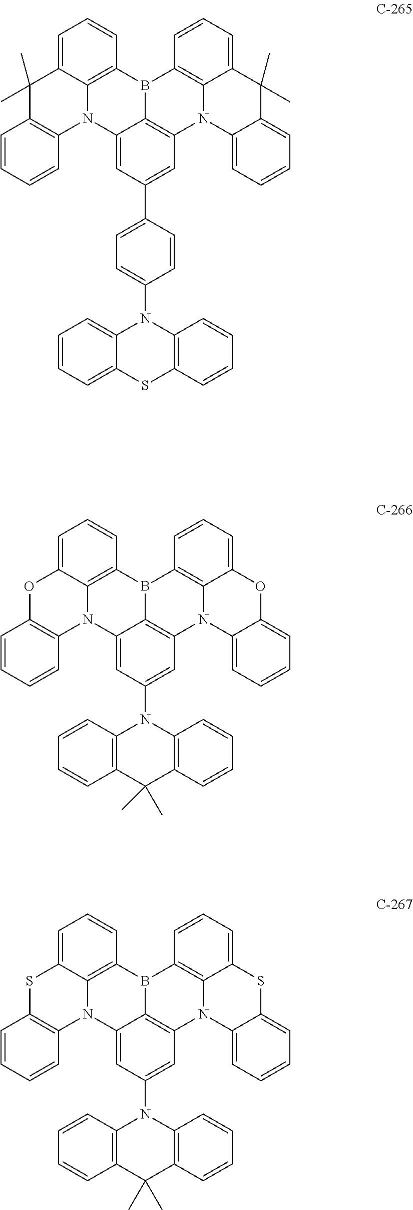 [SMILES: CC1(C)c2ccccc2N2c3cc(-c4ccc(N5c6ccccc6Sc6ccccc65)cc4)cc4c3B(c3cccc1c32)c1cccc2c1N4c1ccccc1C2(C)C ; CC1(C)c2ccccc2N(c2cc3c4c(c2)N2c5ccccc5Oc5cccc(c52)B4c2cccc4c2N3c2ccccc2O4)c2ccccc21 ; CC1(C)c2ccccc2N(c2cc3c4c(c2)N2c5ccccc5Sc5cccc(c52)B4c2cccc4c2N3c2ccccc2S4)c2ccccc21]

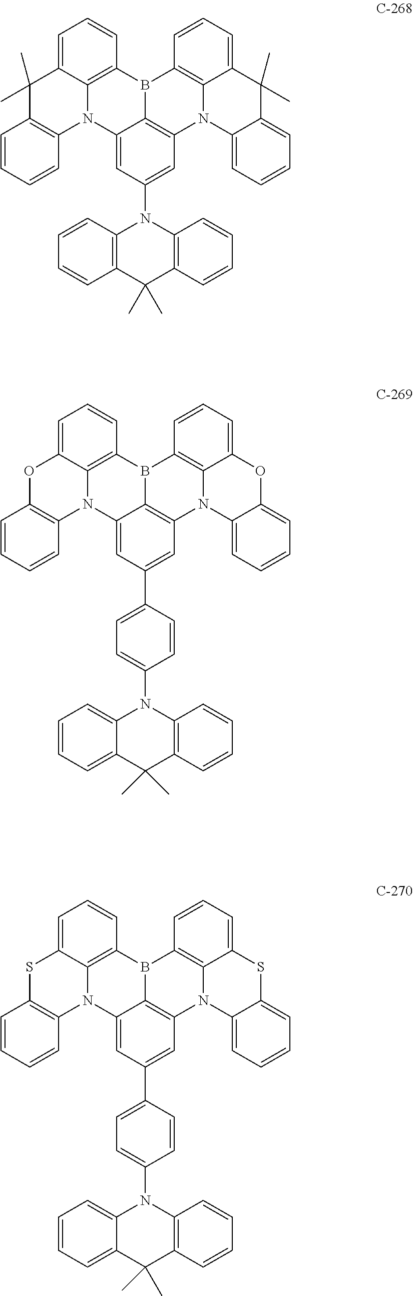 [SMILES: CC1(C)c2ccccc2N(c2cc3c4c(c2)N2c5ccccc5C(C)(C)c5cccc(c52)B4c2cccc4c2N3c2ccccc2C4(C)C)c2ccccc21 ; CC1(C)c2ccccc2N(c2ccc(-c3cc4c5c(c3)N3c6ccccc6Oc6cccc(c63)B5c3cccc5c3N4c3ccccc3O5)cc2)c2ccccc21 ; CC1(C)c2ccccc2N(c2ccc(-c3cc4c5c(c3)N3c6ccccc6Sc6cccc(c63)B5c3cccc5c3N4c3ccccc3S5)cc2)c2ccccc21]

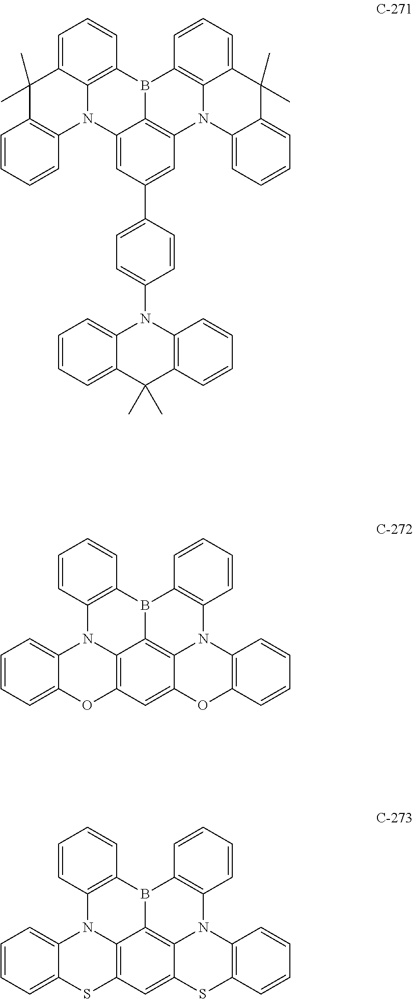 [SMILES: CC1(C)c2ccccc2N(c2ccc(-c3cc4c5c(c3)N3c6ccccc6C(C)(C)c6cccc(c63)B5c3cccc5c3N4c3ccccc3C5(C)C)cc2)c2ccccc21 ; c1ccc2c(c1)B1c3ccccc3-n3c4ccccc4oc4cc5oc6ccccc6n-2c5c1c43 ; c1ccc2c(c1)B1c3ccccc3-n3c4ccccc4sc4cc5sc6ccccc6n-2c5c1c43]

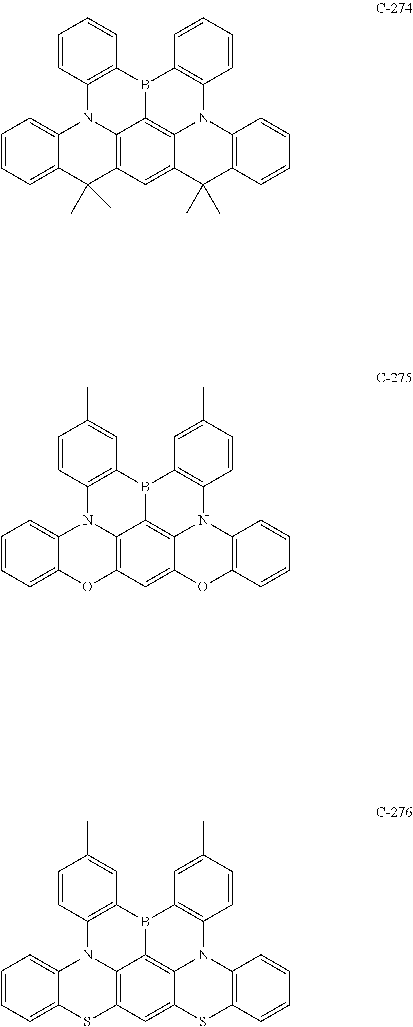 [SMILES: CC1(C)c2ccccc2N2c3ccccc3B3c4ccccc4N4c5ccccc5C(C)(C)c5cc1c2c3c54 ; Cc1ccc2c(c1)B1c3cc(C)ccc3-n3c4ccccc4oc4cc5oc6ccccc6n-2c5c1c43 ; Cc1ccc2c(c1)B1c3cc(C)ccc3-n3c4ccccc4sc4cc5sc6ccccc6n-2c5c1c43]

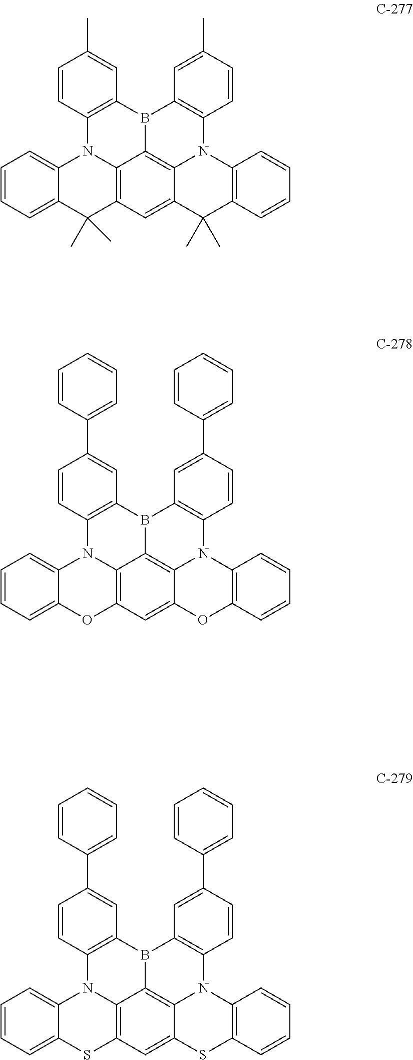 [SMILES: Cc1ccc2c(c1)B1c3cc(C)ccc3N3c4ccccc4C(C)(C)c4cc5c(c1c43)N2c1ccccc1C5(C)C ; c1ccc(-c2ccc3c(c2)B2c4cc(-c5ccccc5)ccc4-n4c5ccccc5oc5cc6oc7ccccc7n-3c6c2c54)cc1 ; c1ccc(-c2ccc3c(c2)B2c4cc(-c5ccccc5)ccc4-n4c5ccccc5sc5cc6sc7ccccc7n-3c6c2c54)cc1]

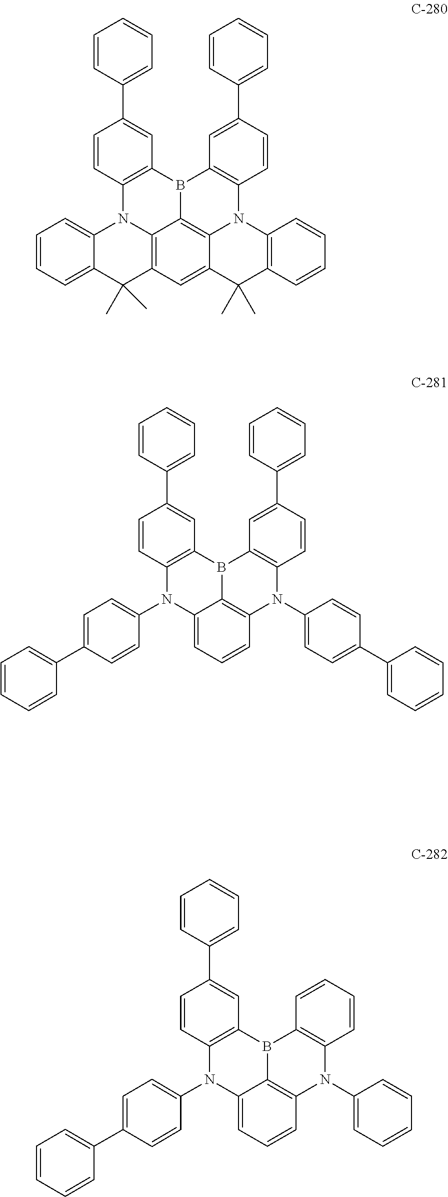 [SMILES: CC1(C)c2ccccc2N2c3ccc(-c4ccccc4)cc3B3c4cc(-c5ccccc5)ccc4N4c5ccccc5C(C)(C)c5cc1c2c3c54 ; c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5ccccc5N(c5ccccc5)c5cccc3c54)cc2)cc1]

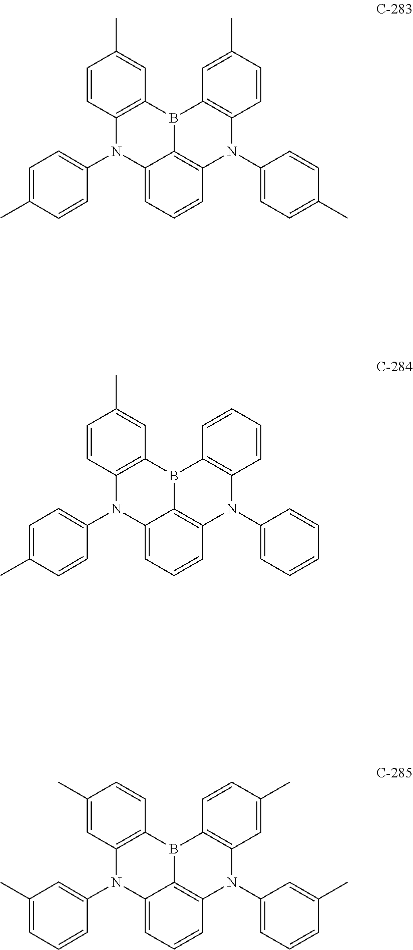

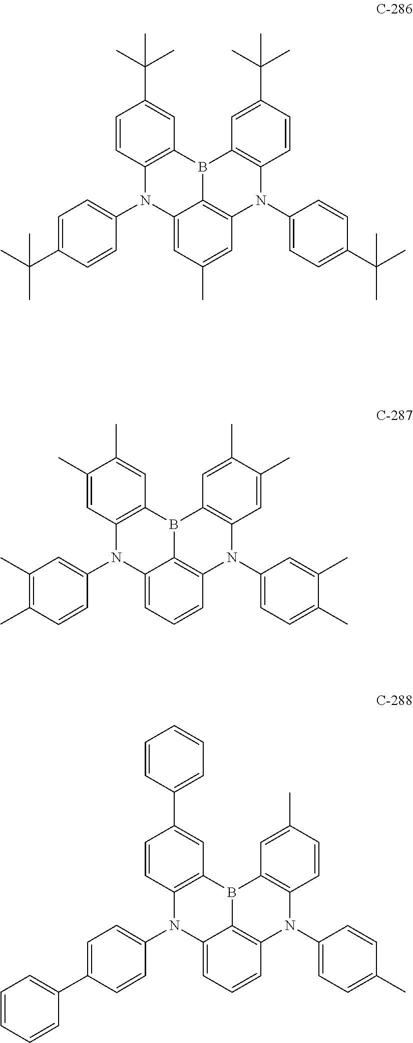

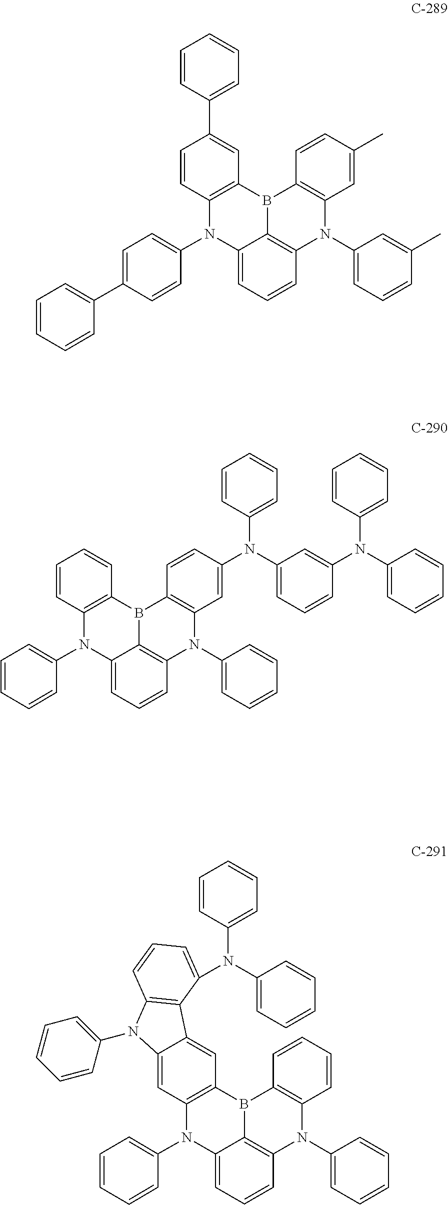 [SMILES: Cc1cccc(N2c3cc(C)ccc3B3c4cc(-c5ccccc5)ccc4N(c4ccc(-c5ccccc5)cc4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1 ; c1ccc(N2c3ccccc3B3c4cc5c6c(N(c7ccccc7)c7ccccc7)cccc6n(-c6ccccc6)c5cc4N(c4ccccc4)c4cccc2c43)cc1]

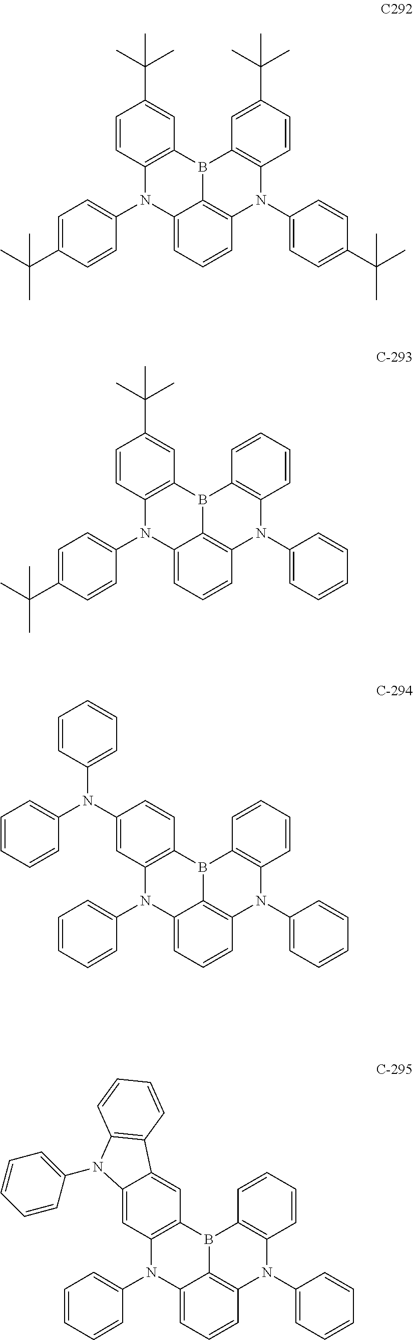

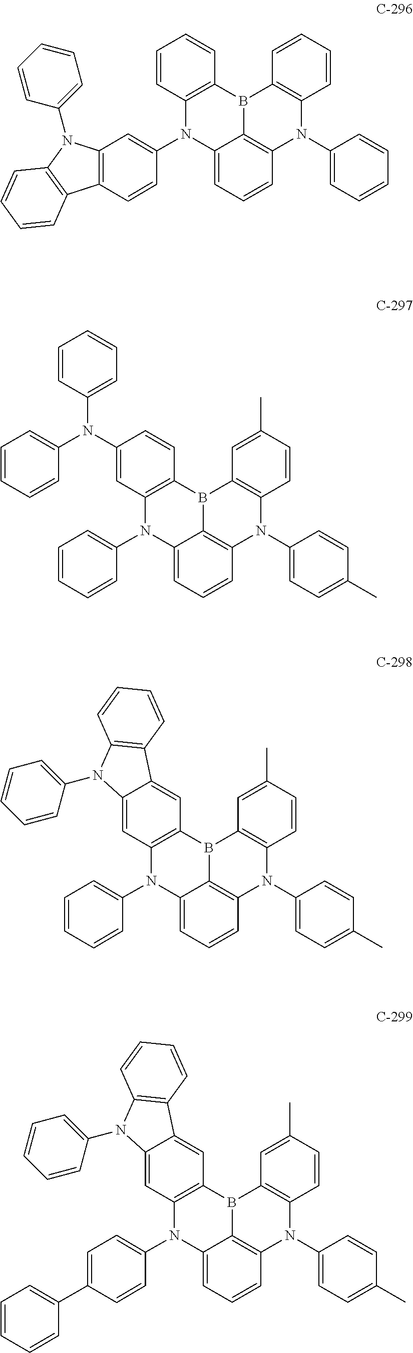 [SMILES: c1ccc(N2c3ccccc3B3c4ccccc4N(c4ccc5c6ccccc6n(-c6ccccc6)c5c4)c4cccc2c43)cc1 ; Cc1ccc(N2c3ccc(C)cc3B3c4ccc(N(c5ccccc5)c5ccccc5)cc4N(c4ccccc4)c4cccc2c43)cc1 ; Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1]

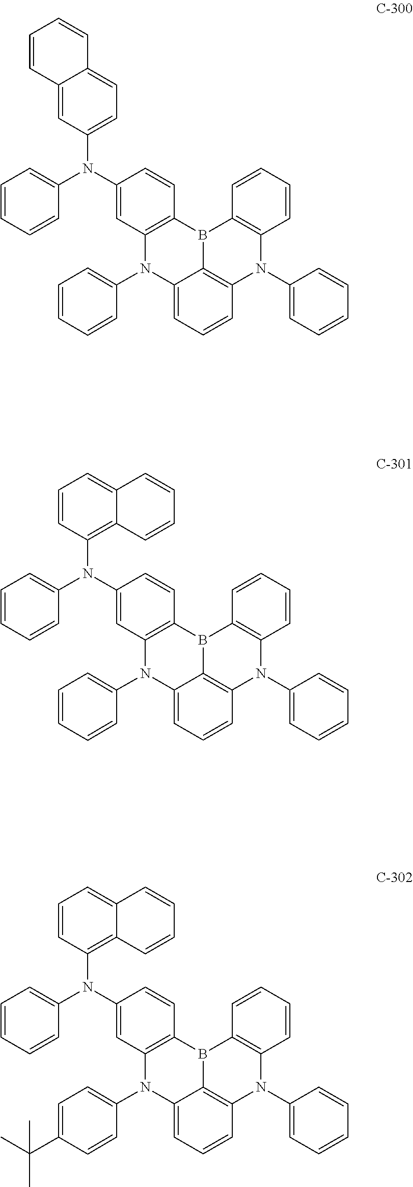 [SMILES: c1ccc(N(c2ccc3c(c2)N(c2ccccc2)c2cccc4c2B3c2ccccc2N4c2ccccc2)c2ccc3ccccc3c2)cc1 ; c1ccc(N2c3ccccc3B3c4ccc(N(c5ccccc5)c5cccc6ccccc56)cc4N(c4ccccc4)c4cccc2c43)cc1 ; CC(C)(C)c1ccc(N2c3cc(N(c4ccccc4)c4cccc5ccccc45)ccc3B3c4ccccc4N(c4ccccc4)c4cccc2c43)cc1]

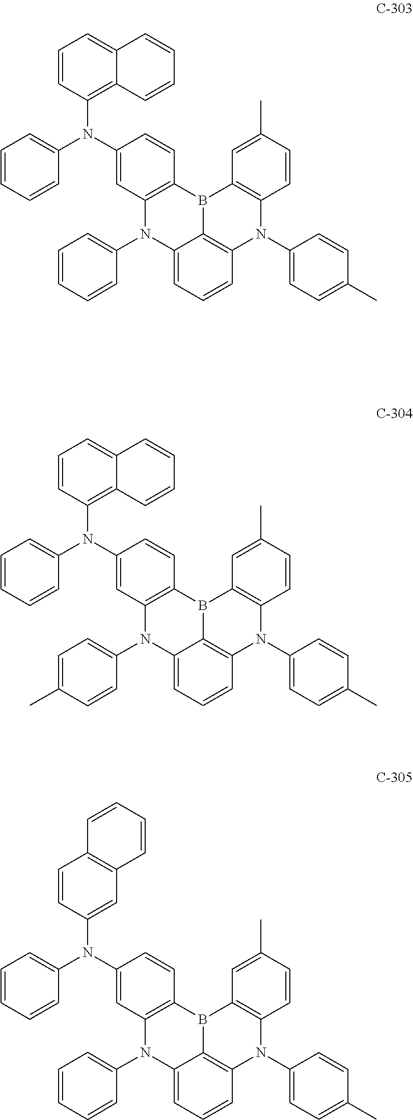 [SMILES: Cc1ccc(N2c3ccc(C)cc3B3c4ccc(N(c5ccccc5)c5cccc6ccccc56)cc4N(c4ccccc4)c4cccc2c43)cc1 ; Cc1ccc(N2c3ccc(C)cc3B3c4ccc(N(c5ccccc5)c5cccc6ccccc56)cc4N(c4ccc(C)cc4)c4cccc2c43)cc1 ; Cc1ccc(N2c3ccc(C)cc3B3c4ccc(N(c5ccccc5)c5ccc6ccccc6c5)cc4N(c4ccccc4)c4cccc2c43)cc1]

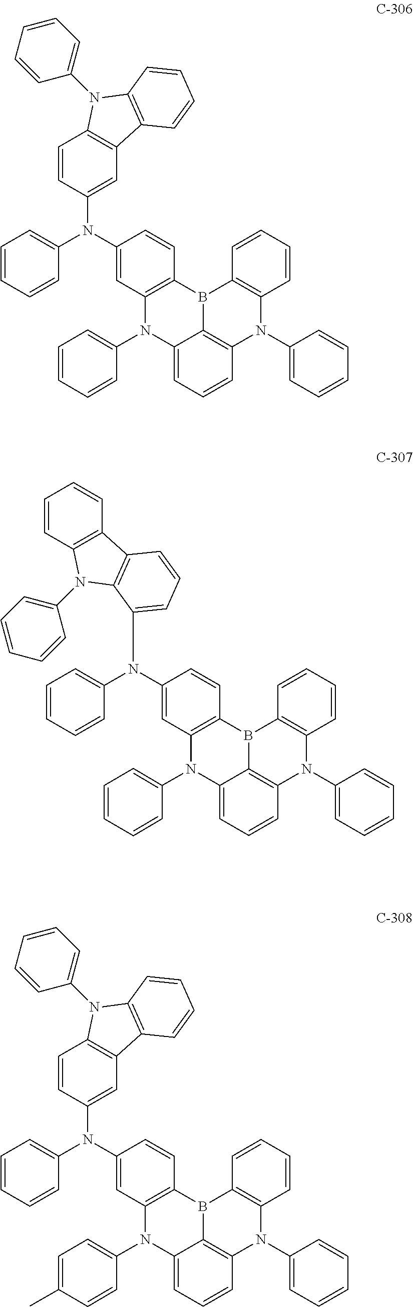 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N(Cc2cccc3c4ccccc4n(-c4ccccc4)c23)c2ccc3c(c2)N(c2ccccc2)c2cccc4c2B3c2ccccc2N4c2ccccc2)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

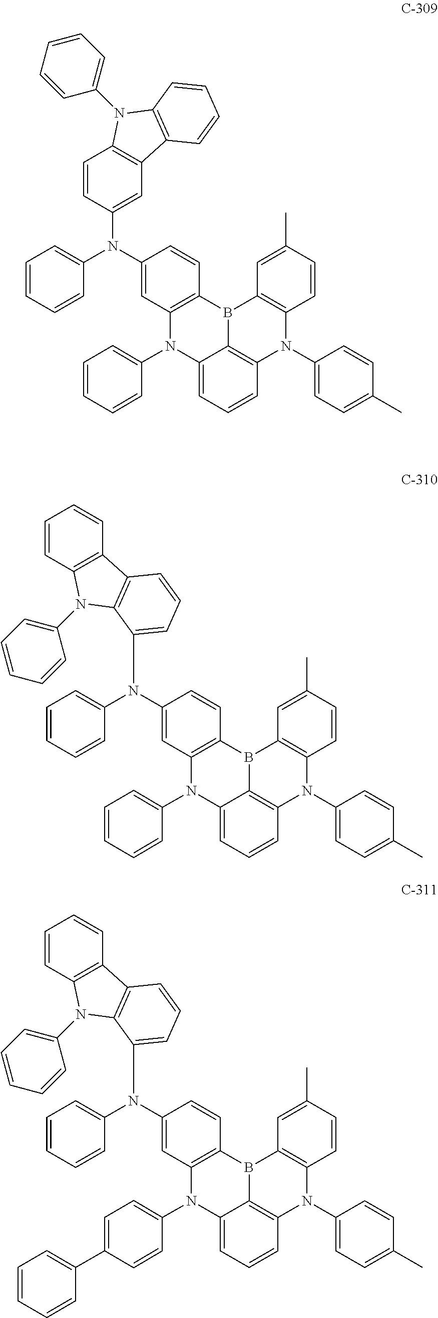 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

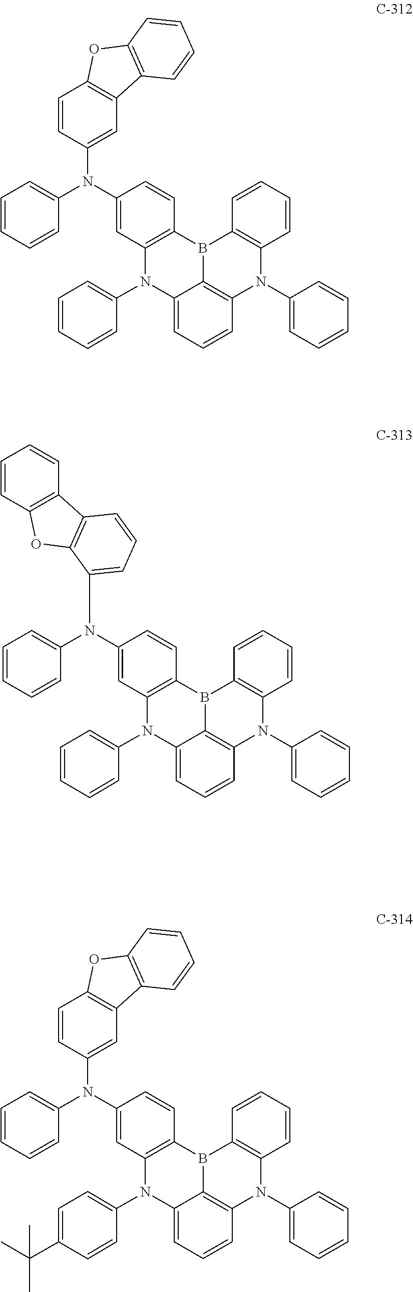 [SMILES: c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1]

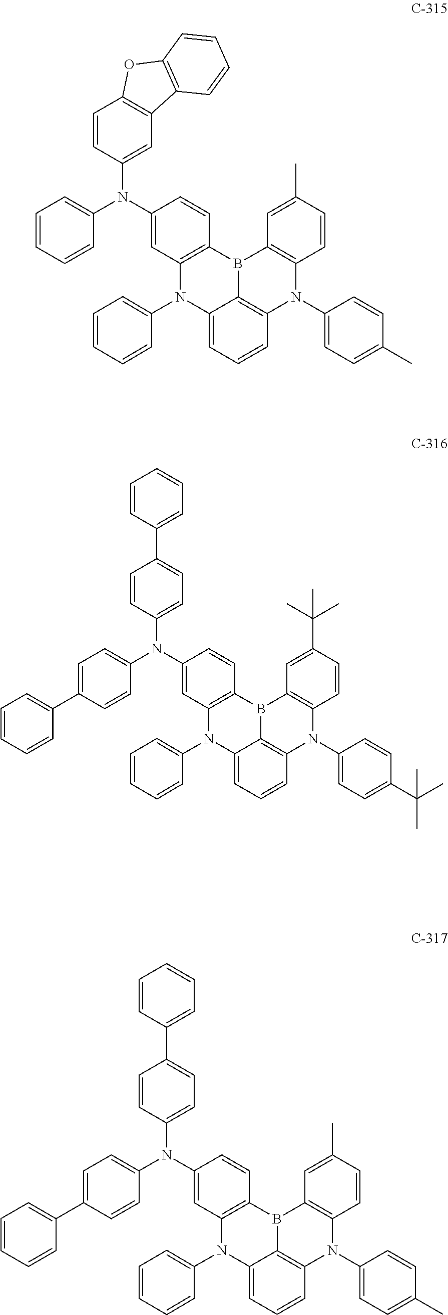 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; CC(C)(C)c1ccc(N2c3ccc(C(C)(C)C)cc3B3c4ccc(N(c5ccc(-c6ccccc6)cc5)c5ccc(-c6ccccc6)cc5)cc4N(c4ccccc4)c4cccc2c43)cc1 ; Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1]

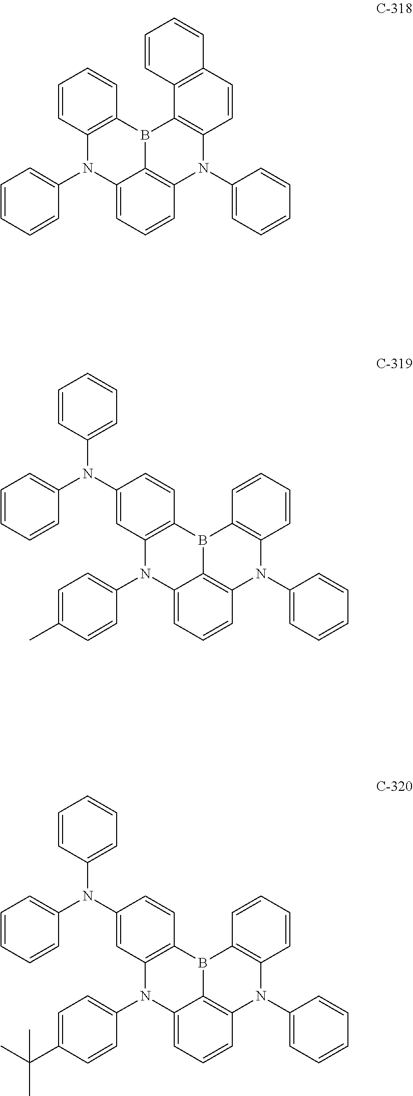

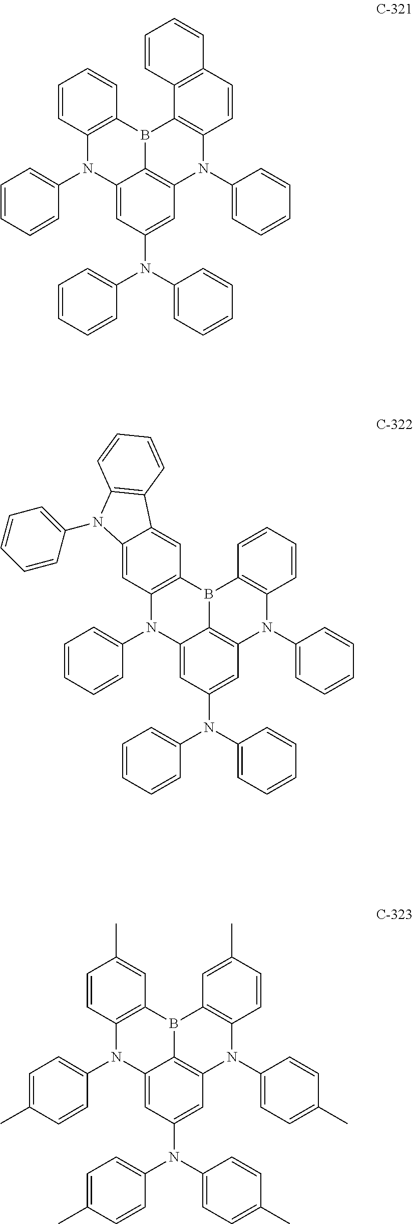

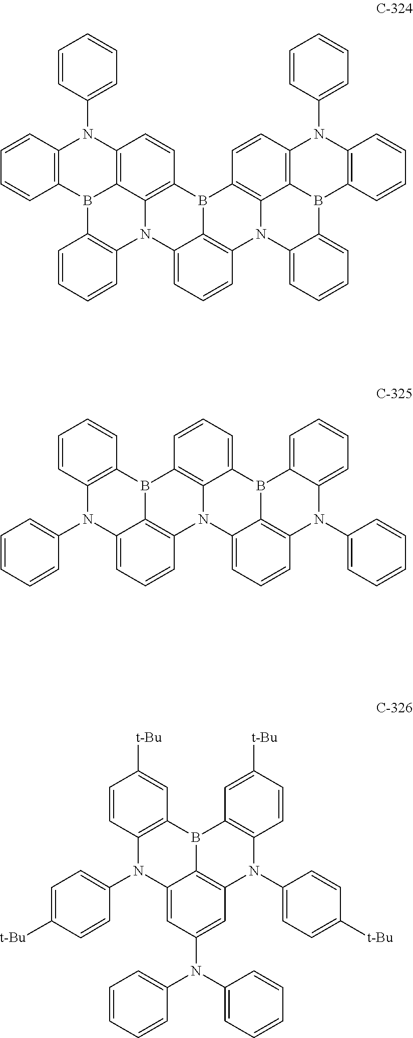

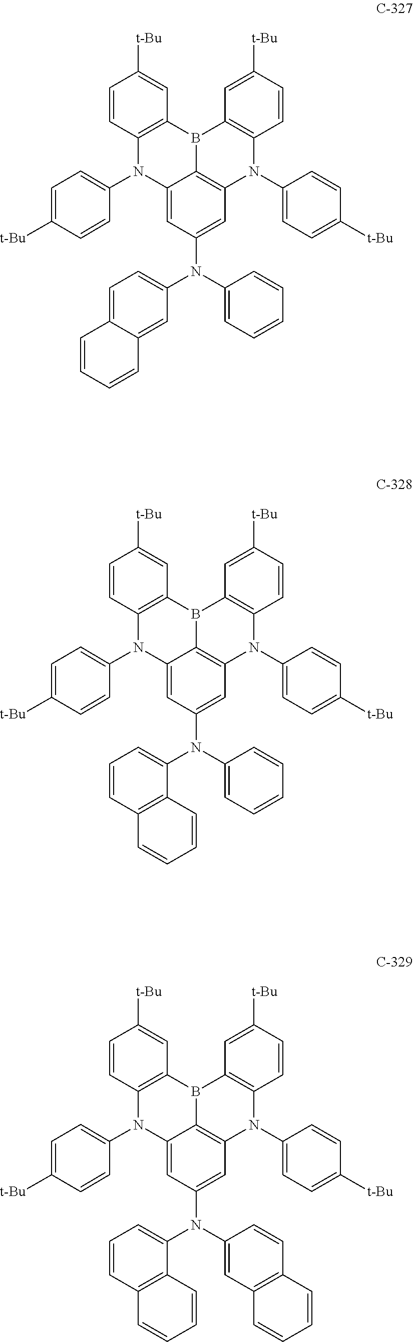

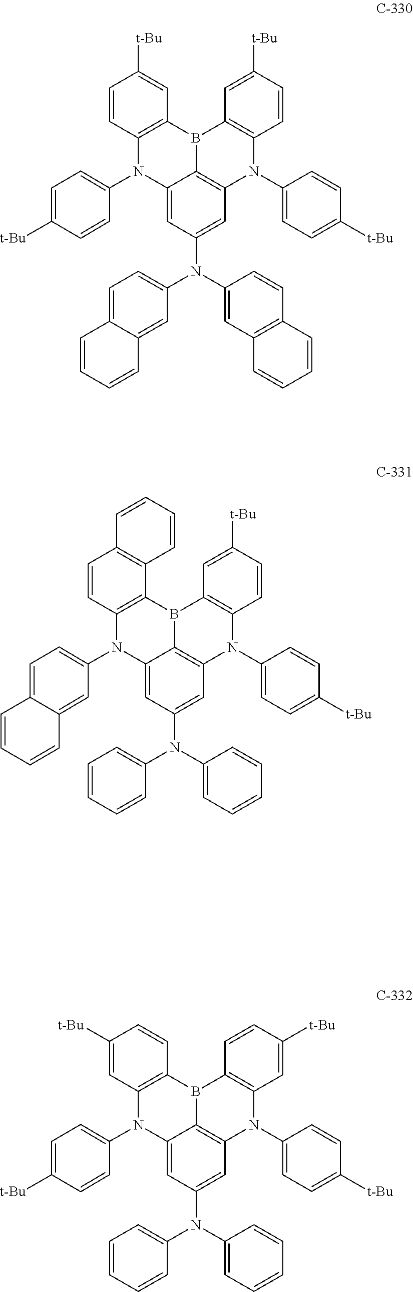

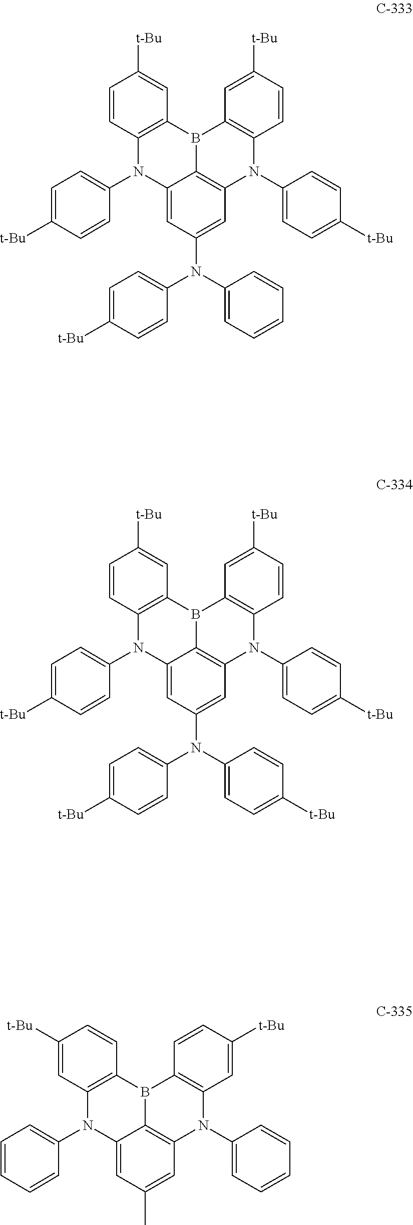

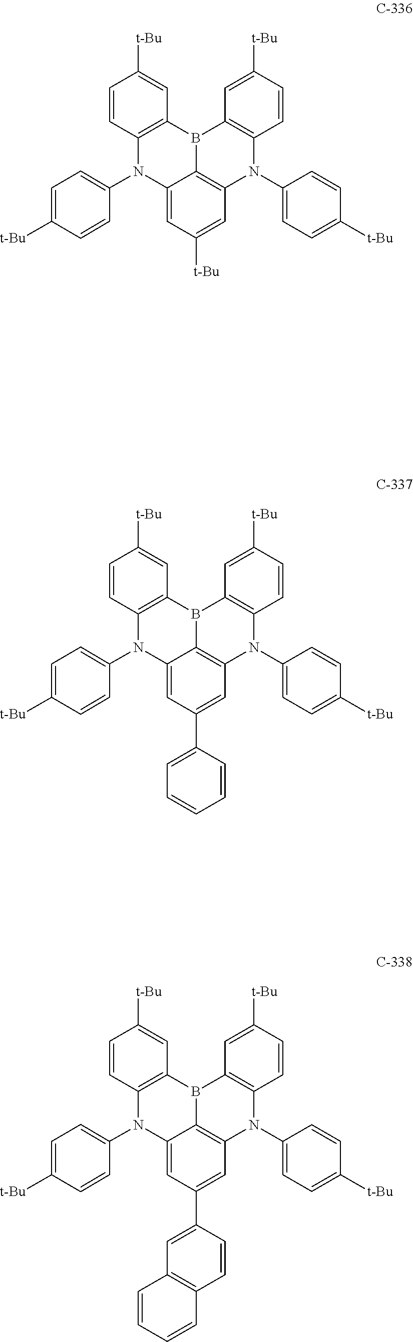

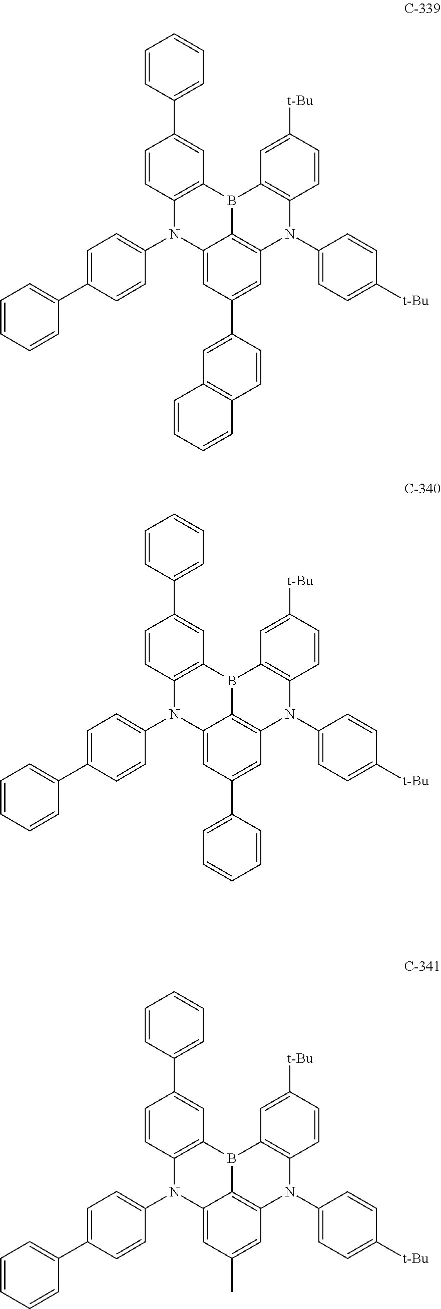

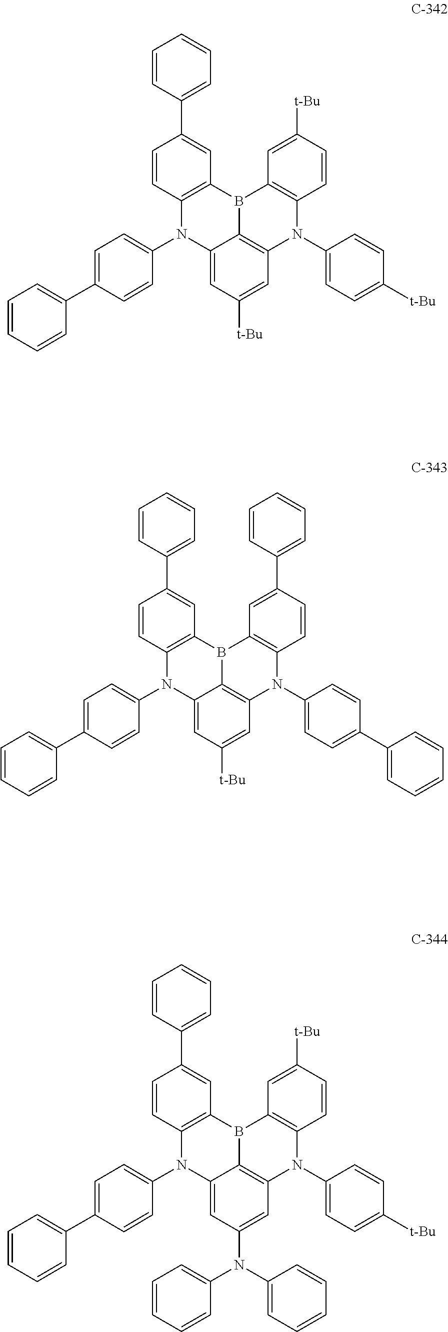

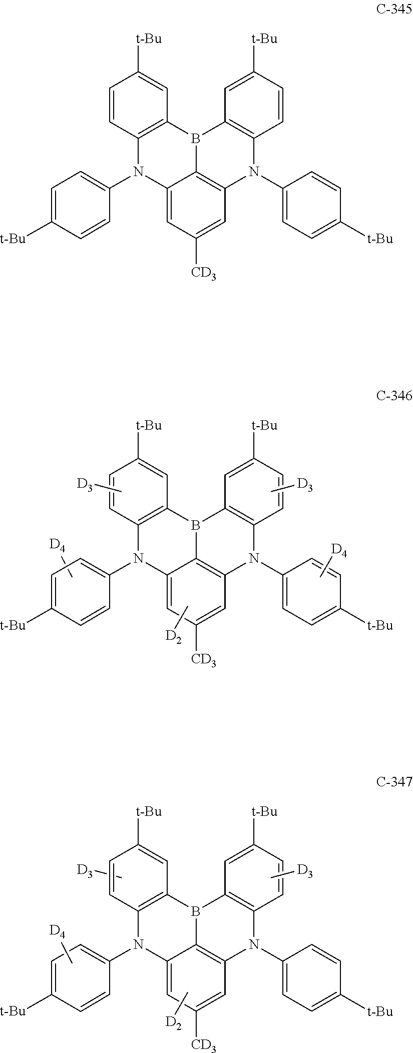

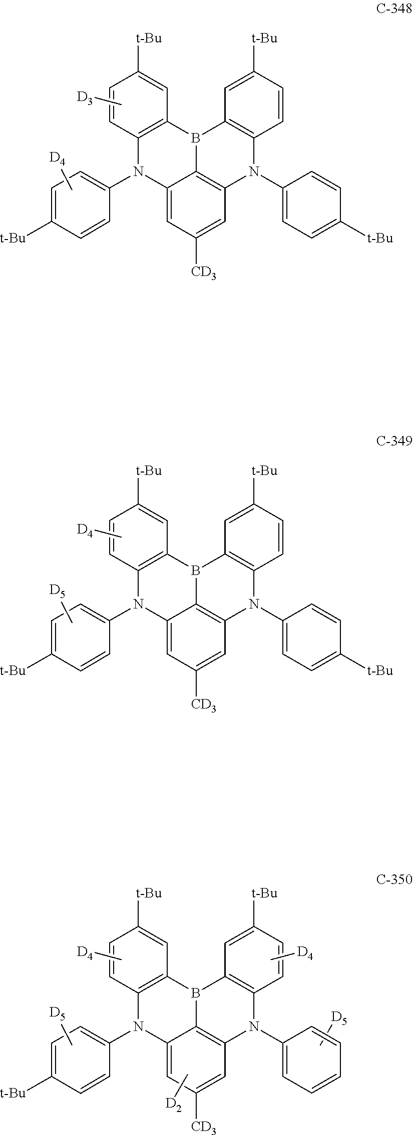

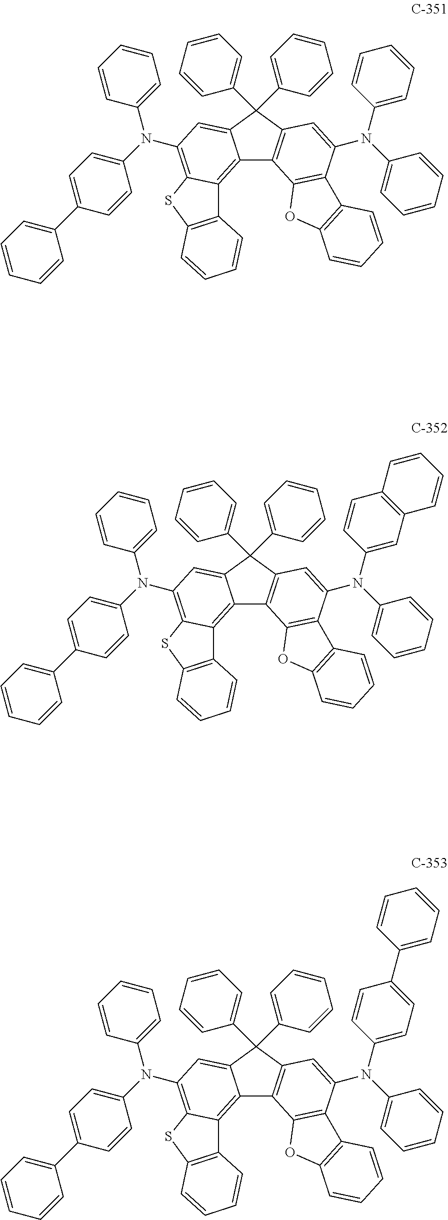 [SMILES: c1ccc(-c2ccc(N(c3ccccc3)c3cc4c(c5c3sc3ccccc35)-c3c(cc(N(c5ccccc5)c5ccccc5)c5c3oc3ccccc35)C4(c3ccccc3)c3ccccc3)cc2)cc1 ; c1ccc(-c2ccc(N(c3ccccc3)c3cc4c(c5c3sc3ccccc35)-c3c(cc(N(c5ccccc5)c5ccc6ccccc6c5)c5c3oc3ccccc35)C4(c3ccccc3)c3ccccc3)cc2)cc1 ; c1ccc(-c2ccc(N(c3ccccc3)c3cc4c(c5c3sc3ccccc35)-c3c(cc(N(c5ccccc5)c5ccc(-c6ccccc6)cc5)c5c3oc3ccccc35)C4(c3ccccc3)c3ccccc3)cc2)cc1]

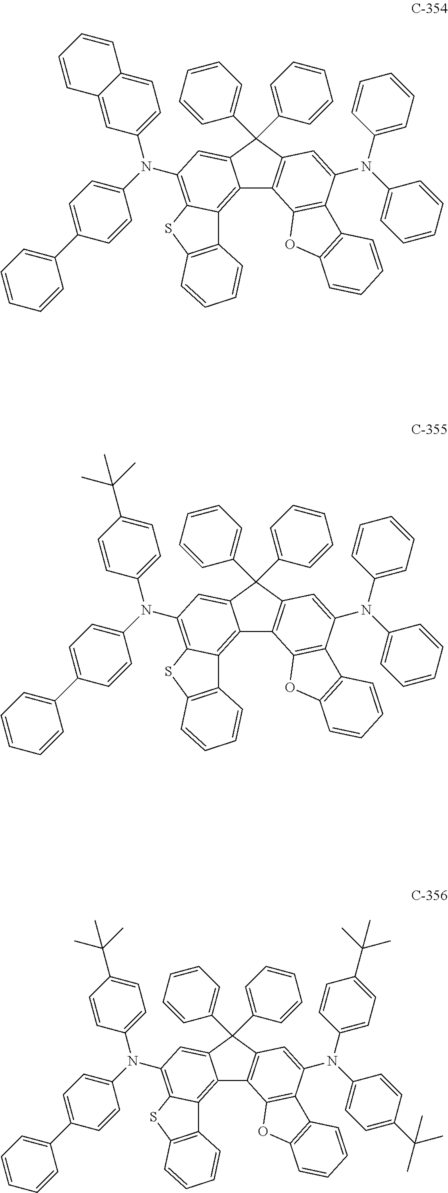 [SMILES: c1ccc(-c2ccc(N(c3ccc4ccccc4c3)c3cc4c(c5c3sc3ccccc35)-c3c(cc(N(c5ccccc5)c5ccccc5)c5c3oc3ccccc35)C4(c3ccccc3)c3ccccc3)cc2)cc1 ; CC(C)(C)c1ccc(N(c2ccc(-c3ccccc3)cc2)c2cc3c(c4c2sc2ccccc24)-c2c(cc(N(c4ccccc4)c4ccccc4)c4c2oc2ccccc24)C3(c2ccccc2)c2ccccc2)cc1 ; CC(C)(C)c1ccc(N(c2ccc(-c3ccccc3)cc2)c2cc3c(c4c2sc2ccccc24)-c2c(cc(N(c4ccc(C(C)(C)C)cc4)c4ccc(C(C)(C)C)cc4)c4c2oc2ccccc24)C3(c2ccccc2)c2ccccc2)cc1]

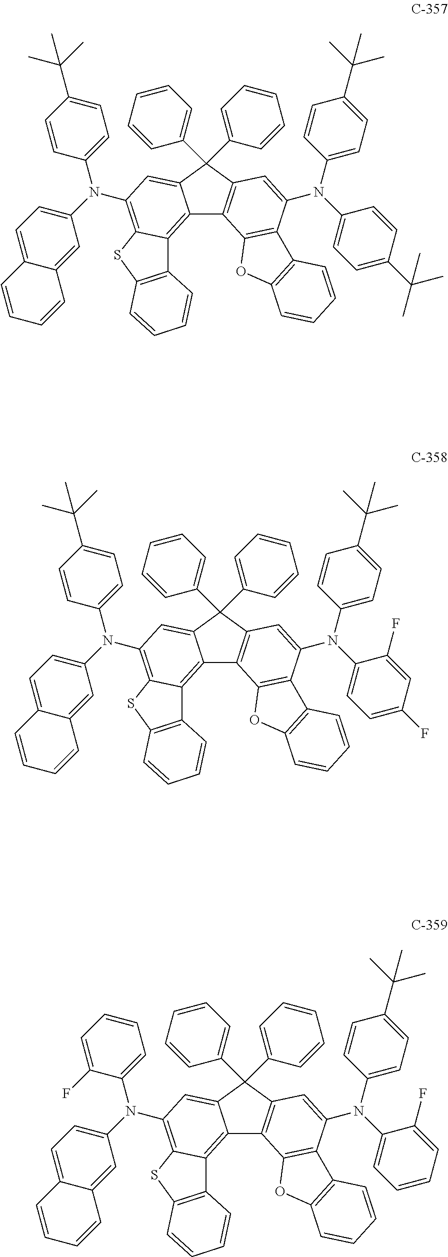 [SMILES: CC(C)(C)c1ccc(N(c2ccc3ccccc3c2)c2cc3c(c4c2sc2ccccc24)-c2c(cc(N(c4ccc(C(C)(C)C)cc4)c4ccc(C(C)(C)C)cc4)c4c2oc2ccccc24)C3(c2ccccc2)c2ccccc2)cc1 ; CC(C)(C)c1ccc(N(c2ccc3ccccc3c2)c2cc3c(c4c2sc2ccccc24)-c2c(cc(N(c4ccc(C(C)(C)C)cc4)c4ccc(F)cc4F)c4c2oc2ccccc24)C3(c2ccccc2)c2ccccc2)cc1 ; CC(C)(C)c1ccc(N(c2ccccc2F)c2cc3c(c4oc5ccccc5c24)-c2c(cc(N(c4ccc5ccccc5c4)c4ccccc4F)c4sc5ccccc5c24)C3(c2ccccc2)c2ccccc2)cc1]

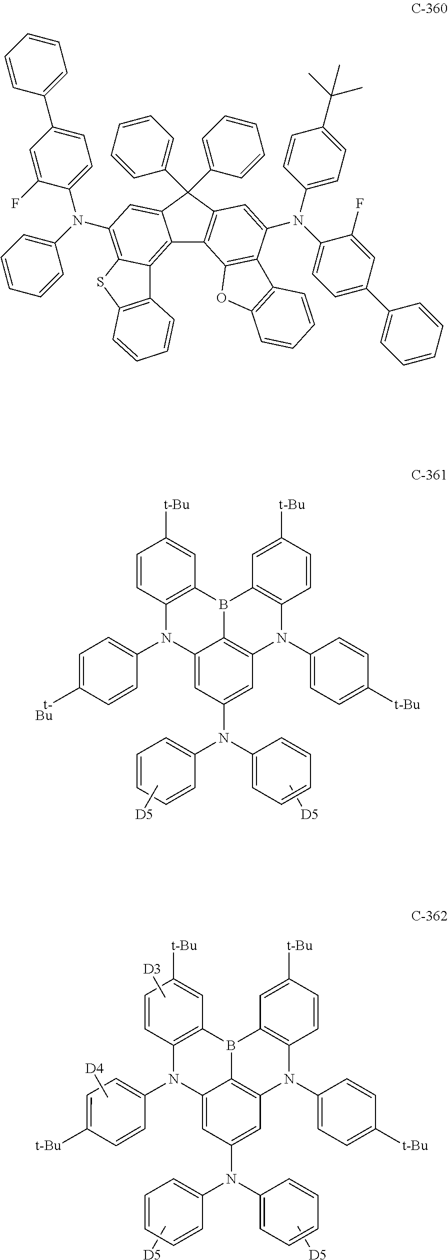

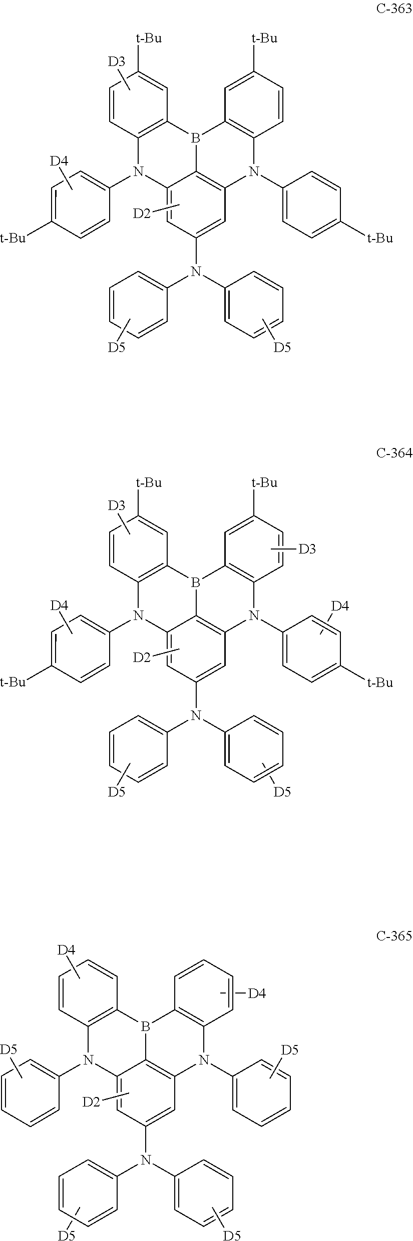

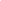

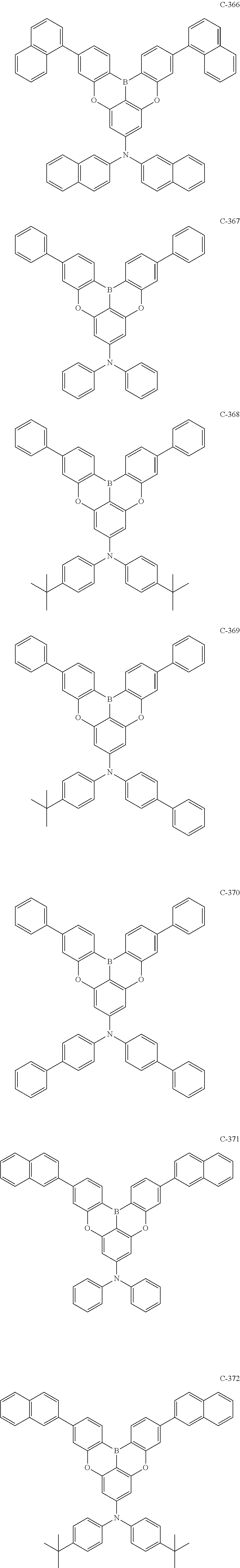

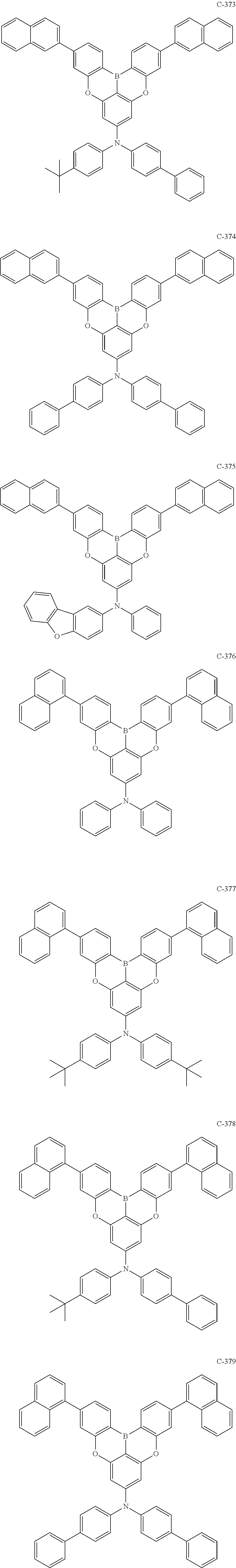

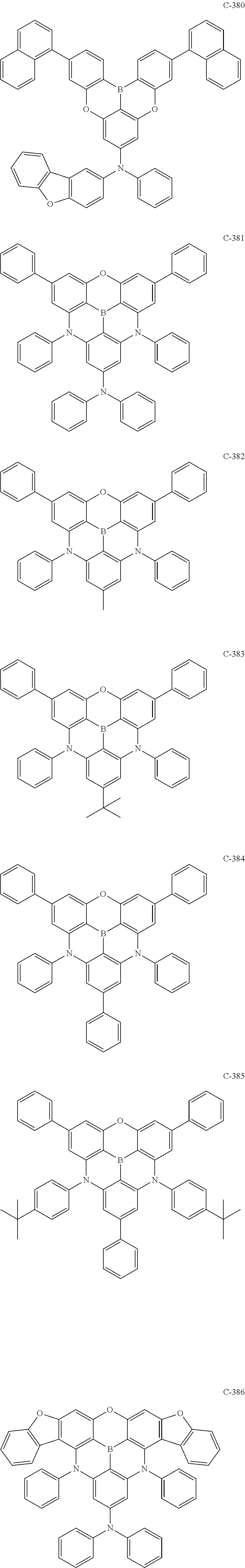

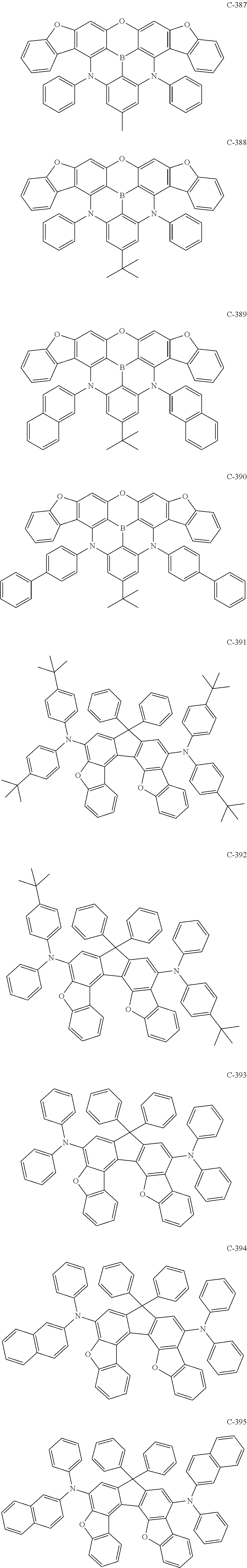

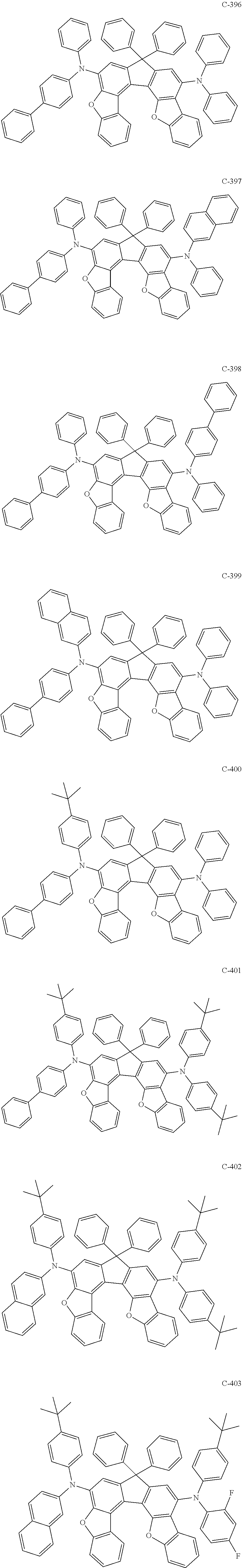

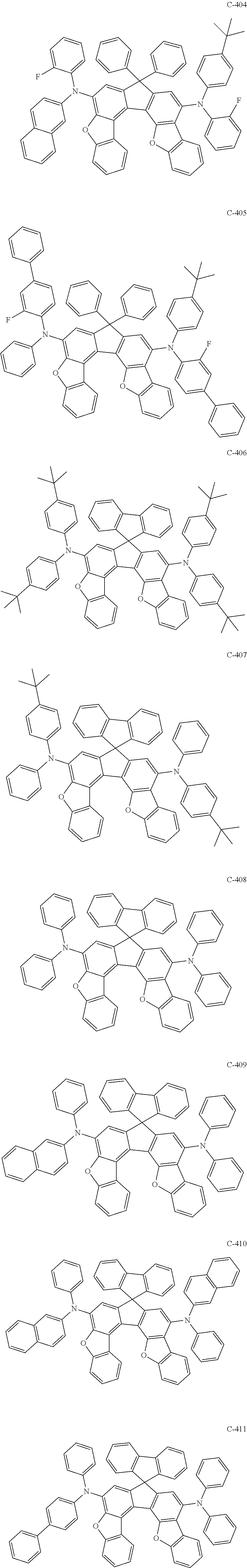

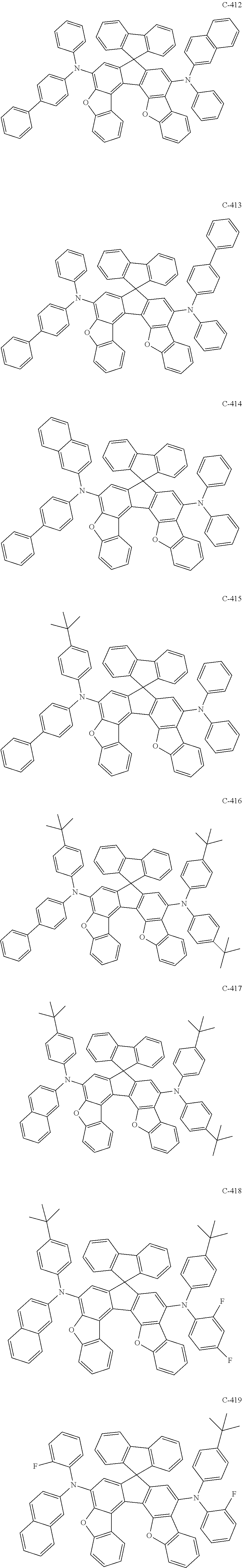

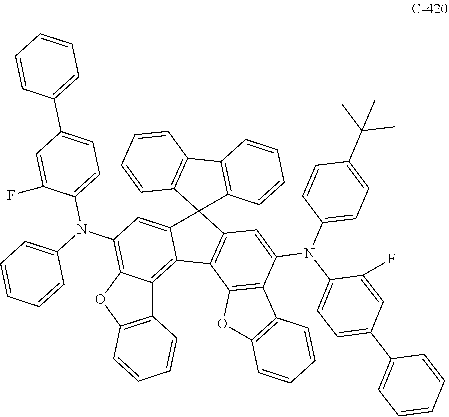 [SMILES: CC(C)(C)c1ccc(N(c2ccc(-c3ccccc3)cc2F)c2cc3c(c4oc5ccccc5c24)-c2c(cc(N(c4ccccc4)c4ccc(-c5ccccc5)cc4F)c4oc5ccccc5c24)C32c3ccccc3-c3ccccc32)cc1]

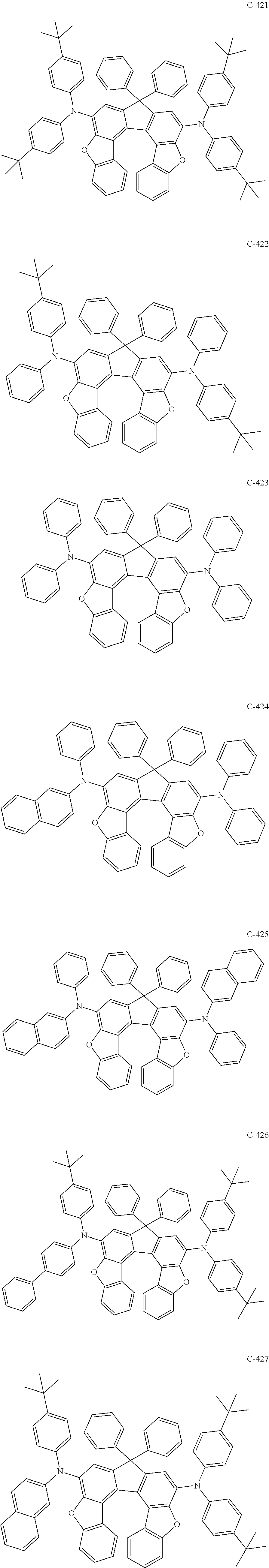

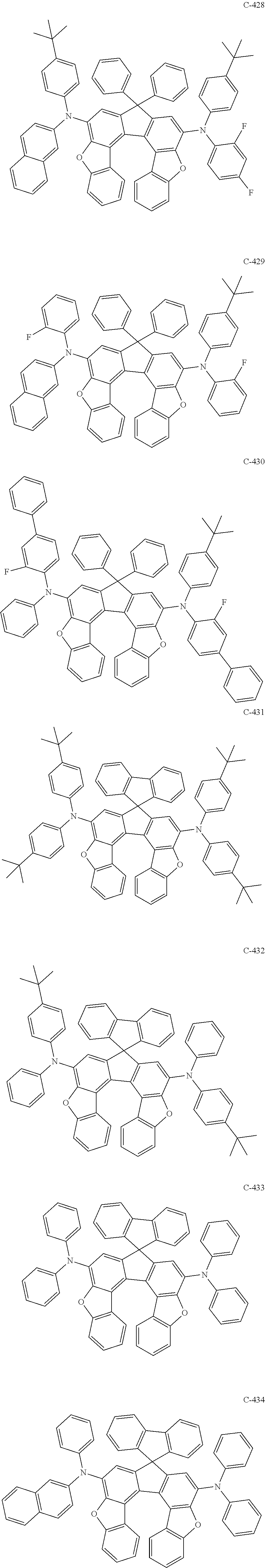

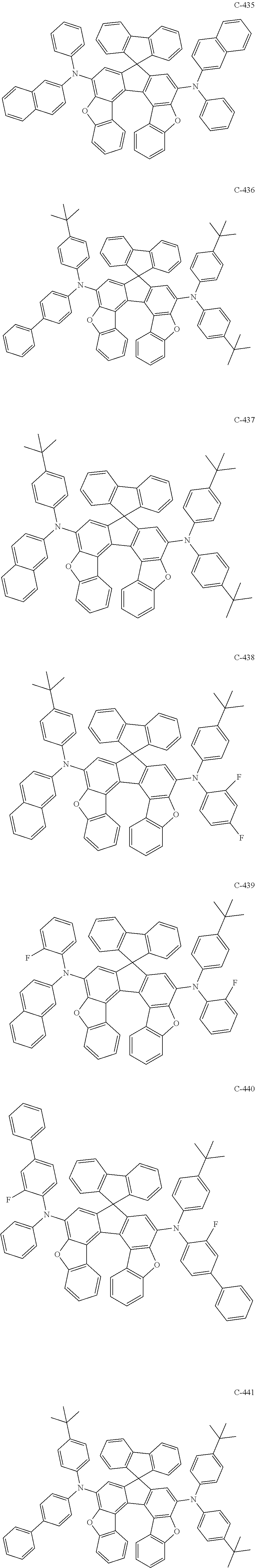

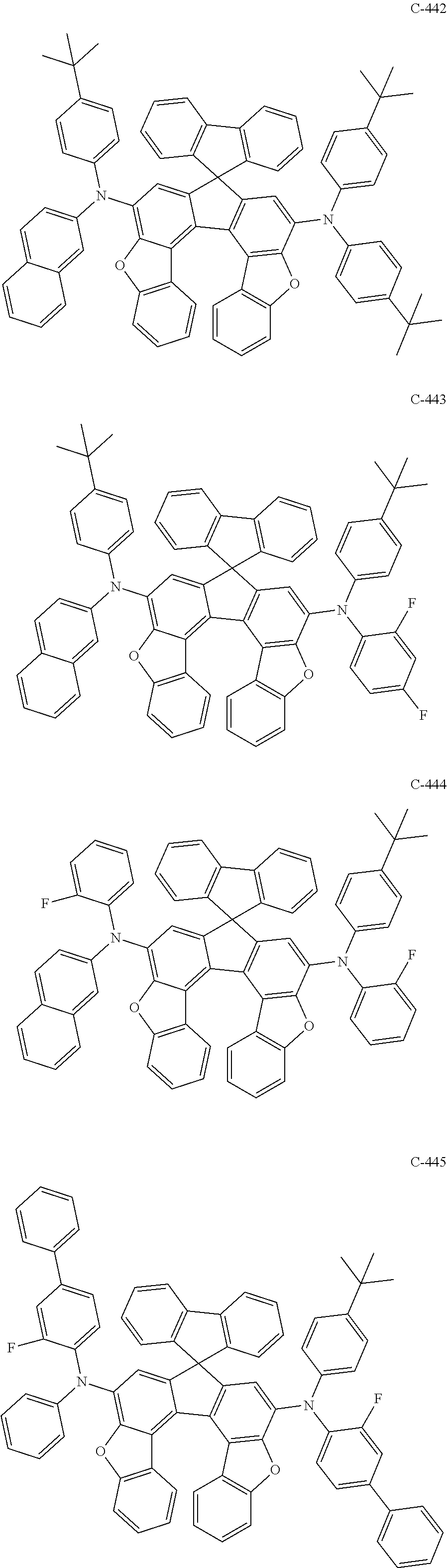

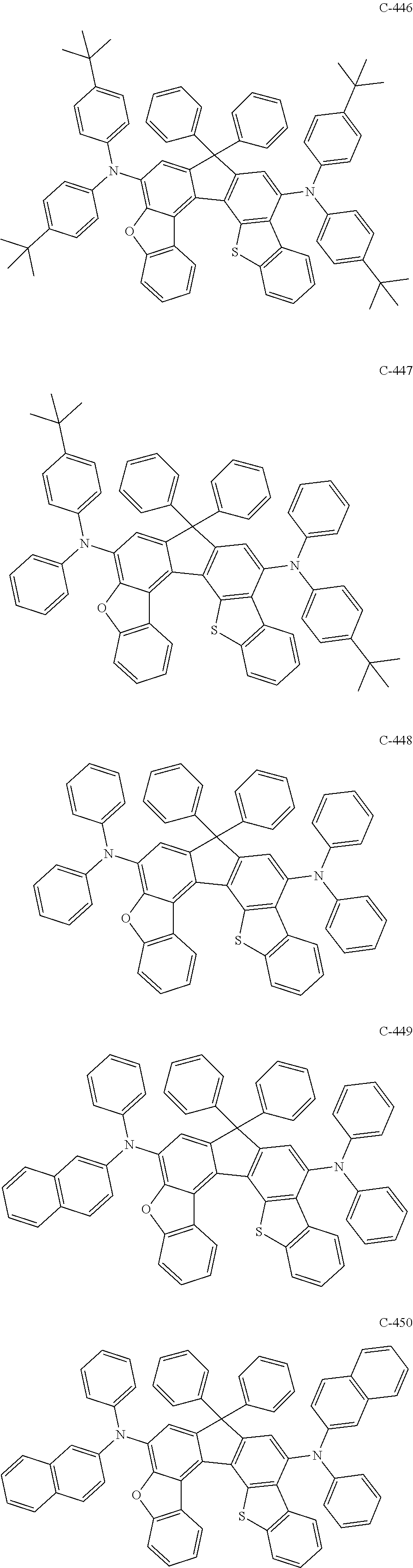

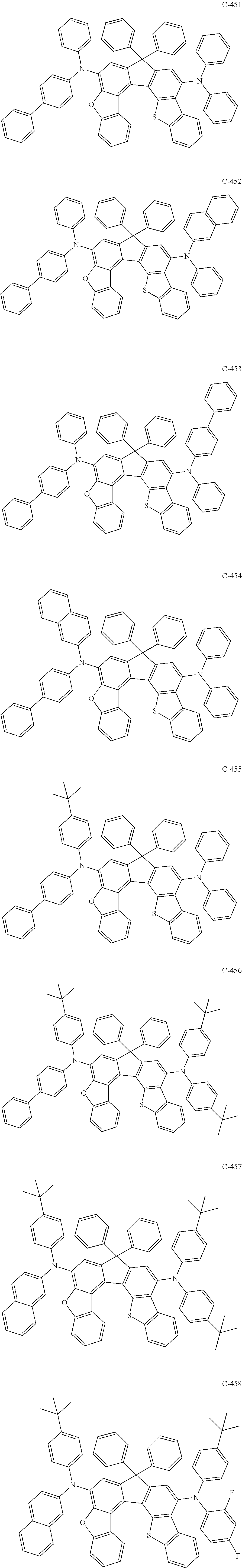

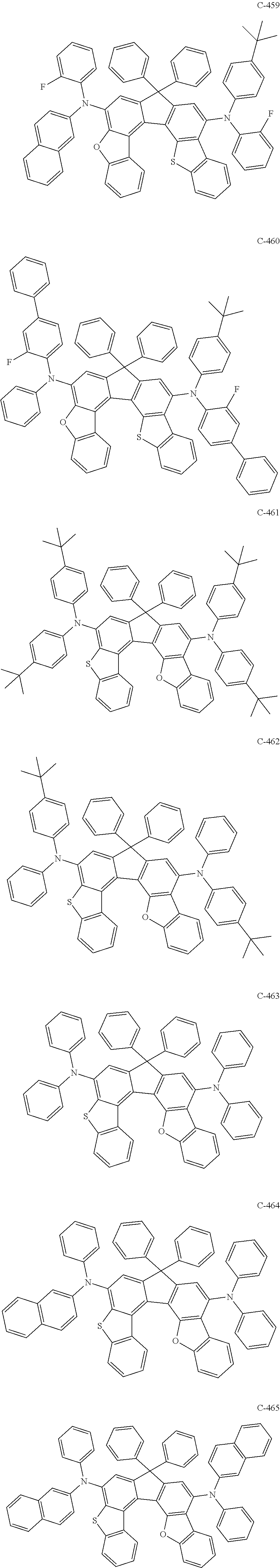

In order to form each layer of the organic electroluminescent device of the present disclosure, dry film-forming methods such as vacuum evaporation, sputtering, plasma, ion plating methods, etc., or wet film-forming methods such as ink jet printing, nozzle printing, slot coating, spin coating, dip coating, flow coating methods, etc., can be used.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a film of a plurality of host materials according to one embodiment, at least two host compounds or a composition comprising the same are pre-mixed to form a pre-mixture, before deposition, and then the pre-mixture is simultaneously deposited from one deposition source to form a light-emitting layer. In this case, it is preferable that at least one compound(s) of the first compound and the second compound used in the pre-mix satisfies the aforementioned equation (1).

According to one embodiment, the organic electroluminescent device of the present disclosure can be used for the manufacture of display devices such as smartphones, tablets, notebooks, PCs, TVs, or display devices for vehicles, or lighting devices such as outdoor or indoor lighting.

Hereinafter, the preparation method of an organic electroluminescent device (OLED) comprising a plurality of host materials according to the present disclosure, and the properties thereof will be explained in order to understand the present disclosure in detail. However, the following examples are only to describe the properties of the OLED according to the present disclosure in order to understand the present disclosure in detail, and the present disclosure is not limited to the following examples.

### [Example 1] Preparation of a Pre-Mix Host Material

Compound H2-157 (Tm: 274° C., Td: 285° C.) (0.7 g) in powder form and compound H1-58 (Tm: 167.5° C., Td: 272° C.) (0.7 g) in powder form were metered, and the two compounds were evenly mixed to prepare the compounds. After melting the materials in powder form by raising the temperature of the vacuum chamber, it was cooled to room temperature. Herein, the term “melting temperature (Tm)” is defined as a glass transition temperature (Tg), when Tm is not measured during DSC (Differential Scanning Calorimetry) measurement, and is defined as measured temperature, when Tm is measured. The deposition temperature (Td) represents a temperature measured during deposition in an evaporator. Thereafter, the cooled product was made in powder form again to prepare a pre-mix host material.

### [Device Example 1] Preparation of an OLED Using a Plurality of Host Materials According to the Present Disclosure

An OLED using a plurality of host materials according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone, ethanol and distilled water, sequentially, and thereafter was stored in isopropanol and then used. After evacuating until the degree of vacuum in the chamber reaches 10-torr, the ITO substrate was mounted on a substrate holder of a vacuum vapor deposition apparatus. Then, compound HT-1 as a hole injection compound was introduced into a cell of the vacuum vapor deposition apparatus, and compound HI was introduced into another cell. The two materials were evaporated and compound HI was deposited in a doping amount of 3 wt % based on the total amount of compound HT-1 and compound HI to form a hole injection layer having a thickness of 10 nm on the ITO substrate. Next, compound HT-1 was evaporated to deposit a first hole transport layer having a thickness of 80 nm on the hole injection layer. Next, compound HT-2 was then introduced into another cell of the vacuum vapor deposition apparatus and was evaporated by applying an electric current to the cell, thereby depositing a second hole transport layer having a thickness of 5 nm on the first hole transport layer. After forming the hole injection layer and the hole transport layers, a light-emitting layer was formed thereon as follows: the pre-mix compound wherein compound H2-157 and compound H1-58 are in the molar ratio of 1:1 was introduced into a cell of the vacuum vapor deposition apparatus as hosts of the light-emitting layer, and compound C-326 was introduced into another cell as a dopant. The two materials were evaporated and the dopant was deposited in a doping amount of 2 wt % based on the total amount of the host and dopant to form a light-emitting layer having a thickness of 20 nm on the second hole transport layer. Next, compound ET-1 was deposited as an electron buffer layer having a thickness of 5 nm on the light-emitting layer. Next, compound EI-1 and compound ET-1 in another two cells were evaporated at a rate of 1:1 to deposit an electron transport layer having a thickness of 30 nm on the electron buffer layer. Next, after depositing compound EI-1 as an electron injection layer having a thickness of 2 nm, an Al cathode having a thickness of 80 nm was deposited by another vacuum vapor deposition apparatus. Thus, the OLED was produced.

### [Comparative Example 1] Preparation of an OLED Comprising a Compound According to the Present Disclosure

An OLED was produced in the same manner as in Device Example 1, except that compound H2-157 was used alone as the host of the light-emitting layer.

### [Comparative Example 2] Preparation of an OLED Comprising a Compound According to the Present Disclosure

An OLED was produced in the same manner as in Device Example 1, except that compound H1-58 was used alone as the host of the light-emitting layer.

### [Comparative Example 3] Preparation of an OLED Comprising a Compound According to the Present Disclosure

An OLED was produced in the same manner as in Device Example 1, except that compound H2-157 and compound H1-58 were co-deposited and used as the hosts of the light-emitting layer.

The compounds used in Device Example 1 and Comparative Examples 1 to 3 above are shown in the following Table 1.

TABLE 1

| | |
|---|---|
| Hole Injection Layer/ Hole Transport Layer | 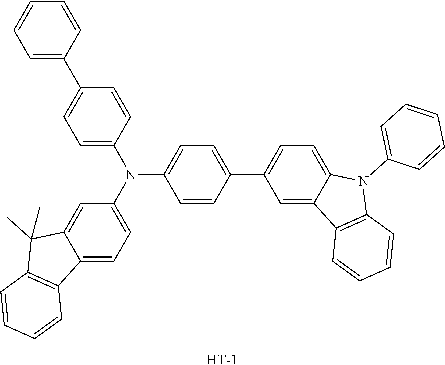 |
| | 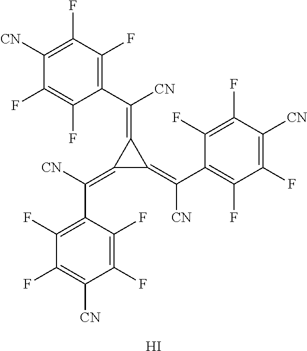 |
| | 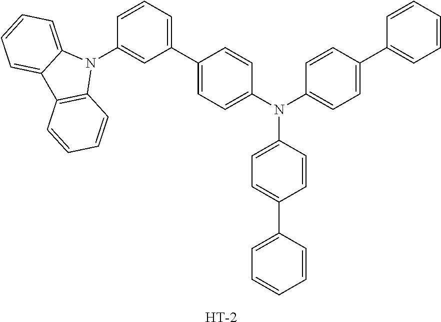 [SMILES: c1ccc(-c2ccc(N(c3ccc(-c4ccccc4)cc3)c3ccc(-c4cccc(-n5c6ccccc6c6ccccc65)c4)cc3)cc2)cc1 ; "HT-2"] |
| Light-Emitting Layer | 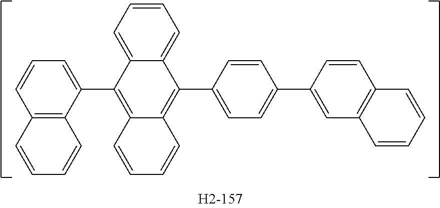 |
| | 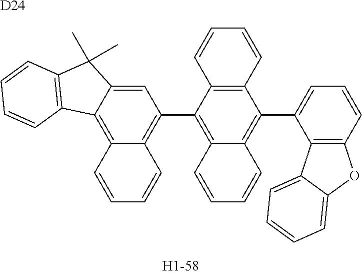 [SMILES: "D24" ; CC1(C)c2ccccc2-c2c1cc(-c1c3ccccc3c(-c3cccc4oc5ccccc5c34)c3ccccc13)c1ccccc21] |
| | 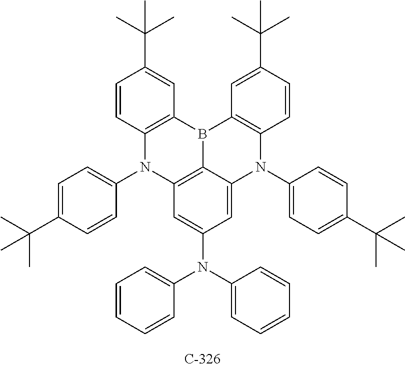 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | 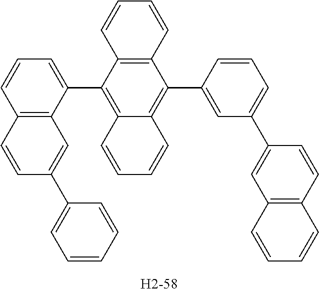 [SMILES: c1ccc(-c2ccc3cccc(-c4c5ccccc5c(-c5cccc(-c6ccc7ccccc7c6)c5)c5ccccc45)c3c2)cc1] |
| | 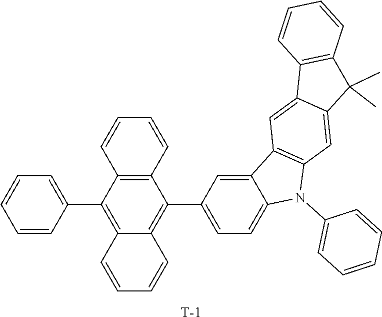 |
| Electron Buffer Layer | 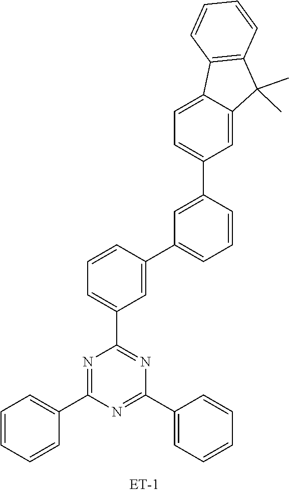 [SMILES: CC1(C)c2ccccc2-c2ccc(-c3cccc(-c4cccc(-c5nc(-c6ccccc6)nc(-c6ccccc6)n5)c4)c3)cc21] |
| Electron Transport Layer/ Electron Injection Layer | 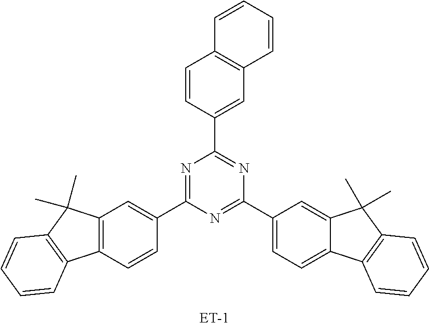 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 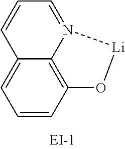 |

### [Device Examples 1-1 to 1-3] Evaluation of Variation with Time During Continuous Process of Host Material of Device Example 1

The forming of a thin film of 2000 A using the plurality of host materials (pre-mix of compounds H2-237 and H1-58) according to Device Example 1 above is referred to as one (1) time, and the deposition was performed three times successively to complete OLEDs according to Device Examples 1-1 to 1-3.

The driving voltage, the current efficiency (cd/A), and the CIE color coordinates at a basis of 1,000 nits, and the minimum time taken to reduce the light intensity from 100% to 95% at a luminance of 1,400 nits (lifespan; T95) of the OLEDs according to Device Examples 1-1 to 1-3 produced as described above, are measured, and the results thereof are shown in the following Table 2.

TABLE 2

| | Driving | Current | CIE Color | | |
|---|---|---|---|---|---|
| | Voltage | Effficienty | Coordinates | | Lifespan |
| | (V) | (cd/A) | x | y | (T95, hr) |
| Device Example | 3.9 | 5.3 | 0.139 | 0.063 | 57 |
| 1-1 | | | | | |
| Device Example | 3.9 | 5.3 | 0.139 | 0.063 | 58 |
| 1-2 | | | | | |
| Device Example | 3.9 | 5.3 | 0.138 | 0.065 | 62 |
| 1-3 | | | | | |

The variation with time during continuous process may be evaluated by seeing how much constantly a ratio among the components forming a film in a continuous process was managed. The variation with time during continuous process was evaluated by examining if single organic electroluminescent compounds constantly maintained a ratio in each thin film of the OLEDs according to Device Examples 1-1 to 1-3 above through a high performance liquid chromatography (HPLC) analysis method. The results thereof are shown in the following Table 3.

TABLE 3

| | H2-237 | H1-58 | H2-237/H1-58 |
|---|---|---|---|
| Device Example | 47.8% | 52.2% | 0.92 |
| 1-1 | | | |
| Device Example | 48:1% | 51.9% | 0.93 |
| 1-2 | | | |
| Device Example | 48.1% | 51.9% | 0.93 |
| 1-3 | | | |

### [Comparative Examples 3-1 to 3-3] Evaluation of Variation with Time During Continuous Process of Host Material of Comparative Example 3

Using the plurality of host materials (simple-mix of compound H2-237 and compound HI-58) according to Comparative Example 3 above, the continuous process was performed in the same manner as in Device Examples 1-1 to 1-3, to complete each of OLEDs of Comparative Examples 3-1 to 3-3.

The variation with time during continuous process was evaluated by examining if the ratio of the components constituting each thin film constantly maintained in the OLEDs according to Device Examples 3-1 to 3-3 above through a HPLC analysis method. The results thereof are shown in the following Table 4.

TABLE 4

| | H2-237 | H1-58 | H2-237/ H1-58 |
|---|---|---|---|
| Comparative | 33.8% | 66.2% | 0.51 |
| Example 3-1 | | | |
| Comparative | 42.1% | 57.9% | 0.73 |
| Example 3-2 | | | |
| Comparative | 49.2% | 50.8% | 0.97 |
| Example 3-3 | | | |

Referring to Tables 3 and 4, it can be seen that the ratio of single organic electroluminescent compounds, that is, H2-237/H1-58, is maintained almost constant in the thin film made of the host material according to Device Example 1, compared to the thin film made of the host material according to Comparative Example 3. From this, when a thin film is formed by using a plurality of host materials according to the present disclosure through a pre-mix, compared to the case of forming a thin film using a simple mixture, it is possible to form a reproducible thin film during a continuous process.

### [Comparative Example 4] Preparation of an OLED Comprising a Compound According to the Present Disclosure

An OLED was produced in the same manner as in Device Example 1, except that compound H2-58 (Tm: 315° C., Td: 310° C.) and compound T-1 (Tm: 331° C., Td: 325° C.) were pre-mixed and used as the host of the light-emitting layer.

### [Comparative Examples 4-1 to 4-3] Evaluation of Variation with Time During Continuous Process of Host Material of Comparative Example 4

Using the pre-mix host material (pre-mix of compound H2-58 and compound T-1) according to Comparative Example 4 above, a continuous process was performed in the same manner as in Comparative Examples 3-1 to 3-3, to complete each of OLEDs of Comparative Examples 4-1 to 4-3.

The variation with time during continuous process was evaluated by examining if the ratio of the components constituting each thin film constantly maintained in the OLEDs according to Device Examples 4-1 to 4-3 above through a HPLC analysis method. The results thereof are shown in the following Table 5.

TABLE 5

| | H2-58 | T-1 | H2-58/T-1 |
|---|---|---|---|
| Comparative | 46.2% | 53.8% | 0.86 |
| Example 4-1 | | | |
| Comparative | 46.3% | 53.7% | 0.86 |
| Example 4-2 | | | |
| Comparative | 13.1% | 86.9% | 0.15 |
| Example 4-3 | | | |

From Table 5 above, it can be seen that it is difficult to form a reproducible thin film during a continuous process, when a thin film is formed using an insoluble host material (Tm>Td) as a pre-mix host material. From this, it can be seen that a reproducible thin film can be formed during a continuous process, when a thin film is formed through a plurality of host materials according to the present disclosure. Further it can be seen that a reproducible thin film formation is possible during a continuous process, when a thin film is formed using pre-mix, compared to the case of forming a thin film using a simple mixture.

The driving voltage, the current efficiency (cd/A), and the CIE color coordinates at a basis of 1,000 nits, and the minimum time taken to reduce light intensity from 100% to 95% at a luminance of 1,400 nits (lifespan; T95) of the organic electroluminescent device according to Device Example 1 and Comparative Examples 1 to 3 produced as described above, are measured, and the results thereof are shown in the following Table 6.

TABLE 6

| | | Driving | Current | CIE Color | | |
|---|---|---|---|---|---|---|
| | | Voltage | Efficiency | Coordinates | | Lifespan |
| | Host | (V) | (cd/A) | x | y | (T95, hr) |
| Device | H2-237: | 3.9 | 5.3 | 0.139 | 0.063 | 58 |
| Example 1 | H1-58 | | | | | |
| | pre-mix | | | | | |
| Comparative | H2-237 | 4.1 | 5.3 | 0.138 | 0.066 | 87 |
| Example 1 | | | | | | |
| Comparative | H1-58 | 3.7 | 5.0 | 0.139 | 0.065 | 26 |
| Example 2 | | | | | | |
| Comparative | H2-237: | 3.8 | 5.4 | 0.139 | 0.066 | 48 |
| Example 3 | H1-58 | | | | | |
| | co- | | | | | |
| | deposition | | | | | |

In the case of a host material having an excellent efficiency property, it is difficult to have fast voltage properties. In the case of a host material having a fast voltage property, it is difficult to have excellent efficiency properties. Thus, it is difficult to develop a single host material that satisfies all of the voltage, efficiency, and lifespan properties. In order to manufacture a fluorescent organic electroluminescent device that satisfies all of these properties, a host having a fast voltage property and a host having an excellent efficiency property should be appropriately selected and mixed. According to the present disclosure, a fluorescence organic electroluminescence with improved driving voltage, efficiency, and lifespan properties by using a plurality of host materials including at least two compounds in the light-emitting layer can be manufactured, compared to the organic electroluminescent device using a single host. In addition, at least one host material included in the plurality of host materials according to the present disclosure is a melting material, and compared to when a simple mixture is used as the host material, when the pre-mix host material is deposited as a light-emitting layer, it can be seen that the process can be improved through the formation of a reproducible thin film since the variation over time during the continuous process can be reduced.

1. A plurality of host materials comprising at least two compounds wherein at least one compound(s) included in the plurality of host materials satisfies the following equation (1), and is represented by the following formula (1):
Tm≤Td equation (1)
wherein, Tm is a melting temperature, and Td is a deposition temperature; 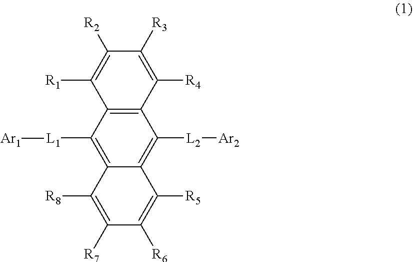
wherein
L₁ and L₂ each independently represent a single bond, a substituted or unsubstituted (C6-C30)arylene, or a substituted or unsubstituted (3- to 30-membered)heteroarylene;
Ar₁ and Ar₂ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C6-C30)aryl, or a substituted or unsubstituted (3- to 30-membered)heteroaryl; and
R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-030) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

2. The plurality of host materials according to claim 1, wherein the compound represented by formula 1 may be represented by any one of the following formulas 1-1 to 1-3, and the plurality of host materials comprise a compound of the following formula 1-1, a compound of the following formula 1-2, a compound of the following formula 1-3, or a combination thereof: 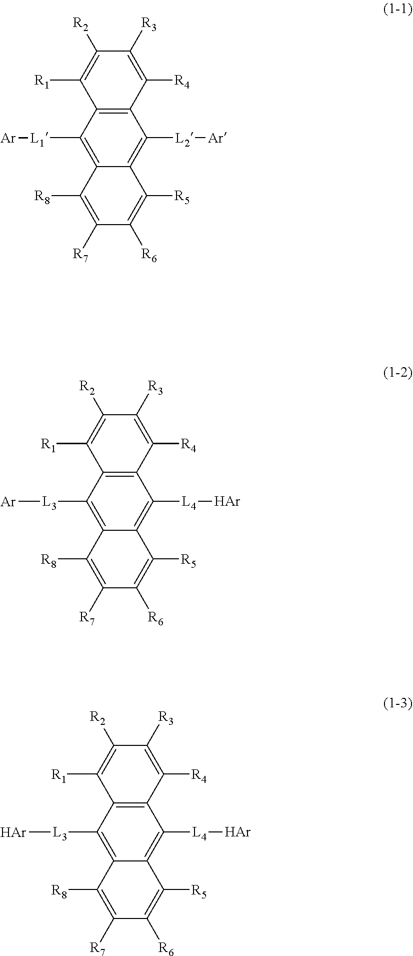
wherein
L₁′, L₂′, L₃, and L₄ each independently represent a single bond or a substituted or unsubstituted (C6-C30)arylene;
Ar and Ar′ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted (C6-C30)aryl;
HAr represents a substituted or unsubstituted (3- to 30-membered)heteroaryl; and
R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

3. The plurality of host materials according to claim 2, wherein HAr is represented by any one of the following formulas 1-1-1 to 1-1-10: 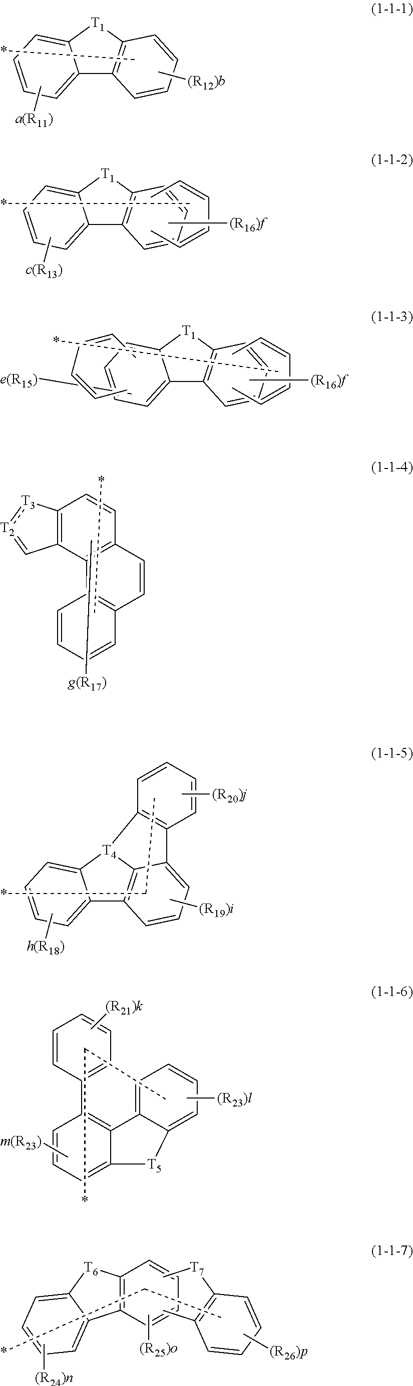 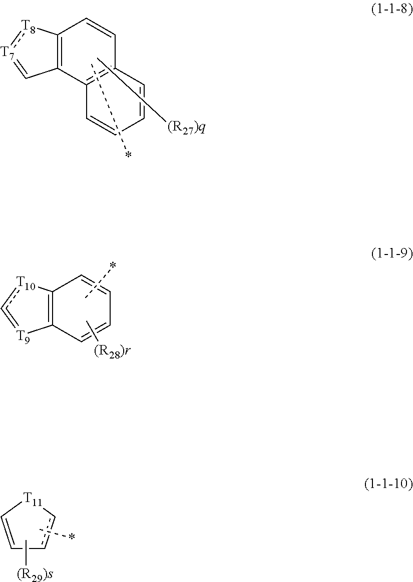
wherein
T₁, T₅, T₈, T₉, and T₁₀ each independently represent —N-L₅-Ar₅, O, or S;
T₂, T₃, T₇, and T₈ each independently represent —N═, —NR—, —O—, or —S—; provided that T and T₇ are —N═, T₃ and T₈ each independently represent —NR—, —O—, or —S—;
T₄ represents N;
T₁₁ represents O or S;
L₅ represents a single bond, a substituted or unsubstituted (C6-C30)arylene, or a substituted or unsubstituted (3- to 30-membered)heteroarylene;
Ar₅ represents a substituted or unsubstituted (C6-C30)aryl or a substituted or unsubstituted (3- to 30-membered)heteroaryl;
R₁₁ to R₂₉ each independently represent hydrogen, deuterion, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino;
o represents an integer of 1 or 2; i, l, and m each independently represent an integer of 1 to 3; a to c, h, j, k, n, p, r, and s each independently represent an integer of 1 to 4; d, e, f, and q each independently represent an integer of 1 to 6; and g represents an integer of 1 to 8; and when a to s are an integer of 2 or more, each of R₁₁ to R₂₉ may be the same or different; and

[symbol]

4. The plurality of host materials according to claim 1, wherein the substituents of the substituted alkyl, the substituted aryl(ene), the substituted heteroaryl(ene), the substituted cycloalkyl, the substituted alkoxy, the substituted triarylsilyl, the substituted trialkylsilyl, the substituted dialkylarylsilyl, the substituted alkyldiarylsilyl, the substituted fused ring of aliphatic ring and aromatic ring, the substituted mono- or di-alkylamino, the substituted mono- or di-alkenylamino, the substituted mono- or di-arylamino, the substituted mono- or di-heteroarylamino, the substituted alkylalkenylamino, the substituted alkylarylamino, the substituted alkylheteroarylamino, the substituted alkenylarylamino, the substituted alkenylheteroarylamino, and the substituted arylheteroarylamino each independently represent at least one selected from the group consisting of deuterium: halogen; cyano; carboxyl; nitro; hydroxy; phosphine oxide; (C1-C30)alkyl; halo(C1-C30)alkyl; (C2-C30)alkenyl; (C2-C30)alkynyl; (C1-C30)alkoxy; (C1-C30)alkylthio; (C3-C30)cycloalkyl; (C3-C30)cycloalkenyl; (3- to 7-membered)heterocycloalkyl; (C6-C30)aryloxy; (C6-C30)arylthio; (5- to 30-membered)heteroaryl unsubstituted or substituted with at least one of (C1-C30)alkyl, (C6-C30)aryl and di(C1-C30)arylamino; (C6-C30)aryl unsubstituted or substituted with at least one of (C1-C30)alkyl, (5- to 30-membered)heteroaryl, and di(C6-C30)arylamino; tri(C1-C30)alkylsilyl; tri(C6-C30)arylsilyl; di(C1-C30)alkyl(C6-C30)arylsilyl; (C1-C30)alkyldi(C6-C30)arylsilyl; amino; mono- or di-(C1-C30)alkylamino; mono- or di-(C6-C30)arylamino unsubstituted or substituted with at least one of (C1-C30)alkyl, (5- to 30-membered)heteroaryl and di(C6-C30)arylamino; (C1-C30)alkyl(C6-C30)arylamino; (C1-C30)alkylcarbonyl; (C1-C30)alkoxycarbonyl; (C6-C30)arylcarbonyl; (C6-C30)arylphosphinyl; di(C6-C30)arylboronyl; di(C1-C30)alkylboronyl; (C1-C30)alkyl(C6-C30)arylboronyl; (C6-C30)ar(C1-C30)alkyl; and (C1-C30)alkyl(C6-C30)aryl.

5. The plurality of host materials according to claim 1, wherein the compound represented by formula 1 is selected from the following compounds: 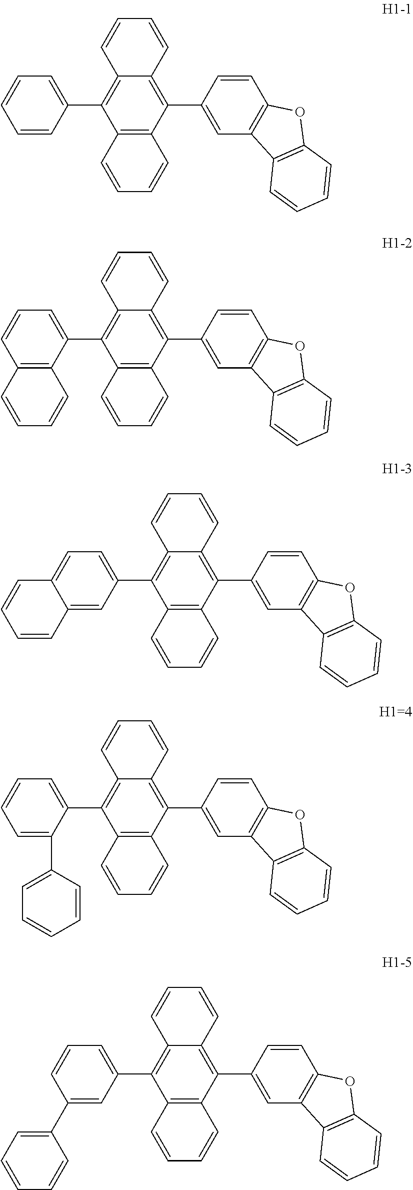 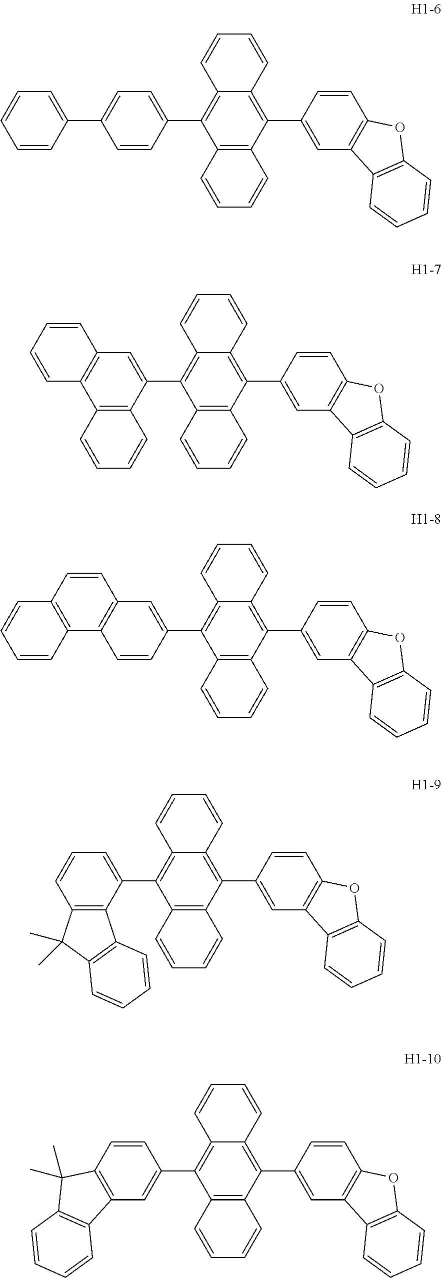 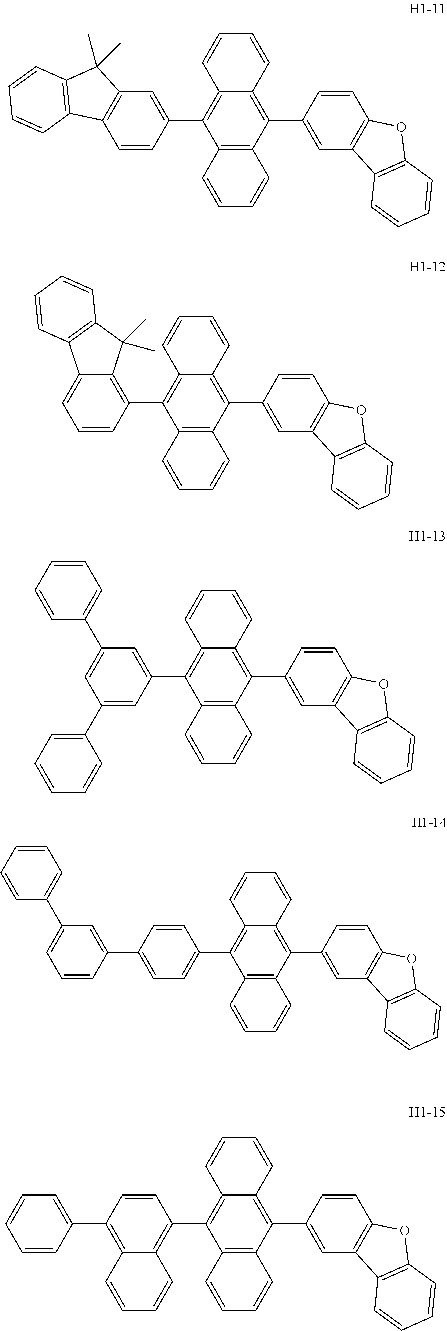 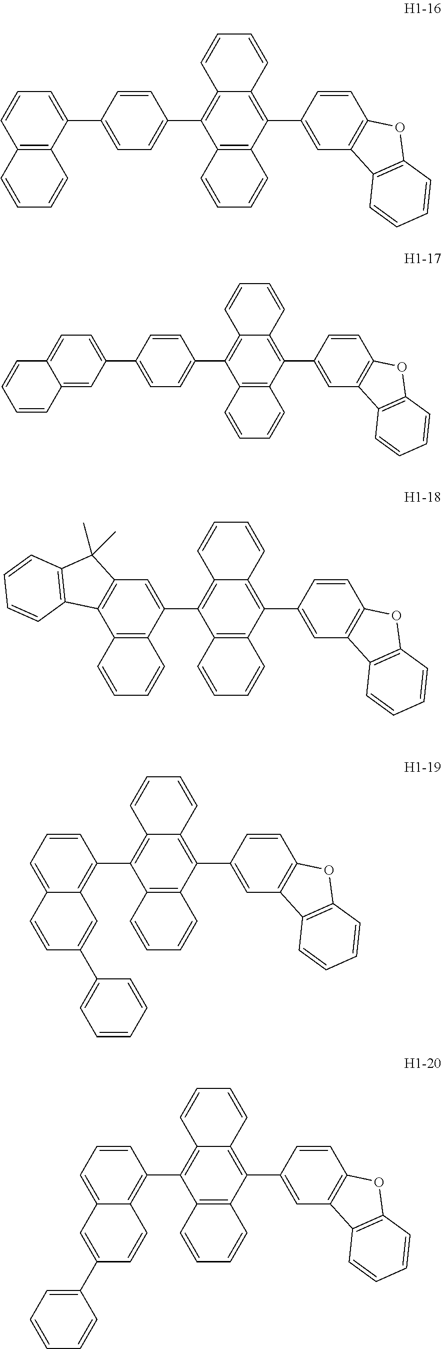 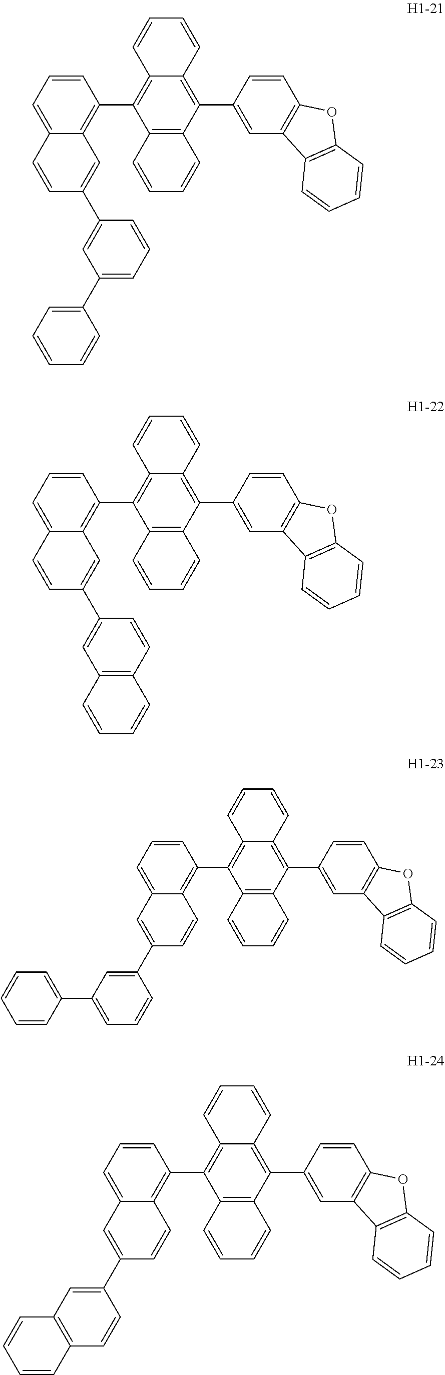 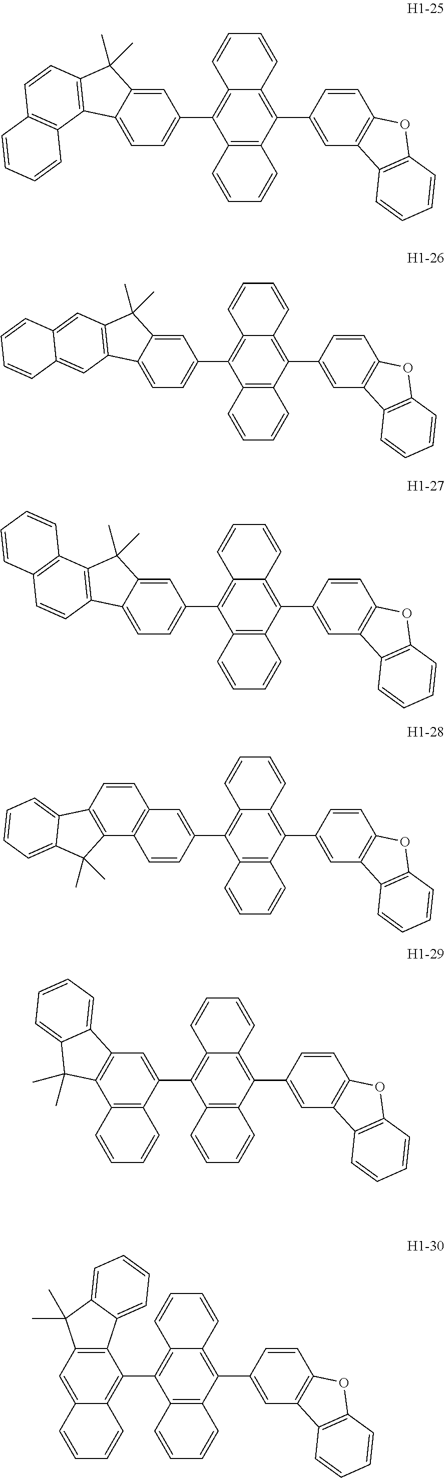 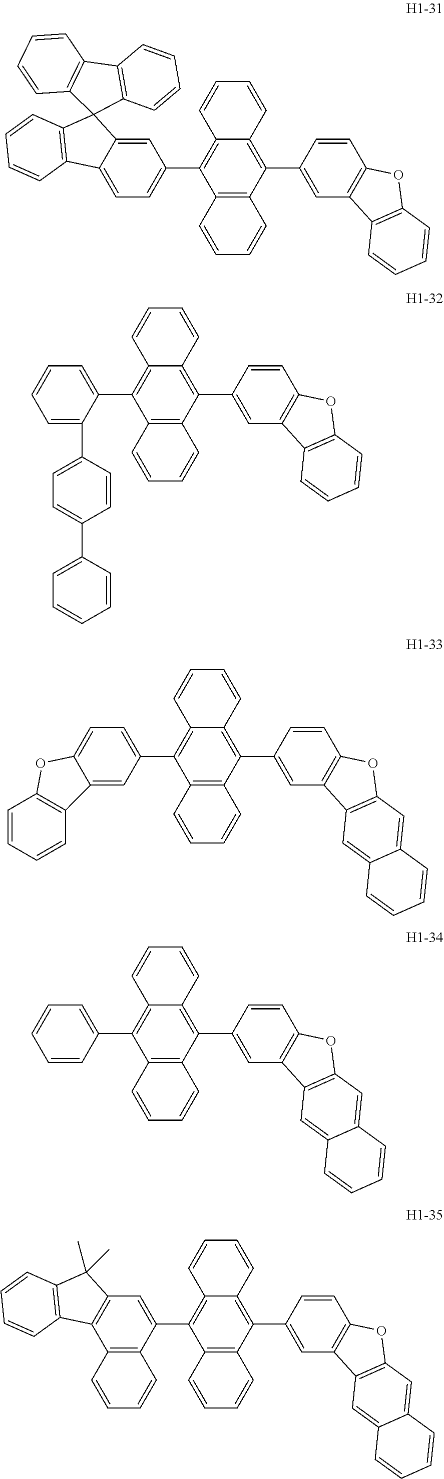 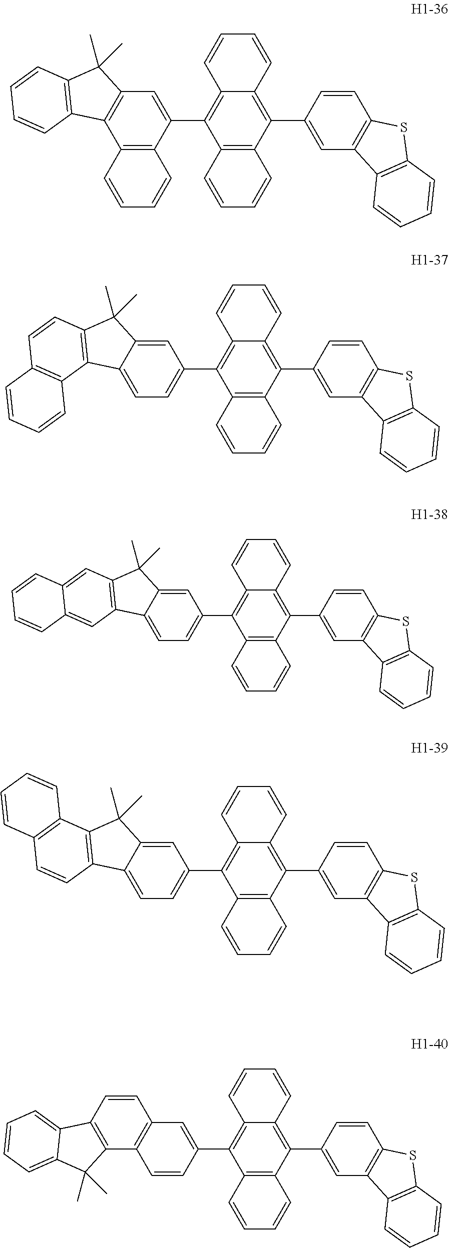 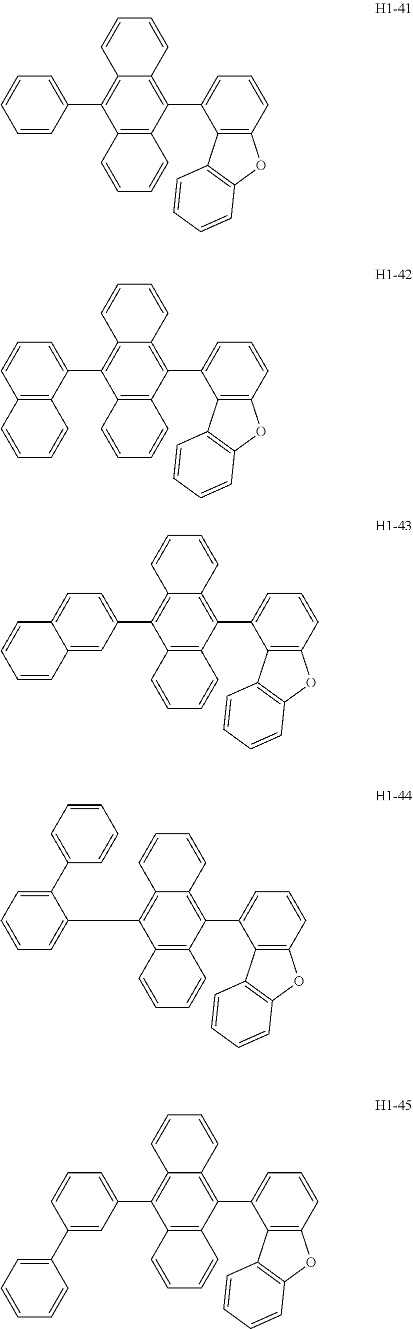 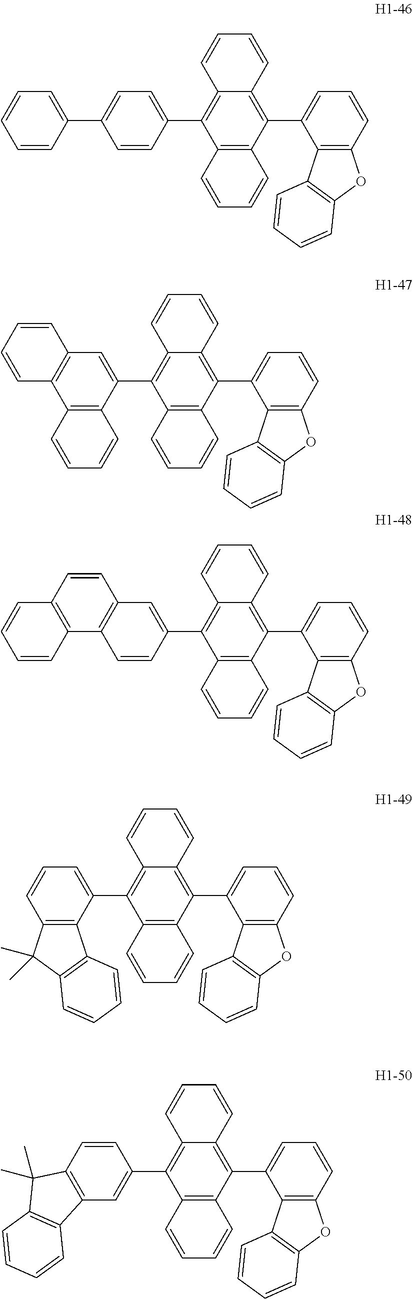 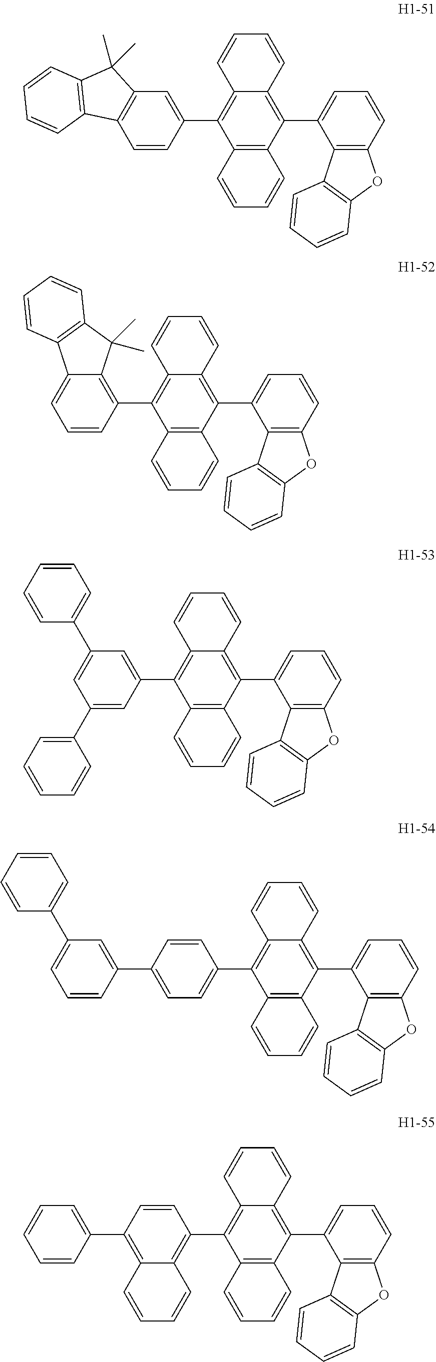 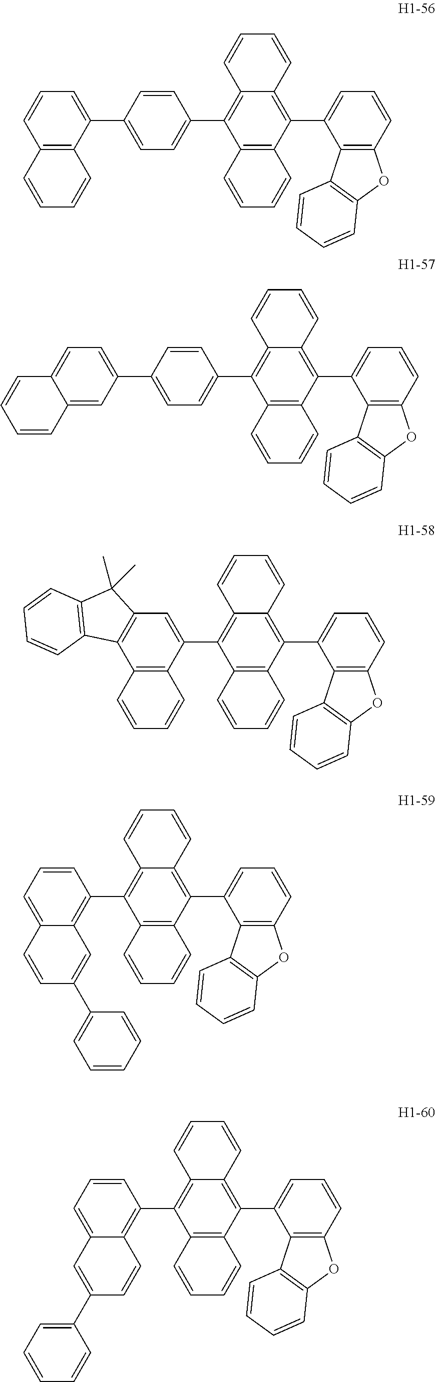 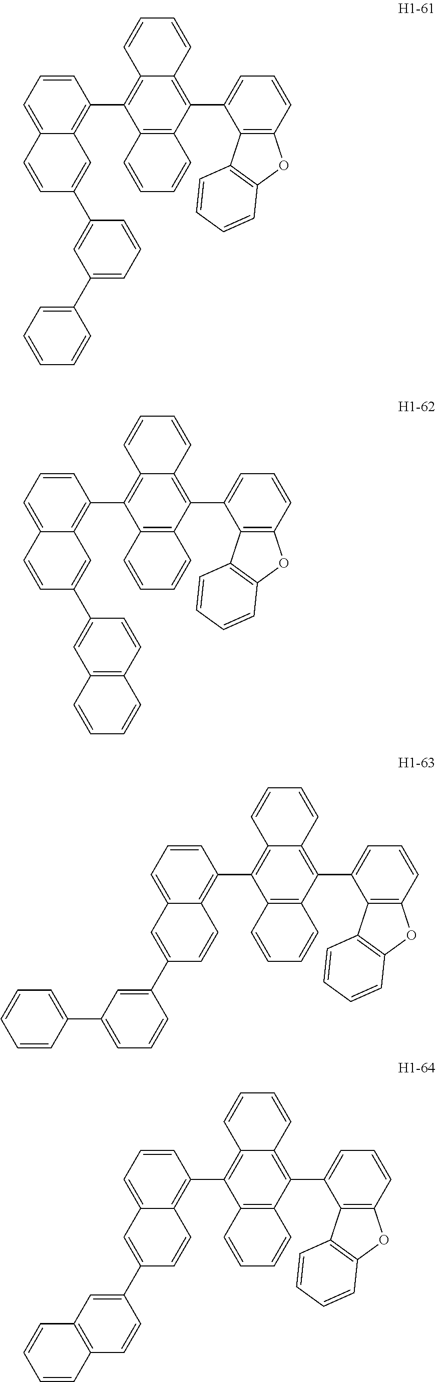 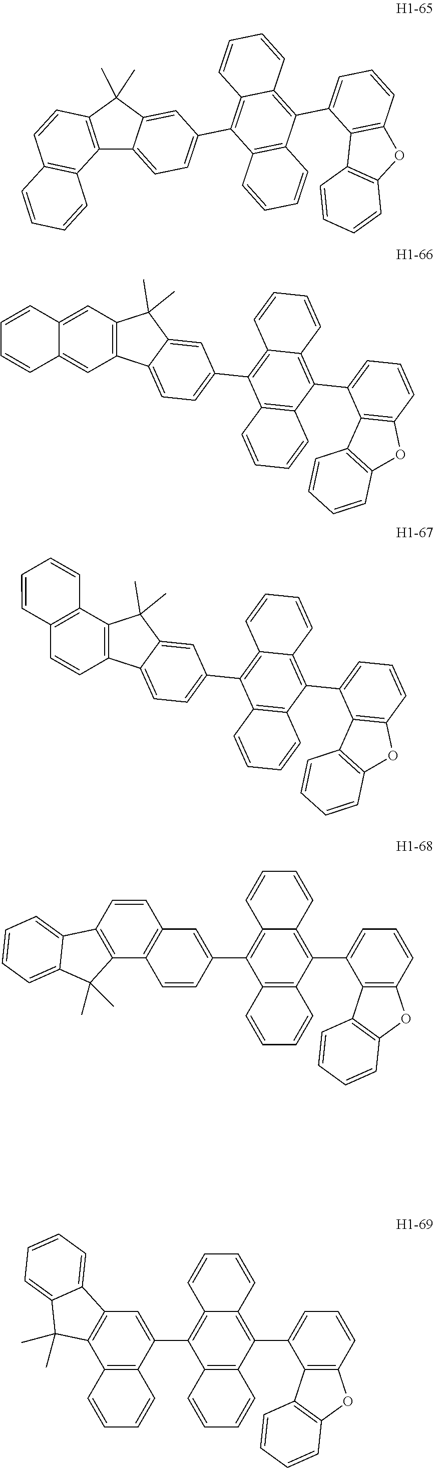 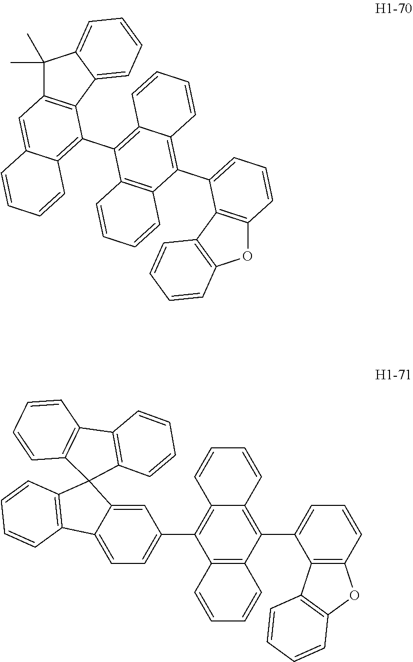 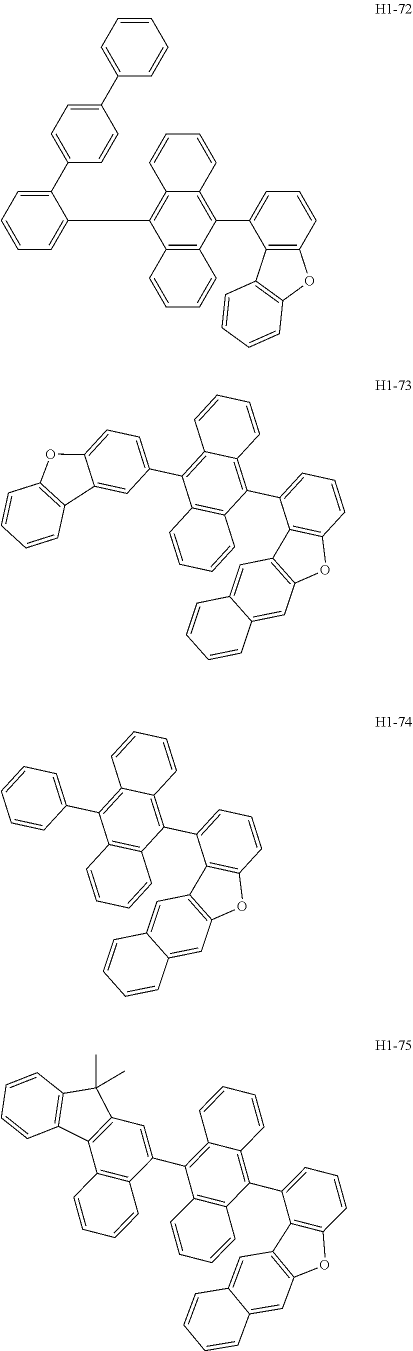 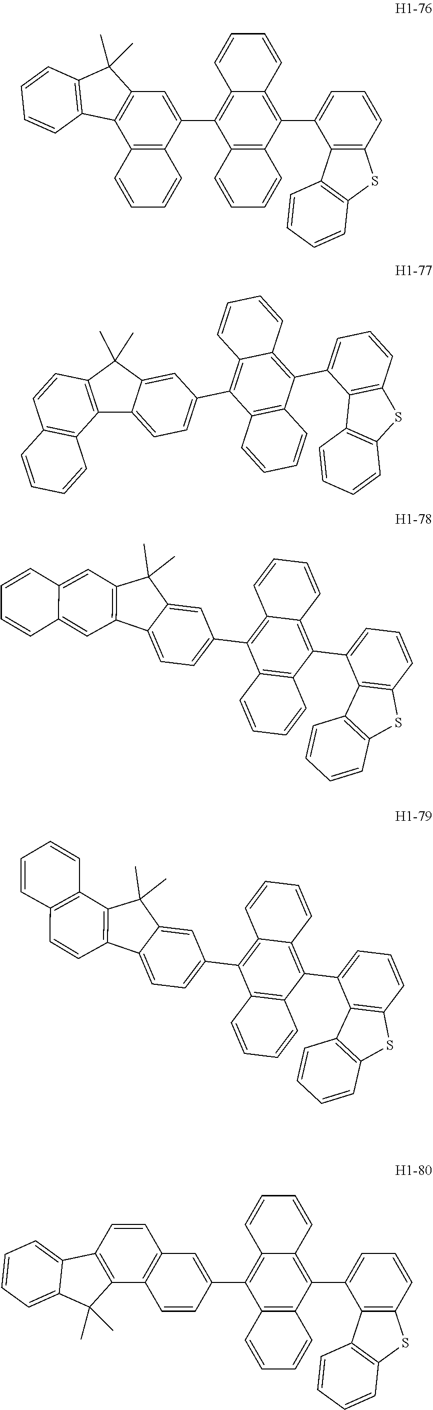 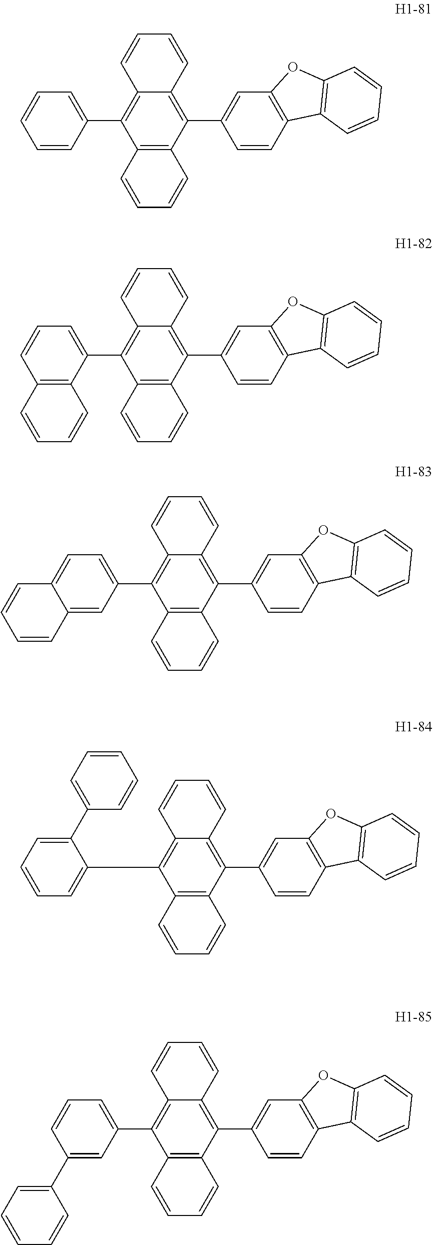 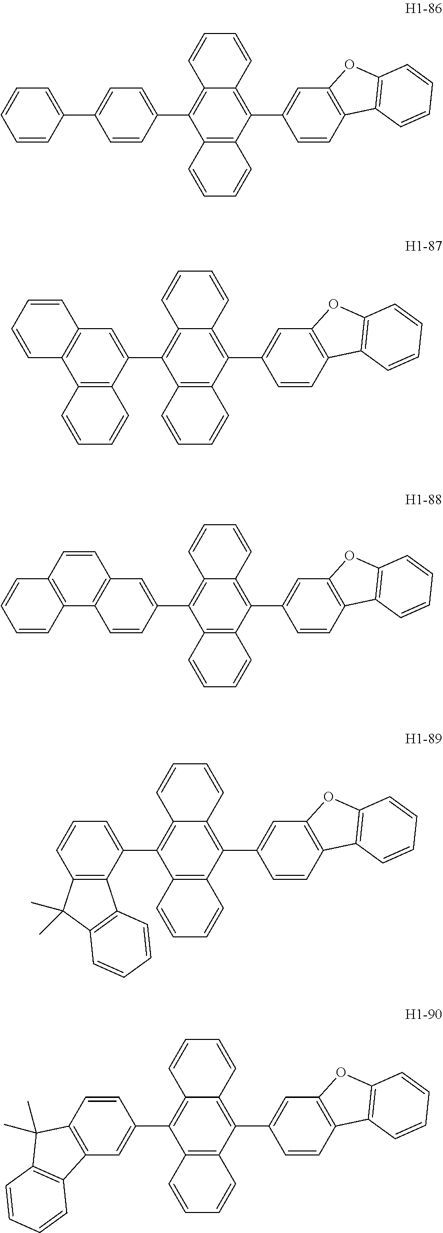 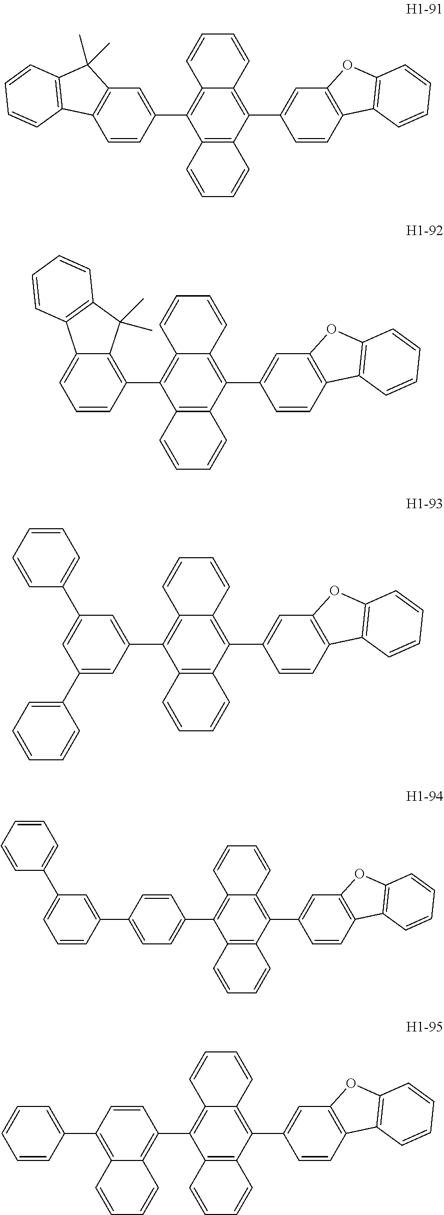 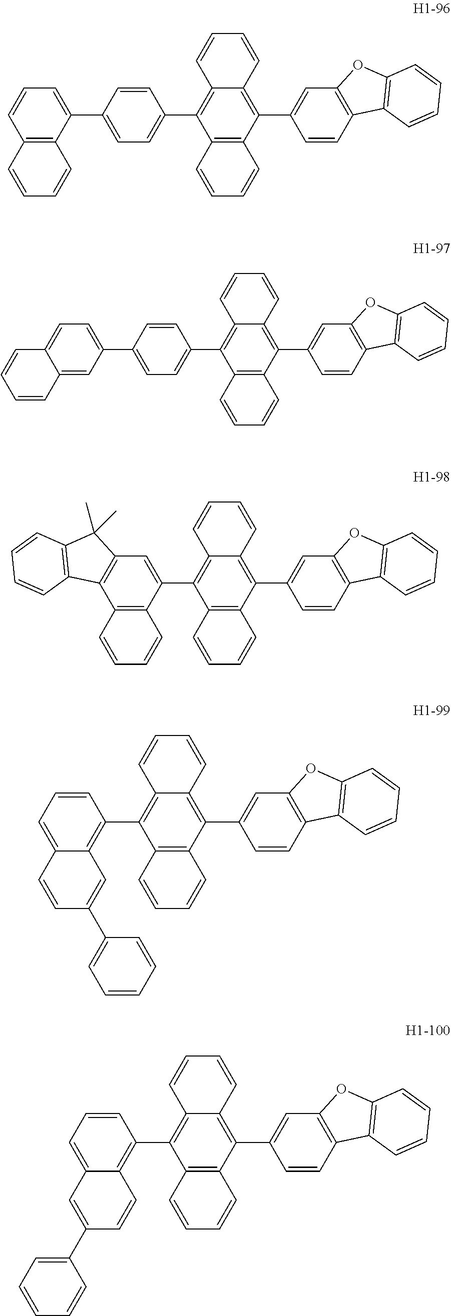 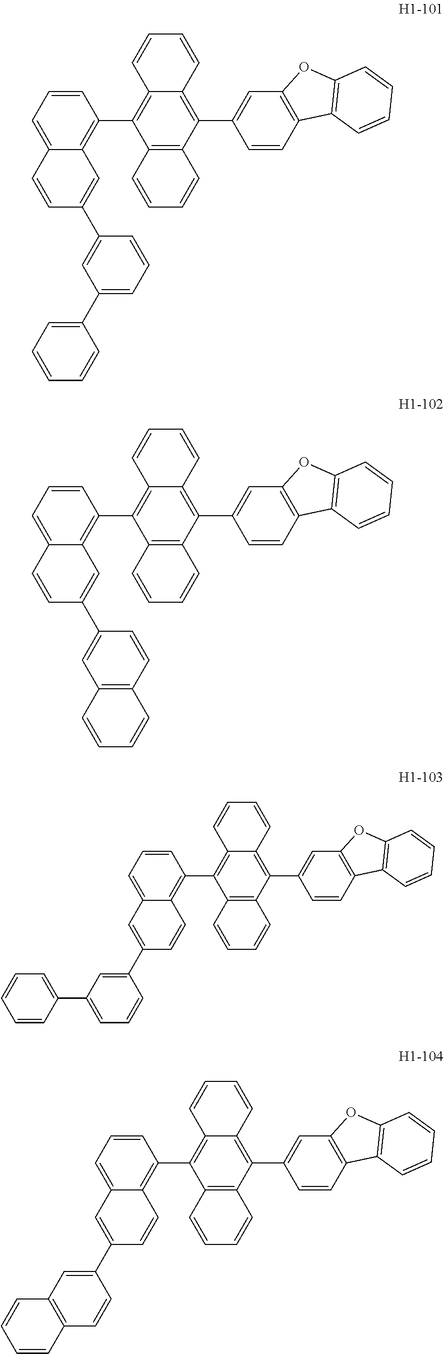 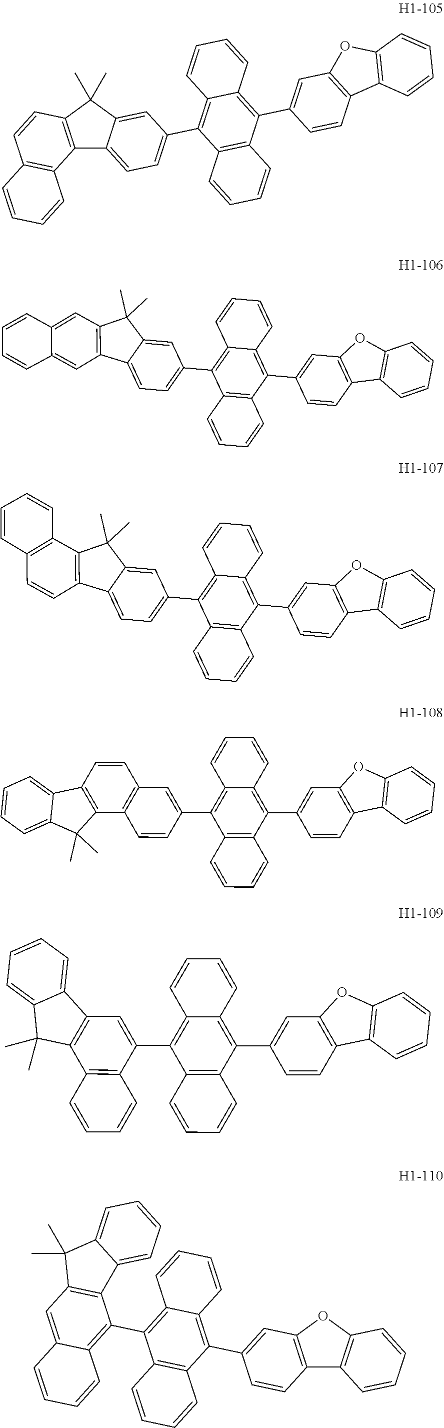 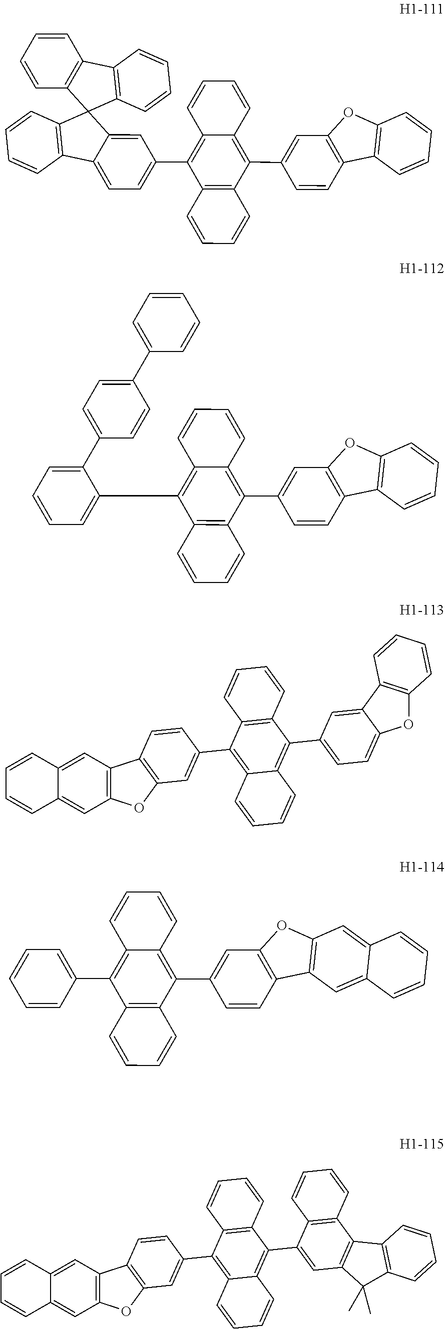 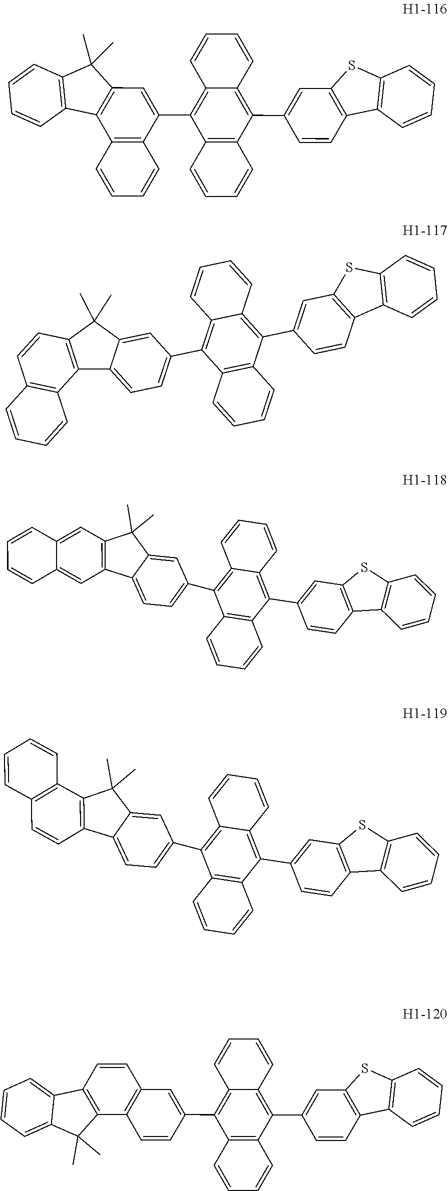 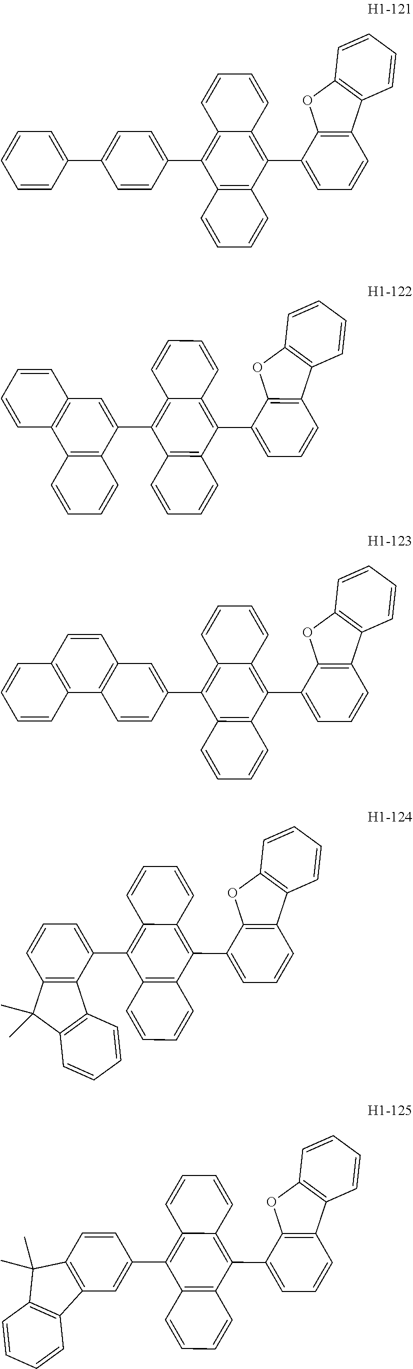 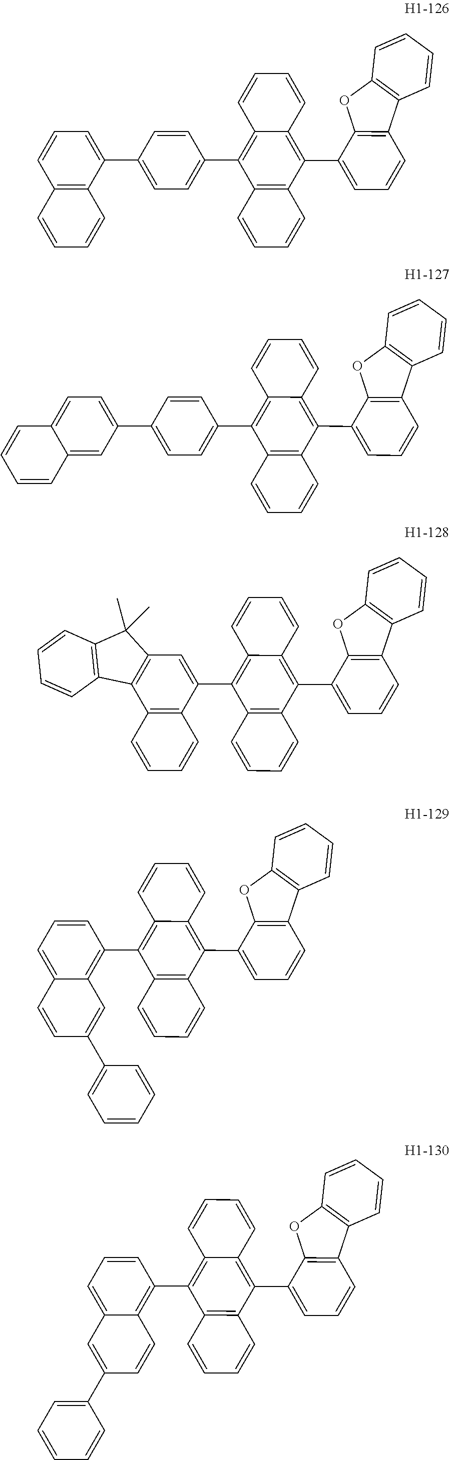 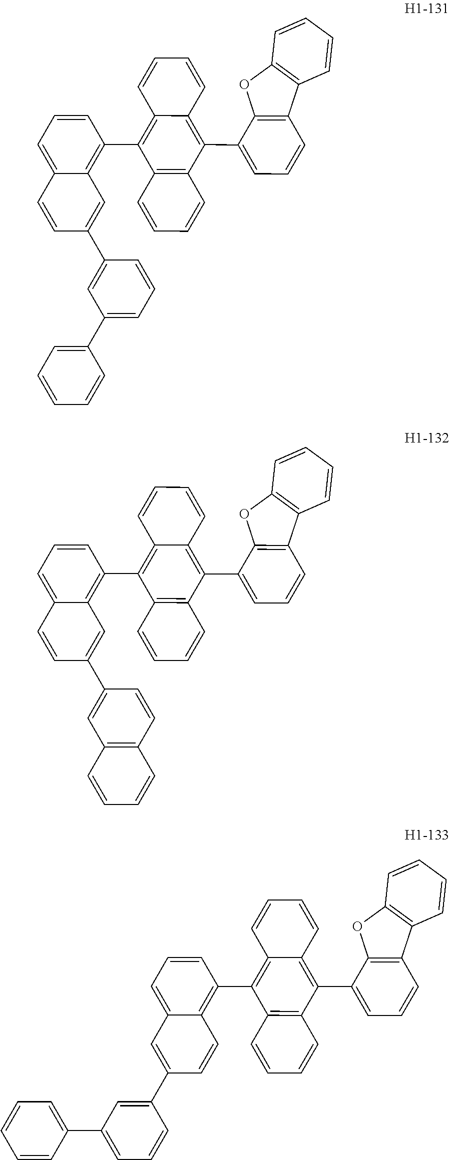 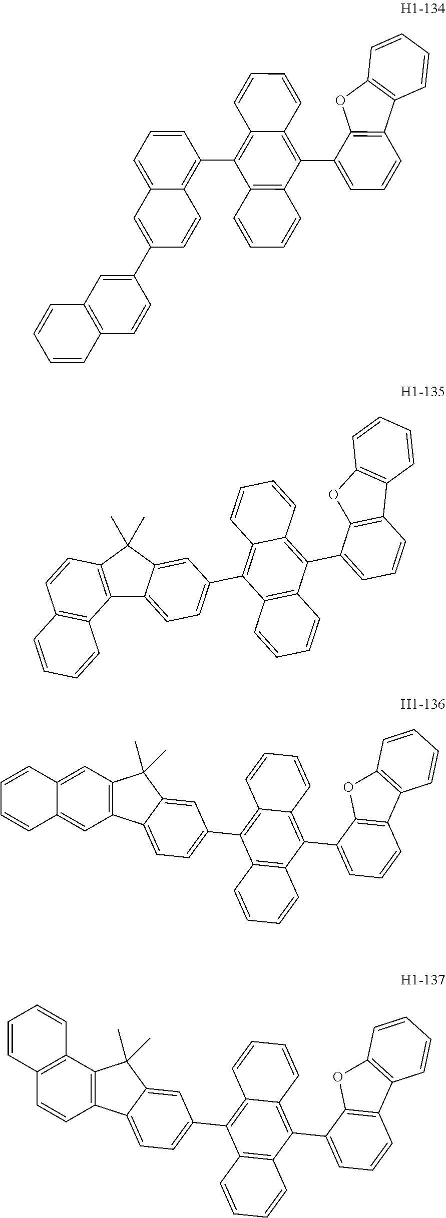 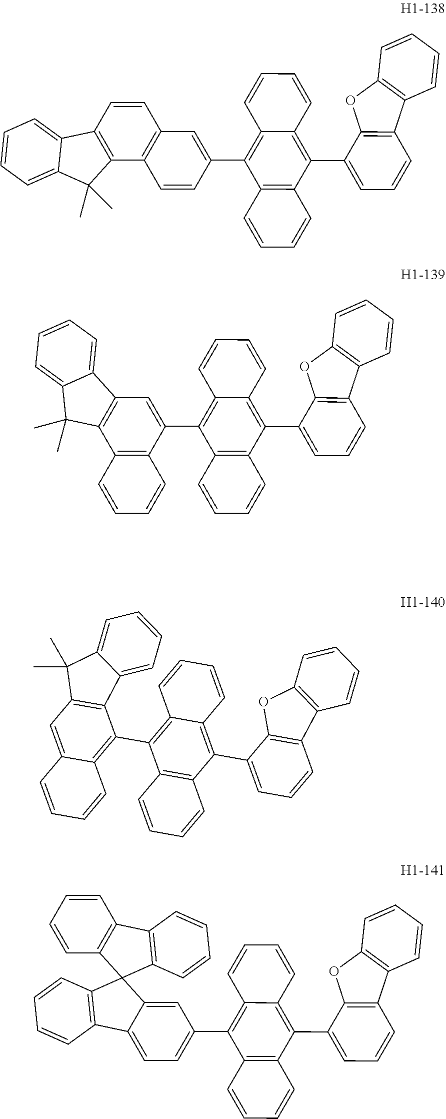 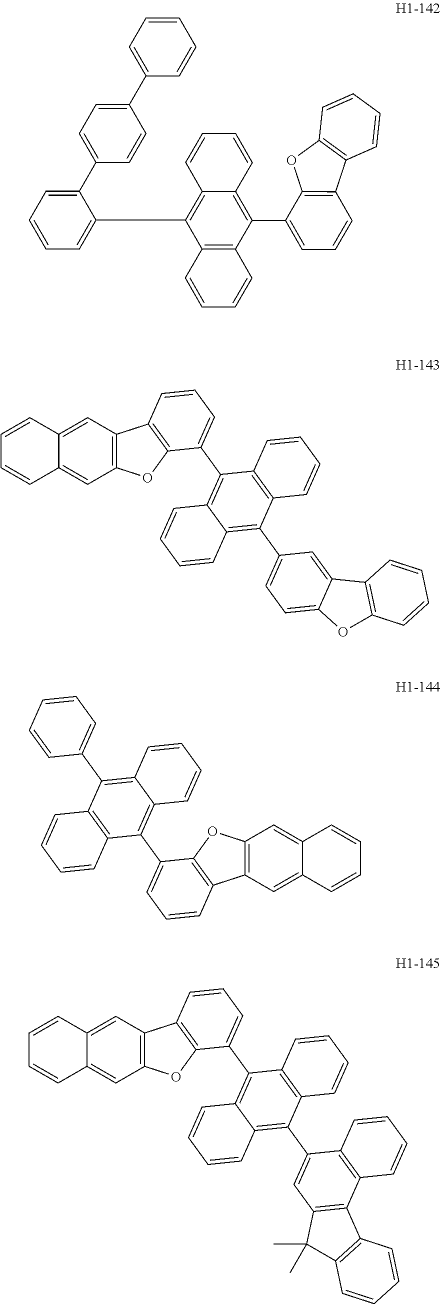 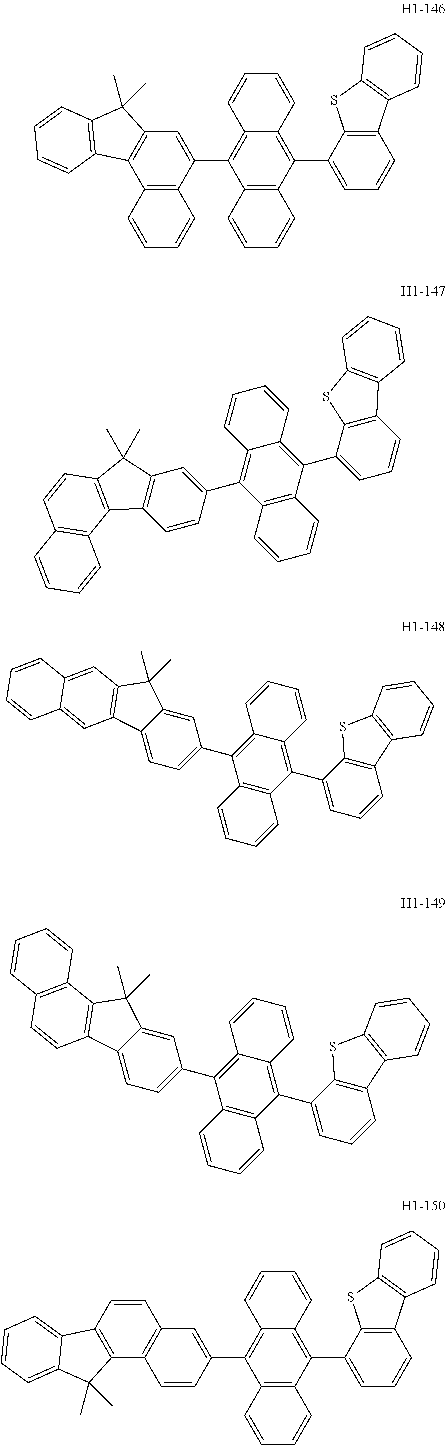 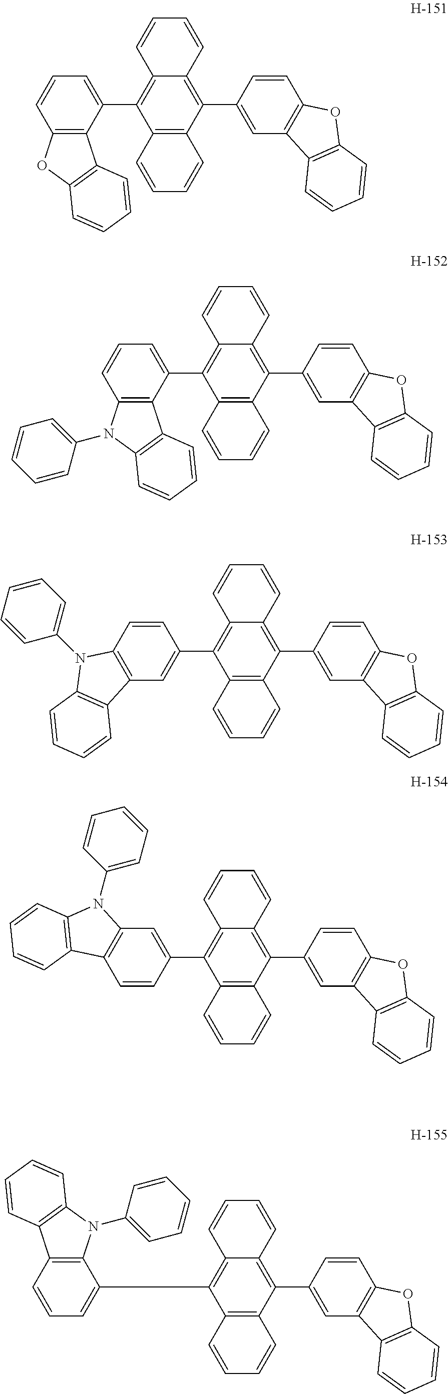 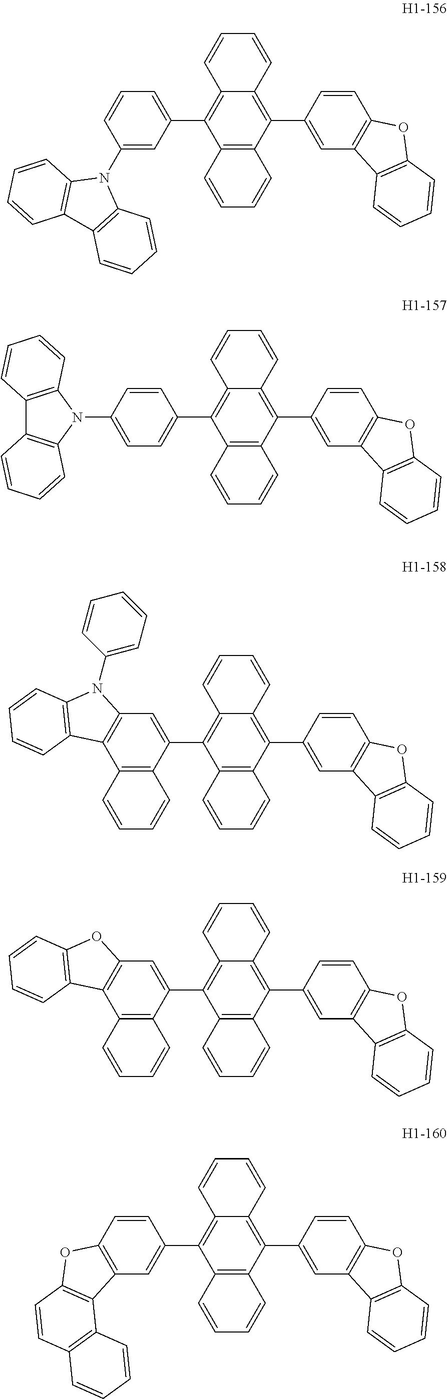 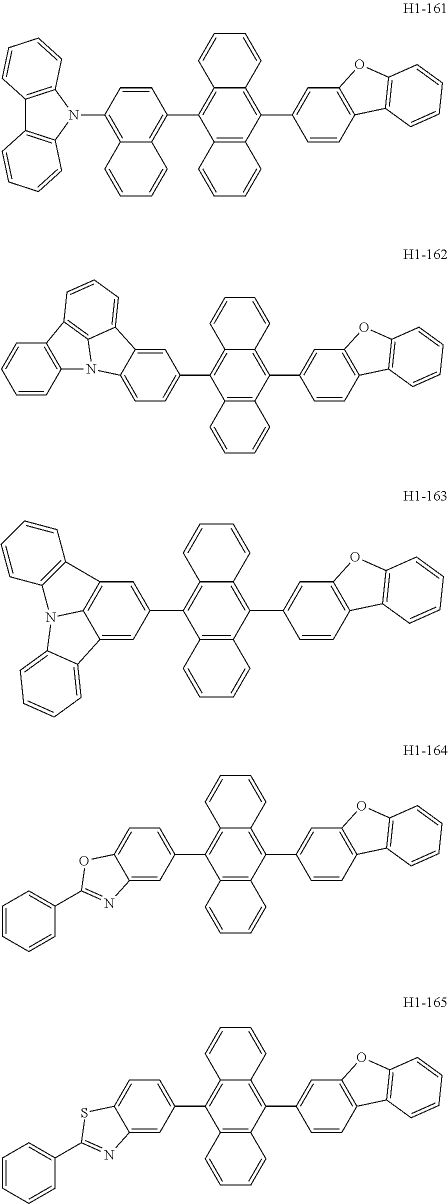 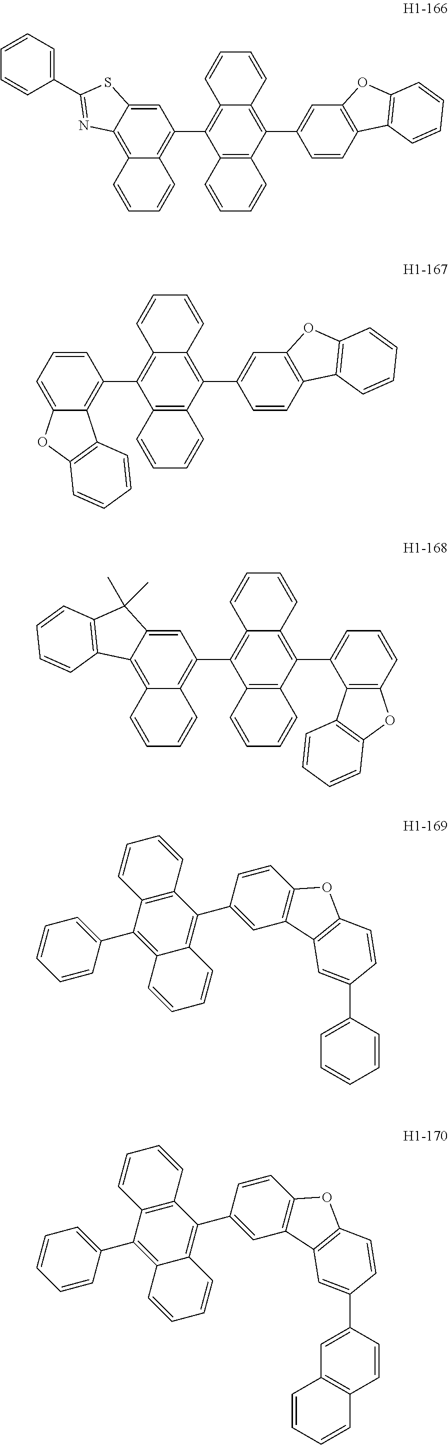 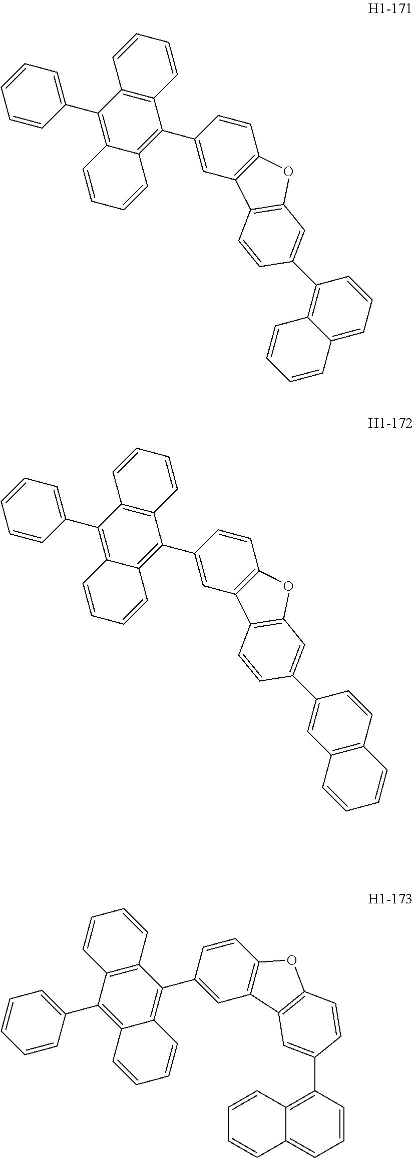 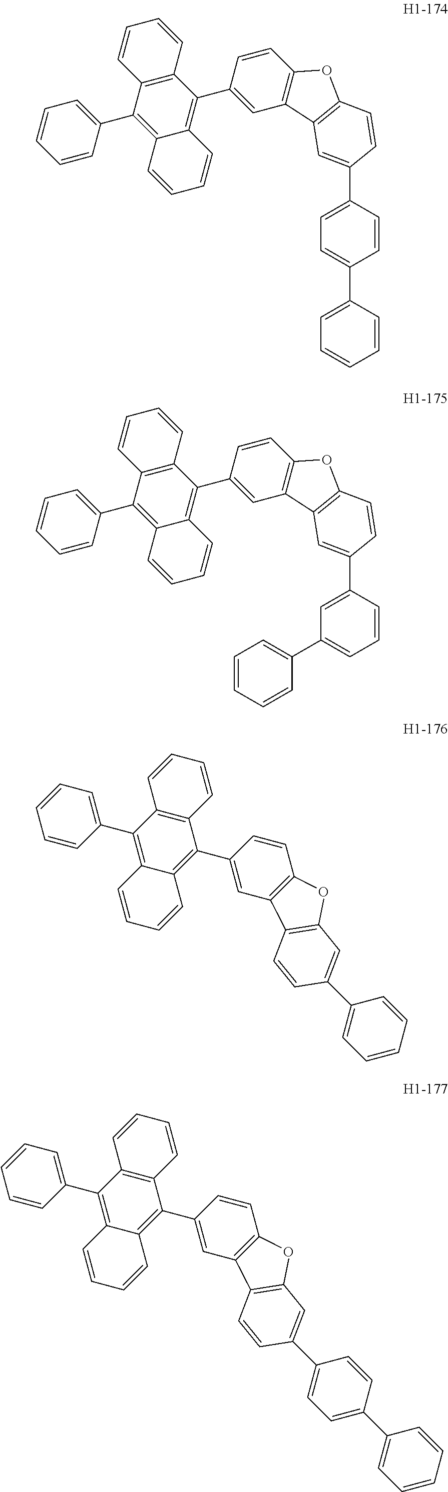 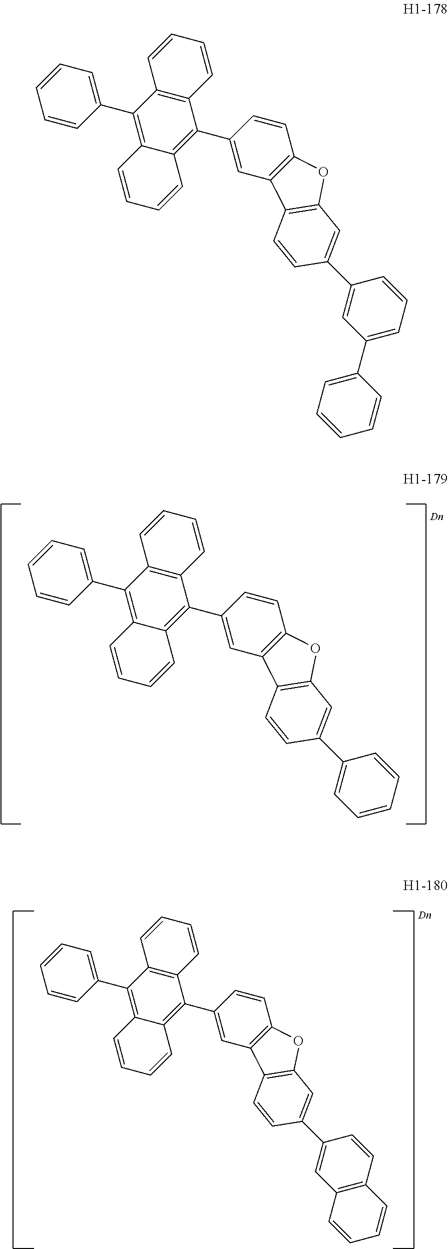 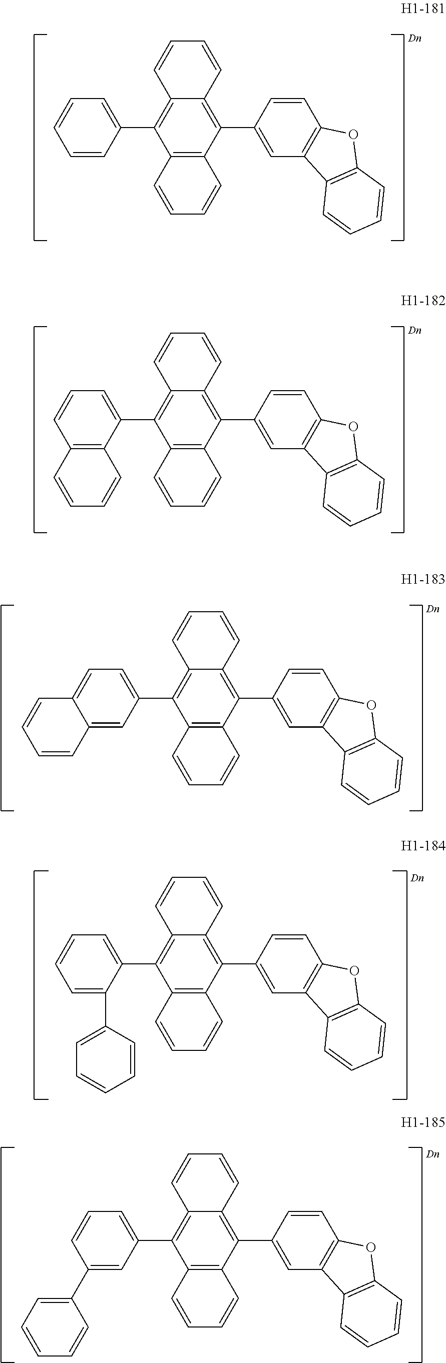 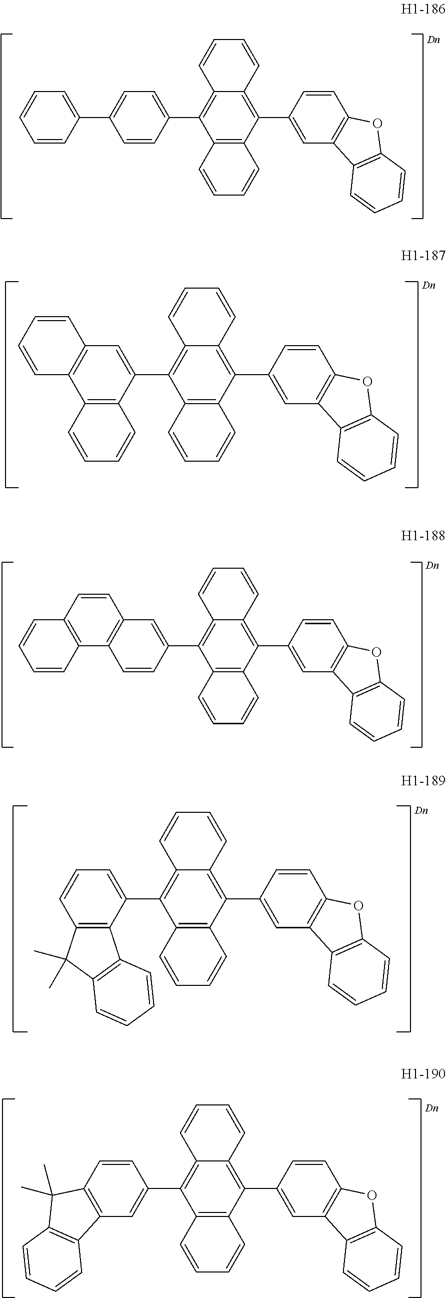 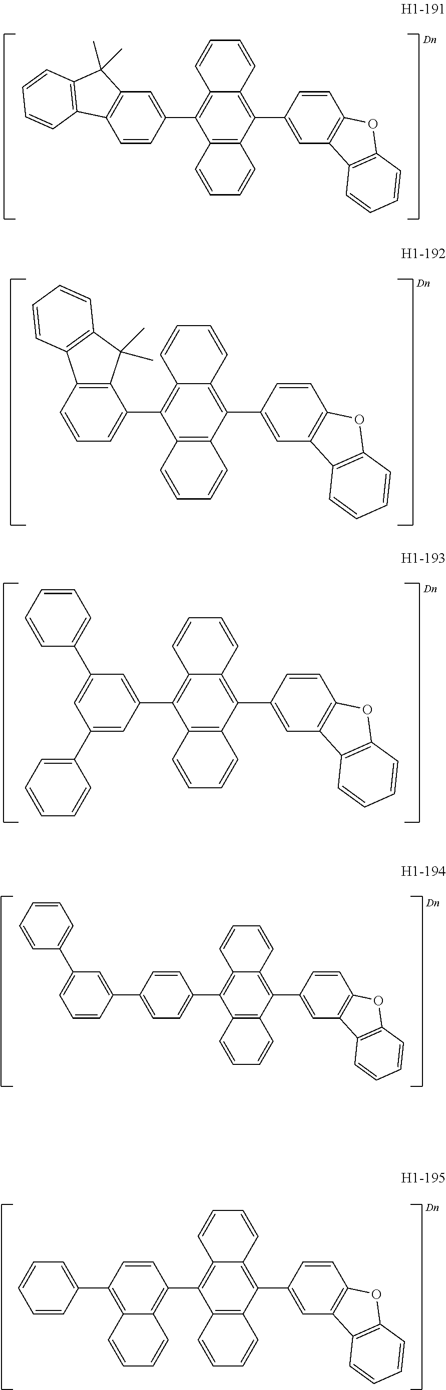 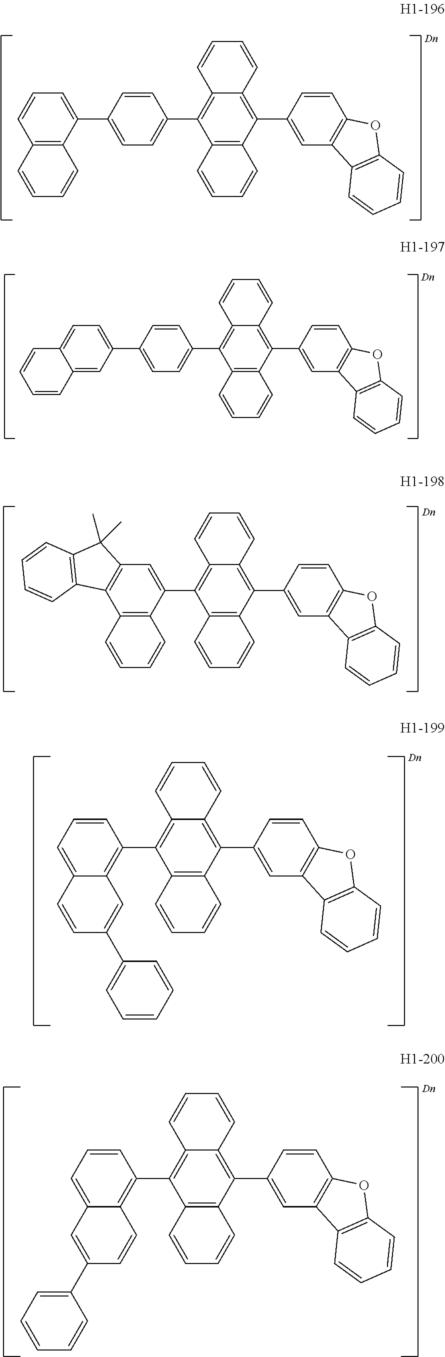 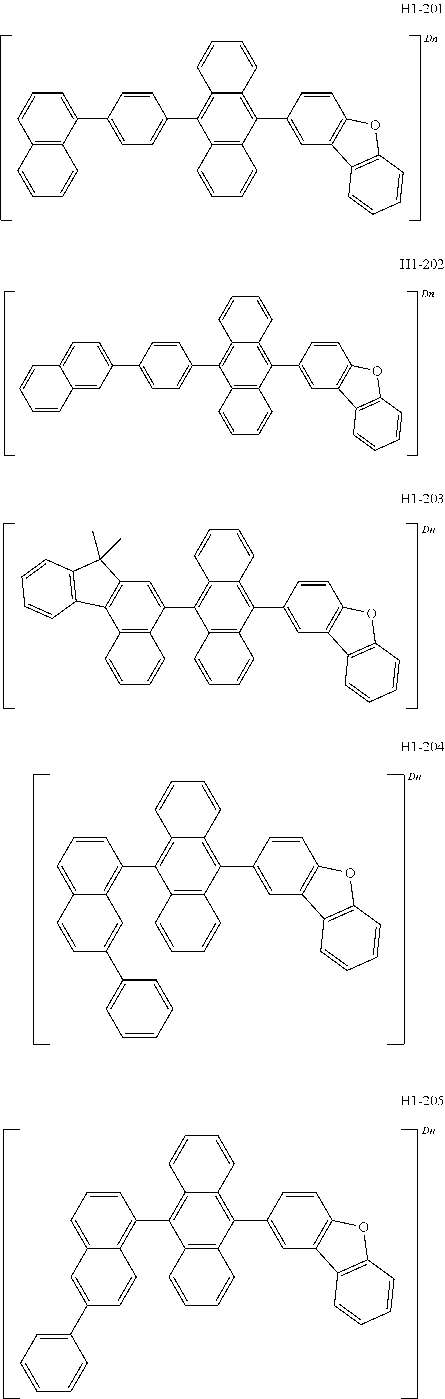 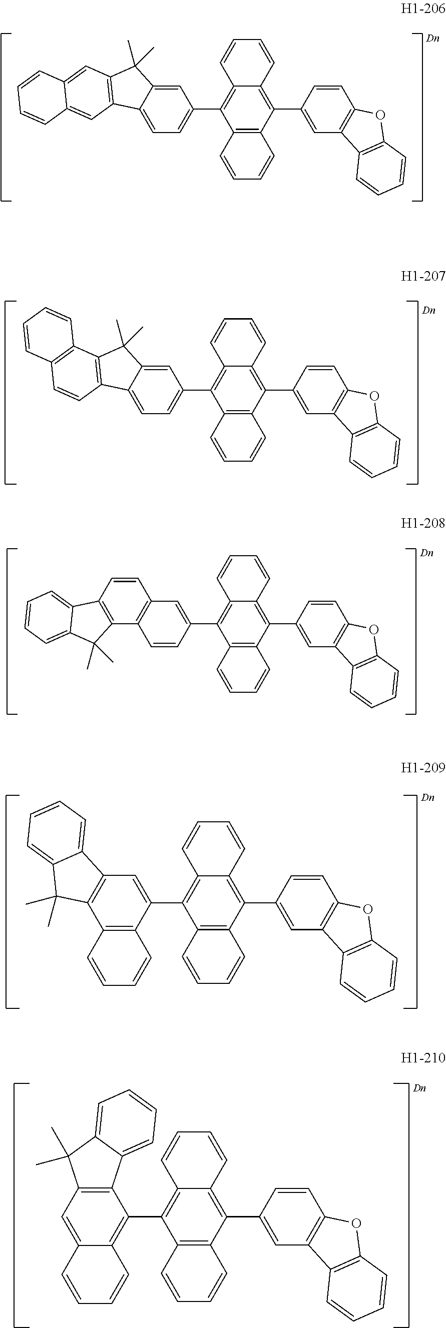 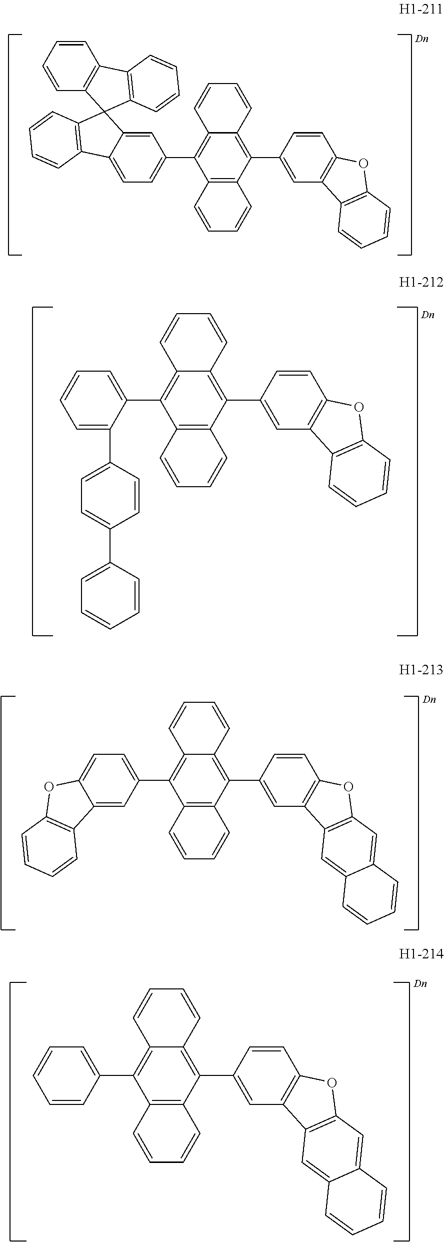 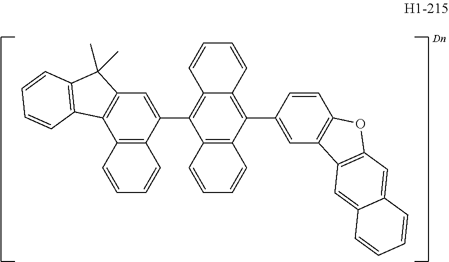 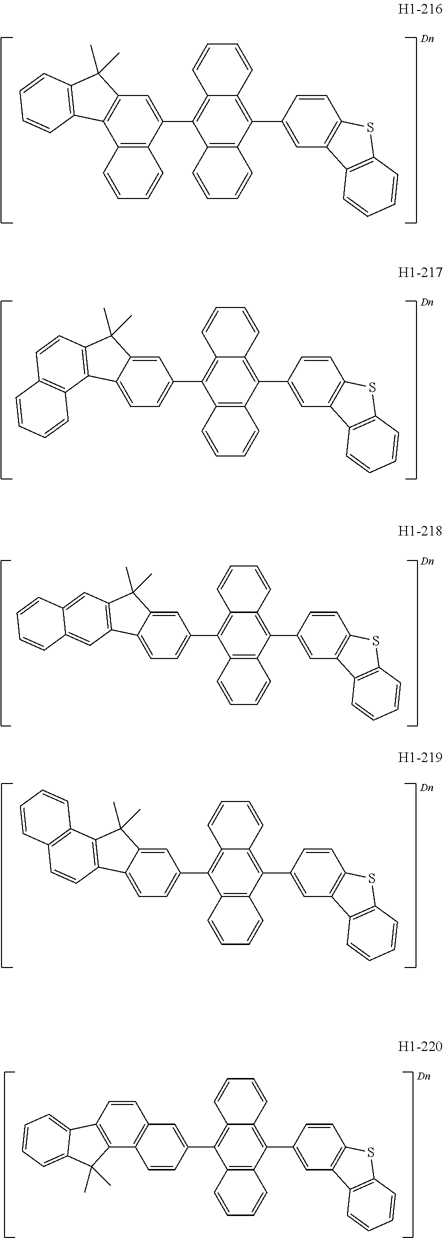 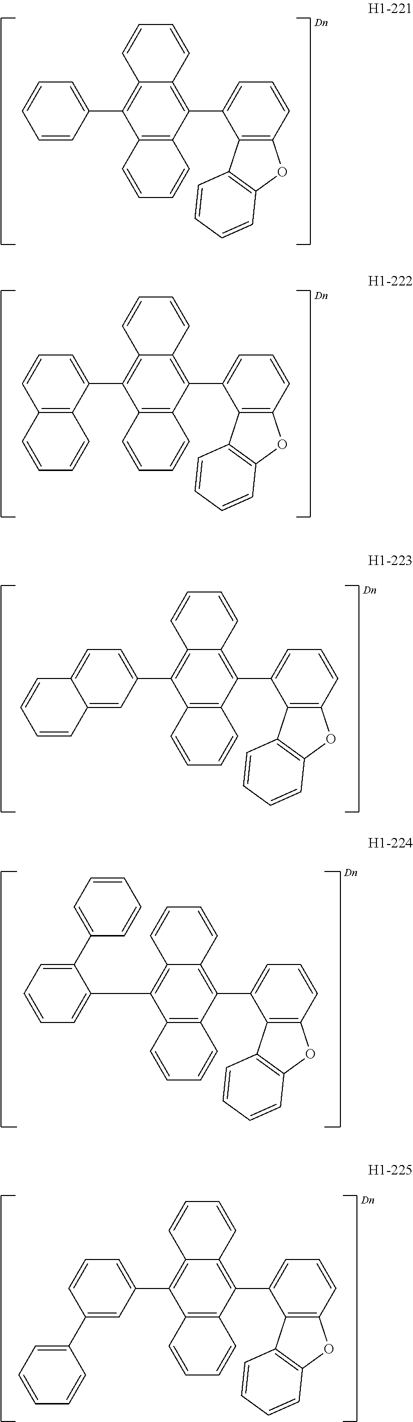 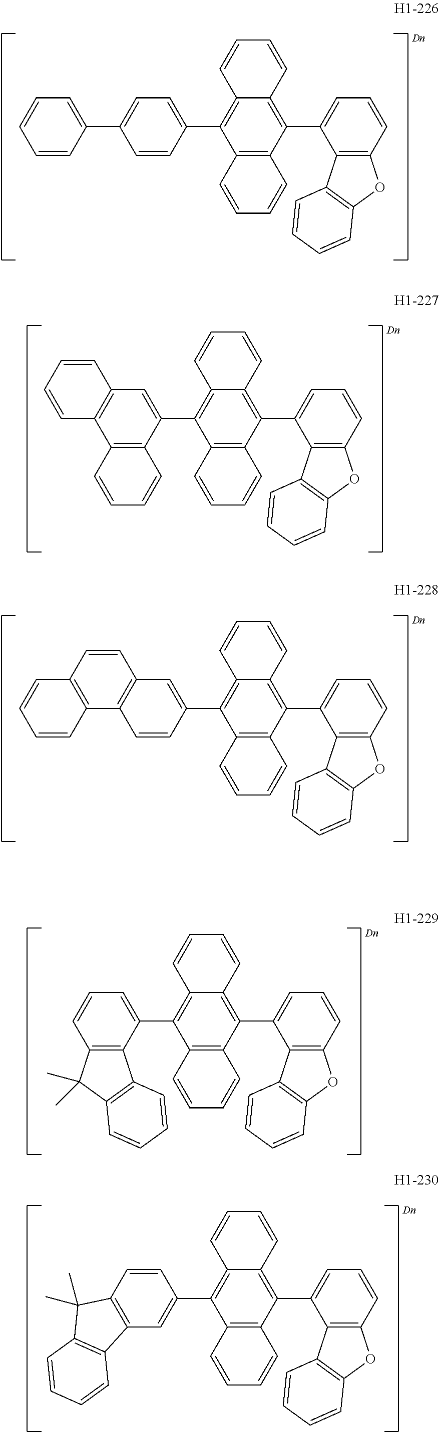 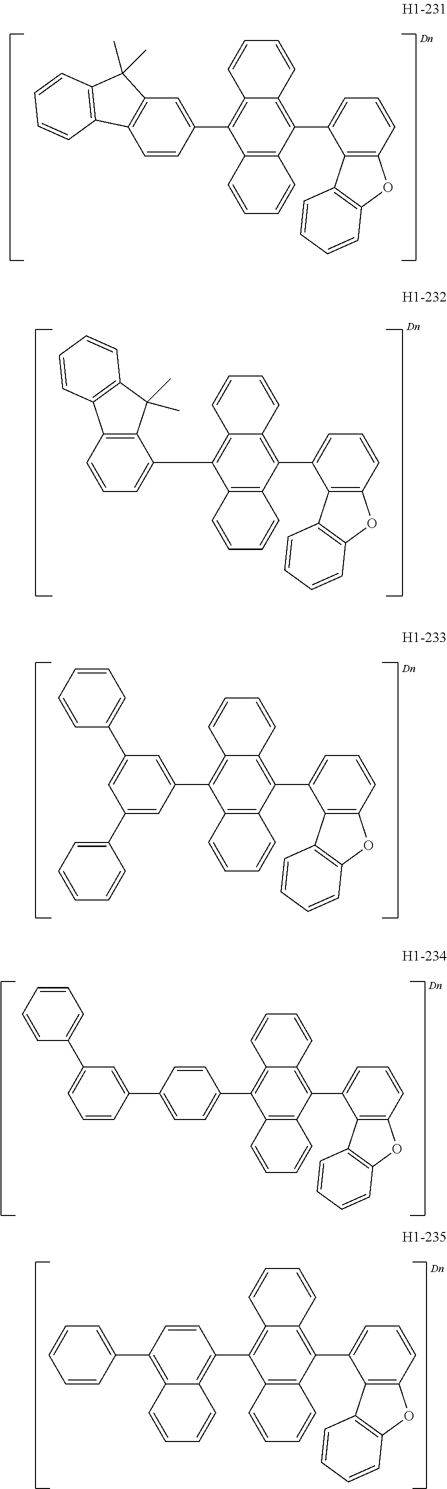 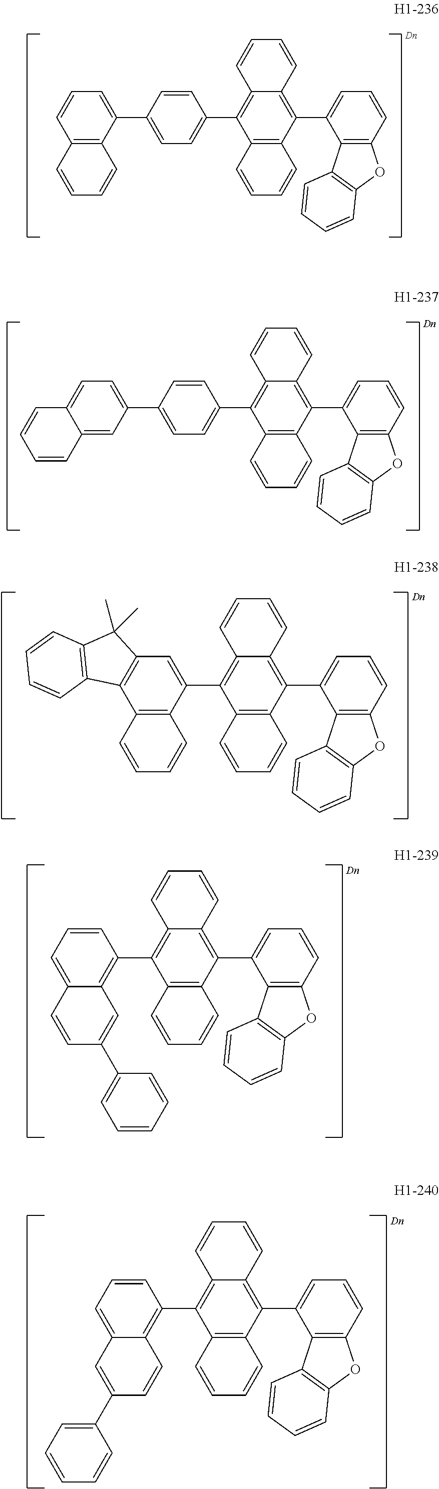 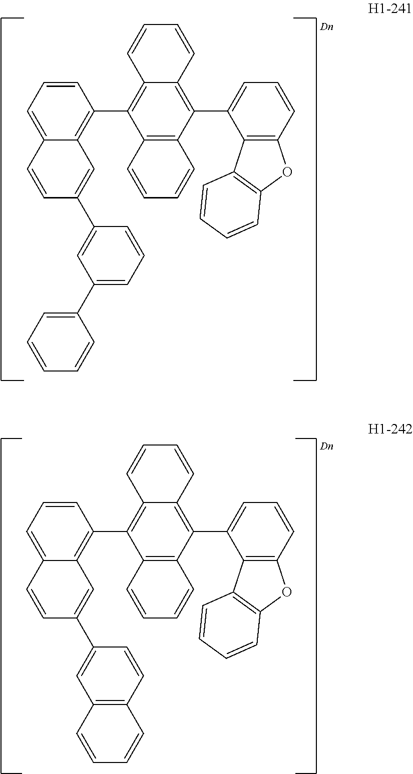 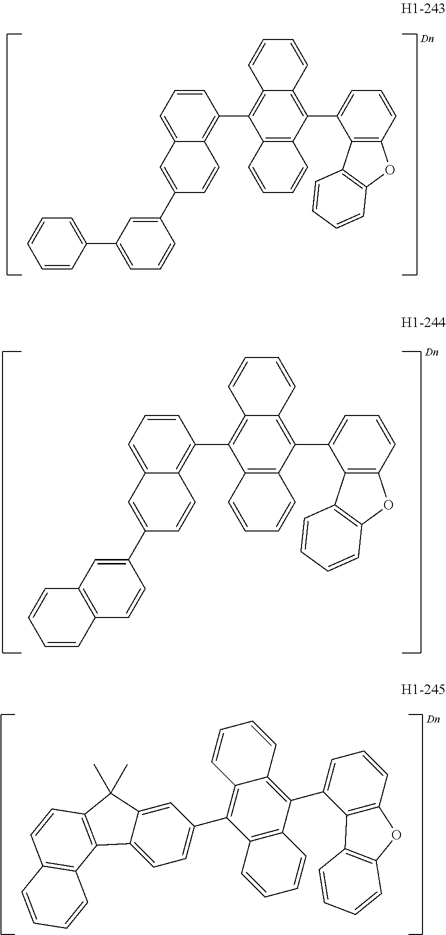 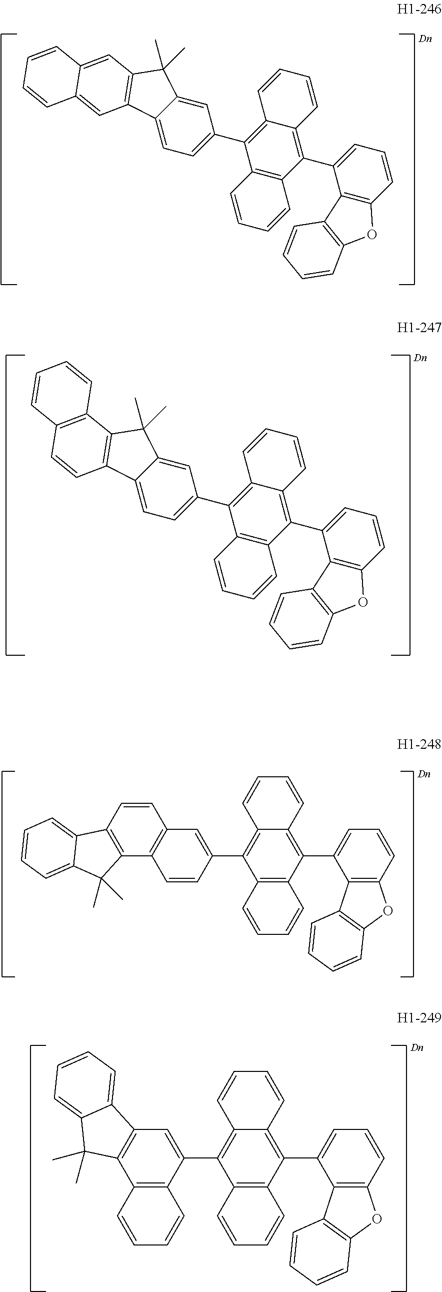 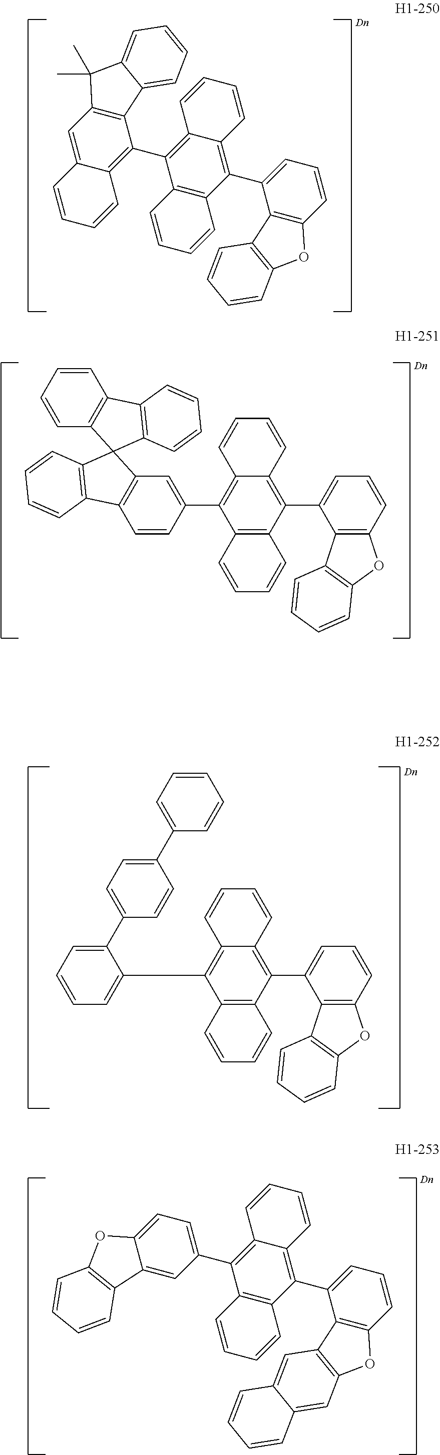 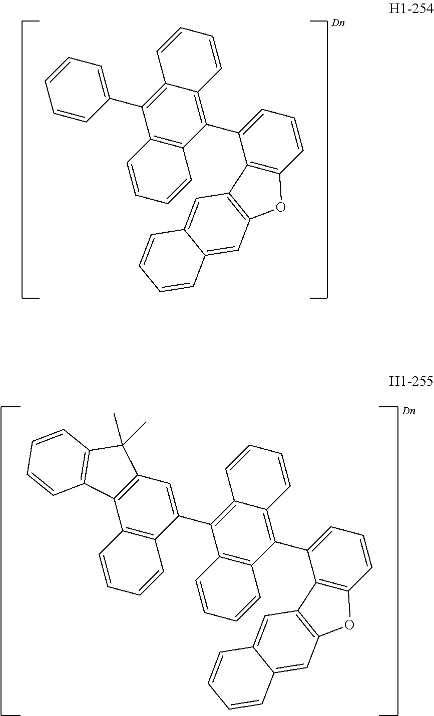 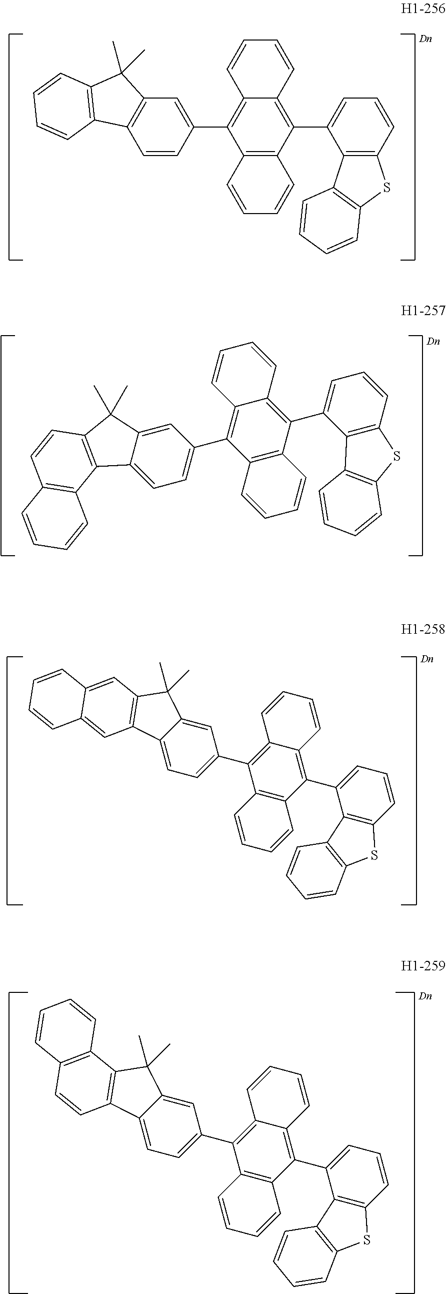 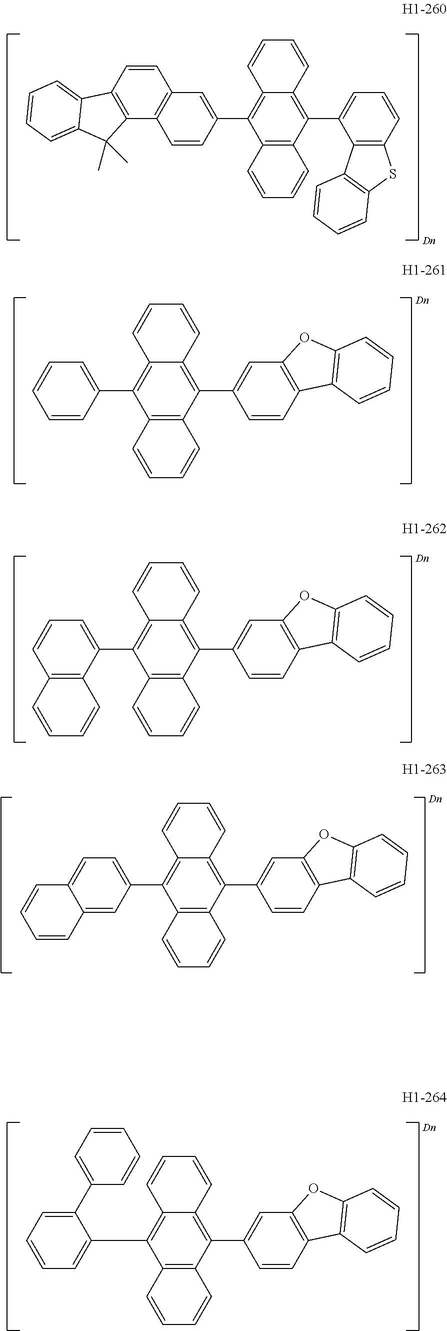 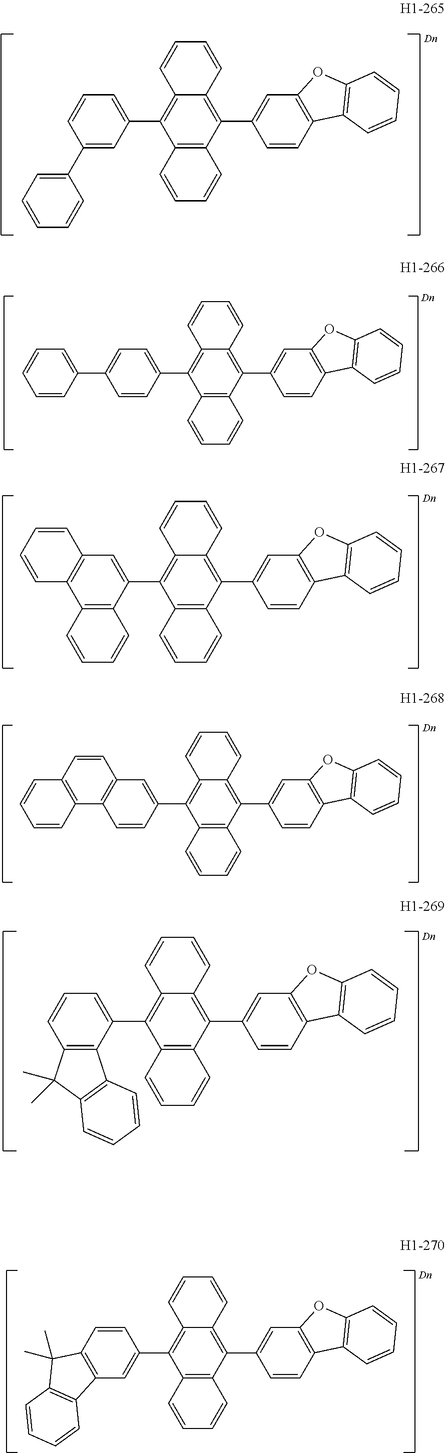 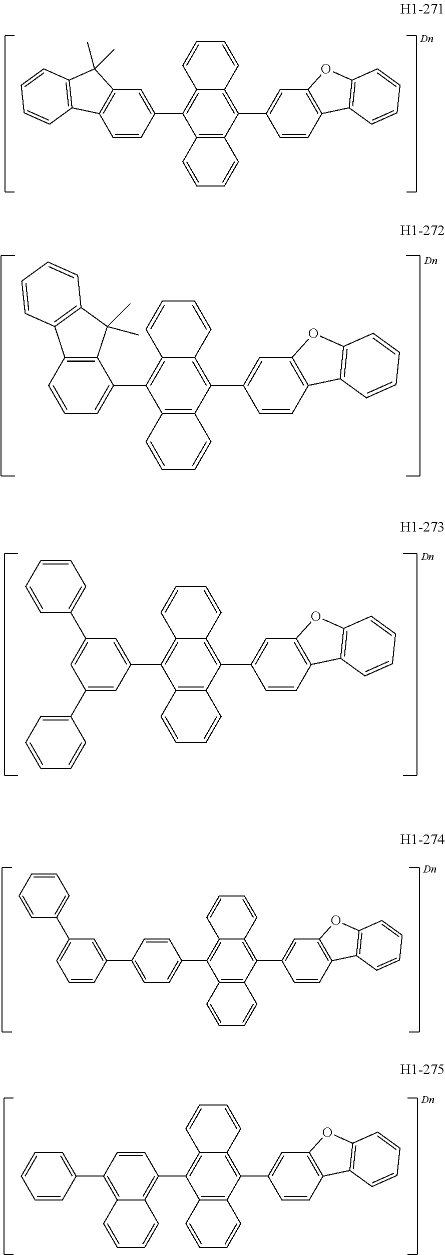 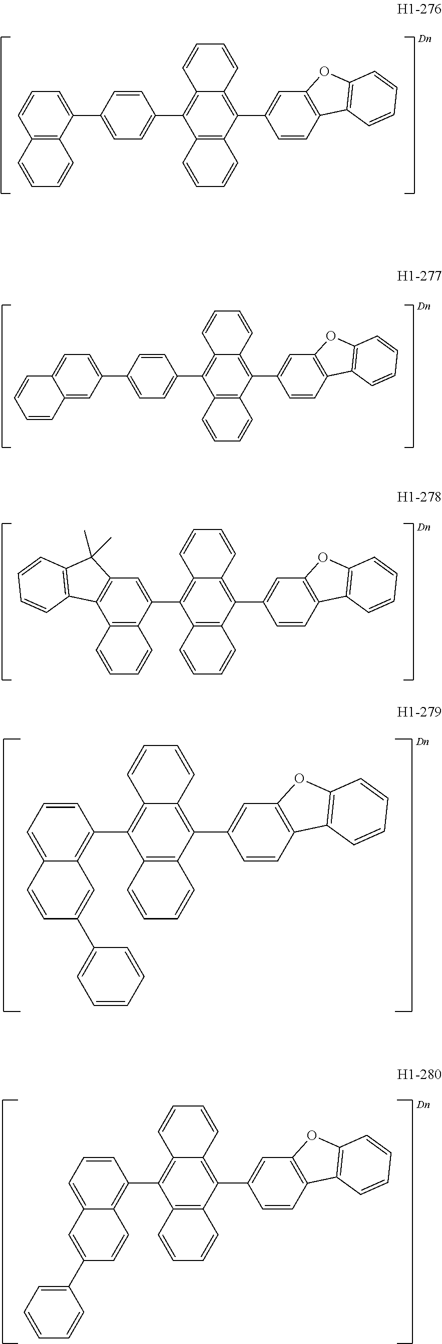 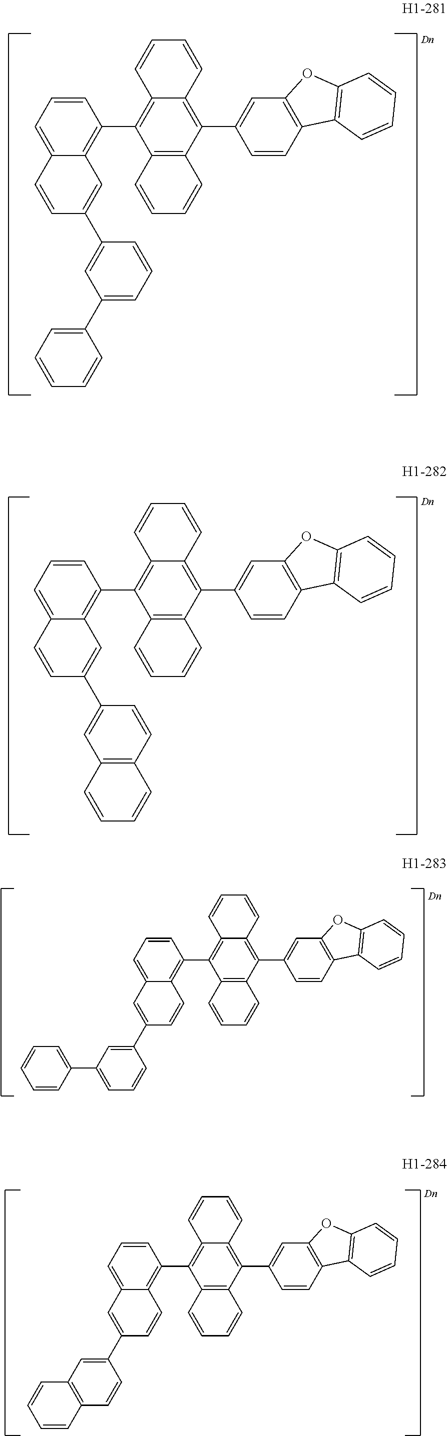 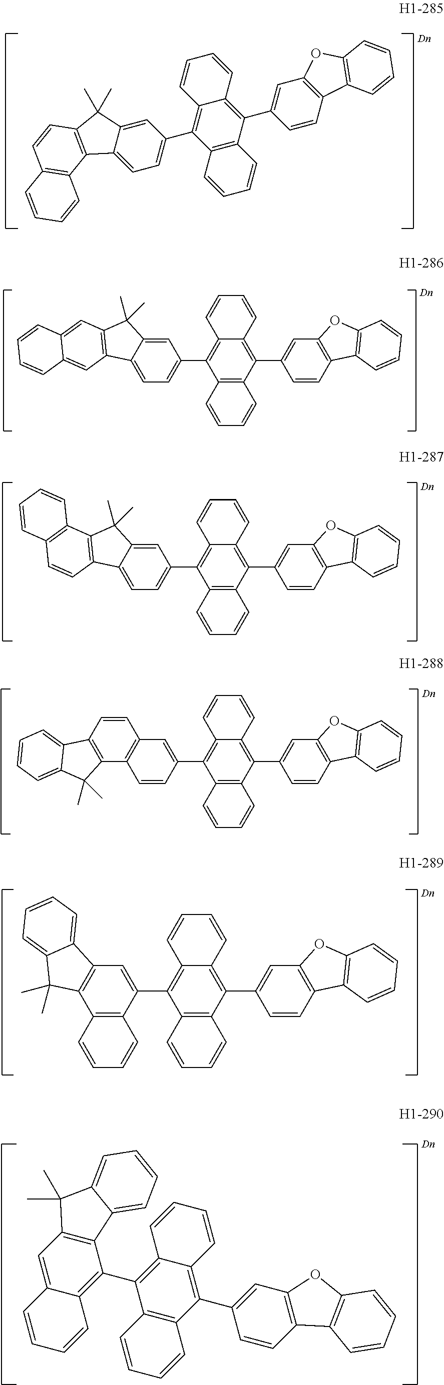 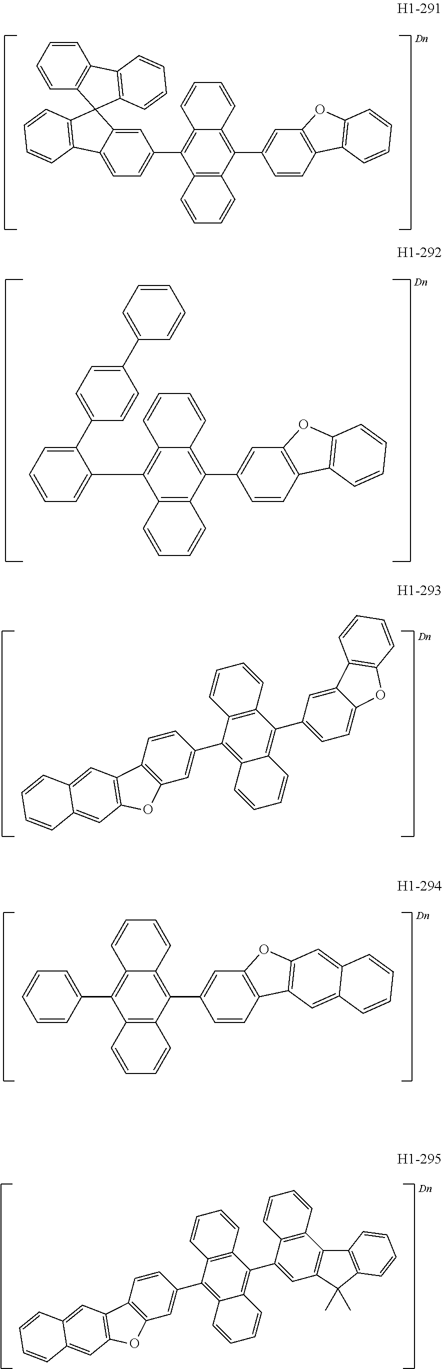 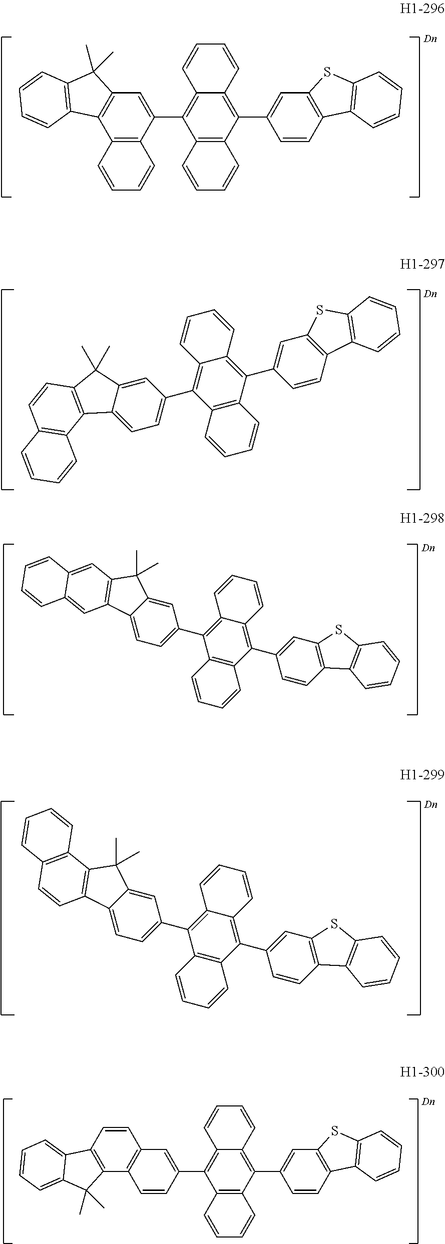 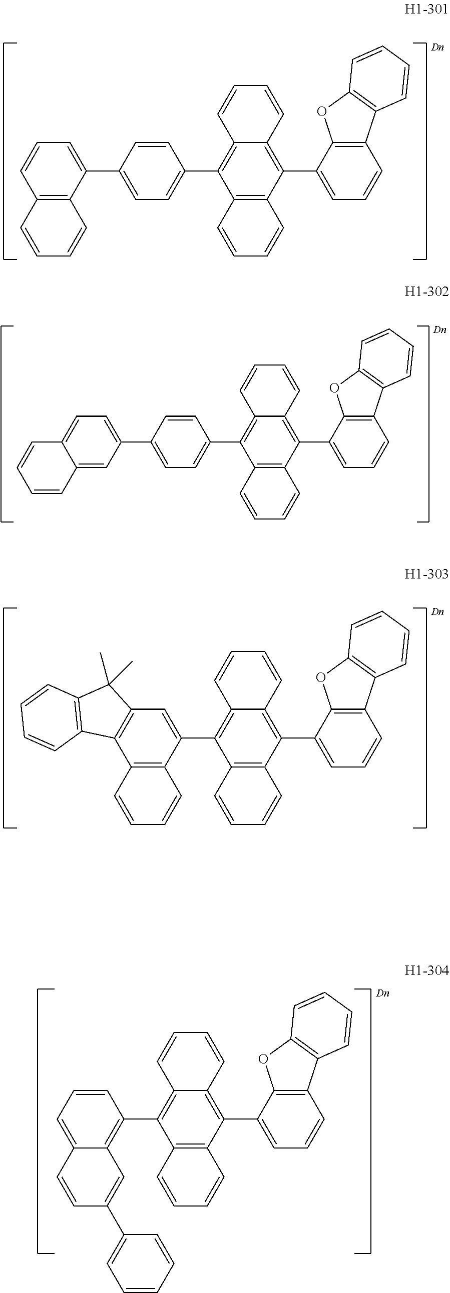 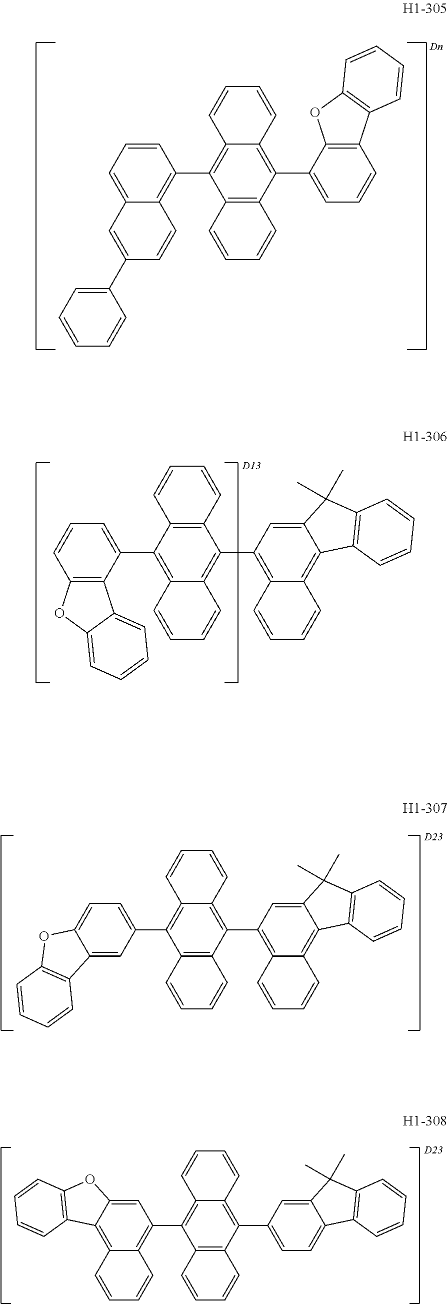 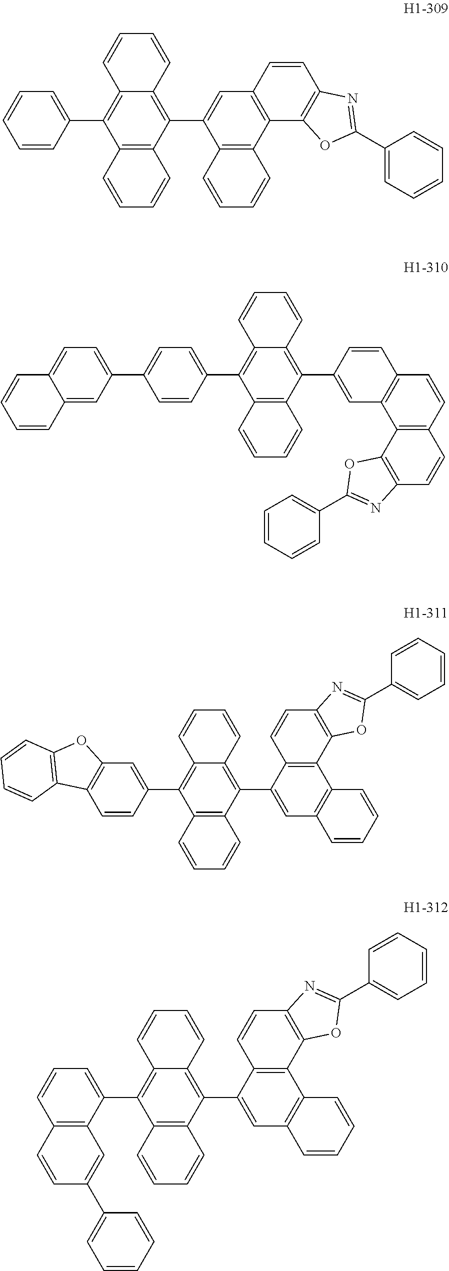 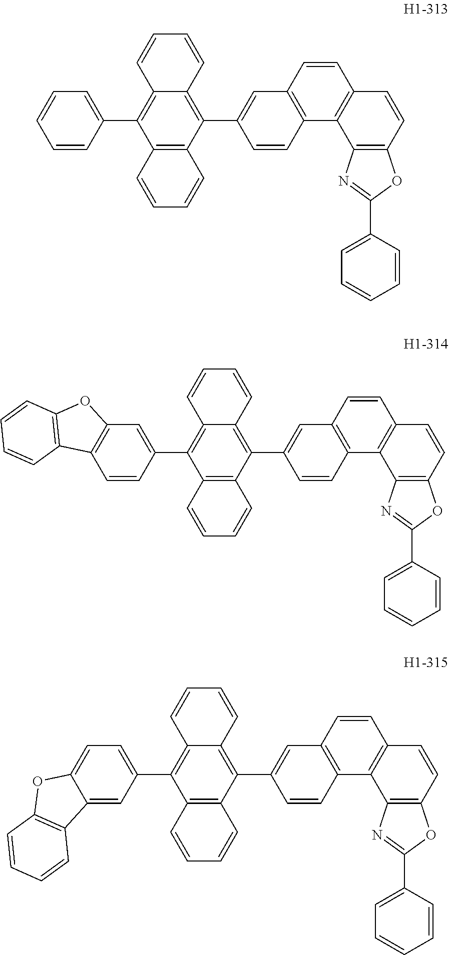 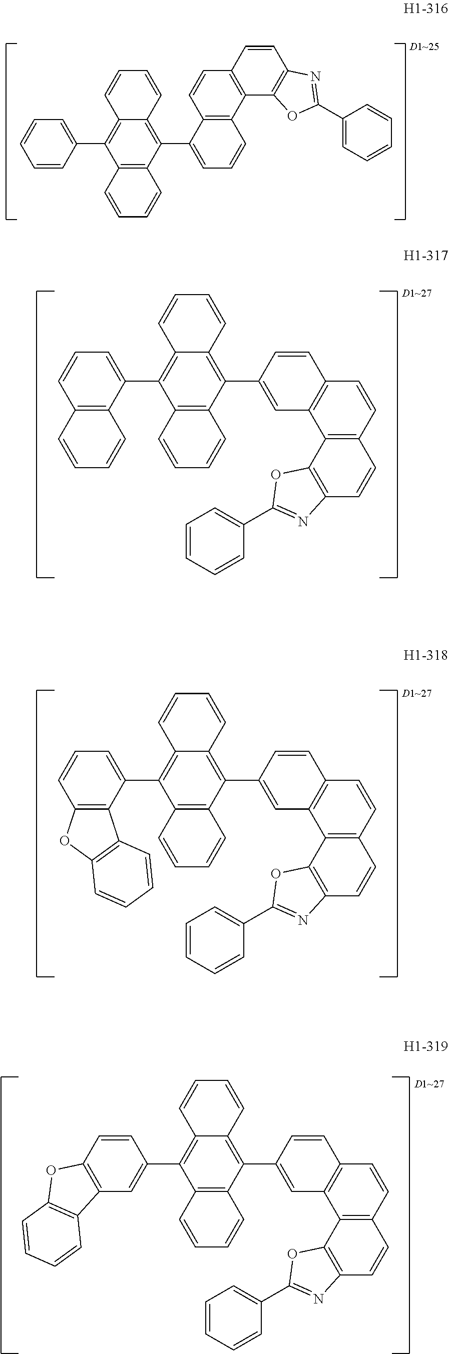 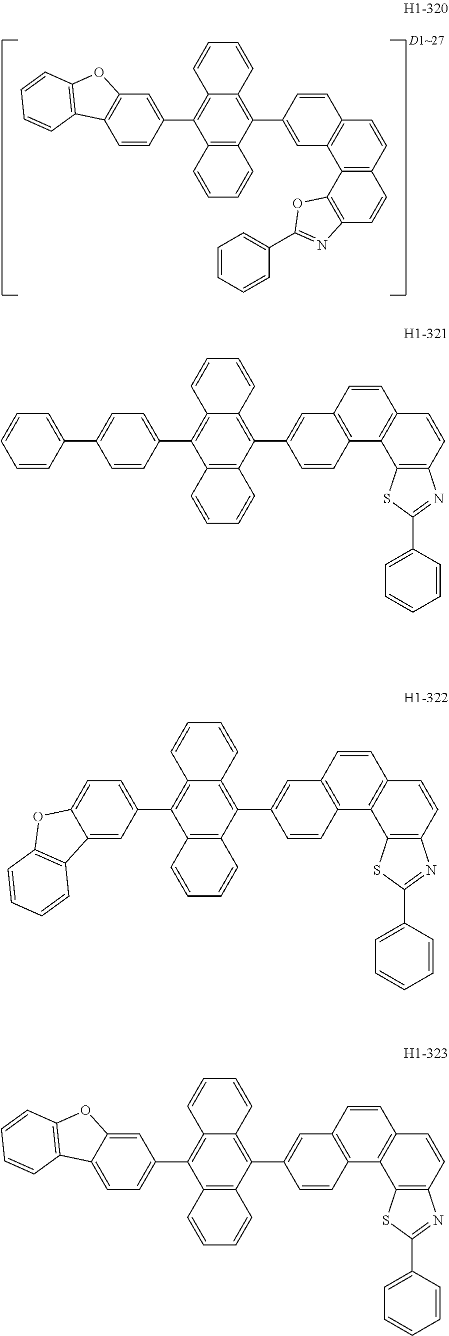 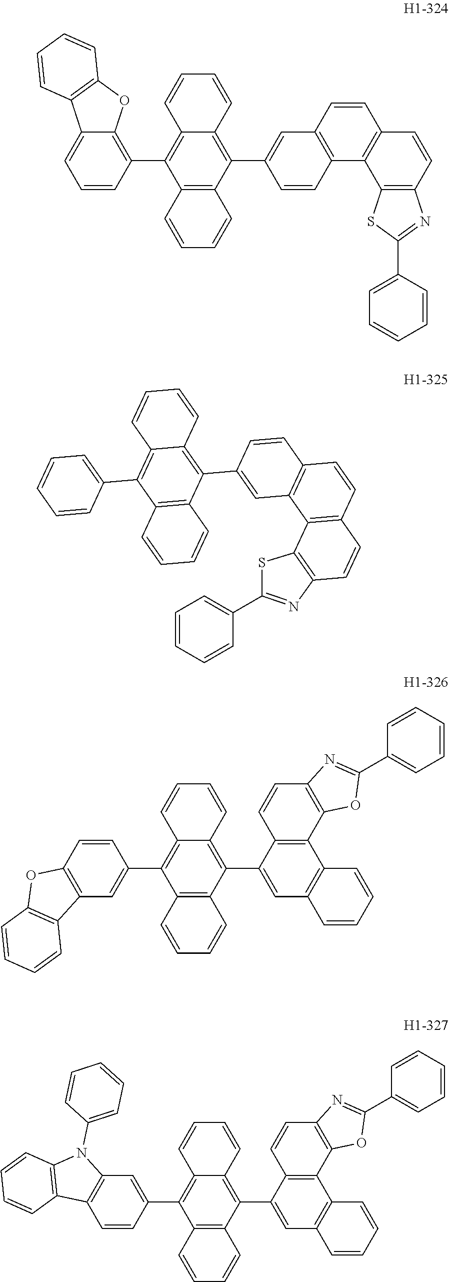 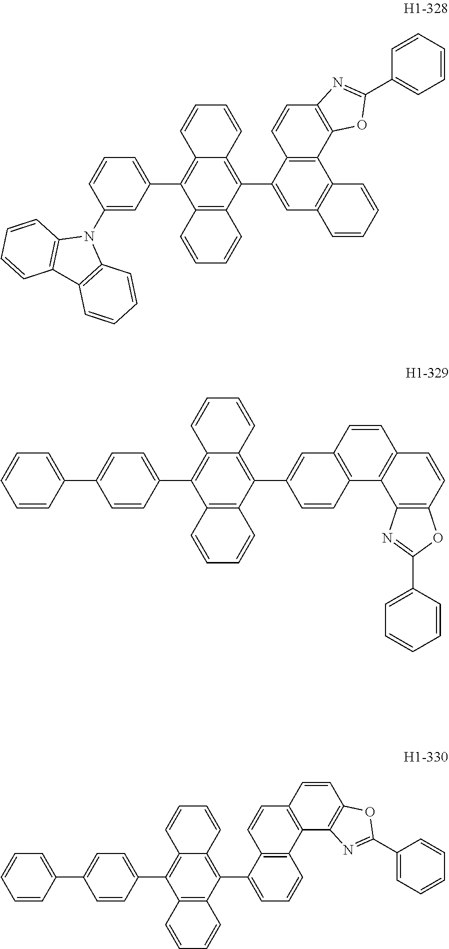 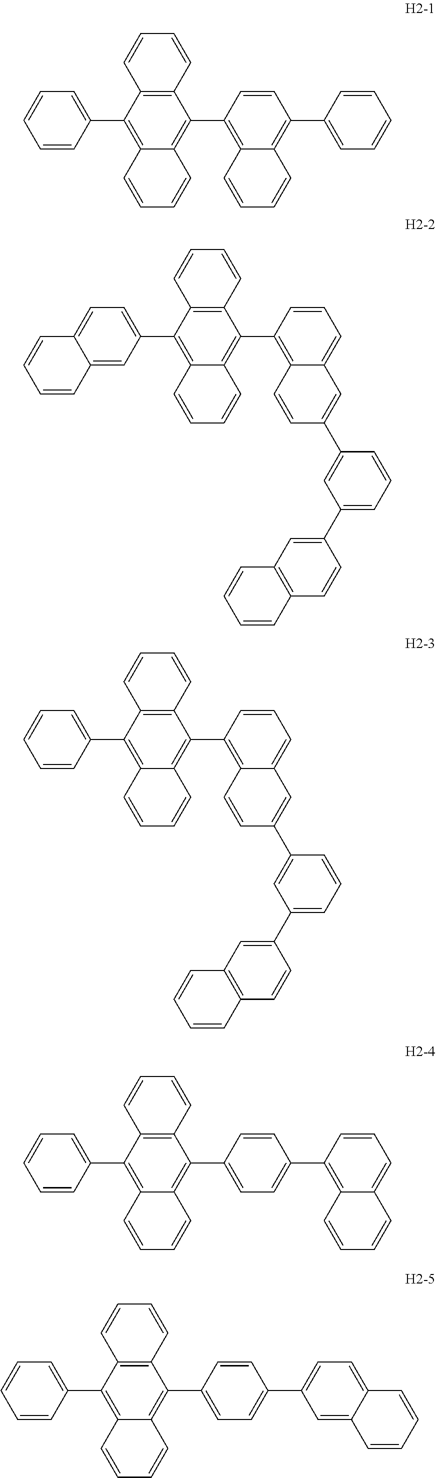 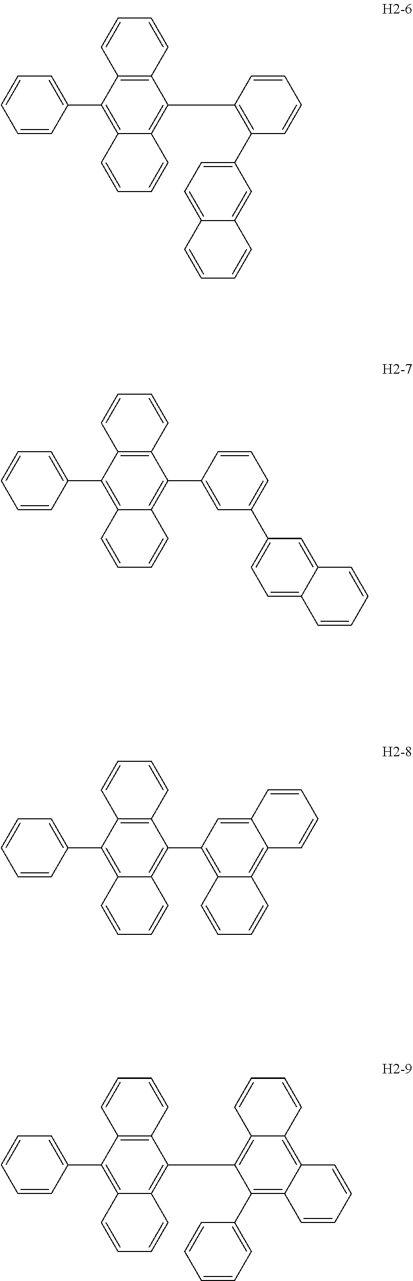 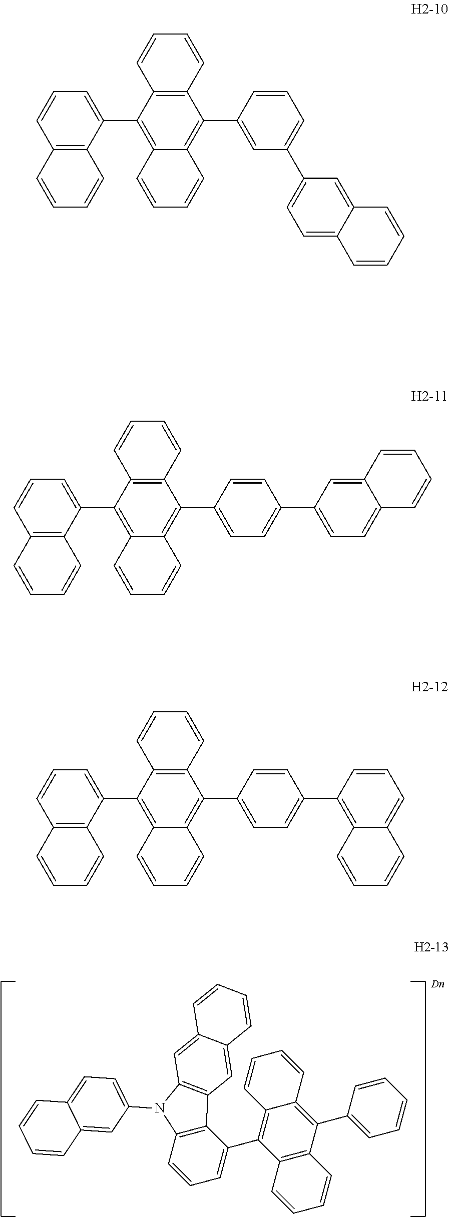 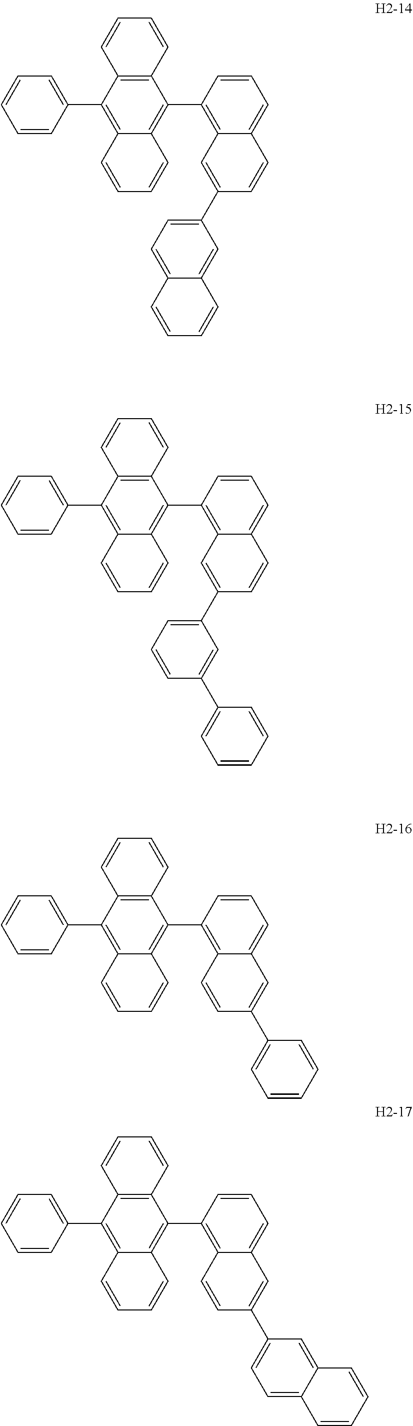 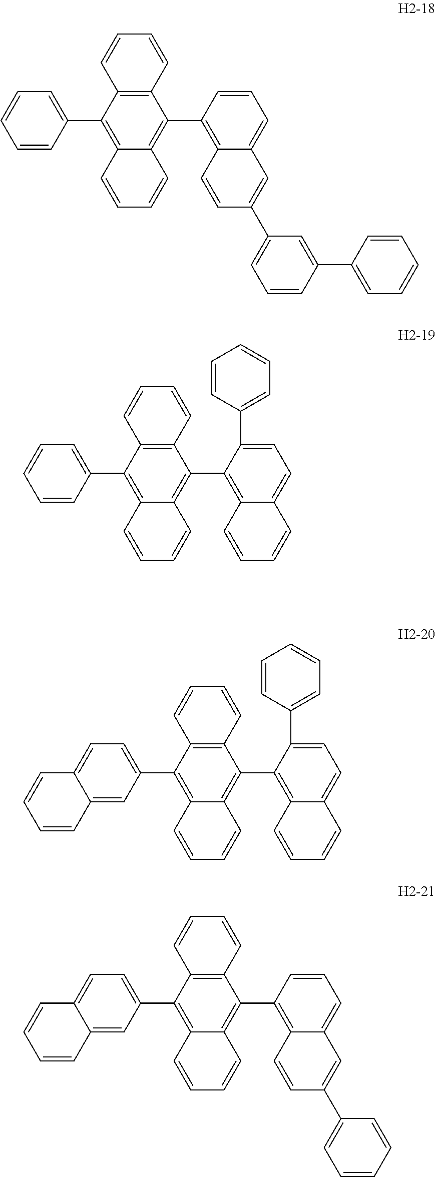 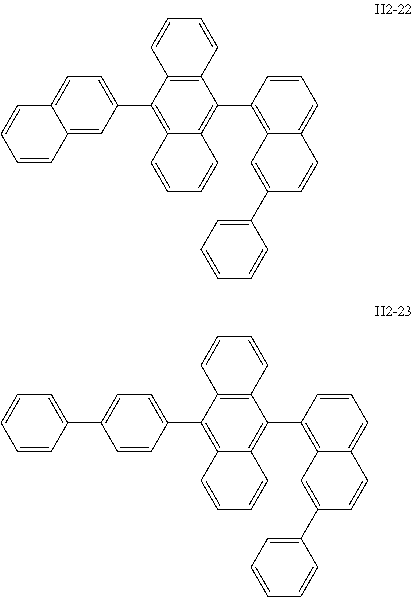 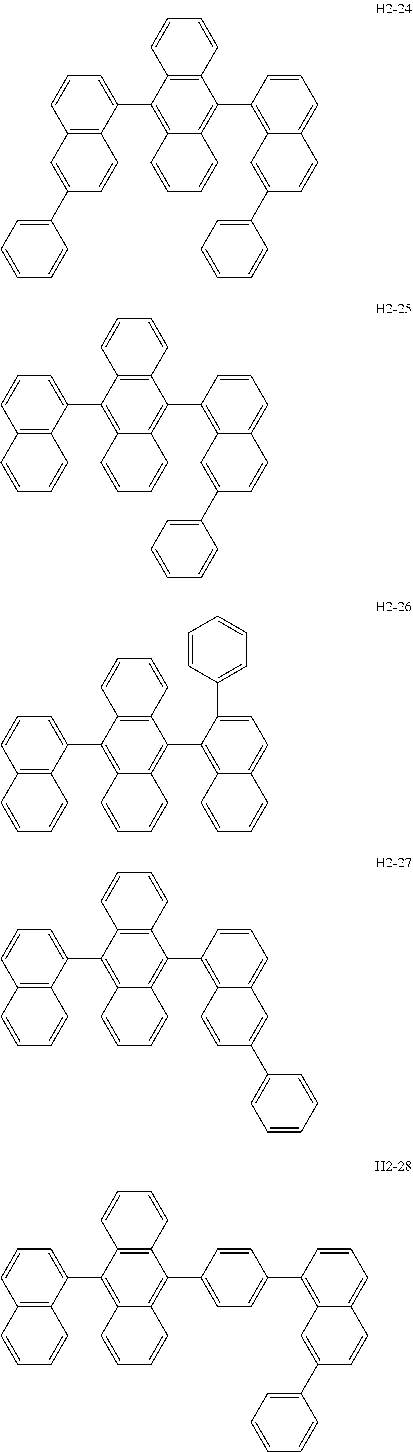 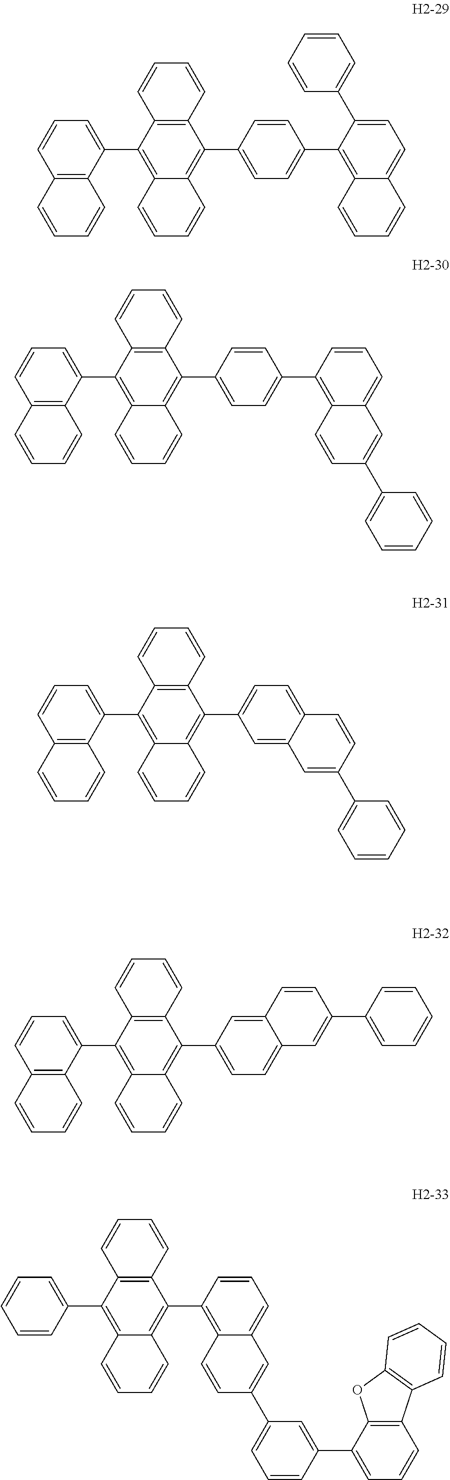 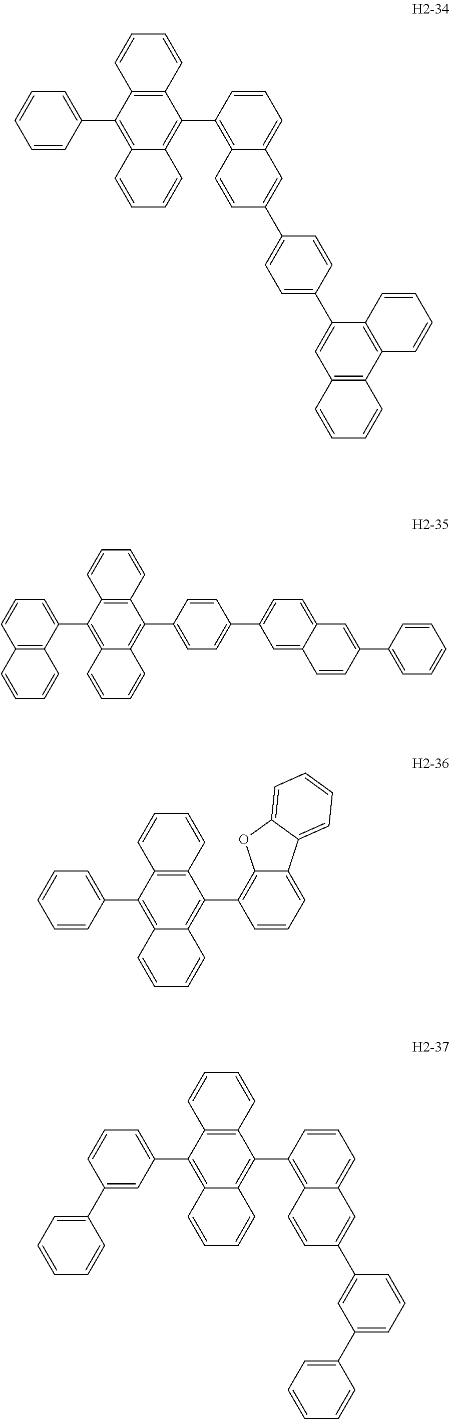 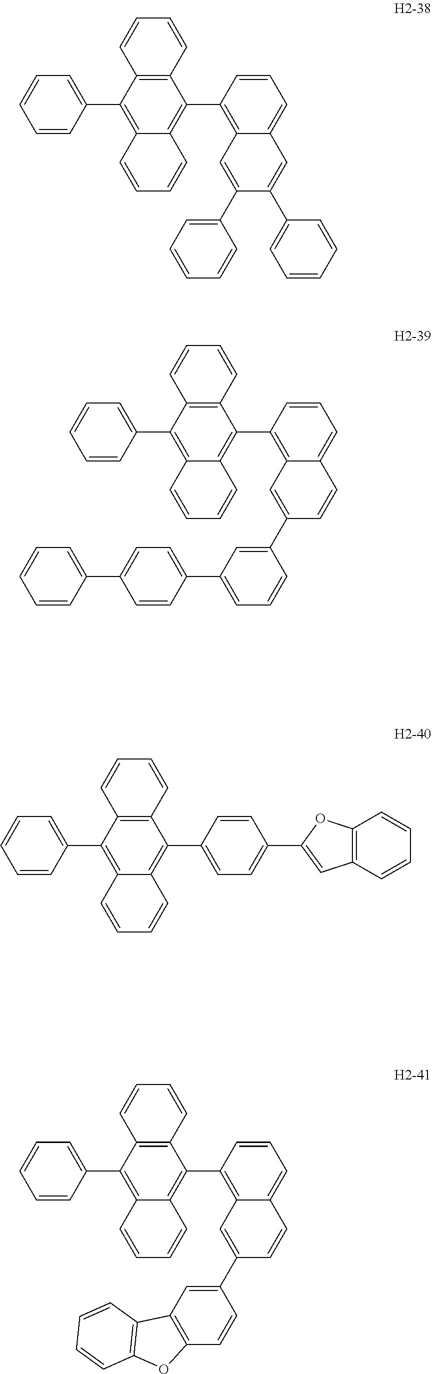 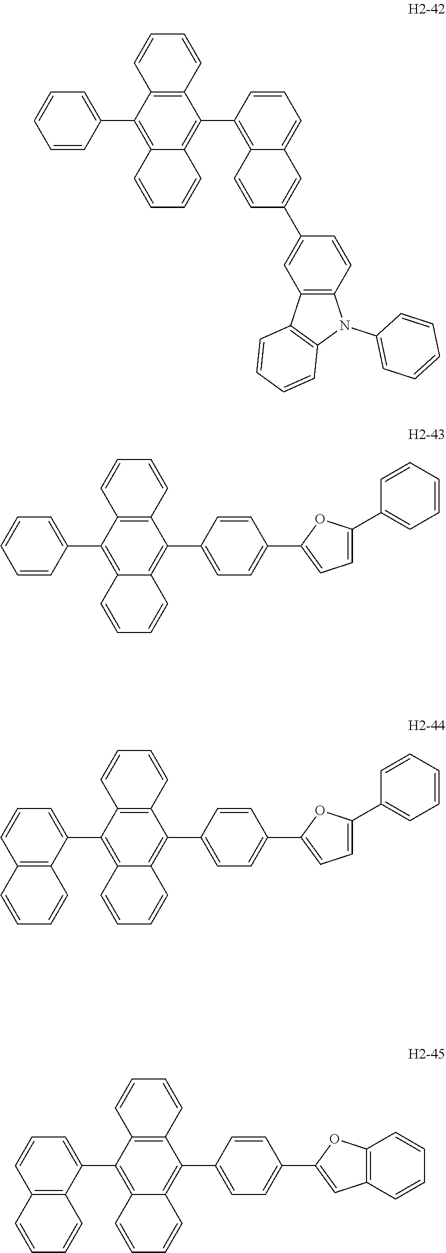 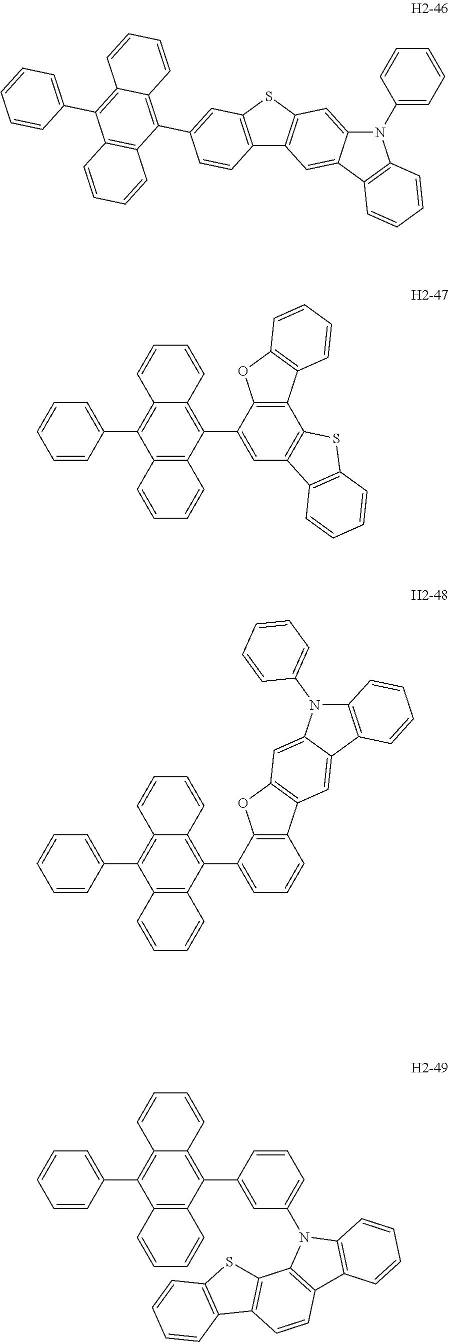 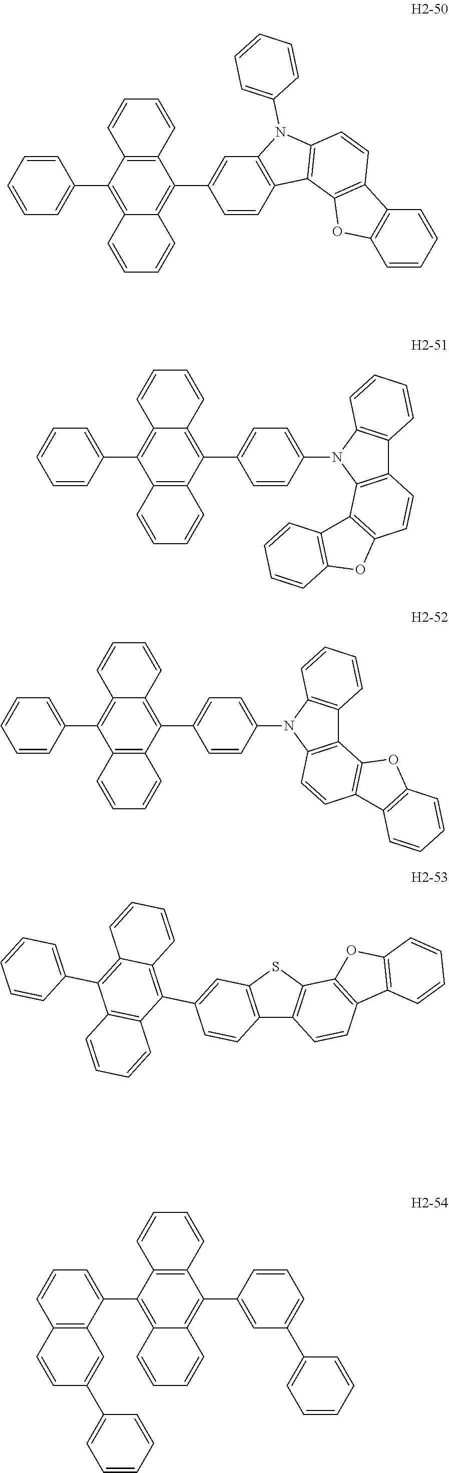 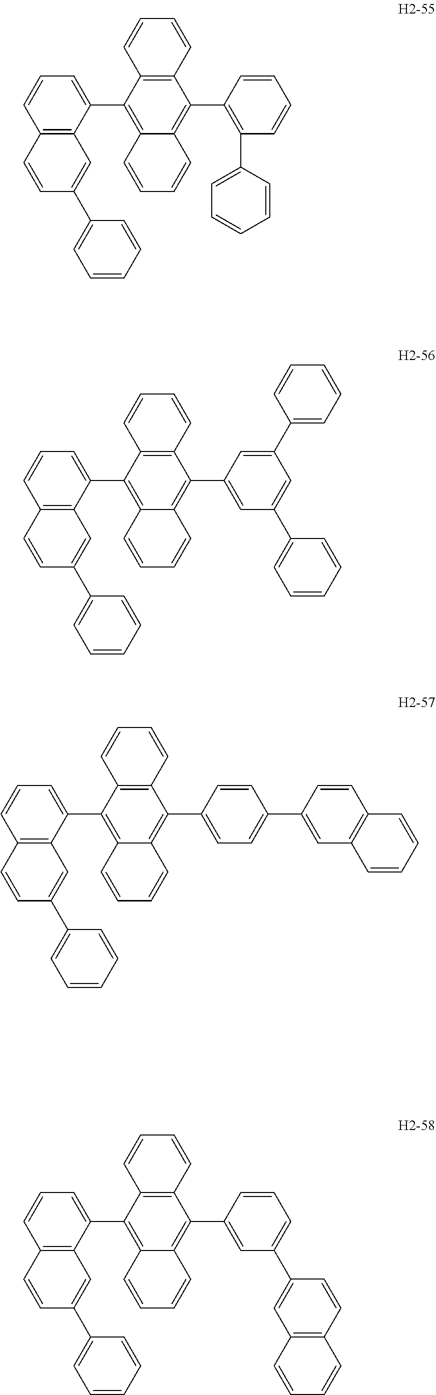 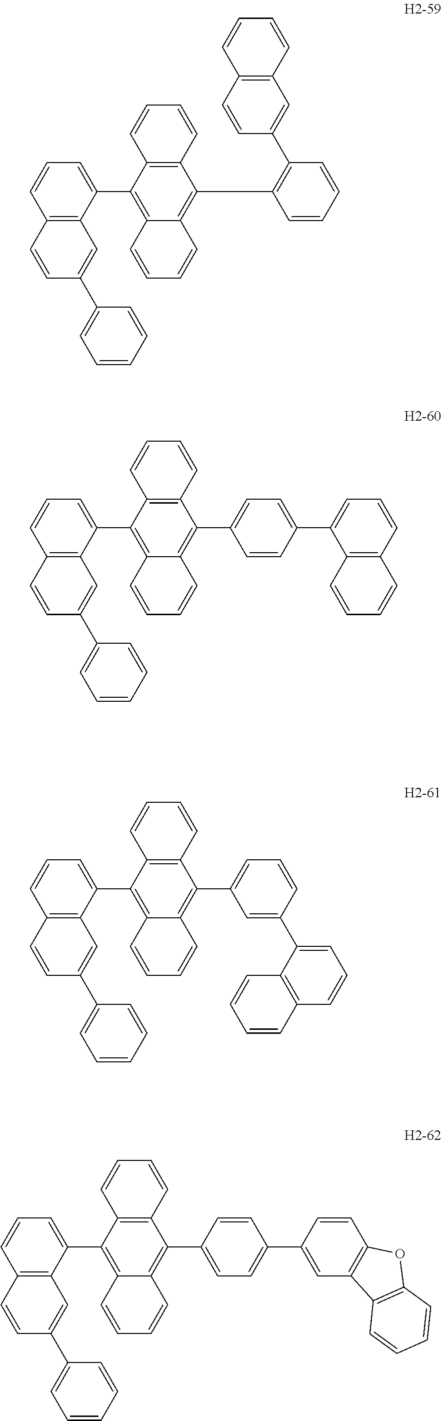 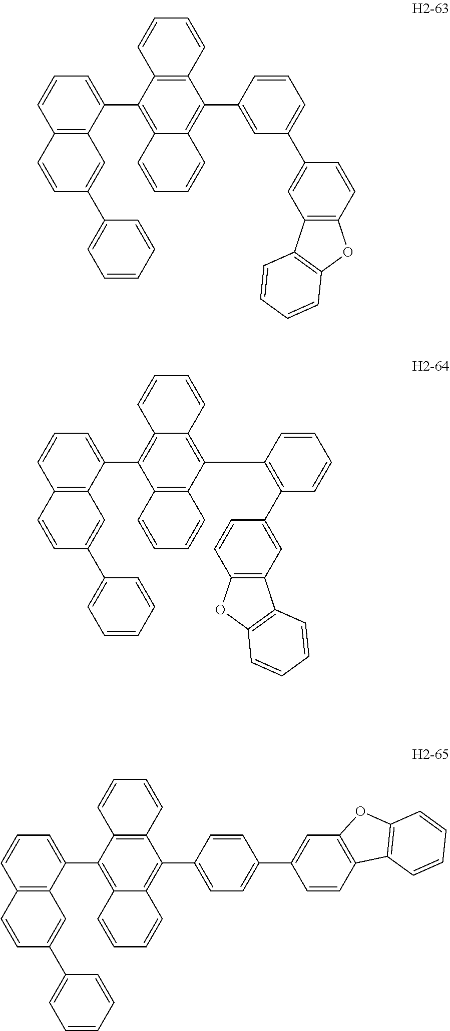 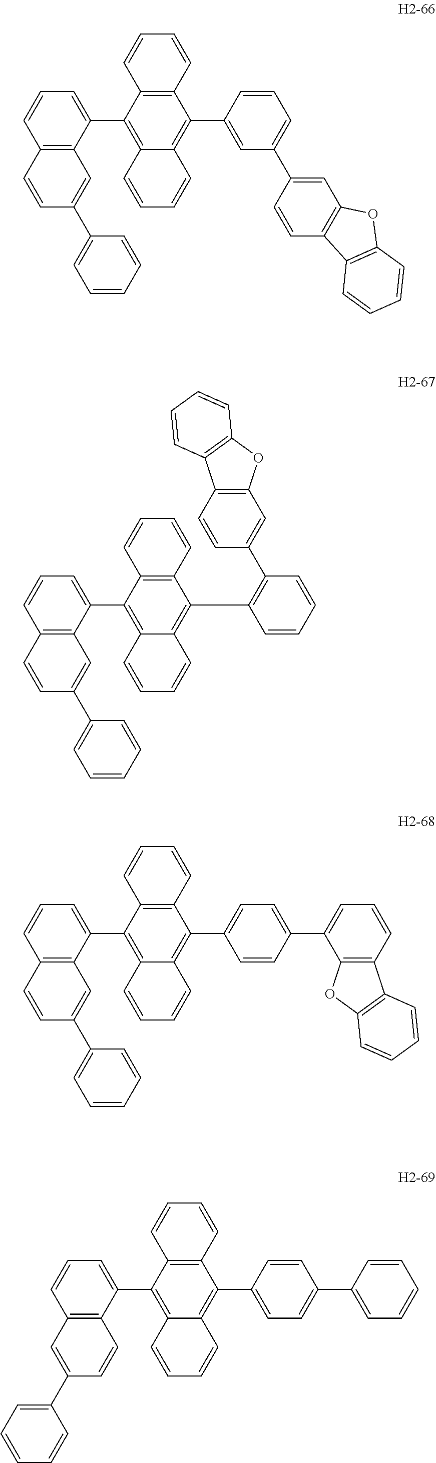 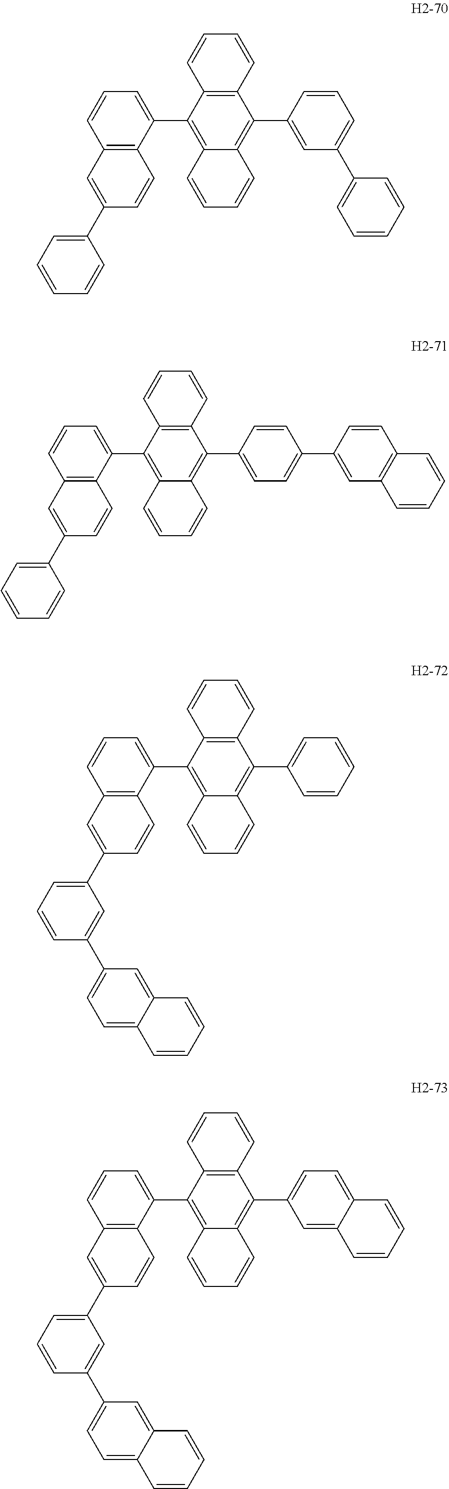 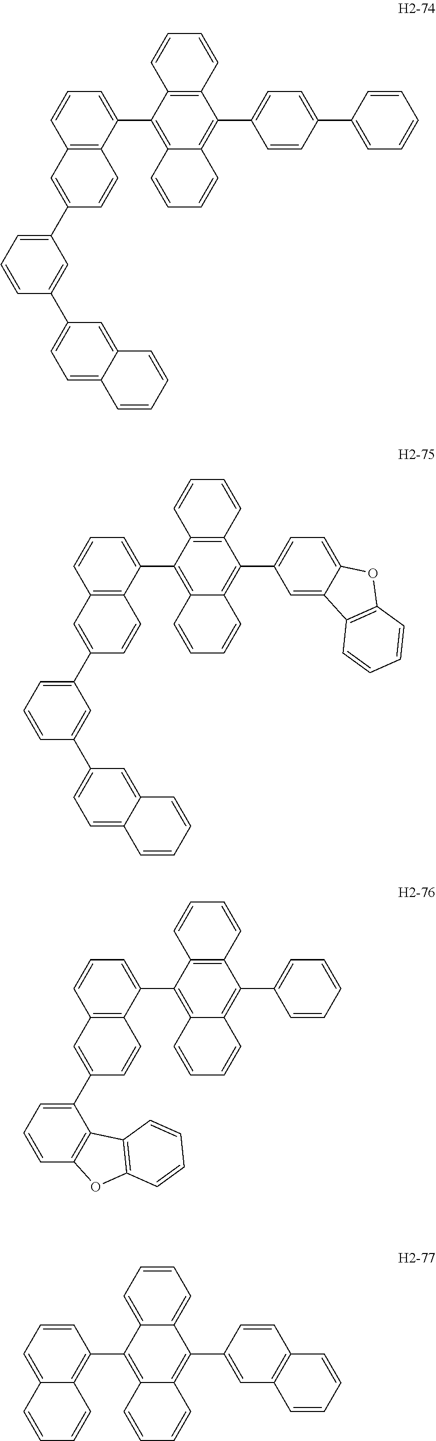 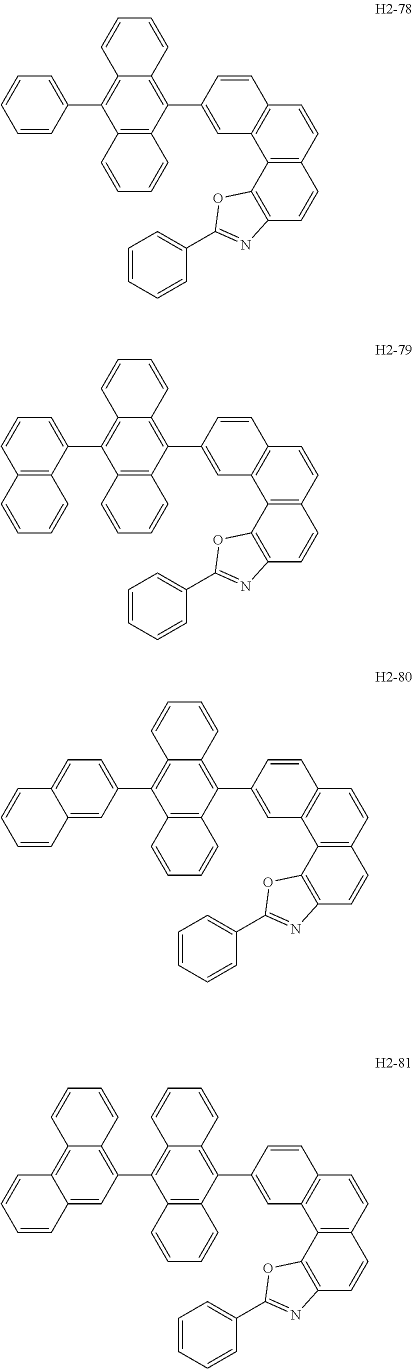 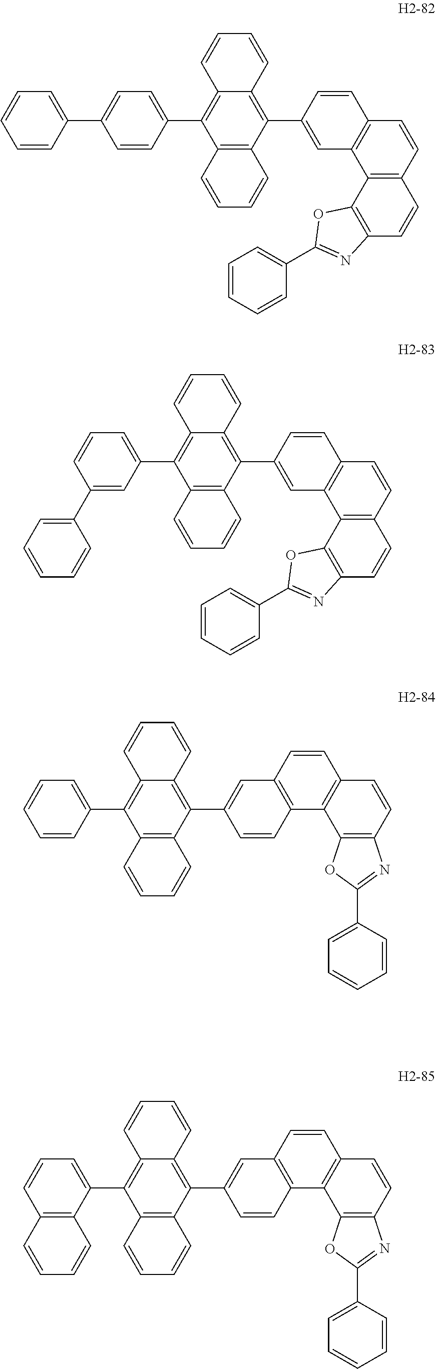 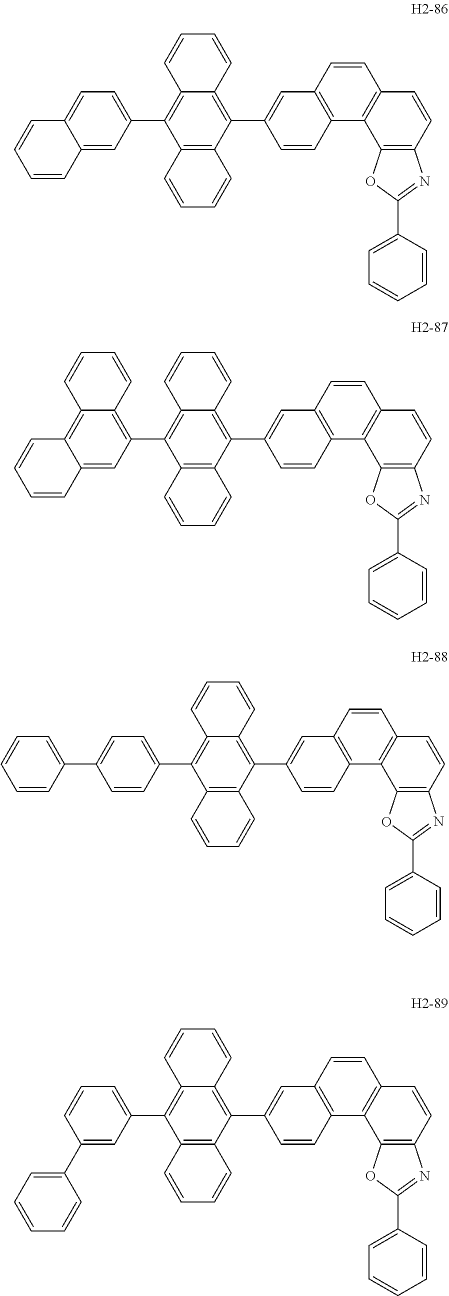 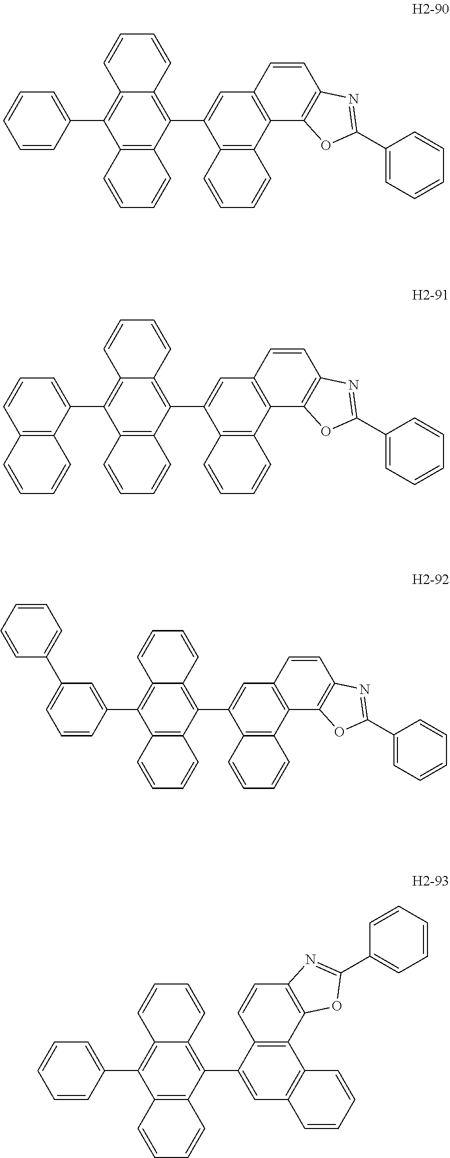 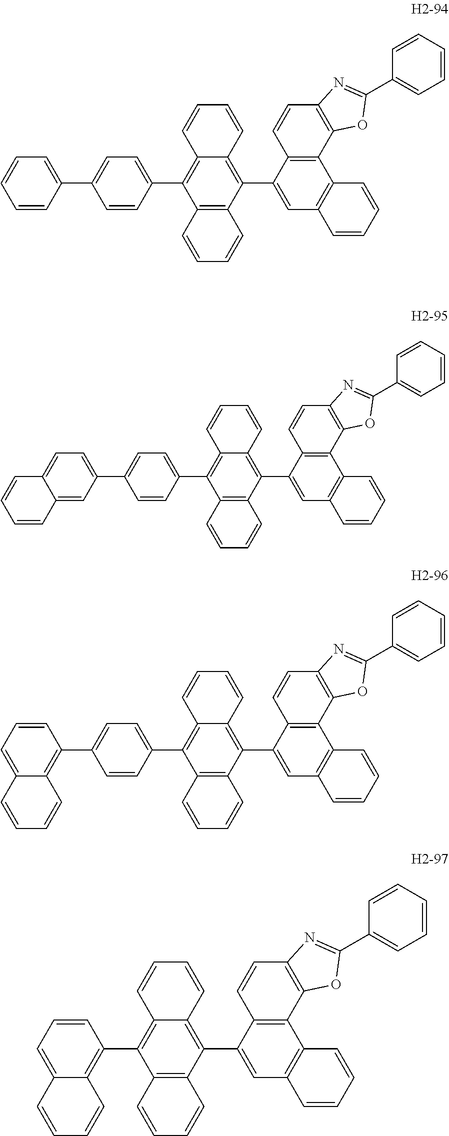 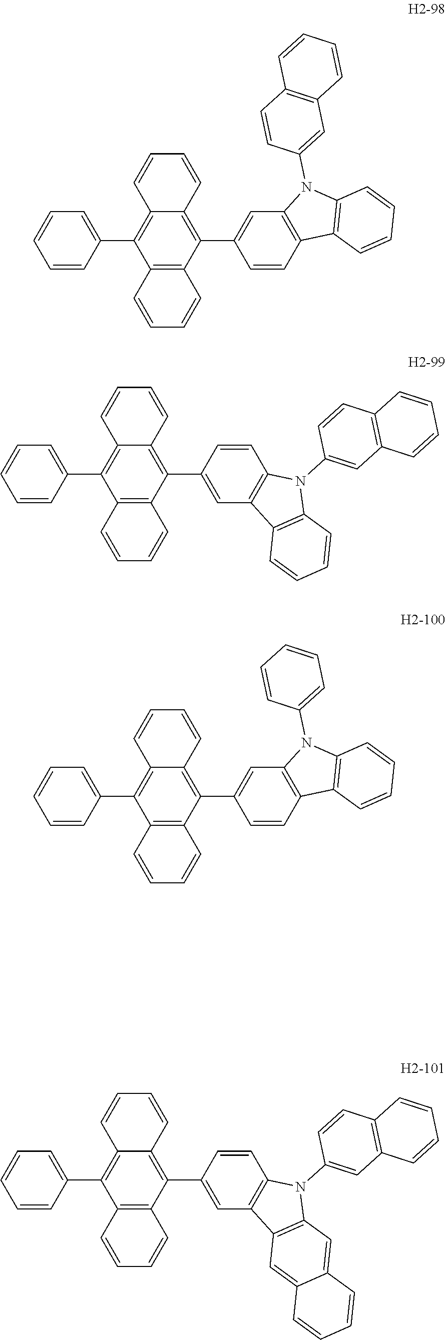 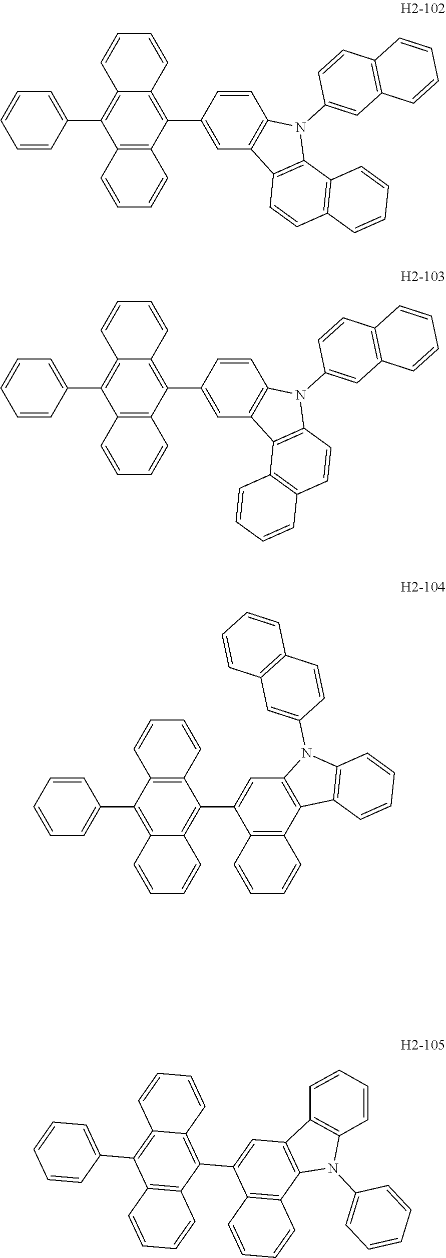 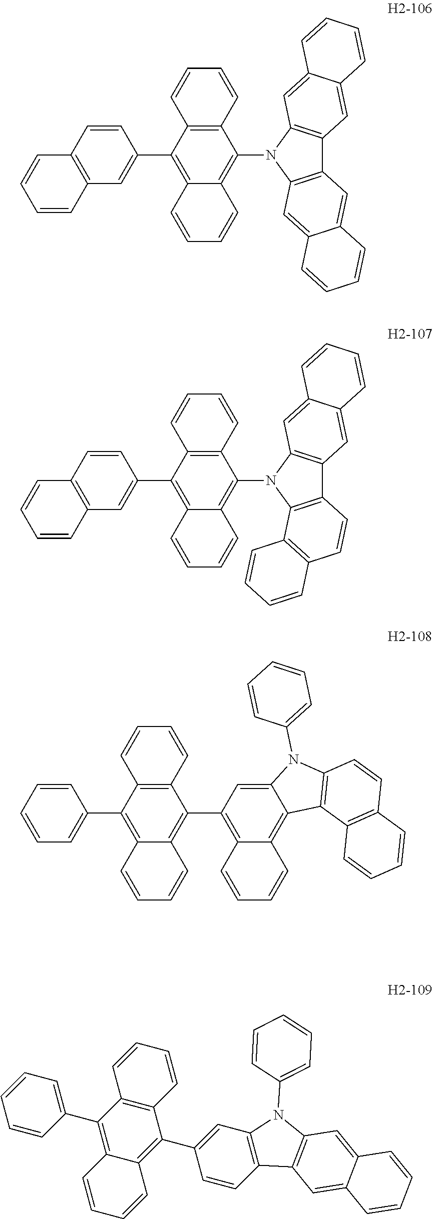 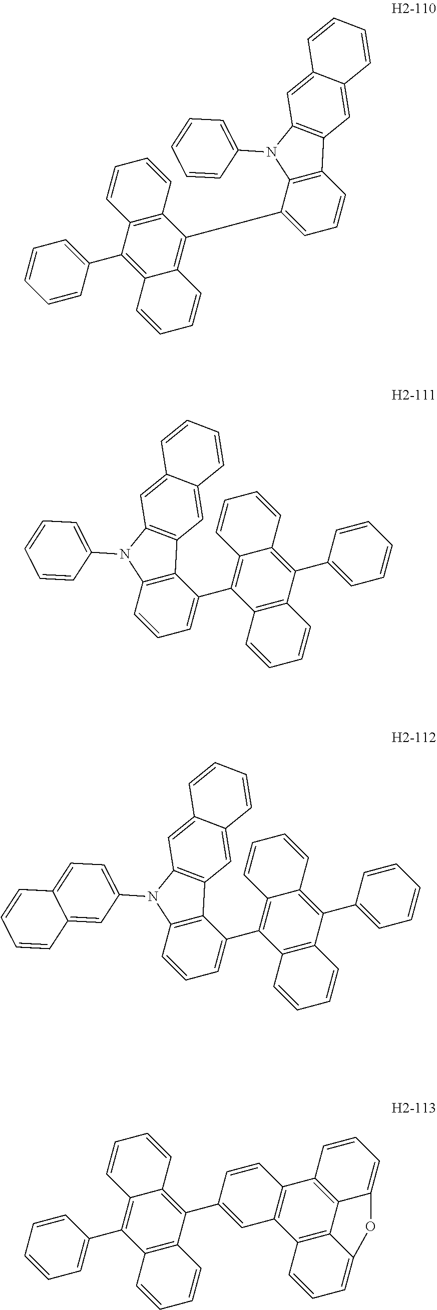 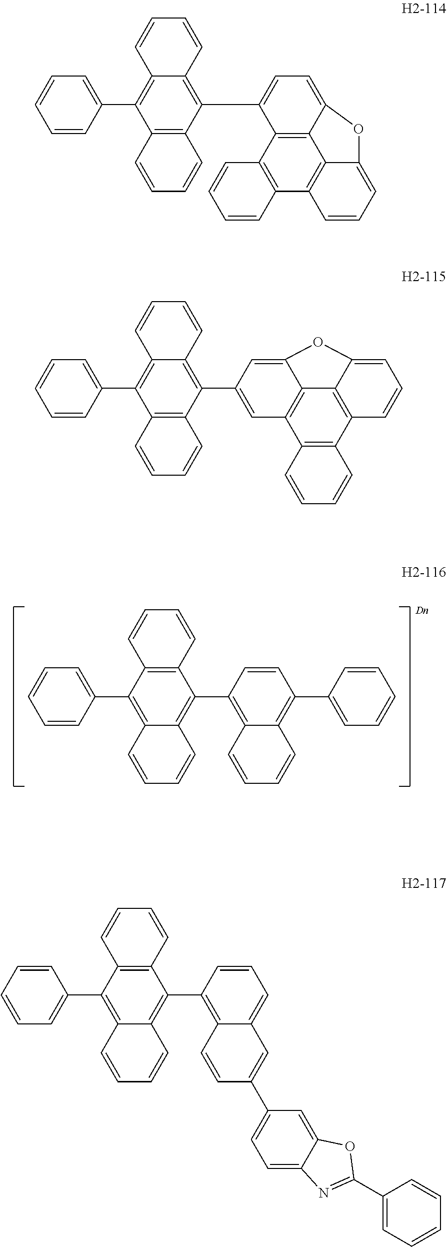 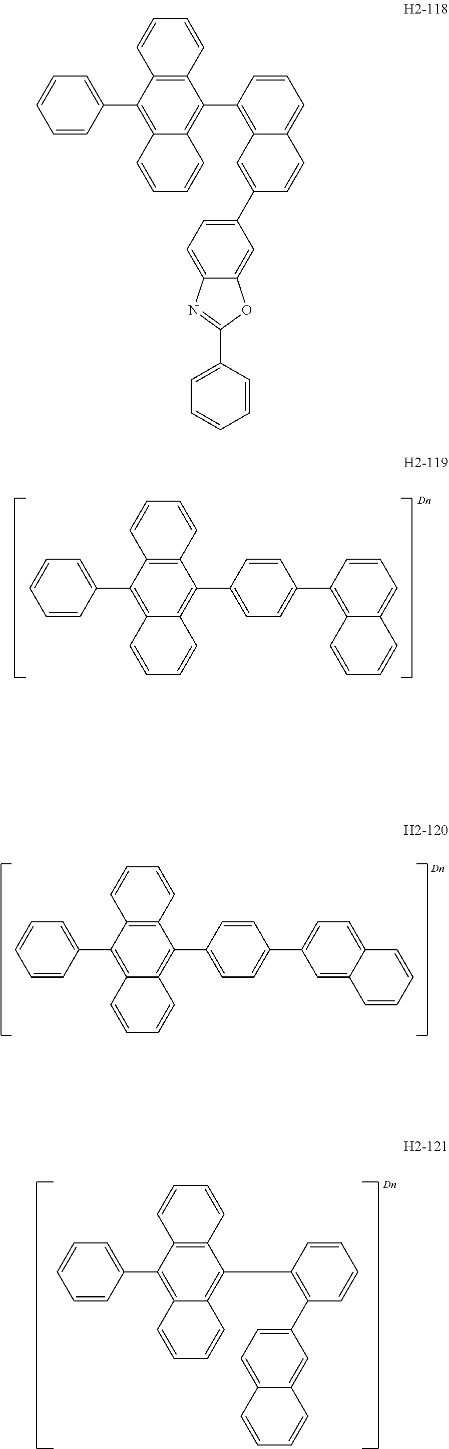 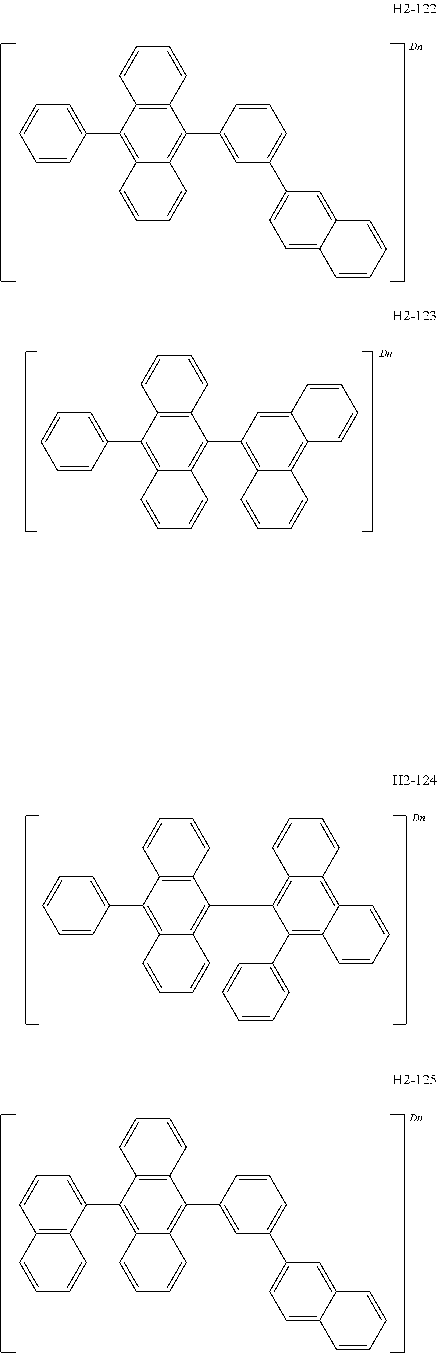 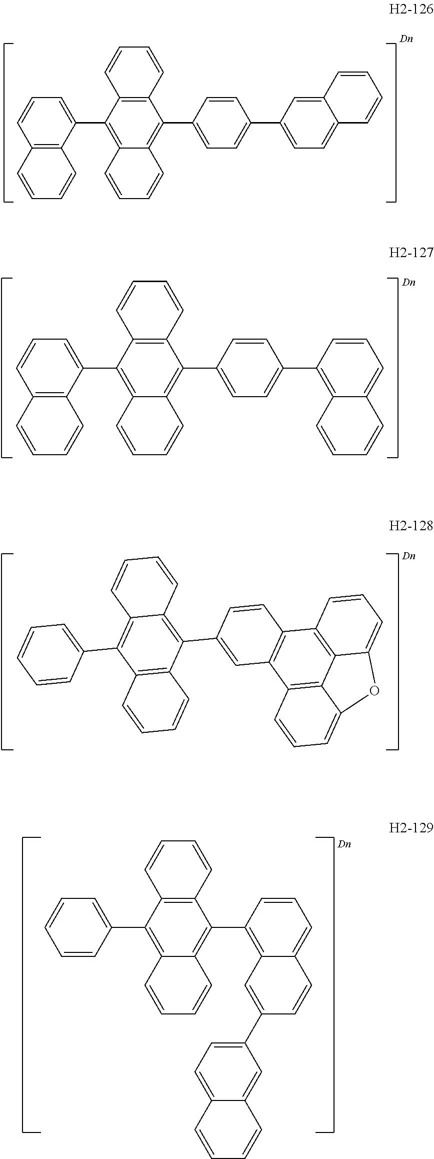 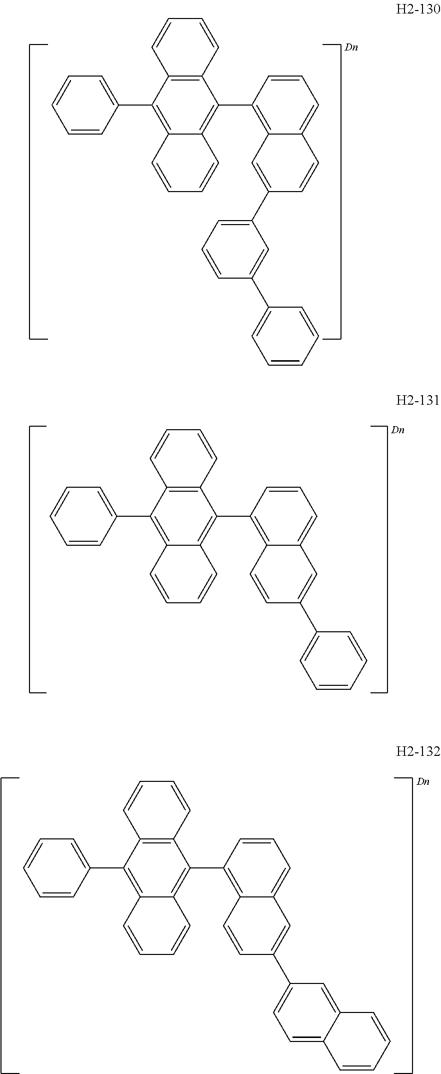 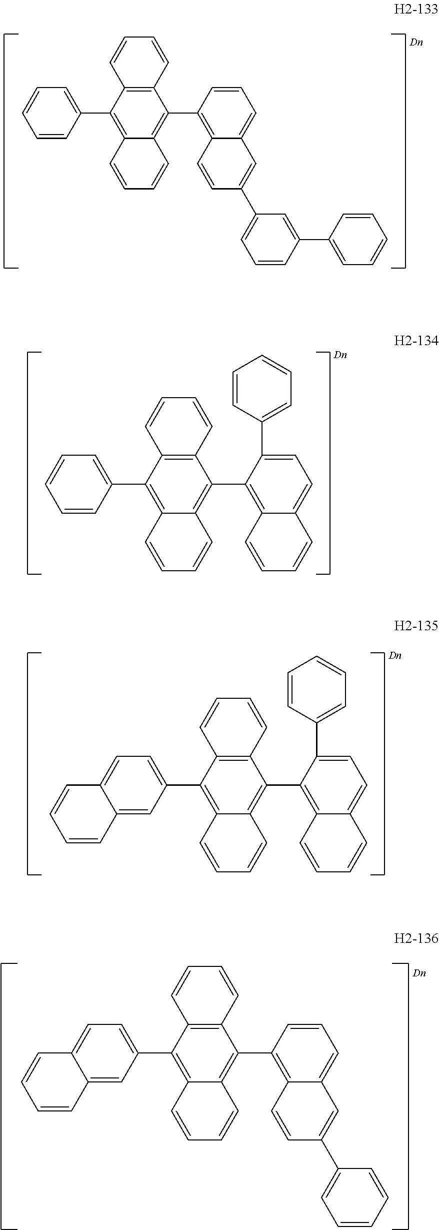 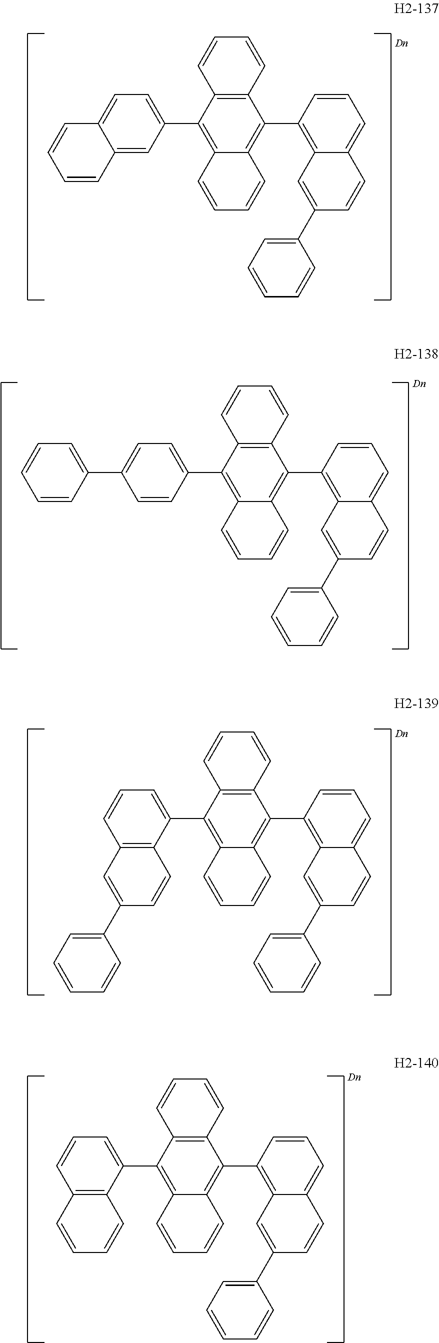 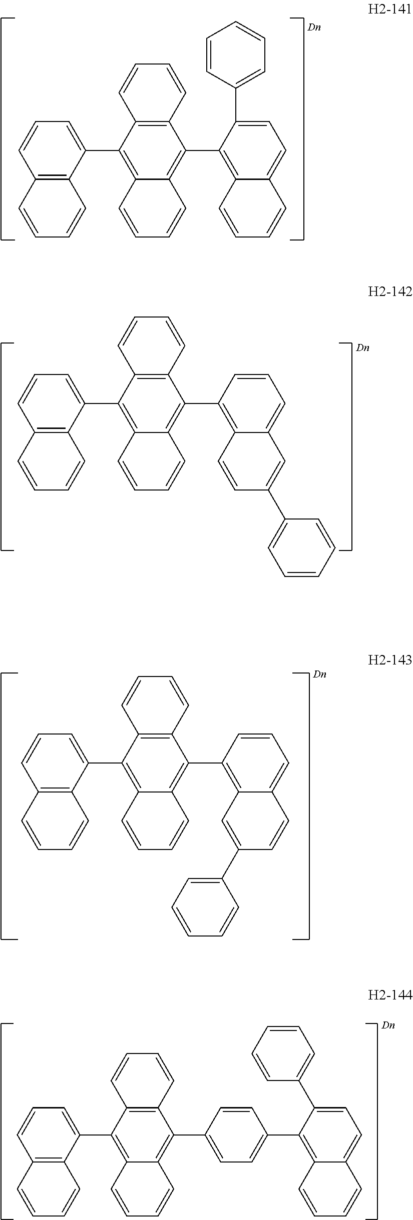 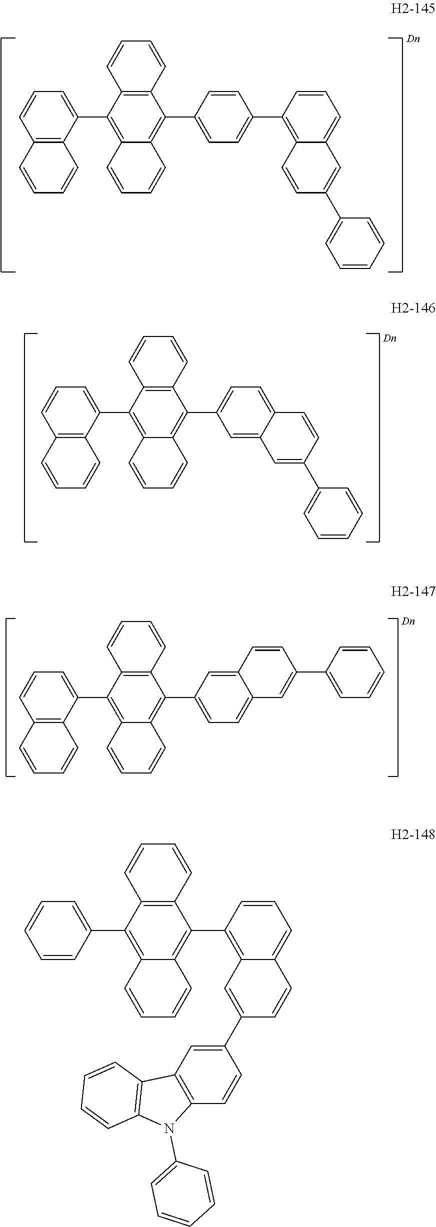 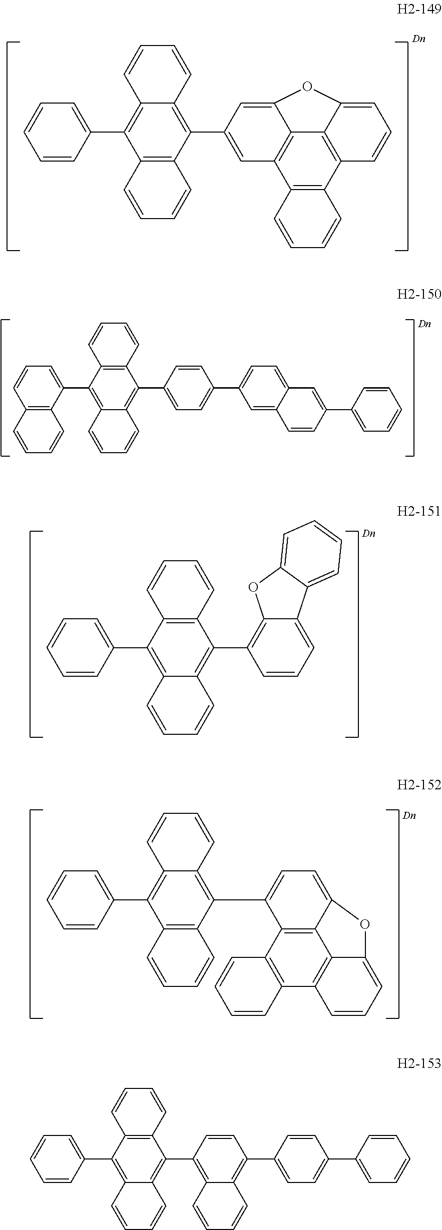 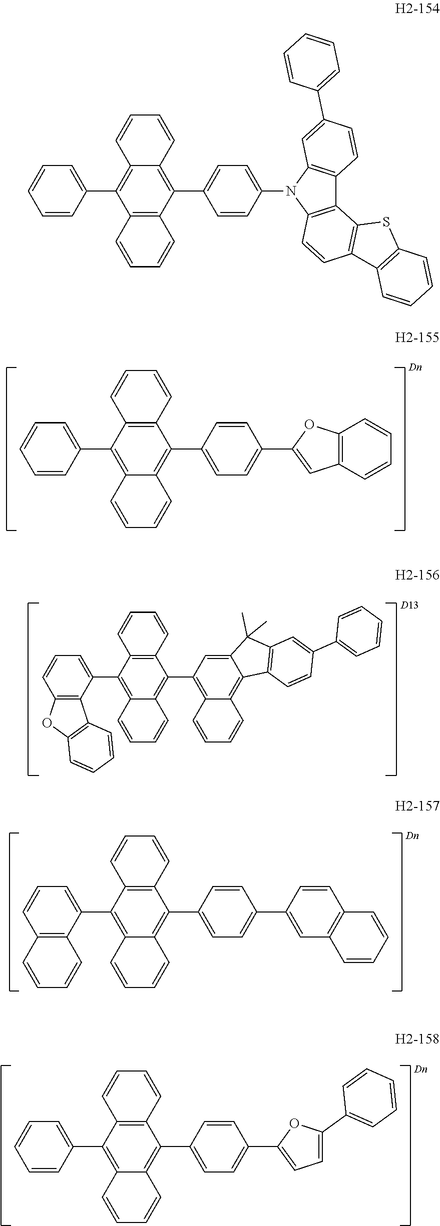 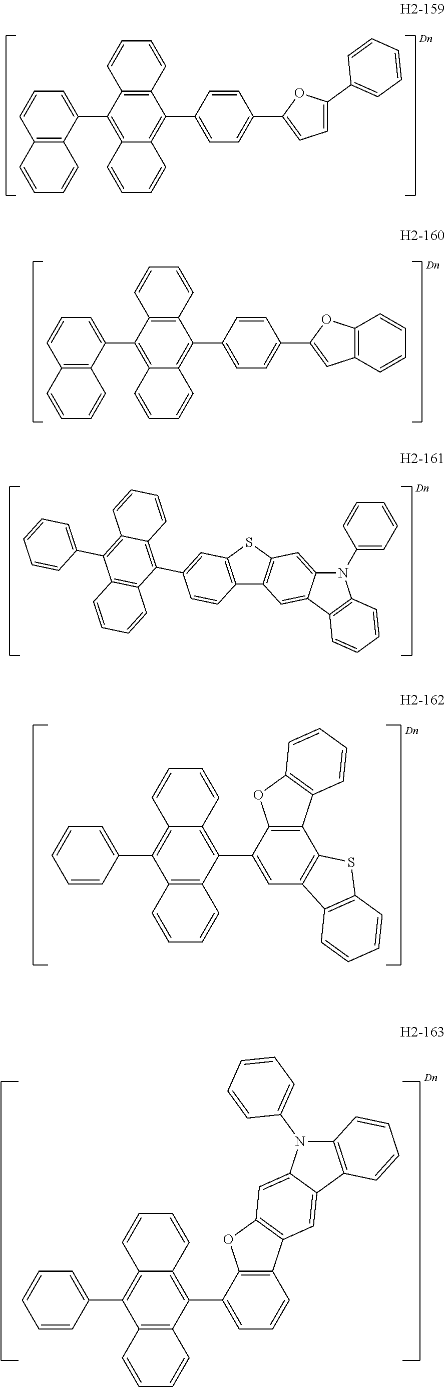 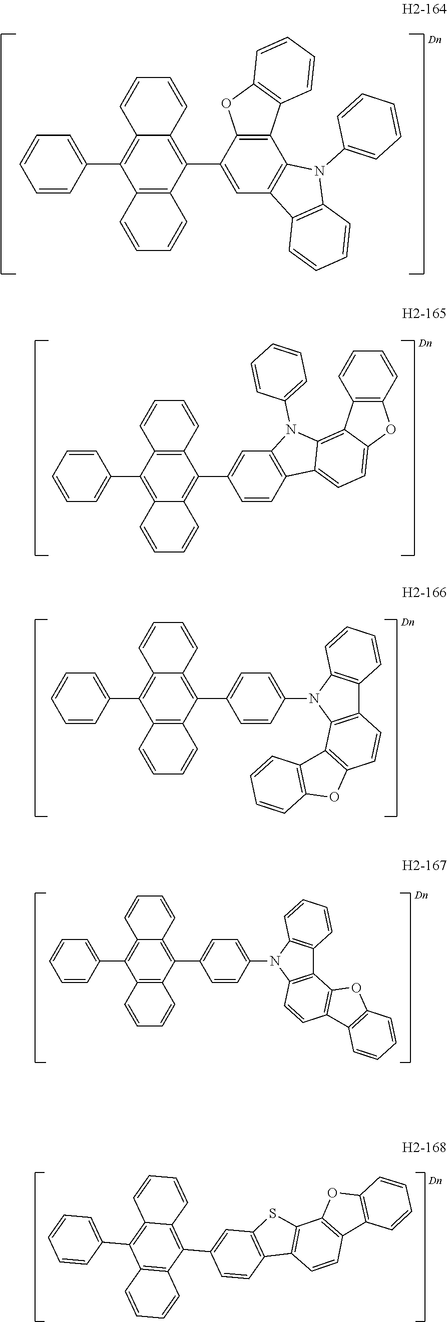 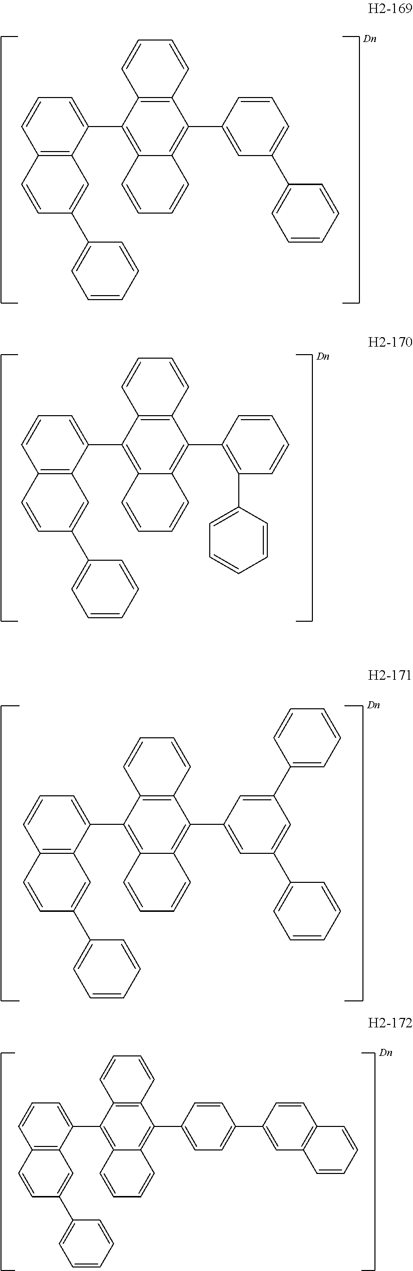 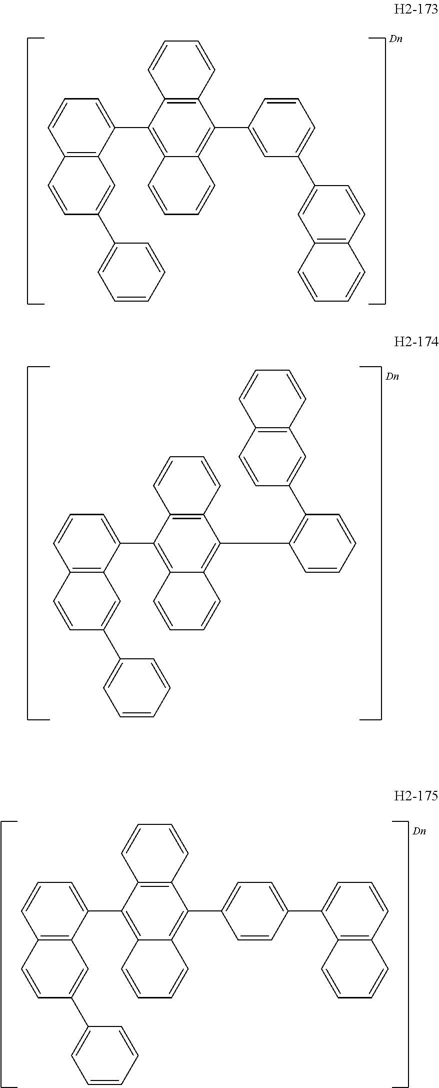 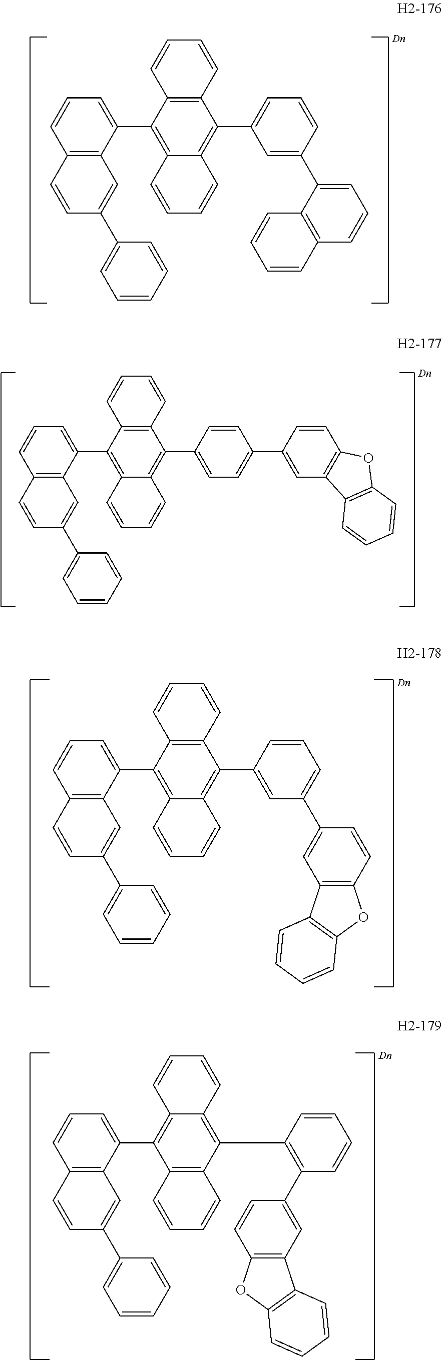 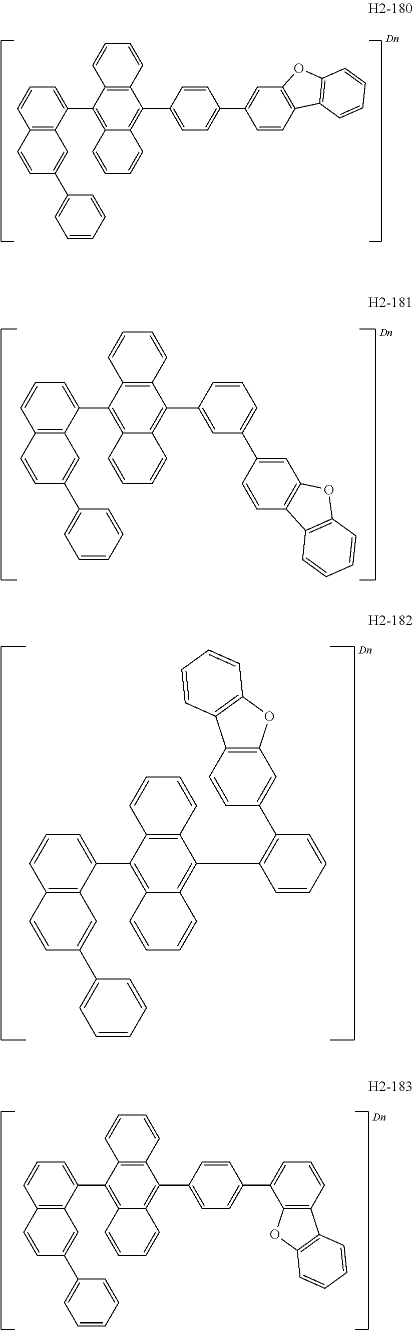 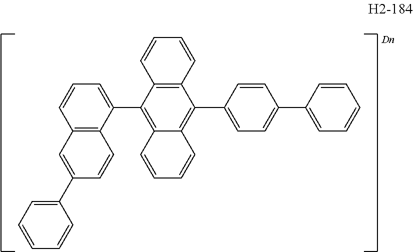 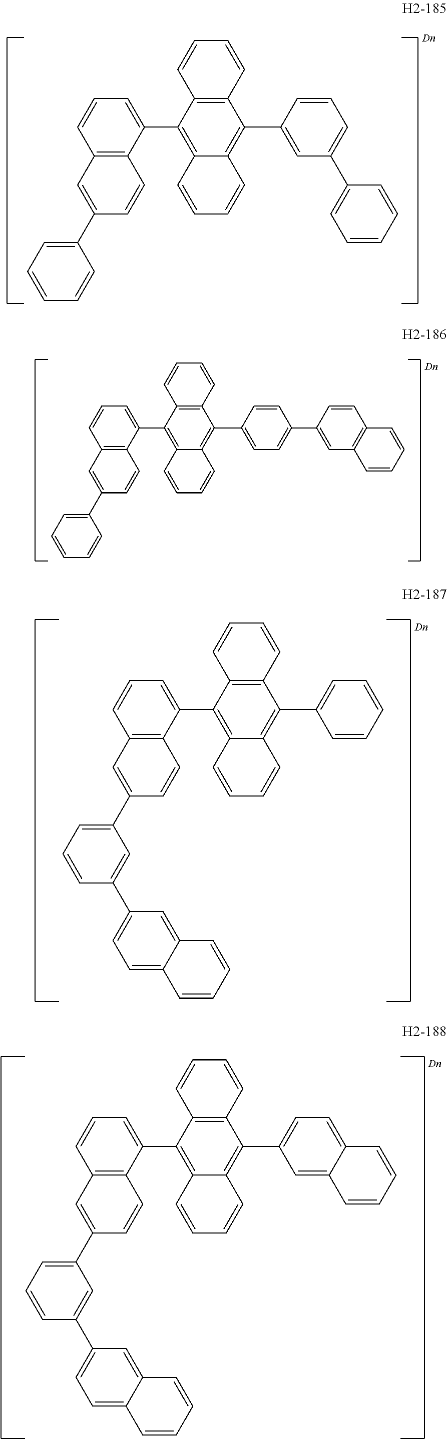 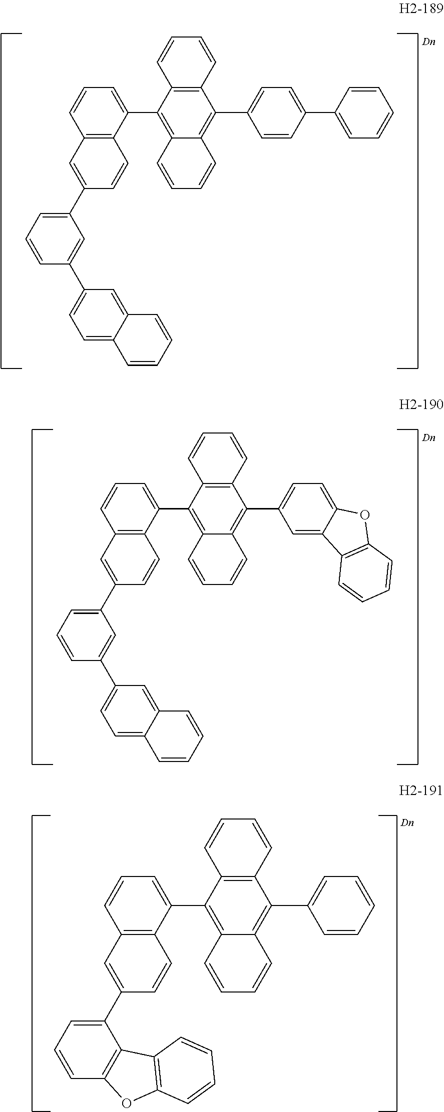 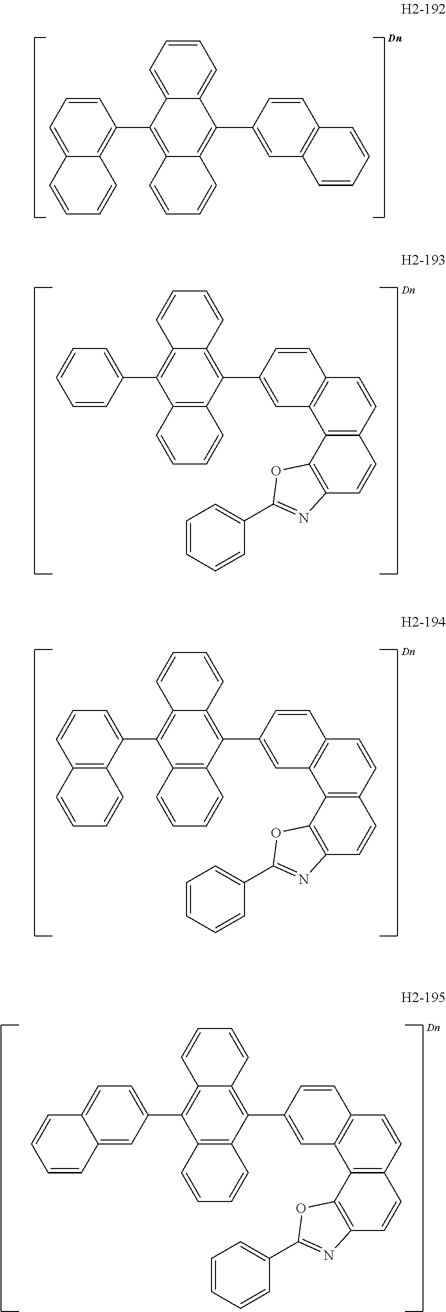 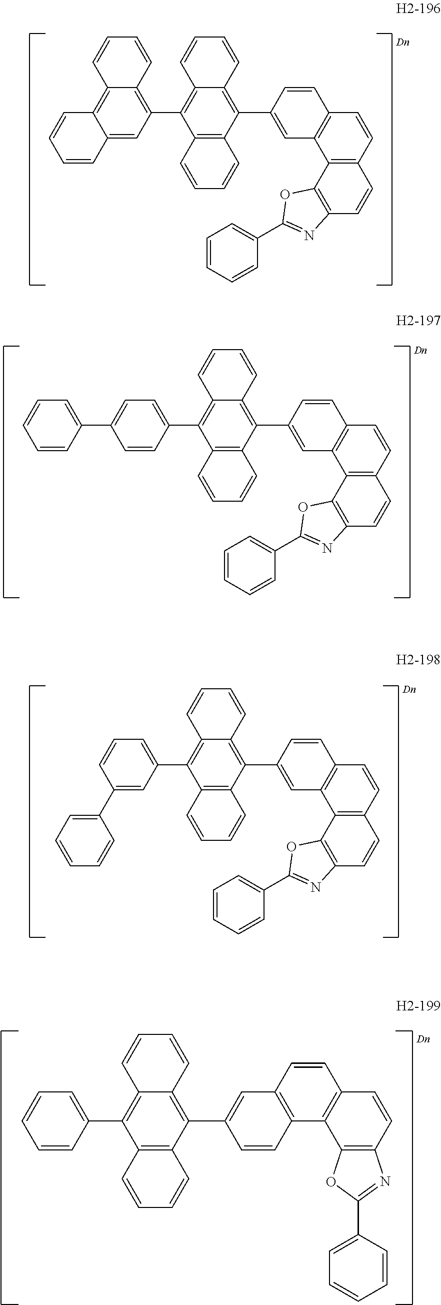 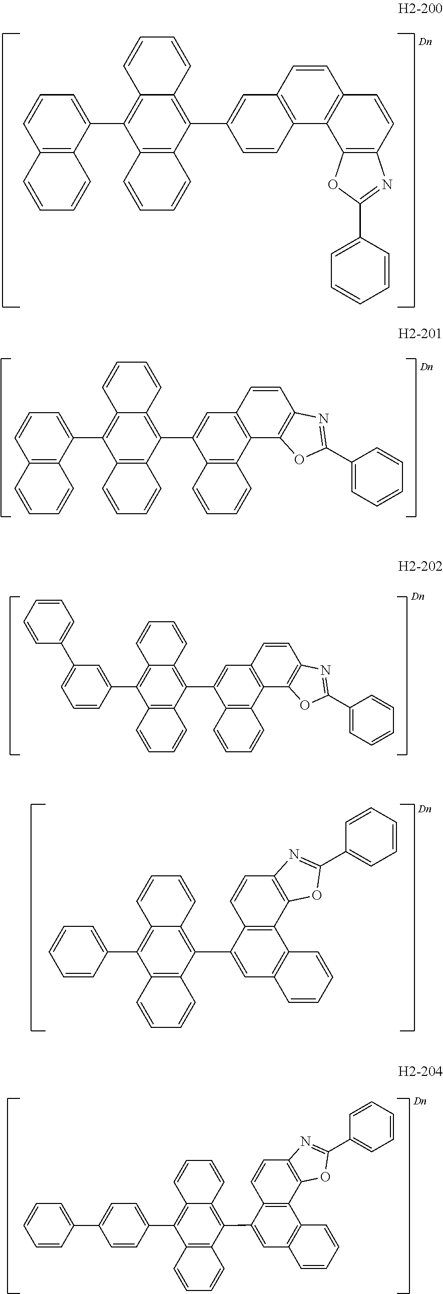 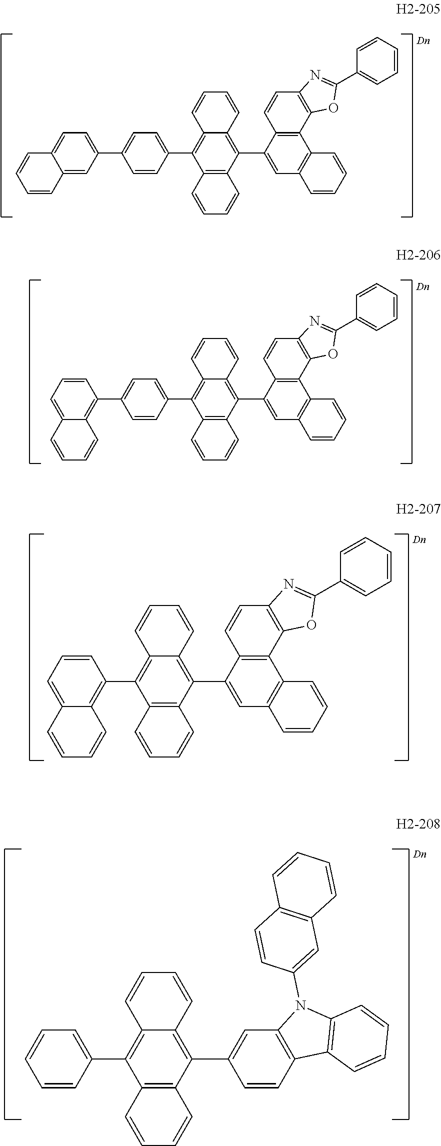 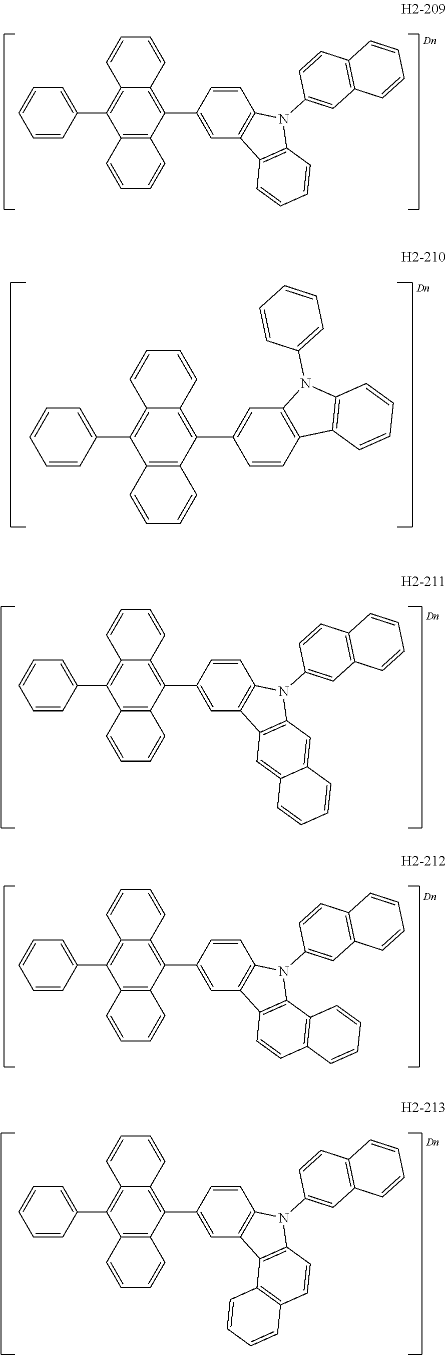 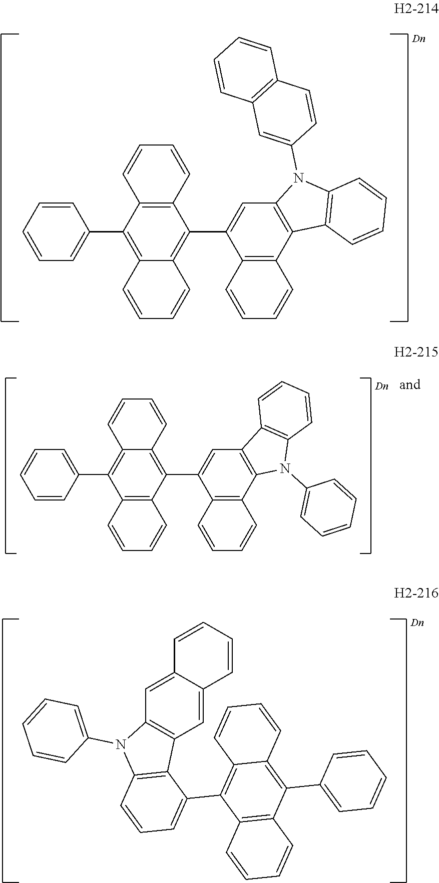
wherein
Dn means that n number of hydrogens is replaced with deuterium, wherein n represents an integer of 1 to 50.

6. The organic electroluminescent device, comprising a plurality of host materials according to claim 1.

7. A composition, comprising at least one first compound represented by formula 1 according to claim 1 and at least one second compound including an anthracene-based moiety.

8. The composition according to claim 7, wherein the second compound is a compound represented by the following formula 11: 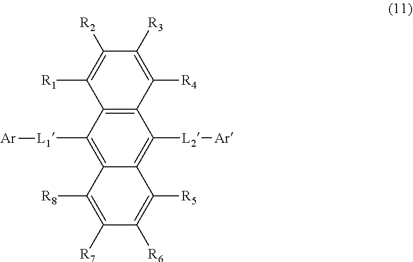
wherein
L₁′ and L₂′ each independently represent a single bond or a substituted or unsubstituted (C6-C30)arylene;
Ar and Ar′ each independently represent hydrogen, deuterium, a substituted or unsubstituted (C3-C30)cycloalkyl, a substituted or unsubstituted tri(C1-C30)alkylsilyl, a substituted or unsubstituted di(C1-C30)alkyl(C6-C30)arylsilyl, or a substituted or unsubstituted (C6-C30)aryl; and
R₁ to R₈ each independently represent hydrogen, deuterium, halogen, cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring of (C3-C30) aliphatic ring and (C6-C30) aromatic ring, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino.

9. The composition according to claim 8, wherein the compound represented by formula 11 is selected from the following compounds: 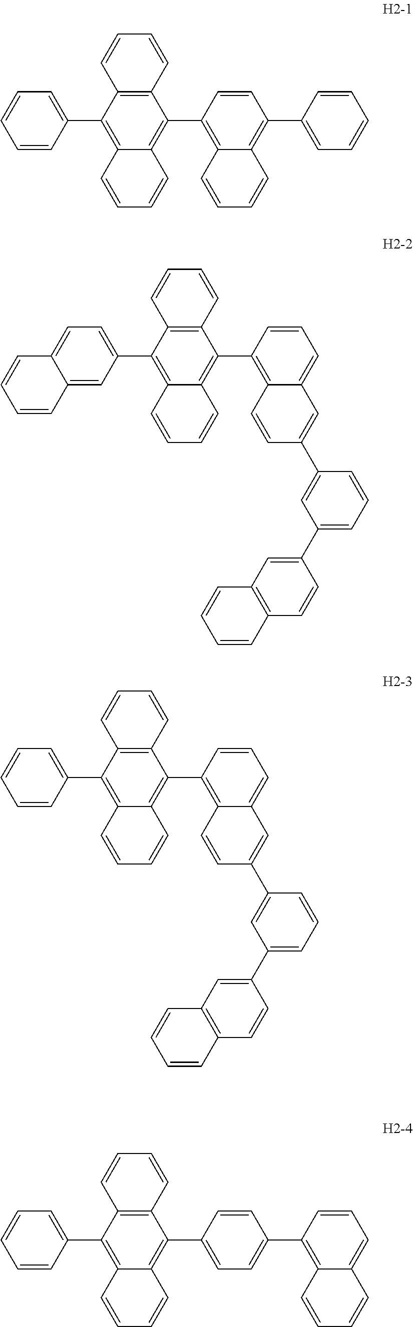 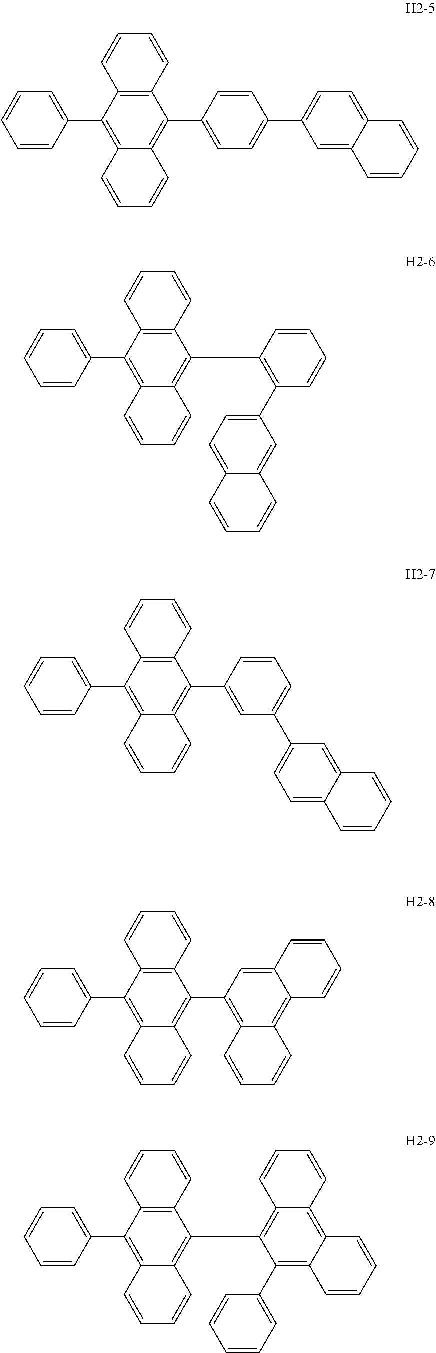 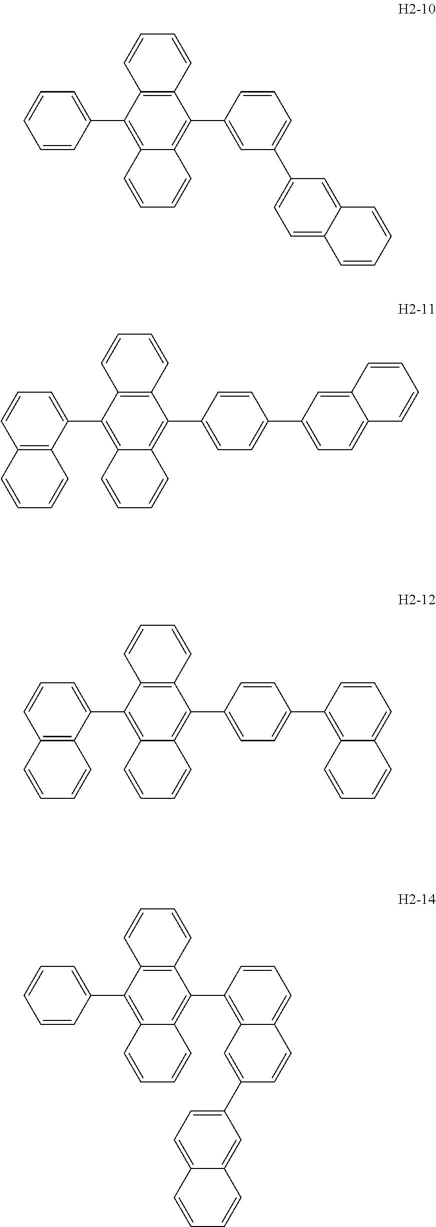 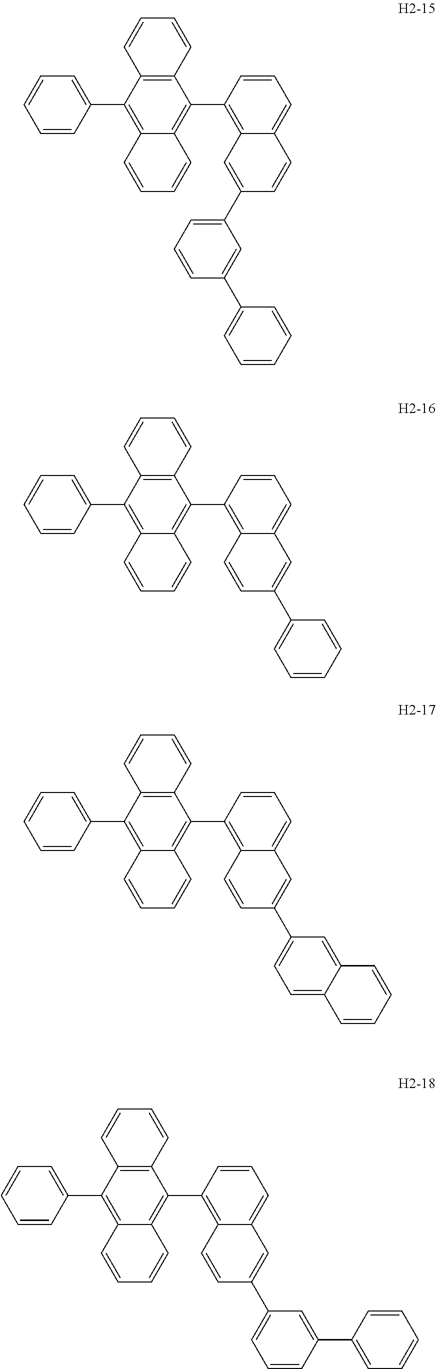 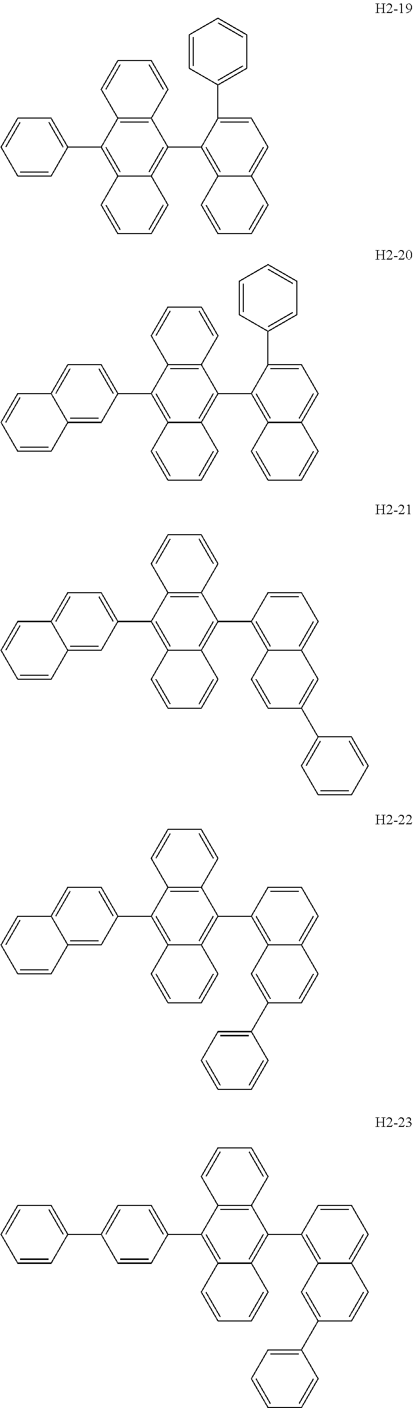 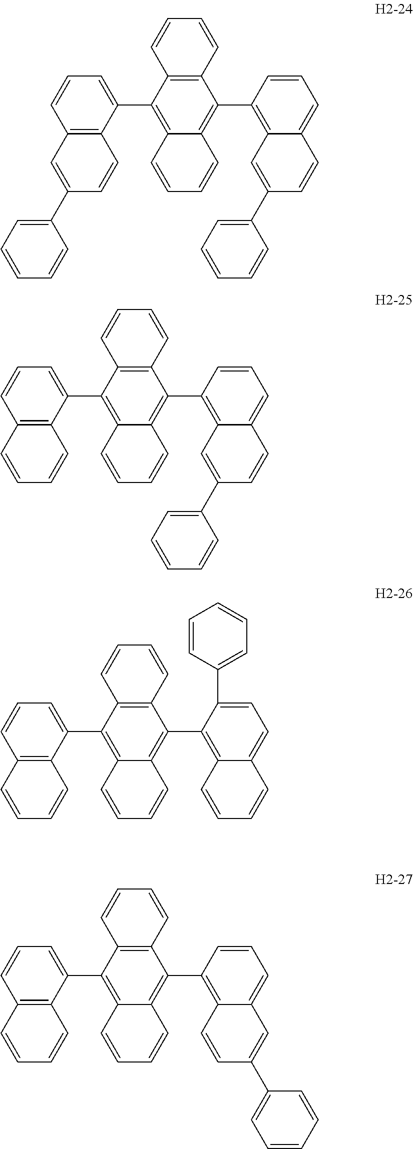 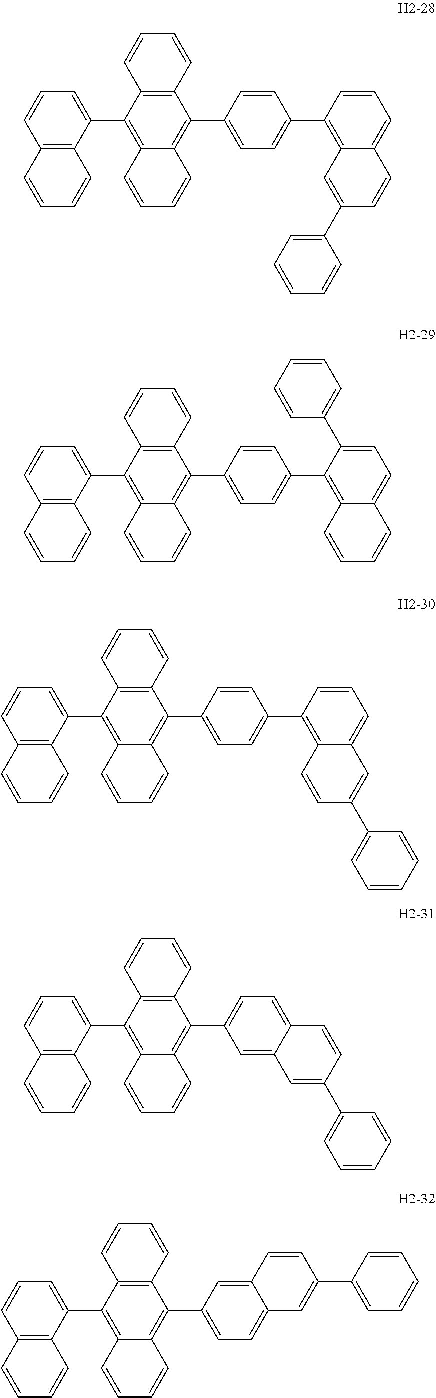 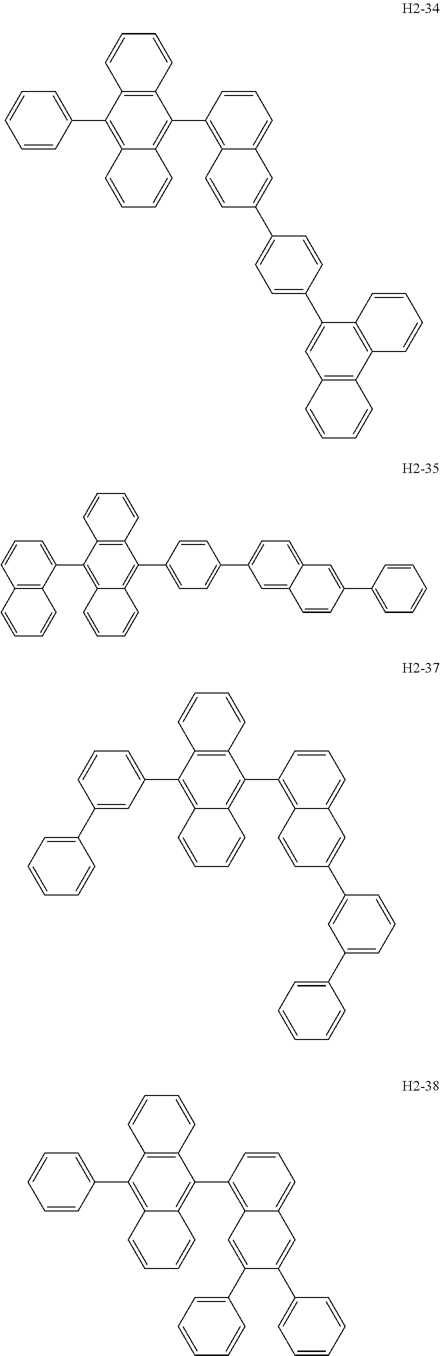 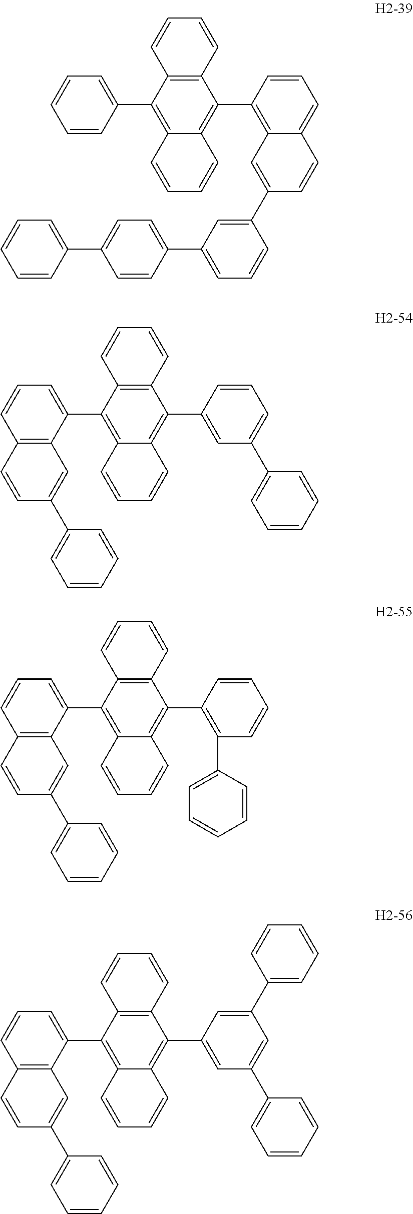 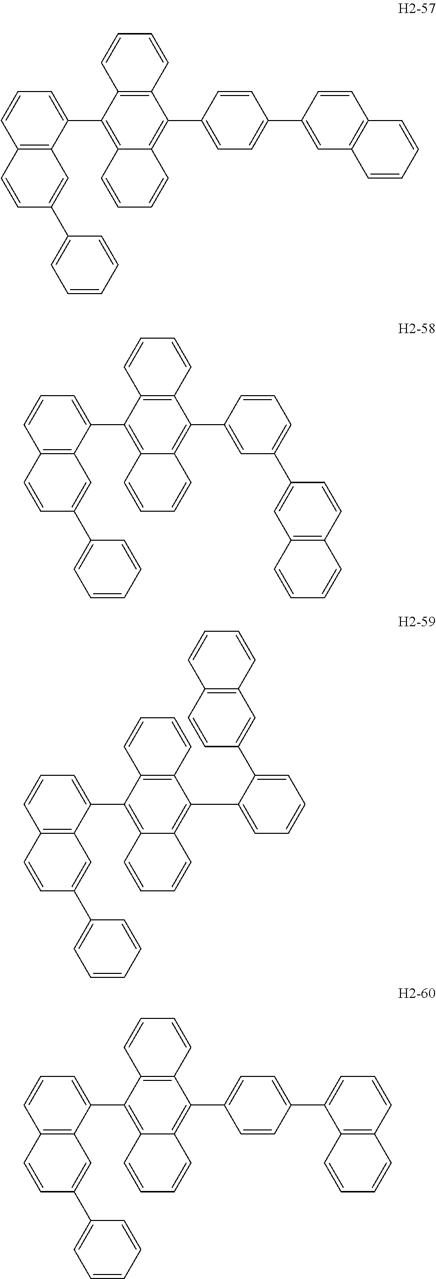 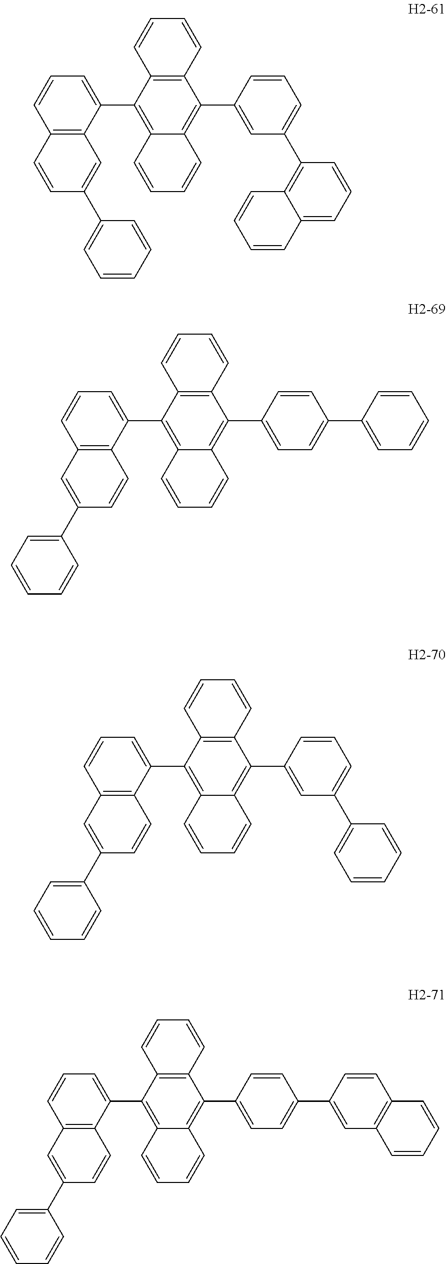 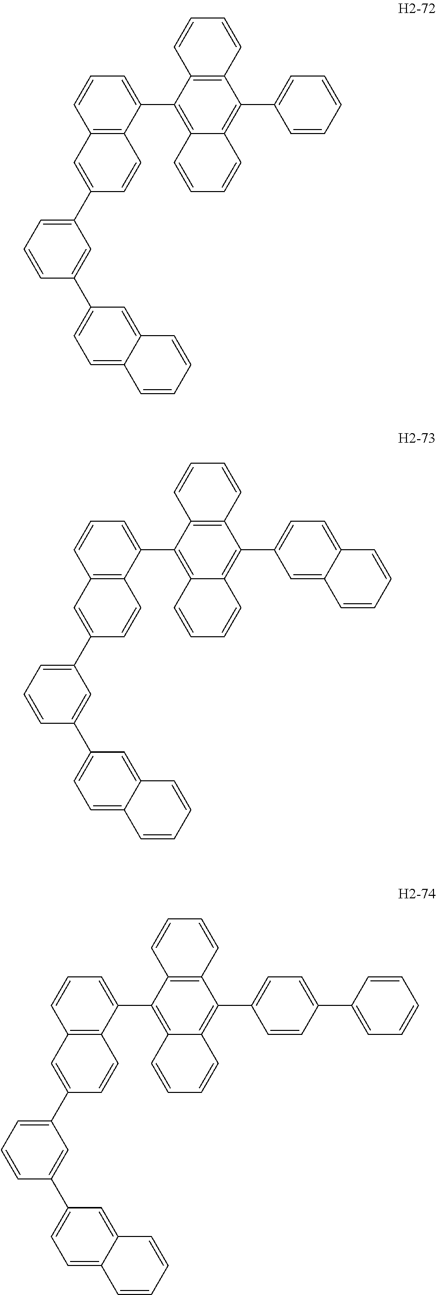 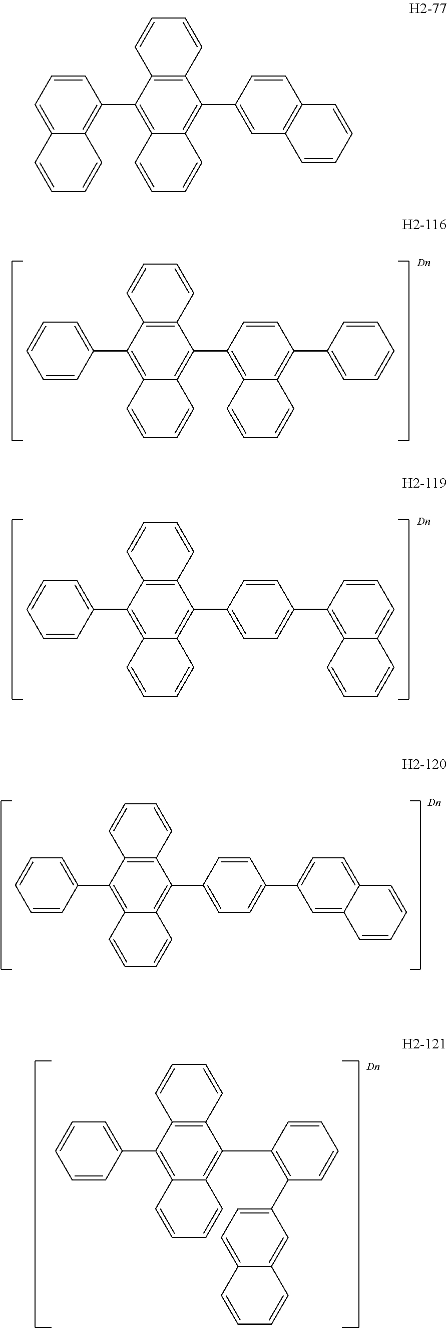 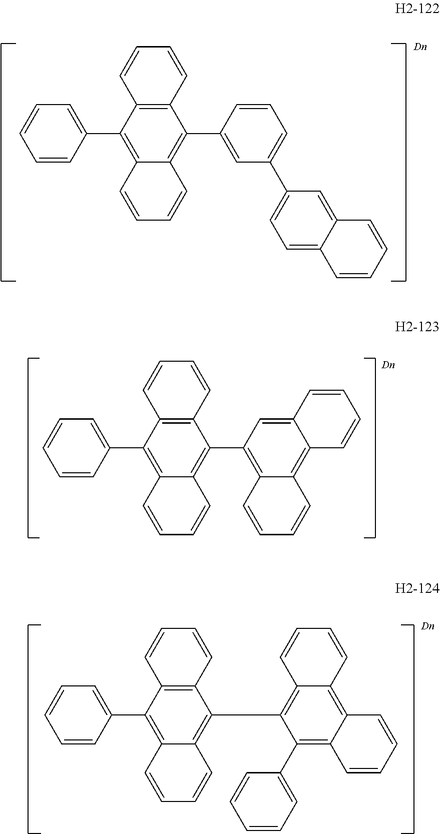 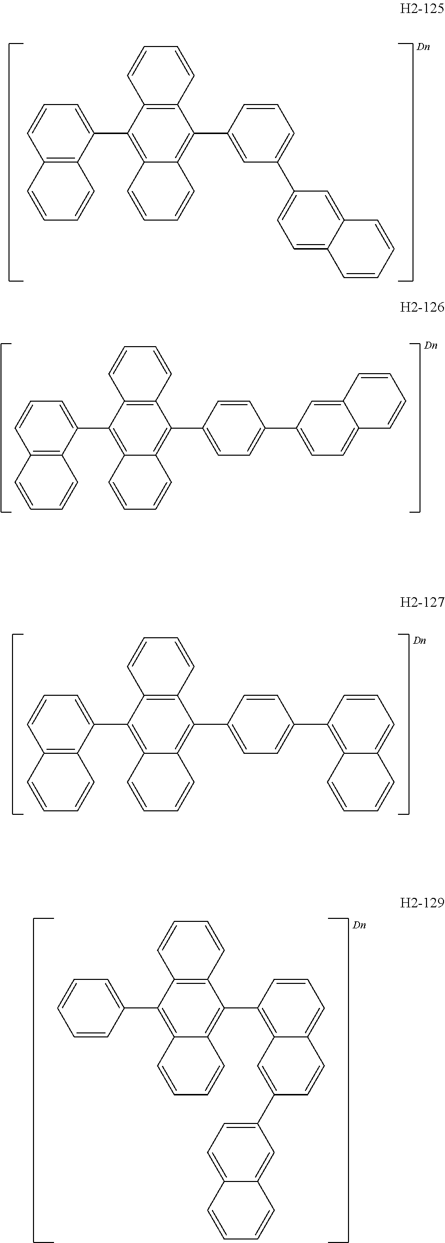 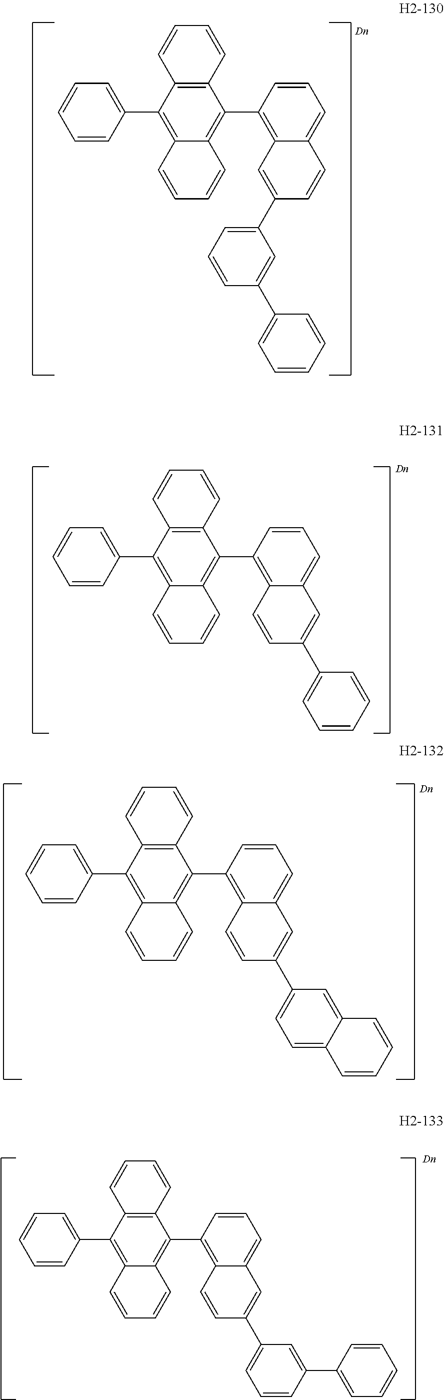 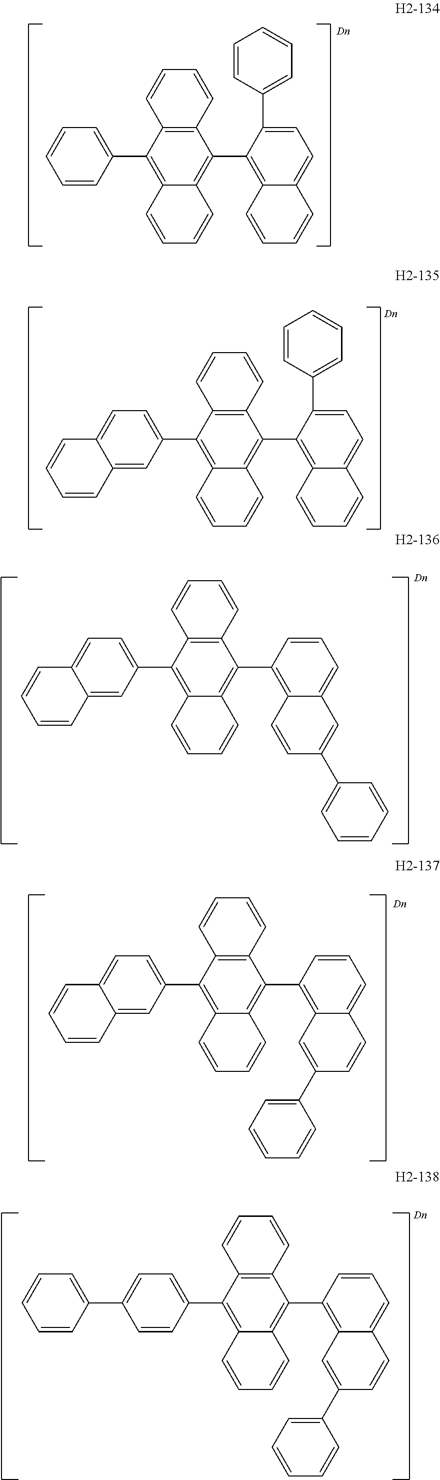 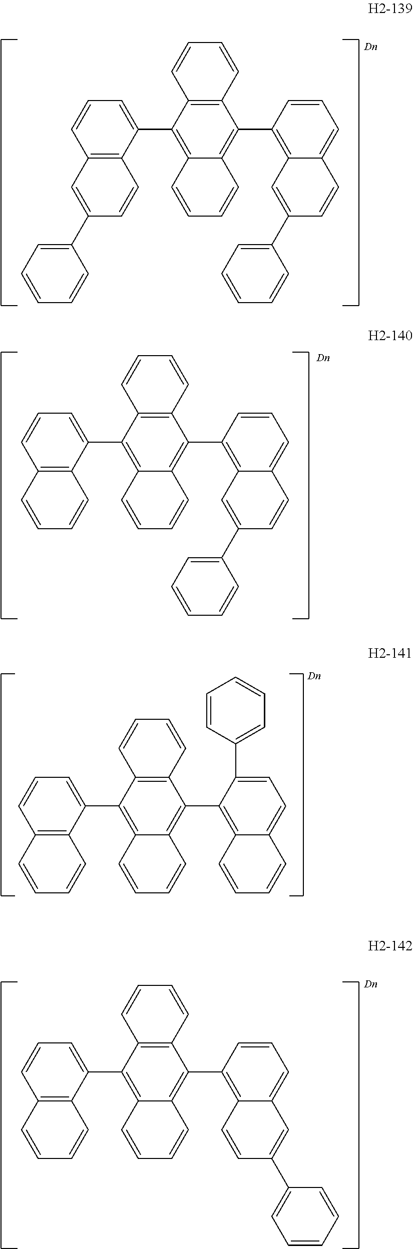 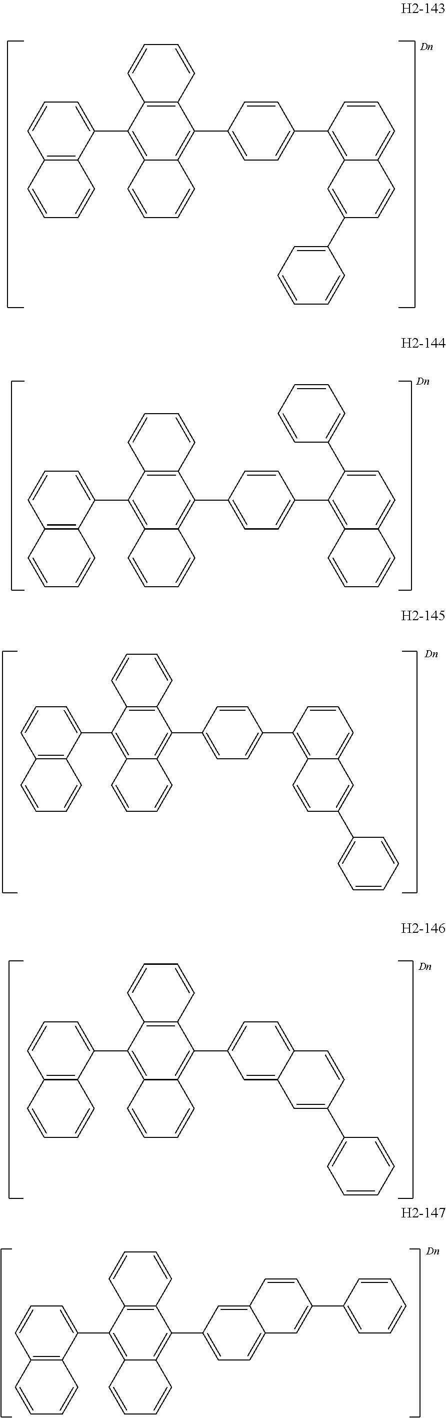 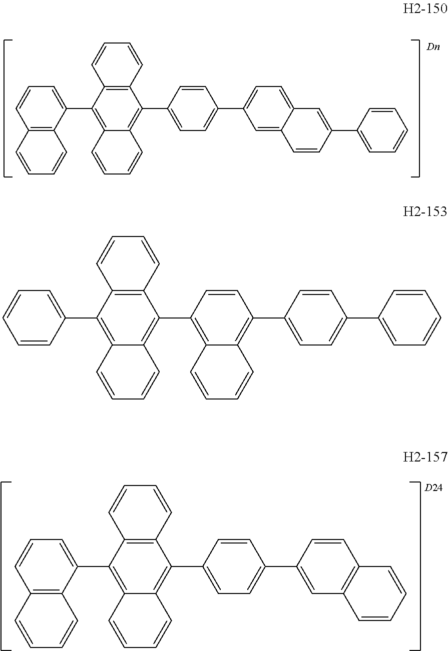 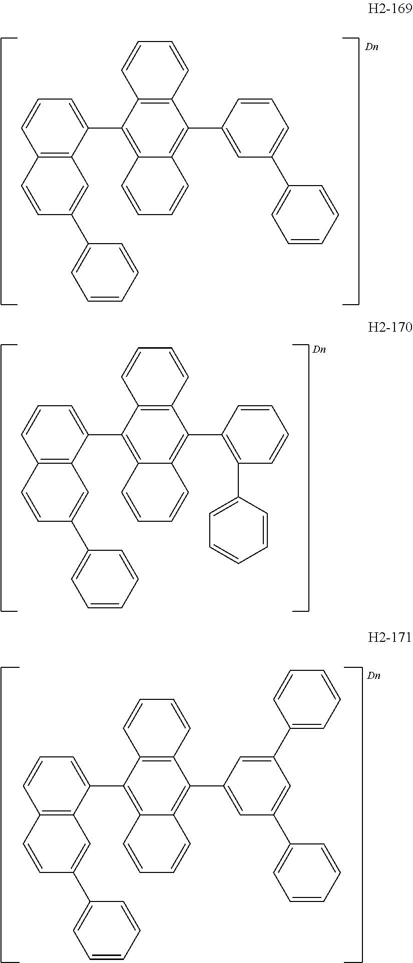 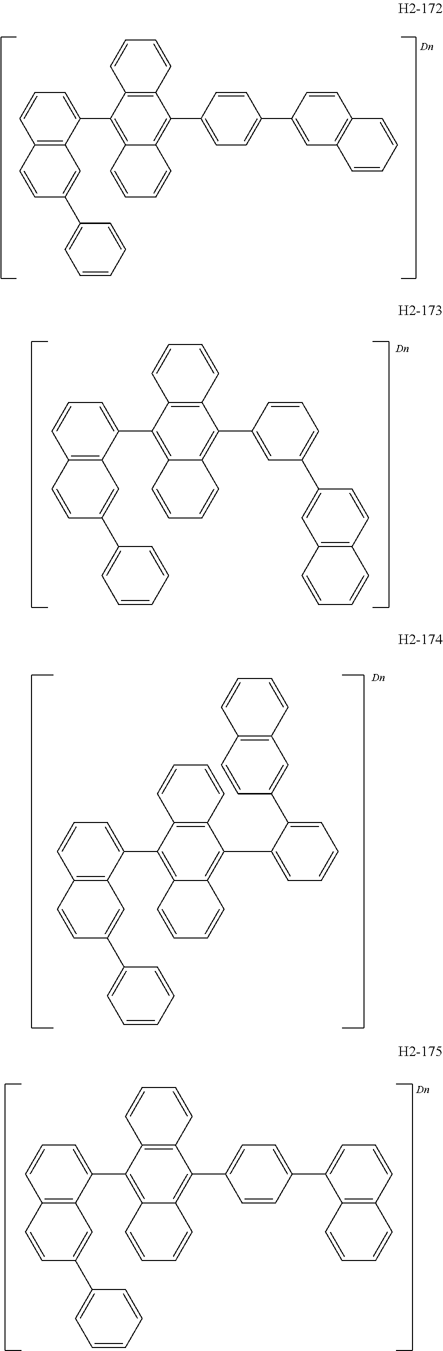 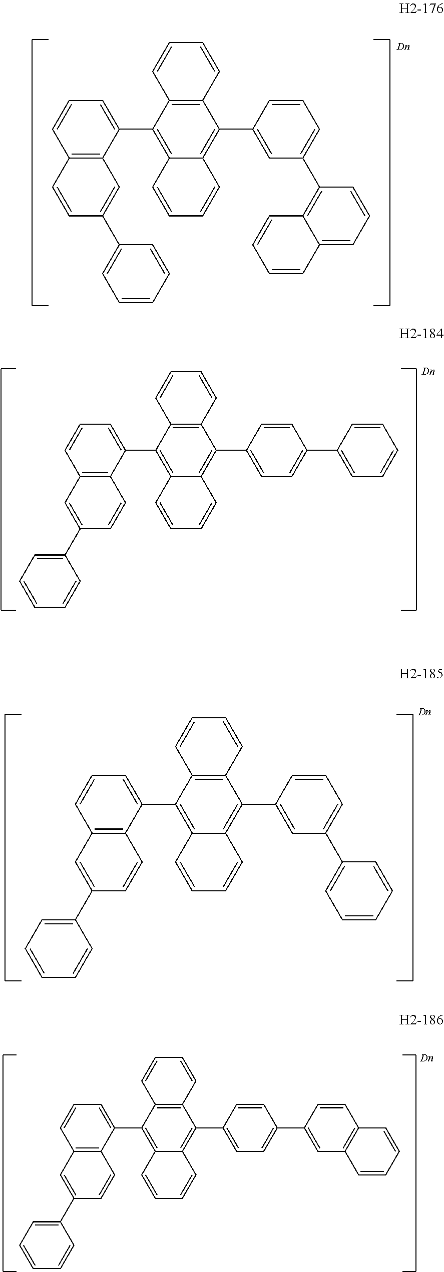 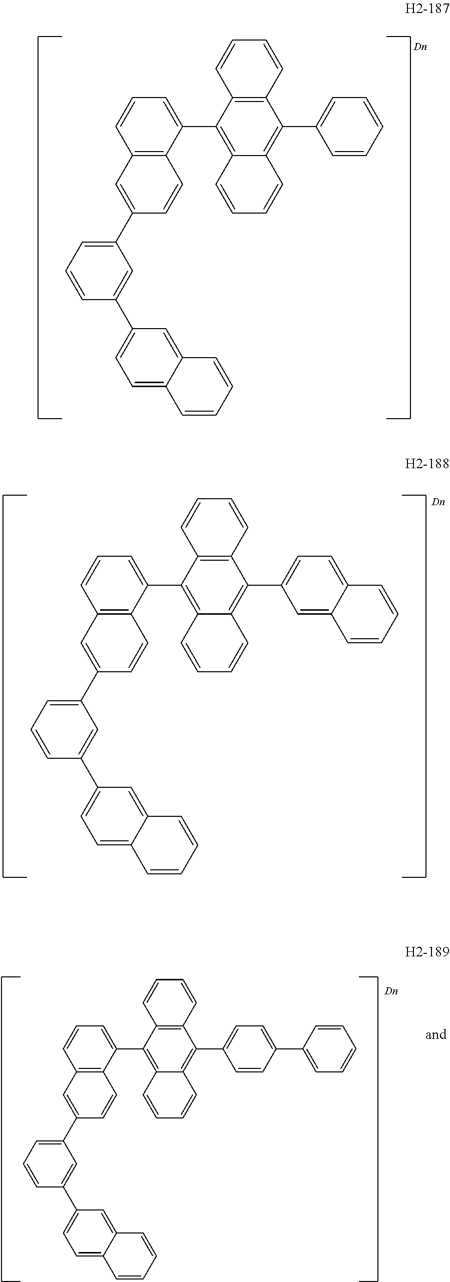 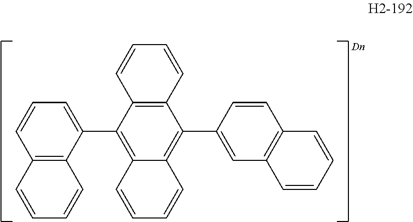
wherein
Dn means that n number of hydrogens is replaced with deuterium, wherein n represents an integer of 1 to 50.

10. An organic electroluminescent device comprising a first electrode; a second electrode; and at least one light-emitting layer between the first electrode and the second electrode, wherein the at least one light-emitting layer comprises a composition according to claim 7.
